(19) United States
(12) Patent Application Publication
(10) Pub. No.: US 2023/0263051 A1
(43) Pub. Date: Aug. 17, 2023

(54) PLURALITY OF HOST MATERIALS AND ORGANIC ELECTROLUMINESCENT DEVICE COMPRISING THE SAME

(71) Applicant: ROHM AND HAAS ELECTRONIC MATERIALS KOREA LTD., Chungcheongnam-do (KR)

(72) Inventors: So-Young JUNG, Gyeonggi-do (KR); Su-Hyun LEE, Gyeonggi-do (KR); Chi-Sik KIM, Gyeonggi-do (KR); Sang-Hee CHO, Gyeonggi-do (KR); Jin-Ri HONG, Gyeonggi-do (KR); Hee-Ryong KANG, Gyeonggi-do (KR); Young-Jae KIM, Gyeonggi-do (KR)

(21) Appl. No.: 18/163,613

(22) Filed: Feb. 2, 2023

(30) Foreign Application Priority Data
Feb. 11, 2022 (KR) 10-2022-0017958
Jan. 11, 2023 (KR) 10-2023-0004503

(51) Int. Cl. H10K 85/60; H10K 50/11

(52) U.S. Cl. CPC H10K 85/636; H10K 85/657; H10K 85/6574; H10K 85/6576; H10K 85/654; H10K 85/622; H10K 85/615; H10K 85/6572; H10K 85/623; H10K 50/11; H10K 2102/301

(57) ABSTRACT

The present disclosure relates to a plurality of host materials comprising at least one first host compound represented by formula 1 and at least one second host compound represented by formula 2 and an organic electroluminescent device comprising the same. By comprising the specific combination of compounds according to the present disclosure as the host materials, an organic electroluminescent device having low driving voltage, high luminous efficiency, and/or significantly improved lifespan characteristics can be provided.

### TECHNICAL FIELD

The present disclosure relates to a plurality of host materials and an organic electroluminescent device comprising the same.

### BACKGROUND ART

The TPD/Alq₃ bilayer small molecule organic electroluminescent device (OLED) with green-emission, which is constituted with a light-emitting layer and a charge transport layer, was first developed by Tang, et al., of Eastman Kodak in 1987. Thereafter, the studies on an OLED have been rapidly effected, and OLEDs have been commercialized. At present, an organic electroluminescent device mainly includes phosphorescent materials having excellent luminous efficiency in panel realization. In many applications such as TVs and lightings, OLED lifespan is insufficient, and high efficiency of OLEDs is still required. Typically, the higher the luminance of an OLED corresponds to a shorter lifespan of the OLED. Accordingly, for prolonged use and high resolution of the display, an OLED having high luminous efficiency and/or long lifespan is necessary.

Korean Patent Application Laid-Open No. 2017-0022865 and CN Patent Application Laid-Open No. 113214237 A disclose a new organic electroluminescent material. However, said references do not specifically disclose a specific combination of host materials as described in the present disclosure. In addition, there is still a need to develop a light-emitting material with more improved performance, such as higher luminous efficiency and/or improved lifespan characteristics by combining the compounds described in said references with a specific compound.

### DISCLOSURE OF THE INVENTION

### Problems to be Solved

The object of the present disclosure is firstly, to provide a plurality of host materials which is able to produce an organic electroluminescent device having low driving voltage, high luminous efficiency, and long lifespan characteristics, and secondly, to provide an organic electroluminescent device with low driving voltage, high luminous efficiency, and/or long lifespan characteristics by comprising a specific combination of compounds according to the present disclosure as host materials.

### Solution to Problems

As a result of intensive studies to solve the technical problem above, the present inventors found that the aforementioned objective can be achieved by a plurality of host materials comprising at least one first host compound represented by the following formula 1 and at least one second host compound represented by the following formula 2, which is different from the formula 1, so that the present invention was completed.

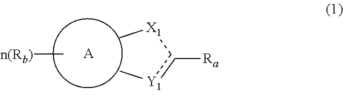

in formula 1,
ring A represents a substituted or unsubstituted aromatic ring in which 4 benzene rings are sequentially fused;
X₁ and Y₁ each independently represent, —N═, —NR_{c}—, —O— or —S—; provided that any one of X₁ and Y₁ is —N═, and the other of X₁ and Y₁ is —NR_{c}—, —O— or —S—;
Rₐ and R_{c} each independently represent, a substituted or unsubstituted (C6-C30)aryl or a substituted or unsubstituted (3- to 30-membered)heteroaryl;
R_{b} represents hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted fused ring of (C3-C30) aliphatic ring and (C6-C30) aromatic ring, —SiR′₁R′₂R′₃, or -L′₁—NR′₁R′₂; provided that at least one of R_{b} is (are) -L′₁—NR′₁R′₂;
L′₁ represents a single bond, a substituted or unsubstituted (C6-C30)arylene, or a substituted or unsubstituted (3- to 30-membered)heteroarylene;
R′₁ to R′₃ each independently represent, a substituted or unsubstituted (C1-C30)alkyl, a substituted or unsubstituted (C2-C30)alkenyl, a substituted or unsubstituted (C6-C30)aryl, a substituted or unsubstituted (3- to 30-membered)heteroaryl, or a substituted or unsubstituted fused ring of (C3-C30) aliphatic ring and (C6-C30) aromatic ring; and
n represents an integer of 1 to 10, when n is an integer of 2 or more, each of R_{b} may be the same or different;

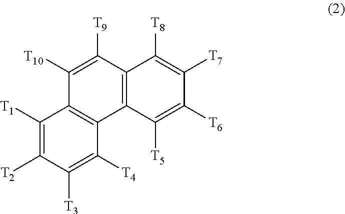

in formula 2,
T₅ and T₆ are linked to each other to form a ring of the following formula 3; or T₇ and Tₐ are linked to each other to form a ring of the following formula 3; or T₅ and T₆ are linked to each other to form a ring of the following formula 3, while T₇ and Tₐ are linked to each other to form a ring of the following formula 3; or T₅ and T₆ are linked to each other to form a ring of the following formula 3, while T₉ and T₁₀ are linked to each other to form a ring of the following formula 3-1; or T₇ and Tₐ are linked to each other to form a ring of the following formula 3, while T₉ and T₁₀ are linked to each other to form a ring of the following formula 3-1; or T₇ and Tₐ are linked to each other to form a ring of the following formula 3, while T₁ and T₂ are linked to each other to form a ring of the following formula 3-1; or T₁ and T₂ are linked to each other to form a ring of the following formula 3, while T₅ and T₆ are linked to each other to form a ring of the following formula 3-1; or T₉ and T₁₀ are linked to each other to form a ring of the following formula 3, while T₁ and T₂ are linked to each other to form a ring of the following formula 3-1; or T₅ and T₆ are linked to each other to form a ring of the following formula 3, while T₃ and T₄ are linked to each other to form a ring of the following formula 3-1;

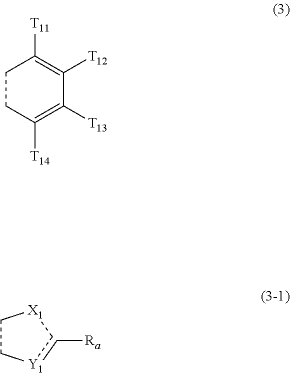

in formulas 2, 3, and 3-1,
T₁ to T₁₄, and T₁ to T₁₀ that do not form a ring, each independently represent, hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted fused ring of (C3-C30) aliphatic ring and (C6-C30) aromatic ring, —SiR₁₁R₁₂R₁₃, —NR₁₄R₁₅, or -L₂-Ar₂; provided that at least one of T₁ to T₁₄ is (are) -L₂-Ar₂;
X₁ and Y₁ each independently represent, —N═, —NR_{c}—, —O— or —S—; provided that any one of X₁ and Y₁ is —N═, and the other of X₁ and Y₁ is —NR_{c}—, —O— or —S—;
Rₐ and R_{c} each independently represent, a substituted or unsubstituted (C6-C30)aryl or a substituted or unsubstituted (3- to 30-membered)heteroaryl;
L₂ represents a single bond, a substituted or unsubstituted (C6-C30)arylene, or a substituted or unsubstituted (3- to 30-membered)heteroarylene;
Ar₂ represents a substituted or unsubstituted (C6-C30)aryl or a substituted or unsubstituted (3- to 30-membered)heteroaryl;
R₁₁ to R₁₅ each independently represent, a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl; and
[symbol] represents a fusing site with the formula 2.

### Advantageous Effects of Invention

By comprising the specific combination of the compounds according to the present disclosure as host materials, an organic electroluminescent device having low driving voltage, high luminous characteristics, and/or significantly improved lifespan characteristics can be provided.

### EMBODIMENTS OF THE INVENTION

Hereinafter, the present disclosure will be described in detail. However, the following description is intended to explain the invention, and is not meant in any way to restrict the scope of the invention.

The present disclosure relates to a plurality of host materials comprising at least one first host compound represented by formula 1 and at least one second host compound represented by formula 2, which is different from the formula 1, and an organic electroluminescent device comprising the host materials.

The present disclosure relates to an organic electroluminescent compound represented by formula 1′ and an organic electroluminescent material comprising the same, and an organic electroluminescent device.

The term “organic electroluminescent compound” in the present disclosure means a compound that may be used in an organic electroluminescent device, and may be comprised in any material layer constituting an organic electroluminescent device, as necessary.

Herein, the term “organic electroluminescent material” means a material that may be used in an organic electroluminescent device, and may comprise at least one compound. The organic electroluminescent material may be comprised in any layer constituting an organic electroluminescent device, as necessary. For example, the organic electroluminescent material may be a hole injection material, a hole transport material, a hole auxiliary material, a light-emitting auxiliary material, an electron blocking material, a light-emitting material (containing host and dopant materials), an electron buffer material, a hole blocking material, an electron transport material, or an electron injection material, etc.

The term “a plurality of organic electroluminescent materials” in the present disclosure means an organic electroluminescent material comprising a combination of at least two compounds, which may be comprised in any layer constituting an organic electroluminescent device. It may mean both a material before being comprised in an organic electroluminescent device (for example, before vapor deposition) and a material after being comprised in an organic electroluminescent device (for example, after vapor deposition). For example, a plurality of organic electroluminescent materials may be a combination of at least two compounds, which may be comprised in at least one layer of a hole injection layer, a hole transport layer, a hole auxiliary layer, a light-emitting auxiliary layer, an electron blocking layer, a light-emitting layer, an electron buffer layer, a hole blocking layer, an electron transport layer, and an electron injection layer. Such at least two compounds may be comprised in the same layer or in different layers, and may be mixture-evaporated or co-evaporated, or may be individually evaporated.

Herein, the term “a plurality of host materials” means an organic electroluminescent material comprising a combination of at least two host materials. It may mean both a material before being comprised in an organic electroluminescent device (e.g., before vapor deposition) and a material after being comprised in an organic electroluminescent device (e.g., after vapor deposition). A plurality of host materials of the present disclosure may be comprised in any light-emitting layer constituting an organic electroluminescent device. The at least two compounds comprised in a plurality of host materials may be comprised together in one light-emitting layer, or may each be comprised in separate light-emitting layers. When at least two compounds are comprised in one light-emitting layer, the at least two compounds may be mixture-evaporated to form a layer or may be individually and simultaneously co-evaporated to form a layer.

Herein, “(C1-C30)alkyl” is meant to be a linear or branched alkyl having 1 to 30 carbon atoms constituting the chain, in which the number of carbon atoms is preferably 1 to 20, and more preferably 1 to 10. The above alkyl may include methyl, ethyl, n-propyl, isopropyl, n-butyl, isobutyl, tert-butyl, sec-butyl, etc. Herein, the term “(C3-C30)cycloalkyl” is meant to be a mono- or polycyclic hydrocarbon having 3 to 30 ring backbone carbon atoms, in which the number of carbon atoms is preferably 3 to 20, and more preferably 3 to 7. The above cycloalkyl may include cyclopropyl, cyclobutyl, cyclopentyl, cyclohexyl, cyclopentylmethyl, cyclohexylmethyl, etc. Herein, “(3- to 7-membered)heterocycloalkyl” is meant to be a cycloalkyl having 3 to 7 ring backbone atoms and including at least one heteroatoms selected from the group consisting of B, N, O, S, Si, and P, preferably the group consisting of O, S and N, in which the number of the ring backbone carbon atoms is preferably 5 to 7, for example, tetrahydrofuran, pyrrolidine, thiolane, tetrahydropyran, etc. Herein, “(C6-C30)aryl(ene)” is a monocyclic or fused ring radical derived from an aromatic hydrocarbon having 6 to 30 ring backbone carbon atoms, in which the number of the ring backbone carbon atoms is preferably 6 to 20, more preferably 6 to 15, may be partially saturated, and may include a spiro structure. Examples of the aryl specifically may be phenyl, biphenyl, terphenyl, quaterphenyl, naphthyl, binaphthyl, phenylnaphthyl, naphthylphenyl, fluorenyl, phenylfluorenyl, dimethylfluorenyl, diphenylfluorenyl, benzofluorenyl, diphenylbenzofluorenyl, dibenzofluorenyl, phenanthrenyl, benzophenanthrenyl, phenylphenanthrenyl, anthracenyl, benzanthracenyl, indenyl, triphenylenyl, pyrenyl, tetracenyl, perylenyl, chrysenyl, benzochrysenyl, naphthacenyl, fluoranthenyl, benzofluoranthenyl, tolyl, xylyl, mesityl, cumenyl, spiro[fluoren-fluoren]yl, spiro[fluoren-benzofluoren]yl, azulenyl, tetramethyl-dihydrophenanthrenyl, etc. More specifically, the aryl may be o-tolyl, m-tolyl, p-tolyl, 2,3-xylyl, 3,4-xylyl, 2,5-xylyl, mesityl, o-cumenyl, m-cumenyl, p-cumenyl, p-t-butylphenyl, p-(2-phenylpropyl)phenyl, 4′-methylbiphenyl, 4″-t-butyl-p-terphenyl-4-yl, o-biphenyl, m-biphenyl, p-biphenyl, o-terphenyl, m-terphenyl-4-yl, m-terphenyl-3-yl, m-terphenyl-2-yl, p-terphenyl-4-yl, p-terphenyl-3-yl, p-terphenyl-2-yl, m-quaterphenyl, 1-naphthyl, 2-naphthyl, 1-fluorenyl, 2-fluorenyl, 3-fluorenyl, 4-fluorenyl, 9-fluorenyl, 9,9-dimethyl-1-fluorenyl, 9,9-dimethyl-2-fluorenyl, 9,9-dimethyl-3-fluorenyl, 9,9-dimethyl-4-fluorenyl, 9,9-diphenyl-1-fluorenyl, 9,9-diphenyl-2-fluorenyl, 9,9-diphenyl-3-fluorenyl, 9,9-diphenyl-4-fluorenyl, 1-anthryl, 2-anthryl, 9-anthryl, 1-phenanthryl, 2-phenanthryl, 3-phenanthryl, 4-phenanthryl, 9-phenanthryl, 1-chrysenyl, 2-chrysenyl, 3-chrysenyl, 4-chrysenyl, 5-chrysenyl, 6-chrysenyl, benzo[c]phenanthryl, benzo[g]chrysenyl, 1-triphenylenyl, 2-triphenylenyl, 3-triphenylenyl, 4-triphenylenyl, 3-fluoranthenyl, 4-fluoranthenyl, 8-fluoranthenyl, 9-fluoranthenyl, benzofluoranthenyl, 11,11-dimethyl-1-benzo[a]fluorenyl, 11,11-dimethyl-2-benzo[a]fluorenyl, 11,11-dimethyl-3-benzo[a]fluorenyl, 11,11-dimethyl-4-benzo[a]fluorenyl, 11,11-dimethyl-5-benzo[a]fluorenyl, 11,11-dimethyl-6-benzo[a]fluorenyl, 11,11-dimethyl-7-benzo[a]fluorenyl, 11,11-dimethyl-8-benzo[a]fluorenyl, 11,11-dimethyl-9-benzo[a]fluorenyl, 11,11-dimethyl-10-benzo[a]fluorenyl, 11,11-dimethyl-1-benzo[b]fluorenyl, 11,11-dimethyl-2-benzo[b]fluorenyl, 11,11-dimethyl-3-benzo[b]fluorenyl, 11,11-dimethyl-4-benzo[b]fluorenyl, 11,11-dimethyl-5-benzo[b]fluorenyl, 11,11-dimethyl-6-benzo[b]fluorenyl, 11,11-dimethyl-7-benzo[b]fluorenyl, 11,11-dimethyl-8-benzo[b]fluorenyl, 11,11-dimethyl-9-benzo[b]fluorenyl, 11,11-dimethyl-10-benzo[b]fluorenyl, 11,11-dimethyl-1-benzo[c]fluorenyl, 11,11-dimethyl-2-benzo[c]fluorenyl, 11,11-dimethyl-3-benzo[c]fluorenyl, 11,11-dimethyl-4-benzo[c]fluorenyl, 11,11-dimethyl-5-benzo[c]fluorenyl, 11,11-dimethyl-6-benzo[c]fluorenyl, 11,11-dimethyl-7-benzo[c]fluorenyl, 11,11-dimethyl-8-benzo[c]fluorenyl, 11,11-dimethyl-9-benzo[c]fluorenyl, 11,11-dimethyl-10-benzo[c]fluorenyl, 11,11-diphenyl-1-benzo[a]fluorenyl, 11,11-diphenyl-2-benzo[a]fluorenyl, 11,11-diphenyl-3-benzo[a]fluorenyl, 11,11-diphenyl-4-benzo[a]fluorenyl, 11,11-diphenyl-5-benzo[a]fluorenyl, 11,11-diphenyl-6-benzo[a]fluorenyl, 11,11-diphenyl-7-benzo[a]fluorenyl, 11,11-diphenyl-8-benzo[a]fluorenyl, 11,11-diphenyl-9-benzo[a]fluorenyl, 11,11-diphenyl-10-benzo[a]fluorenyl, 11,11-diphenyl-1-benzo[b]fluorenyl, 11,11-diphenyl-2-benzo[b]fluorenyl, 11,11-diphenyl-3-benzo[b]fluorenyl, 11,11-diphenyl-4-benzo[b]fluorenyl, 11,11-diphenyl-5-benzo[b]fluorenyl, 11,11-diphenyl-6-benzo[b]fluorenyl, 11,11-diphenyl-7-benzo[b]fluorenyl, 11,11-diphenyl-8-benzo[b]fluorenyl, 11,11-diphenyl-9-benzo[b]fluorenyl, 11,11-diphenyl-10-benzo[b]fluorenyl, 11,11-diphenyl-1-benzo[c]fluorenyl, 11,11-diphenyl-2-benzo[c]fluorenyl, 11,11-diphenyl-3-benzo[c]fluorenyl, 11,11-diphenyl-4-benzo[c]fluorenyl, 11,11-diphenyl-5-benzo[c]fluorenyl, 11,11-diphenyl-6-benzo[c]fluorenyl, 11,11-diphenyl-7-benzo[c]fluorenyl, 11,11-diphenyl-8-benzo[c]fluorenyl, 11,11-diphenyl-9-benzo[c]fluorenyl, 11,11-diphenyl-10-benzo[c]fluorenyl, 9,9,10,10-tetramethyl-9,10-dihydro-1-phenanthrenyl, 9,9,10,10-tetramethyl-9,10-dihydro-2-phenanthrenyl, 9,9,10,10-tetramethyl-9,10-dihydro-3-phenanthrenyl, 9,9,10,10-tetramethyl-9,10-dihydro-4-phenanthrenyl, etc. Herein, “(3- to 30-membered)heteroaryl(ene)” is an aryl having 3 to 30 ring backbone atoms and including at least one, preferably 1 to 4 heteroatoms selected from the group consisting of B, N, O, S, Si, P, Se, and Ge, in which the number of the ring backbone carbon atoms is preferably 3 to 30, and more preferably 5 to 20. The above heteroaryl(ene) may be a monocyclic ring, or a fused ring condensed with at least one benzene ring; and may be partially saturated. Also, the above heteroaryl or heteroarylene herein may be one formed by linking at least one heteroaryl or aryl group to a heteroaryl group via a single bond(s), and may comprise a spiro structure. Examples of the heteroaryl specifically may be a monocyclic ring-type heteroaryl including furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl including benzofuranyl, benzothiophenyl, isobenzofuranyl, dibenzofuranyl, dibenzothiophenyl, dibenzoselenophenyl, benzofuroquinolinyl, benzofuroquinazolinyl, benzofuronaphthiridinyl, benzofuropyrimidinyl, naphthofuropyrimidinyl, benzothienoquinolinyl, benzothienoquinazolinyl, benzothienonaphthiridinyl, benzothienopyrimidinyl, naphthothienopyrimidinyl, pyrimidoindolyl, benzopyrimidoindolyl, benzofuropyrazinyl, naphthofuropyrazinyl, benzothienopyrazinyl, naphthothienopyrazinyl, pyrazinoindolyl, benzopyrazinoindolyl, benzoimidazolyl, benzothiazolyl, benzoisothiazolyl, benzoisoxazolyl, benzoxazolyl, imidazopyridinyl, isoindolyl, indolyl, benzoindolyl, indazolyl, benzothiadiazolyl, quinolyl, isoquinolyl, cinnolinyl, quinazolinyl, quinoxalinyl, carbazolyl, azacarbazolyl, benzocarbazolyl, dibenzocarbazolyl, phenoxazinyl, phenanthridinyl, benzodioxolyl, indolizidinyl, acridinyl, silafluorenyl, germafluorenyl, benzotriazolyl, phenazinyl, imidazopyridinyl, chromenoquinazolinyl, thiochromenoquinazolinyl, dimethylbenzopyrimidinyl, indolocarbazolyl, indenocarbazolyl, etc. More specifically, the heteroaryl may be 1-pyrrolyl, 2-pyrrolyl, 3-pyrrolyl, 2-pyridinyl, 3-pyridinyl, 4-pyridinyl, 2-pyrimidinyl, 4-pyrimidinyl, 5-pyrimidinyl, 6-pyrimidinyl, 1,2,3-triazin-4-yl, 1,2,4-triazin-3-yl, 1,3,5-triazin-2-yl, 1-imidazolyl, 2-imidazolyl, 1-pyrazolyl, 1-indolizidinyl, 2-indolizidinyl, 3-indolizidinyl, 5-indolizidinyl, 6-indolizidinyl, 7-indolizidinyl, 8-indolizidinyl, 2-imidazopyridinyl, 3-imidazopyridinyl, 5-imidazopyridinyl, 6-imidazopyridinyl, 7-imidazopyridinyl, 8-imidazopyridinyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 2-furyl, 3-furyl, 2-benzofuranyl, 3-benzofuranyl, 4-benzofuranyl, 5-benzofuranyl, 6-benzofuranyl, 7-benzofuranyl, 1-isobenzofuranyl, 3-isobenzofuranyl, 4-isobenzofuranyl, 5-isobenzofuranyl, 6-isobenzofuranyl, 7-isobenzofuranyl, 2-quinolyl, 3-quinolyl, 4-quinolyl, 5-quinolyl, 6-quinolyl, 7-quinolyl, 8-quinolyl, 1-isoquinolyl, 3-isoquinolyl, 4-isoquinolyl, 5-isoquinolyl, 6-isoquinolyl, 7-isoquinolyl, 8-isoquinolyl, 2-quinoxalinyl, 5-quinoxalinyl, 6-quinoxalinyl, 1-carbazolyl, 2-carbazolyl, 3-carbazolyl, 4-carbazolyl, 9-carbazolyl, azacarbazol-1-yl, azacarbazol-2-yl, azacarbazol-3-yl, azacarbazol-4-yl, azacarbazol-5-yl, azacarbazol-6-yl, azacarbazol-7-yl, azacarbazol-8-yl, azacarbazol-9-yl, 1-phenanthridinyl, 2-phenanthridinyl, 3-phenanthridinyl, 4-phenanthridinyl, 6-phenanthridinyl, 7-phenanthridinyl, 8-phenanthridinyl, 9-phenanthridinyl, 10-phenanthridinyl, 1-acridinyl, 2-acridinyl, 3-acridinyl, 4-acridinyl, 9-acridinyl, 2-oxazolyl, 4-oxazolyl, 5-oxazolyl, 2-oxadiazolyl, 5-oxadiazolyl, 3-furazanyl, 2-thienyl, 3-thienyl, 2-methylpyrrol-1-yl, 2-methylpyrrol-3-yl, 2-methylpyrrol-4-yl, 2-methylpyrrol-5-yl, 3-methylpyrrol-1-yl, 3-methylpyrrol-2-yl, 3-methylpyrrol-4-yl, 3-methylpyrrol-5-yl, 2-t-butylpyrrol-4-yl, 3-(2-phenylpropyl)pyrrol-1-yl, 2-methyl-1-indolyl, 4-methyl-1-indolyl, 2-methyl-3-indolyl, 4-methyl-3-indolyl, 2-t-butyl-1-indolyl, 4-t-butyl-1-indolyl, 2-t-butyl-3-indolyl, 4-t-butyl-3-indolyl, 1-dibenzofuranyl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-naphtho-[1,2-b]-benzofuranyl, 2-naphtho-[1,2-b]-benzofuranyl, 3-naphtho-[1,2-b]-benzofuranyl, 4-naphtho-[1,2-b]-benzofuranyl, 5-naphtho-[1,2-b]-benzofuranyl, 6-naphtho-[1,2-b]-benzofuranyl, 7-naphtho-[1,2-b]-benzofuranyl, 8-naphtho-[1,2-b]-benzofuranyl, 9-naphtho-[1,2-b]-benzofuranyl, 10-naphtho-[1,2-b]-benzofuranyl, 1-naphtho-[2,3-b]-benzofuranyl, 2-naphtho-[2,3-b]-benzofuranyl, 3-naphtho-[2,3-b]-benzofuranyl, 4-naphtho-[2,3-b]-benzofuranyl, 5-naphtho-[2,3-b]-benzofuranyl, 6-naphtho-[2,3-b]-benzofuranyl, 7-naphtho-[2,3-b]-benzofuranyl, 8-naphtho-[2,3-b]-benzofuranyl, 9-naphtho-[2,3-b]-benzofuranyl, 10-naphtho-[2,3-b]-benzofuranyl, 1-naphtho-[2,1-b]-benzofuranyl, 2-naphtho-[2,1-b]-benzofuranyl, 3-naphtho-[2,1-b]-benzofuranyl, 4-naphtho-[2,1-b]-benzofuranyl, 5-naphtho-[2,1-b]-benzofuranyl, 6-naphtho-[2,1-b]-benzofuranyl, 7-naphtho-[2,1-b]-benzofuranyl, 8-naphtho-[2,1-b]-benzofuranyl, 9-naphtho-[2,1-b]-benzofuranyl, 10-naphtho-[2,1-b]-benzofuranyl, 1-naphtho-[1,2-b]-benzothiophenyl, 2-naphtho-[1,2-b]-benzothiophenyl, 3-naphtho-[1,2-b]-benzothiophenyl, 4-naphtho-[1,2-b]-benzothiophenyl, 5-naphtho-[1,2-b]-benzothiophenyl, 6-naphtho-[1,2-b]-benzothiophenyl, 7-naphtho-[1,2-b]-benzothiophenyl, 8-naphtho-[1,2-b]-benzothiophenyl, 9-naphtho-[1,2-b]-benzothiophenyl, 10-naphtho-[1,2-b]-benzothiophenyl, 1-naphtho-[2,3-b]-benzothiophenyl, 2-naphtho-[2,3-b]-benzothiophenyl, 3-naphtho-[2,3-b]-benzothiophenyl, 4-naphtho-[2,3-b]-benzothiophenyl, 5-naphtho-[2,3-b]-benzothiophenyl, 1-naphtho-[2,1-b]-benzothiophenyl, 2-naphtho-[2,1-b]-benzothiophenyl, 3-naphtho-[2,1-b]-benzothiophenyl, 4-naphtho-[2,1-b]-benzothiophenyl, 5-naphtho-[2,1-b]-benzothiophenyl, 6-naphtho-[2,1-b]-benzothiophenyl, 7-naphtho-[2,1-b]-benzothiophenyl, 8-naphtho-[2,1-b]-benzothiophenyl, 9-naphtho-[2,1-b]-benzothiophenyl, 10-naphtho-[2,1-b]-benzothiophenyl, 2-benzofuro[3,2-d]pyrimidinyl, 6-benzofuro[3,2-d]pyrimidinyl, 7-benzofuro[3,2-d]pyrimidinyl, 8-benzofuro[3,2-d]pyrimidinyl, 9-benzofuro[3,2-d]pyrimidinyl, 2-benzothio[3,2-d]pyrimidinyl, 6-benzothio[3,2-d]pyrimidinyl, 7-benzothio[3,2-d]pyrimidinyl, 8-benzothio[3,2-d]pyrimidinyl, 9-benzothio[3,2-d]pyrimidinyl, 2-benzofuro[3,2-d]pyrazinyl, 6-benzofuro[3,2-d]pyrazinyl, 7-benzofuro[3,2-d]pyrazinyl, 8-benzofuro[3,2-d]pyrazinyl, 9-benzofuro[3,2-d]pyrazinyl, 2-benzothio[3,2-d]pyrazinyl, 6-benzothio[3,2-d]pyrazinyl, 7-benzothio[3,2-d]pyrazinyl, 8-benzothio[3,2-d]pyrazinyl, 9-benzothio[3,2-d]pyrazinyl, 1-silafluorenyl, 2-silafluorenyl, 3-silafluorenyl, 4-silafluorenyl, 1-germafluorenyl, 2-germafluorenyl, 3-germafluorenyl, 4-germafluorenyl, 1-dibenzoselenophenyl, 2-dibenzoselenophenyl, 3-dibenzoselenophenyl, 4-dibenzoselenophenyl, etc. Herein, the term “a fused ring of (C3-C30) aliphatic ring and (C6-C30) aromatic ring” means a ring formed by fusing at least one aliphatic ring having 3 to 30 ring backbone carbon atoms in which the carbon atoms number is preferably 3 to 25, more preferably 3 to 18, and at least one aromatic ring having 6 to 30 ring backbone carbon atoms in which the carbon atoms number is preferably 6 to 25, more preferably 6 to 18. For example, the fused ring may be a fused ring of at least one benzene and at least one cyclohexane, or a fused ring of at least one naphthalene and at least one cyclopentane, etc. Herein, the carbon atoms in the fused ring of (C3-C30) aliphatic ring and (C6-C30) aromatic ring may be replaced with at least one heteroatom selected from B, N, O, S, Si and P, preferably at least one heteroatom selected from N, O and S. The term “Halogen” in the present disclosure includes F, Cl, Br, and I.

In addition, “ortho (o),” “meta (m),” and “para (p)” are meant to signify the substitution position of all substituents. Ortho position is a compound with substituents, which are adjacent to each other, e.g., at the 1 and 2 positions on benzene. Meta position is the next substitution position of the immediately adjacent substitution position, e.g., a compound with substituents at the 1 and 3 positions on benzene. Para position is the next substitution position of the meta position, e.g., a compound with substituents at the 1 and 4 positions on benzene.

Herein, the term “a ring formed in linking to an adjacent substituent” means a substituted or unsubstituted (3- to 30-membered) mono- or polycyclic, alicyclic, aromatic ring, or a combination thereof, formed by linking or fusing two or more adjacent substituents, preferably a substituted or unsubstituted (5- to 25-membered) mono- or polycyclic, alicyclic, aromatic ring, or a combination thereof. Further, the formed ring may include at least one heteroatom selected from the group consisting of B, N, O, S, Si and P, preferably, N, O and S. According to one embodiment of the present disclosure, the number of atoms in the ring skeleton is 5 to 20; according to another embodiment of the present disclosure, the number of atoms in the ring skeleton is 5 to 15. In one embodiment, the fused ring may be, for example, a substituted or unsubstituted dibenzothiophene ring, a substituted or unsubstituted dibenzofuran ring, a substituted or unsubstituted naphthalene ring, a substituted or unsubstituted phenanthrene ring, a substituted or unsubstituted fluorene ring, a substituted or unsubstituted benzofluorene ring, a substituted or unsubstituted benzothiophene ring, a substituted or unsubstituted benzofuran ring, a substituted or unsubstituted indole ring, a substituted or unsubstituted indene ring, a substituted or unsubstituted benzene ring, or a substituted or unsubstituted carbazole ring, etc.

In addition, “substituted” in the expression “substituted or unsubstituted” means that a hydrogen atom in a certain functional group is replaced with another atom or functional group, i.e., a substituent, and substituted with a group to which two or more substituents are connected among the substituents. For example, “a substituent to which two or more substituents are connected” may be pyridine-triazine. That is, pyridine-triazine may be heteroaryl or may be interpreted as one substituent in which two heteroaryls are connected. The substituents of the substituted alkyl, the substituted alkenyl, the substituted cycloalkyl, the substituted alkoxy, the substituted aryl(ene), the substituted heteroaryl(ene) and the substituted fused ring of aliphatic ring and aromatic ring in the formulas of the present disclosure, each independently represent at least one selected from the group consisting of deuterium; halogen; cyano; carboxyl; nitro; hydroxyl; (C1-C30)alkyl; halo(C1-C30)alkyl; (C2-C30)alkenyl; (C2-C30)alkynyl; (C1-C30)alkoxy; (C1-C30)alkylthio; (C3-C30)cycloalkyl; (C3-C30)cycloalkenyl; (3- to 7-membered)heterocycloalkyl; (C6-C30)aryloxy; (C6-C30)arylthio; (3- to 30-membered)heteroaryl unsubstituted or substituted by at least one of (C1-C30)alkyl and (C6-C30)aryl; (C6-C30)aryl unsubstituted or substituted by at least one of deuterium, cyano, (C1-C30)alkyl, (C3-C30)cycloalkyl, tri(C1-C30)alkylsilyl and (3- to 30-membered)heteroaryl; tri(C1-C30)alkylsilyl; tri(C6-C30)arylsilyl; di(C1-C30)alkyl(C6-C30)arylsilyl; (C1-C30)alkyldi(C6-C30)arylsilyl; a fused ring of (C3-C30) aliphatic ring and (C6-C30) aromatic ring; amino; mono- or di- (C1-C30)alkylamino; mono- or di- (C2-C30)alkenylamino; (C1-C30)alkyl(C2-C30)alkenylamino; mono- or di- (C6-C30)arylamino; (C1-C30)alkyl(C6-C30)arylamino; mono- or di- (3- to 30-membered)heteroaryl; (C1-C30)alkyl(3- to 30-membered)heteroarylamino; (C2-C30)alkenyl(C6-C30)arylamino; (C2-C30)alkenyl(3- to 30-membered)heteroarylamino; (C6-C30)aryl(3- to 30-membered)heteroarylamino; (C1-C30)alkylcarbonyl; (C1-C30)alkoxycarbonyl; (C6-C30)arylcarbonyl; di(C6-C30)arylboronyl; di(C1-C30)alkylboronyl; (C1-C30)alkyl(C6-C30)arylboronyl; (C6-C30)ar(C1-C30)alkyl; and (C1-C30)alkyl(C6-C30)aryl. For example, the substituents of the substituted groups may be deuterium; cyano; methyl; a substituted or unsubstituted phenyl; biphenyl; naphthyl; terphenyl; triphenylsilanyl; phenanthrenyl; anthracenyl; chrysenyl; triphenylenyl; a substituted or unsubstituted fluorenyl; spirobifluorenyl; a substituted or unsubstituted pyridyl; carbazolyl; a substituted or unsubstituted dibenzofuranyl; dibenzothiophenyl, etc.

Hereinafter, the plurality of host materials according to one embodiment will be described.

The plurality of host materials according to one embodiment comprise at least one first host compound comprising a compound represented by formula 1 and at least one second host compound comprising a compound represented by formula 2; and the plurality of host materials may be comprised in the light-emitting layer of an organic electroluminescent device according to one embodiment.

The first host compound as the host materials according to one embodiment is represented by the following formula 1.

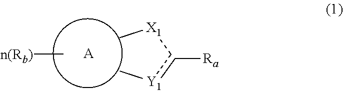

in formula 1,
ring A represents a substituted or unsubstituted aromatic ring in which 4 benzene rings are sequentially fused;
X₁ and Y₁ each independently represent, —N═, —NR_{c}—, —O— or —S—; provided that any one of X₁ and Y₁ is —N═, and the other of X₁ and Y₁ is —NR_{c}—, —O— or —S—;
Rₐ and R_{c} each independently represent, a substituted or unsubstituted (C6-C30)aryl or a substituted or unsubstituted (3- to 30-membered)heteroaryl;
R_{b} represents hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted fused ring of (C3-C30) aliphatic ring and (C6-C30) aromatic ring, —SiR′₁R′₂R′₃, or -L′₁—NR′₁R′₂; provided that at least one of R_{b} is (are) -L′₁—NR′₁R′₂;
L′₁ represents a single bond, a substituted or unsubstituted (C6-C30)arylene, or a substituted or unsubstituted (3- to 30-membered)heteroarylene;
R′₁ to R′₃ each independently represent, a substituted or unsubstituted (C1-C30)alkyl, a substituted or unsubstituted (C2-C30)alkenyl, a substituted or unsubstituted (C6-C30)aryl, a substituted or unsubstituted (3- to 30-membered)heteroaryl, or a substituted or unsubstituted fused ring of (C3-C30) aliphatic ring and (C6-C30) aromatic ring; and n represents an integer of 1 to 10, when n is an integer of 2 or more, each of R_{b} may be the same or different.

In one embodiment, at least one of X₁ and Y₁ may be —N═, and the other of X₁ and Y₁ may be —O—.

In one embodiment, Rₐ may be a substituted or unsubstituted (C6-C30)aryl, preferably a substituted or unsubstituted (C6-C25)aryl, more preferably (C6-C18)aryl unsubstituted or substituted by deuterium. For example, Rₐ may be phenyl unsubstituted or substituted by deuterium, a substituted or unsubstituted naphthyl, or a substituted or unsubstituted biphenyl.

In one embodiment, R_{b} may be hydrogen or -L′₁—NR′₁R′₂.

In one embodiment, L′₁ may be a single bond, a substituted or unsubstituted (C6-C30)arylene, or a substituted or unsubstituted (5- to 30-membered)heteroarylene, preferably a single bond, a substituted or unsubstituted (C6-C25)arylene, or a substituted or unsubstituted (5- to 25-membered)heteroarylene, more preferably a single bond, a substituted or unsubstituted (C6-C18)arylene, or a substituted or unsubstituted (5- to 18-membered)heteroarylene. For example, L′₁ may be a single bond, a substituted or unsubstituted phenylene, a substituted or unsubstituted naphthalenylene, or a substituted or unsubstituted dibenzofuranylene.

In one embodiment, R′₁ and R′₂ each independently may be a substituted or unsubstituted (C6-C30)aryl, a substituted or unsubstituted (5- to 30-membered)heteroaryl, or a substituted or unsubstituted fused ring of (C3-C30) aliphatic ring and (C6-C30) aromatic ring, preferably, a substituted or unsubstituted (C6-C25)aryl, or a substituted or unsubstituted (5- to 25-membered)heteroaryl, more preferably a substituted or unsubstituted (C6-C18)aryl, or a substituted or unsubstituted (5- to 18-membered)heteroaryl. For example, R′₁ and R′₂ each independently may be a substituted or unsubstituted phenyl, a substituted or unsubstituted biphenyl, a substituted or unsubstituted naphthyl, a substituted or unsubstituted terphenyl, a substituted or unsubstituted tetraphenyl, a substituted or unsubstituted phenanthrenyl, a substituted or unsubstituted fluorenyl, a substituted or unsubstituted dibenzofuranyl, a substituted or unsubstituted dibenzothiophenyl, a substituted or unsubstituted dibenzoselenophenyl, or a substituted or unsubstituted pyridinyl. The substituents of the substituted groups may be, for example, deuterium, cyano, methyl, phenyl, naphthyl, biphenyl, terphenyl, triphenylsilanyl, or dibenzofuranyl.

In one embodiment, the host compound represented by formula 1 may be represented by the following formula 1-1.

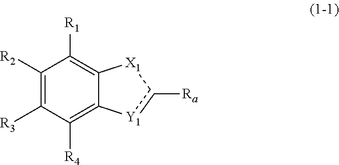

in formula 1-1,
X₁, Y₁, and Rₐ are as defined in formula 1; and
one of R₁ and R₂, and R₃ and R₄ is linked to each other to form the following formula 1A, and the other is linked to each other to form the following formula 1B; or any one of R₁ and R₂, R₂ and R₃, and R₃ and R₄ is linked to each other to form the following formula 1C or 1D;

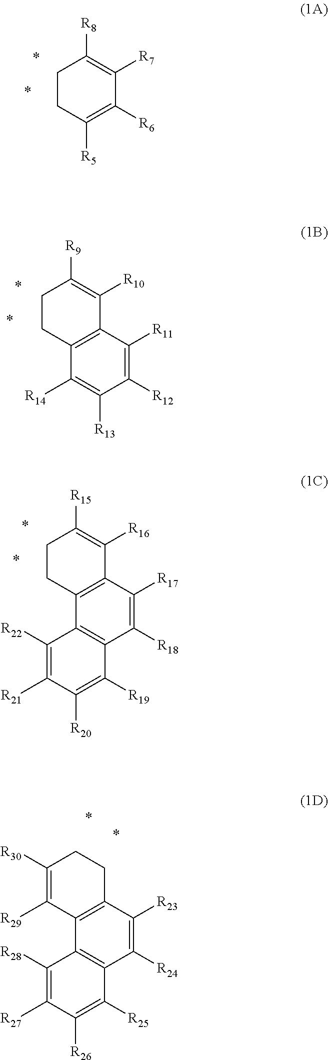

in formulas 1-1 and 1A to 1D
R₁ to R₄ which do not form the formula 1C or 1D, and R₅ to R₃₀ are as defined as R_{b} in formula 1; provided that at least one of R₅ to R₁₄ and at least one of R₁₅ to R₃₀ is (are) -L′₁-NR′₁R′₂; and
L′₁, R′₁, and R′₂ are as defined in formula 1.

According to one embodiment, the compound represented by formula 1-1 may be represented by any one of the following formulas 11-1 to 11-8.

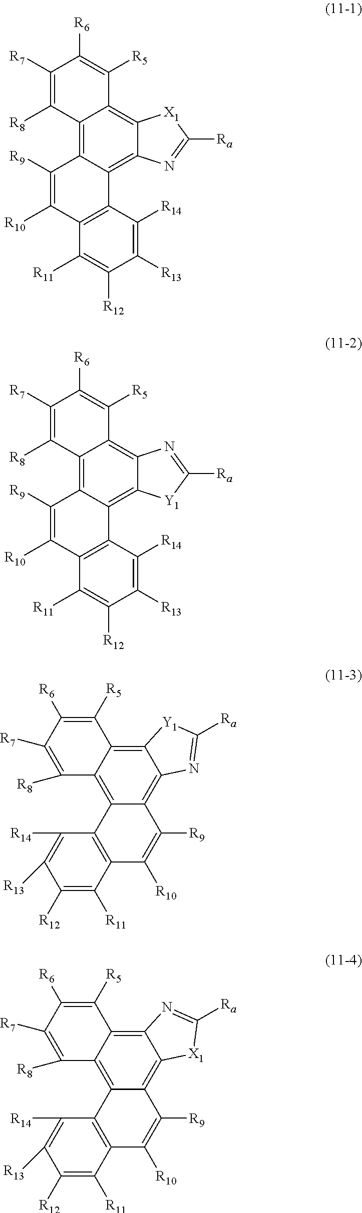

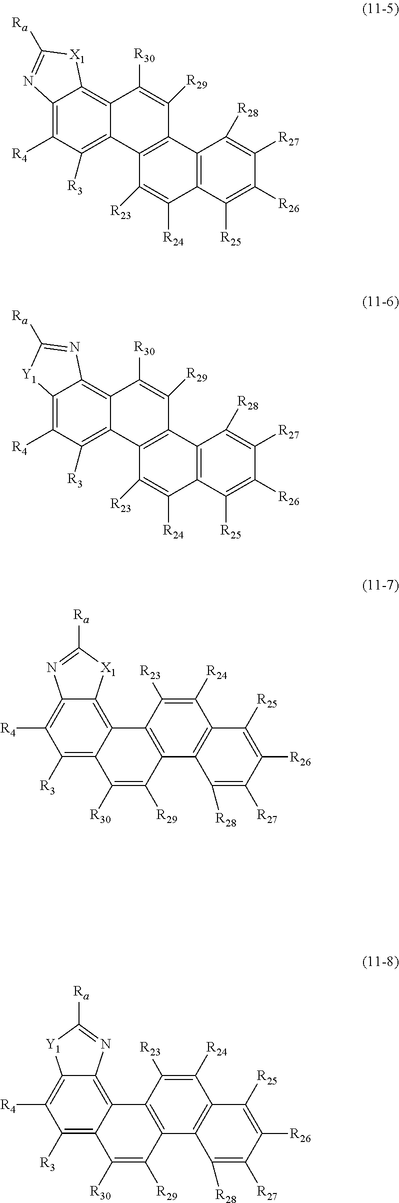

in formulas 11-1 to 11-8
X₁, Y₁, Rₐ, R₃ to R₁₄, and R₂₃ to R₃₀ are as defined in formula 1-1.

According to one embodiment, the first host compound represented by formula 1 may be more specifically illustrated by the following compounds, but is not limited thereto.

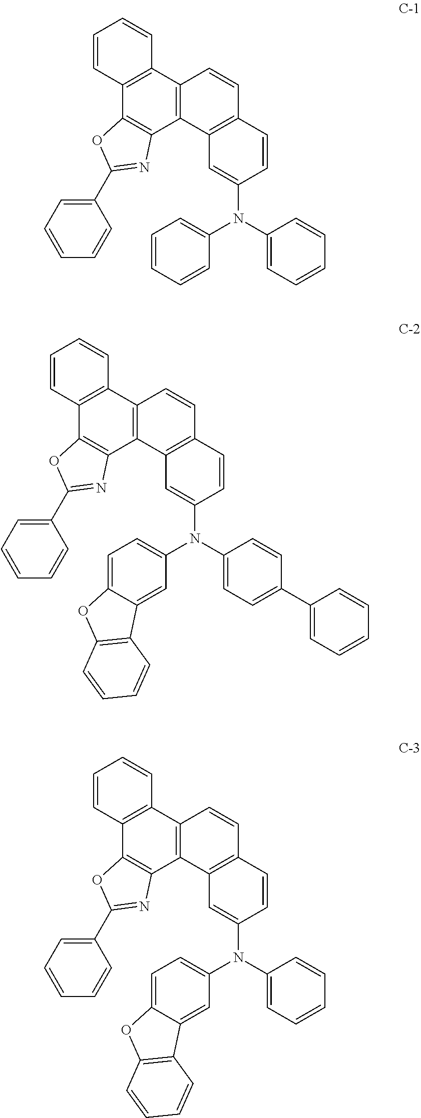 [SMILES: c1ccc(-c2nc3c(o2)c2ccccc2c2ccc4ccc(N(c5ccccc5)c5ccccc5)cc4c23)cc1 ; c1ccc(-c2ccc(N(c3ccc4oc5ccccc5c4c3)c3ccc4ccc5c6ccccc6c6oc(-c7ccccc7)nc6c5c4c3)cc2)cc1 ; c1ccc(-c2nc3c(o2)c2ccccc2c2ccc4ccc(N(c5ccccc5)c5ccc6oc7ccccc7c6c5)cc4c23)cc1]

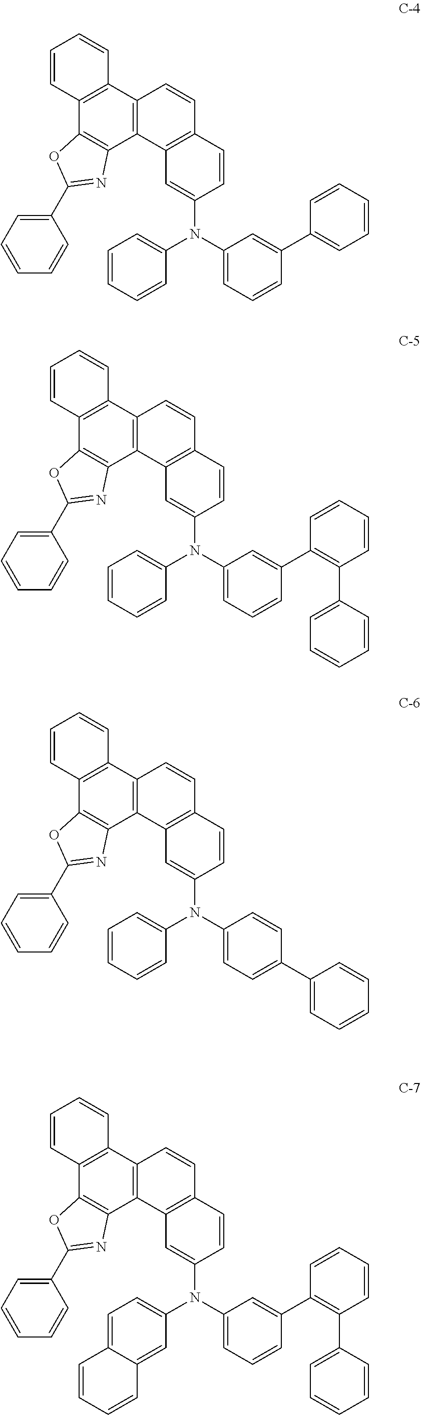 [SMILES: c1ccc(-c2cccc(N(c3ccccc3)c3ccc4ccc5c6ccccc6c6oc(-c7ccccc7)nc6c5c4c3)c2)cc1 ; c1ccc(-c2nc3c(o2)c2ccccc2c2ccc4ccc(N(c5ccccc5)c5cccc(-c6ccccc6-c6ccccc6)c5)cc4c23)cc1 ; c1ccc(-c2ccc(N(c3ccccc3)c3ccc4ccc5c6ccccc6c6oc(-c7ccccc7)nc6c5c4c3)cc2)cc1 ; c1ccc(-c2nc3c(o2)c2ccccc2c2ccc4ccc(N(c5cccc(-c6ccccc6-c6ccccc6)c5)c5ccc6ccccc6c5)cc4c23)cc1]

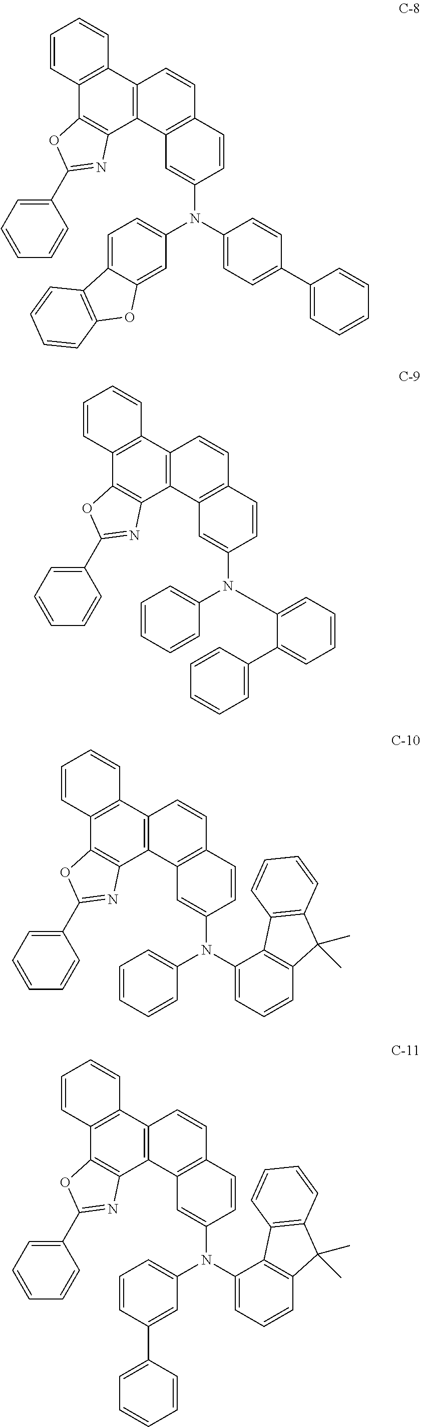 [SMILES: c1ccc(-c2ccc(N(c3ccc4c(c3)oc3ccccc34)c3ccc4ccc5c6ccccc6c6oc(-c7ccccc7)nc6c5c4c3)cc2)cc1 ; c1ccc(-c2nc3c(o2)c2ccccc2c2ccc4ccc(N(c5ccccc5)c5ccccc5-c5ccccc5)cc4c23)cc1 ; CC1(C)c2ccccc2-c2c(N(c3ccccc3)c3ccc4ccc5c6ccccc6c6oc(-c7ccccc7)nc6c5c4c3)cccc21 ; CC1(C)c2ccccc2-c2c(N(c3cccc(-c4ccccc4)c3)c3ccc4ccc5c6ccccc6c6oc(-c7ccccc7)nc6c5c4c3)cccc21]

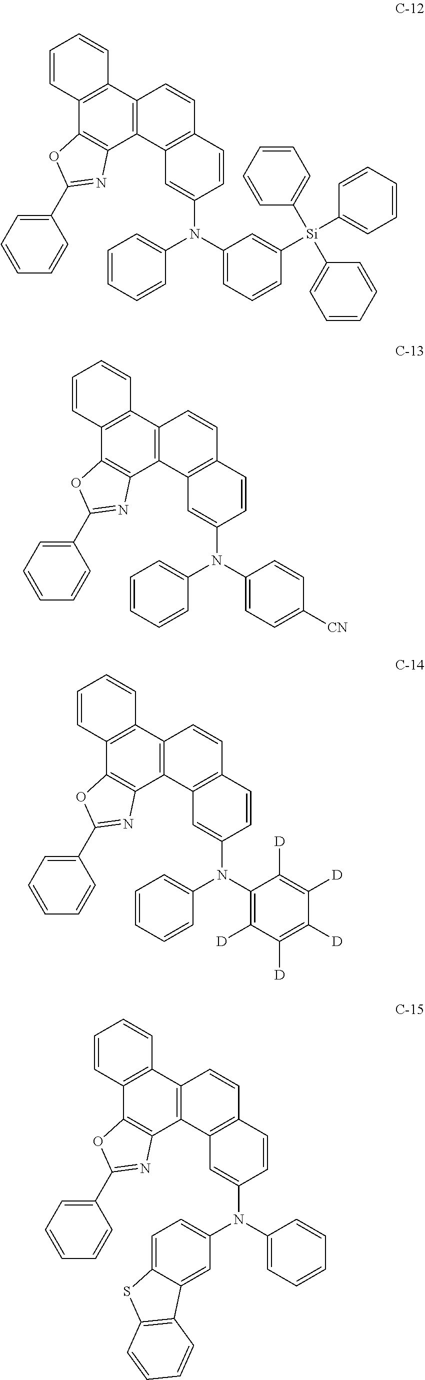 [SMILES: c1ccc(-c2nc3c(o2)c2ccccc2c2ccc4ccc(N(c5ccccc5)c5cccc([Si](c6ccccc6)(c6ccccc6)c6ccccc6)c5)cc4c23)cc1 ; N#Cc1ccc(N(c2ccccc2)c2ccc3ccc4c5ccccc5c5oc(-c6ccccc6)nc5c4c3c2)cc1 ; [2H]c1c([2H])c([2H])c(N(c2ccccc2)c2ccc3ccc4c5ccccc5c5oc(-c6ccccc6)nc5c4c3c2)c([2H])c1[2H] ; c1ccc(-c2nc3c(o2)c2ccccc2c2ccc4ccc(N(c5ccccc5)c5ccc6sc7ccccc7c6c5)cc4c23)cc1]

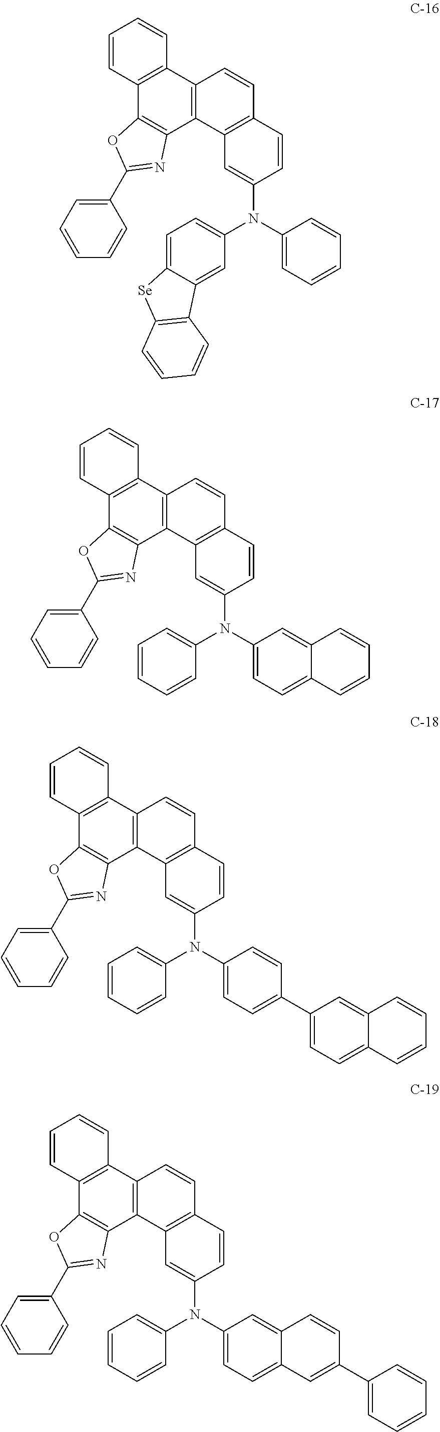 [SMILES: c1ccc(-c2nc3c(o2)c2ccccc2c2ccc4ccc(N(c5ccccc5)c5ccc6[se]c7ccccc7c6c5)cc4c23)cc1 ; c1ccc(-c2nc3c(o2)c2ccccc2c2ccc4ccc(N(c5ccccc5)c5ccc6ccccc6c5)cc4c23)cc1 ; c1ccc(-c2nc3c(o2)c2ccccc2c2ccc4ccc(N(c5ccccc5)c5ccc(-c6ccc7ccccc7c6)cc5)cc4c23)cc1 ; c1ccc(-c2ccc3cc(N(c4ccccc4)c4ccc5ccc6c7ccccc7c7oc(-c8ccccc8)nc7c6c5c4)ccc3c2)cc1]

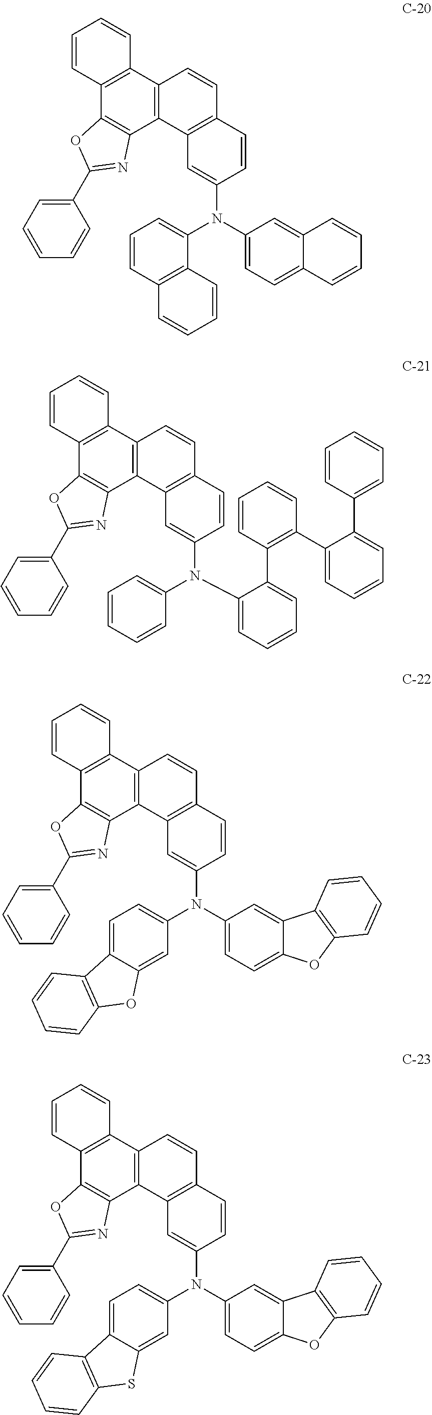 [SMILES: c1ccc(-c2nc3c(o2)c2ccccc2c2ccc4ccc(N(c5ccc6ccccc6c5)c5cccc6ccccc56)cc4c23)cc1 ; c1ccc(-c2nc3c(o2)c2ccccc2c2ccc4ccc(N(c5ccccc5)c5ccccc5-c5ccccc5-c5ccccc5-c5ccccc5)cc4c23)cc1 ; c1ccc(-c2nc3c(o2)c2ccccc2c2ccc4ccc(N(c5ccc6c(c5)oc5ccccc56)c5ccc6oc7ccccc7c6c5)cc4c23)cc1 ; c1ccc(-c2nc3c(o2)c2ccccc2c2ccc4ccc(N(c5ccc6c(c5)sc5ccccc56)c5ccc6oc7ccccc7c6c5)cc4c23)cc1]

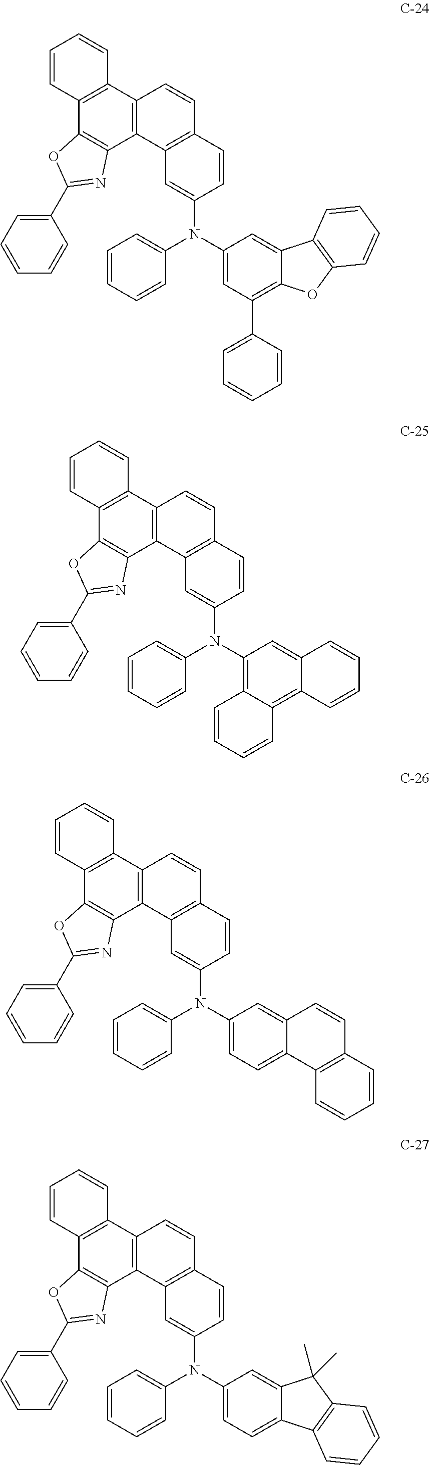 [SMILES: c1ccc(-c2nc3c(o2)c2ccccc2c2ccc4ccc(N(c5ccccc5)c5cc(-c6ccccc6)c6oc7ccccc7c6c5)cc4c23)cc1 ; c1ccc(-c2nc3c(o2)c2ccccc2c2ccc4ccc(N(c5ccccc5)c5cc6ccccc6c6ccccc56)cc4c23)cc1 ; c1ccc(-c2nc3c(o2)c2ccccc2c2ccc4ccc(N(c5ccccc5)c5ccc6c(ccc7ccccc76)c5)cc4c23)cc1 ; CC1(C)c2ccccc2-c2ccc(N(c3ccccc3)c3ccc4ccc5c6ccccc6c6oc(-c7ccccc7)nc6c5c4c3)cc21]

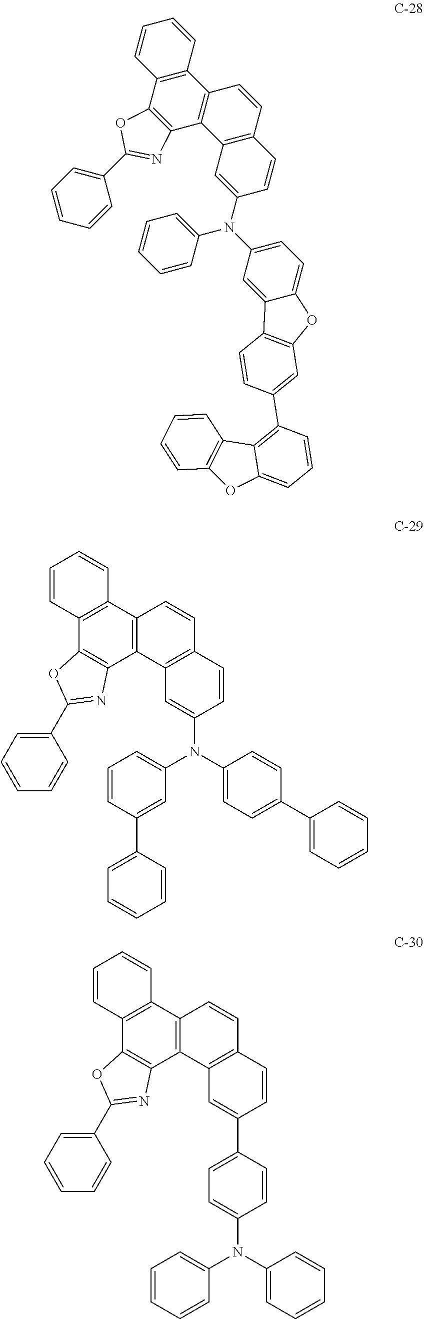

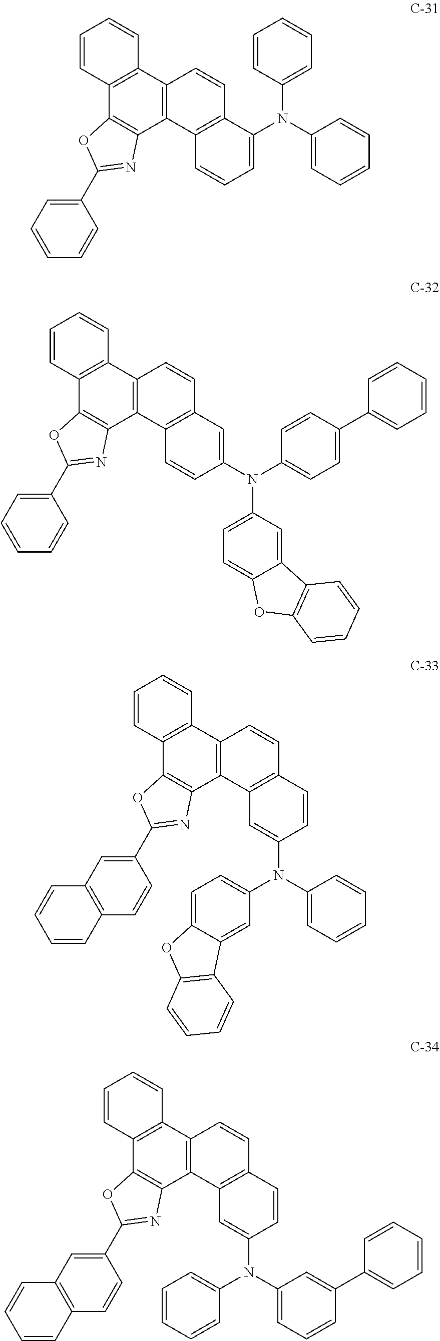 [SMILES: c1ccc(-c2nc3c(o2)c2ccccc2c2ccc4c(N(c5ccccc5)c5ccccc5)cccc4c23)cc1 ; c1ccc(-c2ccc(N(c3ccc4c(ccc5c6ccccc6c6oc(-c7ccccc7)nc6c45)c3)c3ccc4oc5ccccc5c4c3)cc2)cc1 ; c1ccc(N(c2ccc3oc4ccccc4c3c2)c2ccc3ccc4c5ccccc5c5oc(-c6ccc7ccccc7c6)nc5c4c3c2)cc1 ; c1ccc(-c2cccc(N(c3ccccc3)c3ccc4ccc5c6ccccc6c6oc(-c7ccc8ccccc8c7)nc6c5c4c3)c2)cc1]

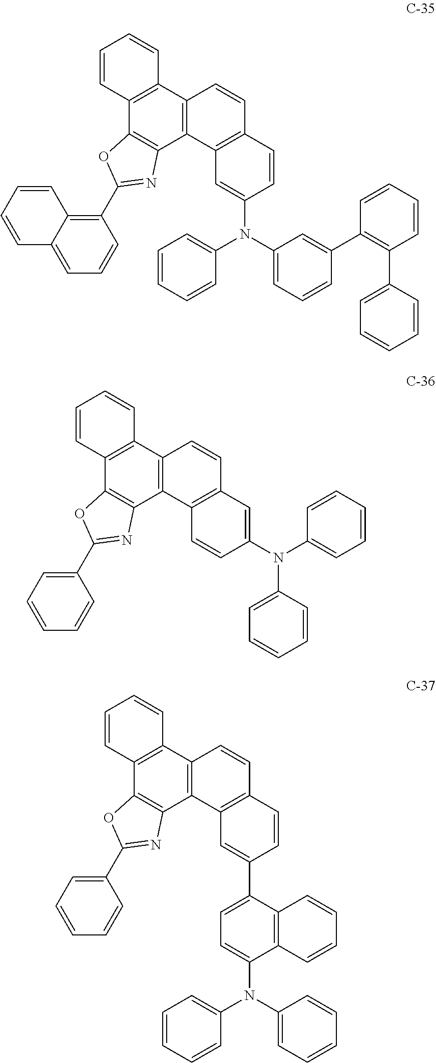 [SMILES: c1ccc(-c2ccccc2-c2cccc(N(c3ccccc3)c3ccc4ccc5c6ccccc6c6oc(-c7cccc8ccccc78)nc6c5c4c3)c2)cc1 ; c1ccc(-c2nc3c(o2)c2ccccc2c2ccc4cc(N(c5ccccc5)c5ccccc5)ccc4c23)cc1 ; c1ccc(-c2nc3c(o2)c2ccccc2c2ccc4ccc(-c5ccc(N(c6ccccc6)c6ccccc6)c6ccccc56)cc4c23)cc1]

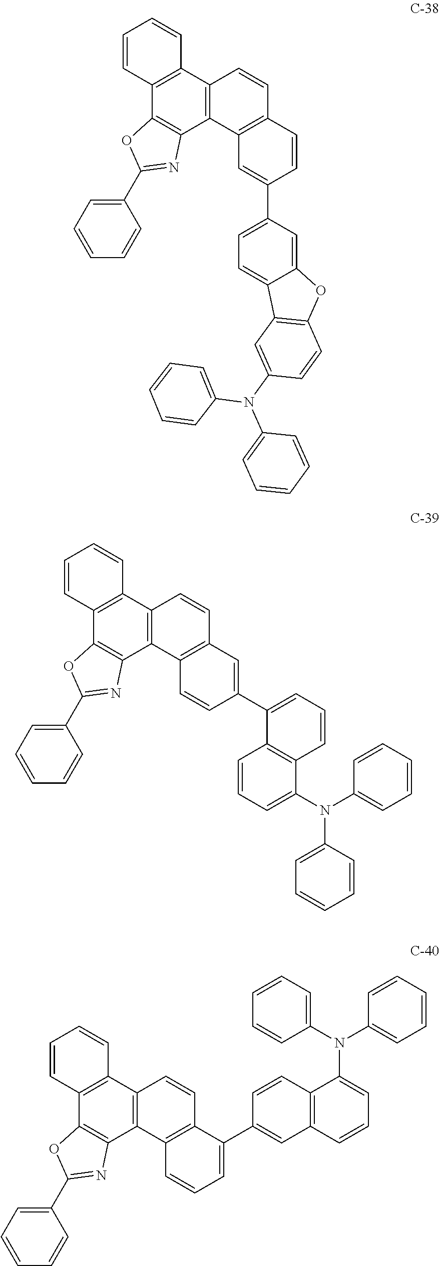 [SMILES: c1ccc(-c2nc3c(o2)c2ccccc2c2ccc4ccc(-c5ccc6c(c5)oc5ccc(N(c7ccccc7)c7ccccc7)cc56)cc4c23)cc1 ; c1ccc(-c2nc3c(o2)c2ccccc2c2ccc4cc(-c5cccc6c(N(c7ccccc7)c7ccccc7)cccc56)ccc4c23)cc1 ; c1ccc(-c2nc3c(o2)c2ccccc2c2ccc4c(-c5ccc6c(N(c7ccccc7)c7ccccc7)cccc6c5)cccc4c23)cc1]

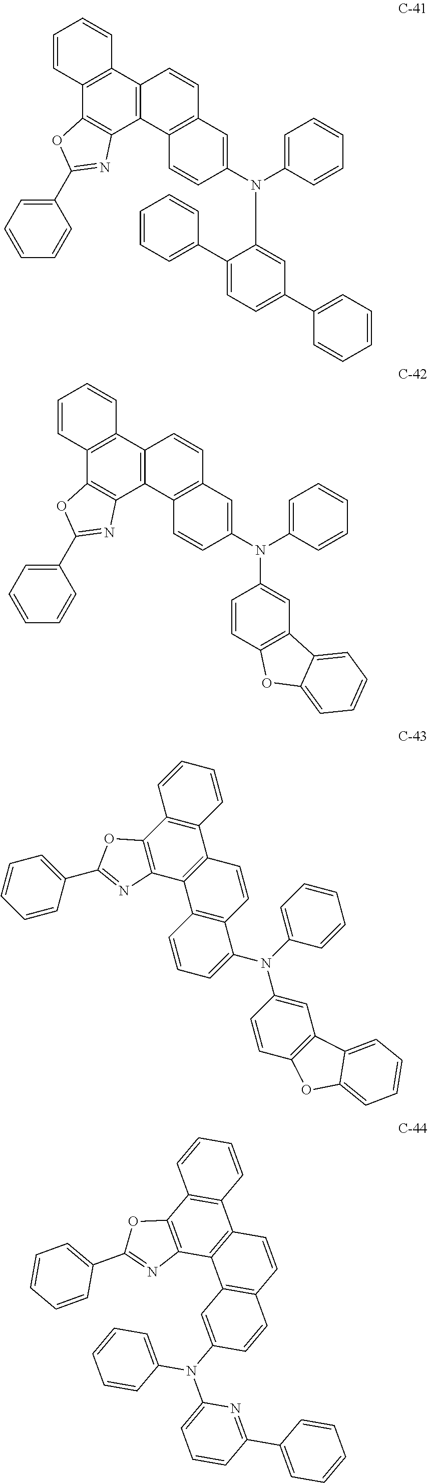 [SMILES: c1ccc(-c2ccc(-c3ccccc3)c(N(c3ccccc3)c3ccc4c(ccc5c6ccccc6c6oc(-c7ccccc7)nc6c45)c3)c2)cc1 ; c1ccc(-c2nc3c(o2)c2ccccc2c2ccc4cc(N(c5ccccc5)c5ccc6oc7ccccc7c6c5)ccc4c23)cc1 ; c1ccc(-c2nc3c(o2)c2ccccc2c2ccc4c(N(c5ccccc5)c5ccc6oc7ccccc7c6c5)cccc4c23)cc1 ; c1ccc(-c2cccc(N(c3ccccc3)c3ccc4ccc5c6ccccc6c6oc(-c7ccccc7)nc6c5c4c3)n2)cc1]

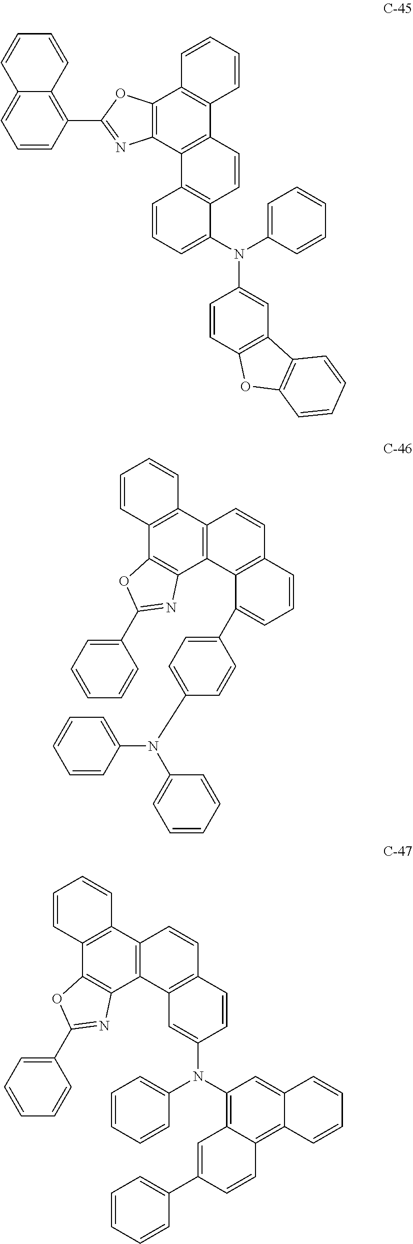 [SMILES: c1ccc(N(c2ccc3oc4ccccc4c3c2)c2cccc3c2ccc2c4ccccc4c4oc(-c5cccc6ccccc56)nc4c32)cc1 ; c1ccc(-c2nc3c(o2)c2ccccc2c2ccc4cccc(-c5ccc(N(c6ccccc6)c6ccccc6)cc5)c4c23)cc1 ; c1ccc(-c2ccc3c(c2)c(N(c2ccccc2)c2ccc4ccc5c6ccccc6c6oc(-c7ccccc7)nc6c5c4c2)cc2ccccc23)cc1]

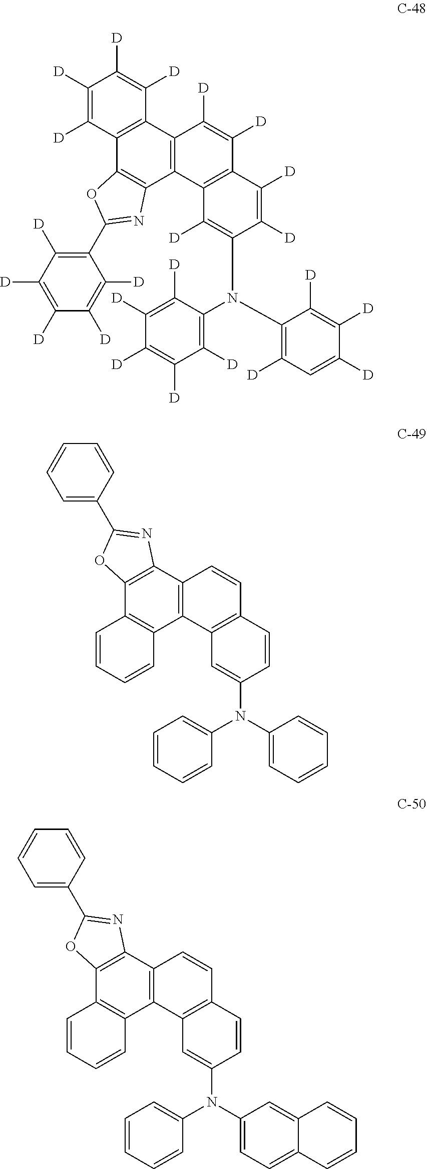 [SMILES: [2H]c1cc([2H])c(N(c2c([2H])c([2H])c([2H])c([2H])c2[2H])c2c([2H])c([2H])c3c([2H])c([2H])c4c5c([2H])c([2H])c([2H])c([2H])c5c5oc(-c6c([2H])c([2H])c([2H])c([2H])c6[2H])nc5c4c3c2[2H])c([2H])c1[2H] ; c1ccc(-c2nc3c4ccc5ccc(N(c6ccccc6)c6ccccc6)cc5c4c4ccccc4c3o2)cc1 ; c1ccc(-c2nc3c4ccc5ccc(N(c6ccccc6)c6ccc7ccccc7c6)cc5c4c4ccccc4c3o2)cc1]

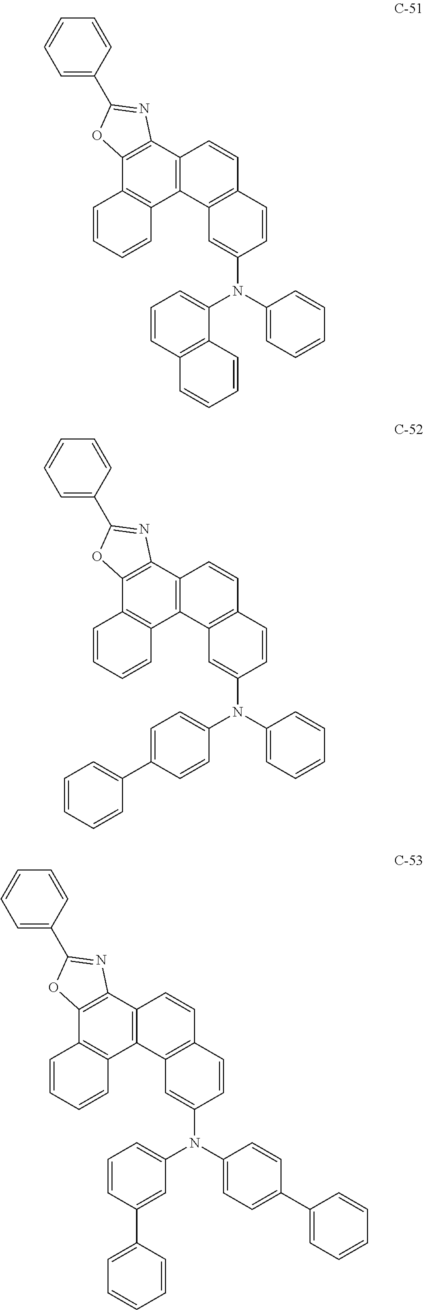 [SMILES: c1ccc(-c2nc3c4ccc5ccc(N(c6ccccc6)c6cccc7ccccc67)cc5c4c4ccccc4c3o2)cc1 ; c1ccc(-c2ccc(N(c3ccccc3)c3ccc4ccc5c6nc(-c7ccccc7)oc6c6ccccc6c5c4c3)cc2)cc1 ; c1ccc(-c2ccc(N(c3cccc(-c4ccccc4)c3)c3ccc4ccc5c6nc(-c7ccccc7)oc6c6ccccc6c5c4c3)cc2)cc1]

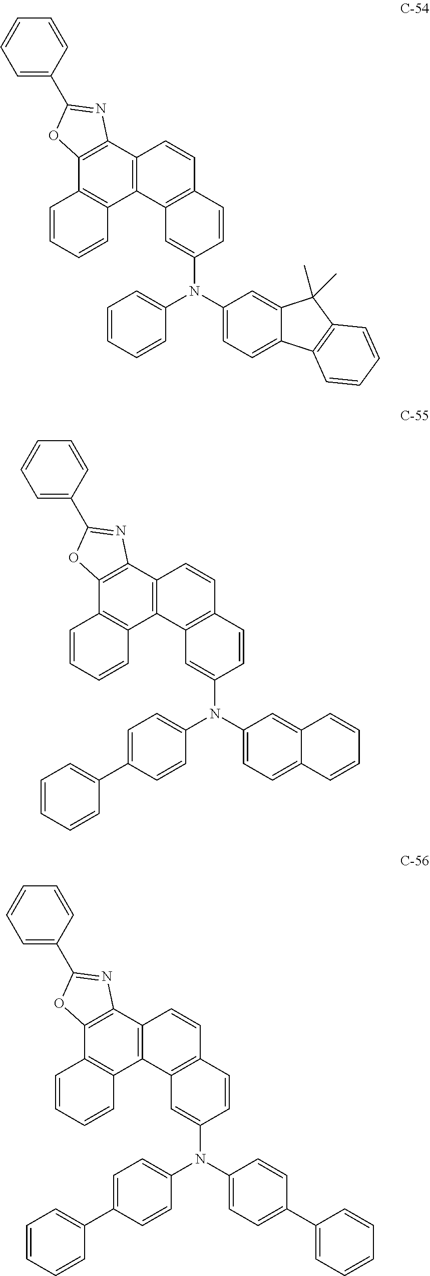 [SMILES: CC1(C)c2ccccc2-c2ccc(N(c3ccccc3)c3ccc4ccc5c6nc(-c7ccccc7)oc6c6ccccc6c5c4c3)cc21 ; c1ccc(-c2ccc(N(c3ccc4ccccc4c3)c3ccc4ccc5c6nc(-c7ccccc7)oc6c6ccccc6c5c4c3)cc2)cc1 ; c1ccc(-c2ccc(N(c3ccc(-c4ccccc4)cc3)c3ccc4ccc5c6nc(-c7ccccc7)oc6c6ccccc6c5c4c3)cc2)cc1]

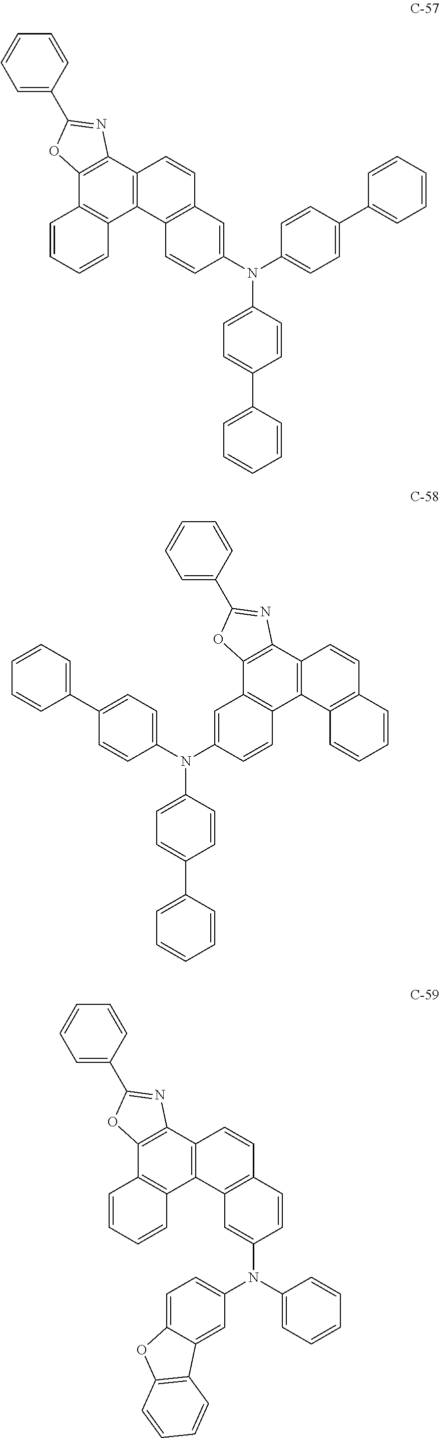 [SMILES: c1ccc(-c2ccc(N(c3ccc(-c4ccccc4)cc3)c3ccc4c(ccc5c6nc(-c7ccccc7)oc6c6ccccc6c45)c3)cc2)cc1 ; c1ccc(-c2ccc(N(c3ccc(-c4ccccc4)cc3)c3ccc4c(c3)c3oc(-c5ccccc5)nc3c3ccc5ccccc5c43)cc2)cc1 ; c1ccc(-c2nc3c4ccc5ccc(N(c6ccccc6)c6ccc7oc8ccccc8c7c6)cc5c4c4ccccc4c3o2)cc1]

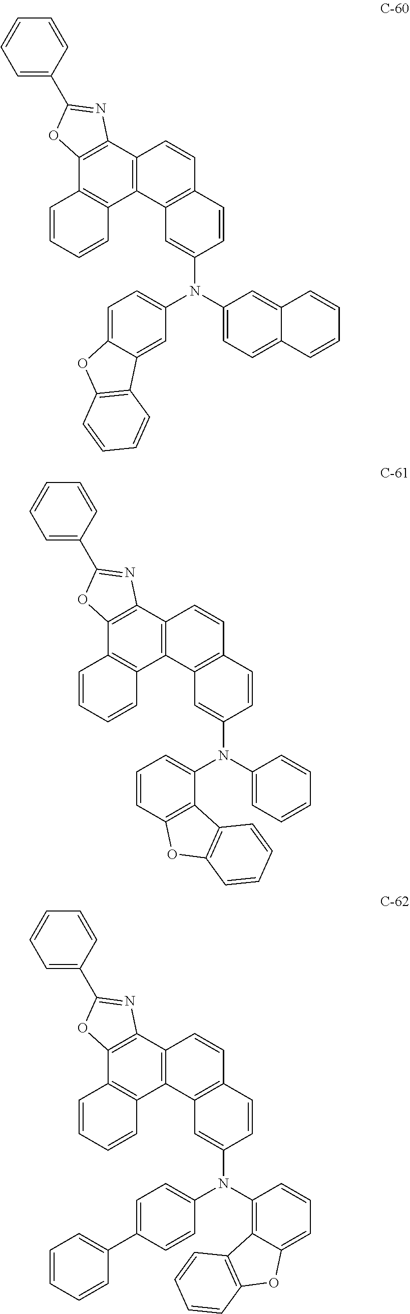

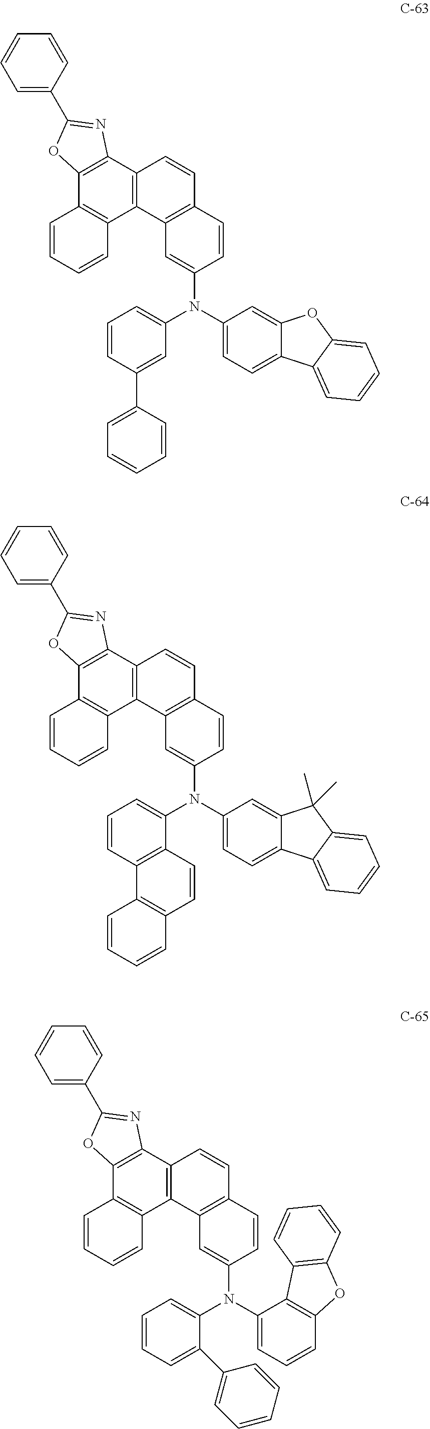 [SMILES: c1ccc(-c2cccc(N(c3ccc4c(c3)oc3ccccc34)c3ccc4ccc5c6nc(-c7ccccc7)oc6c6ccccc6c5c4c3)c2)cc1 ; CC1(C)c2ccccc2-c2ccc(N(c3ccc4ccc5c6nc(-c7ccccc7)oc6c6ccccc6c5c4c3)c3cccc4c3ccc3ccccc34)cc21 ; c1ccc(-c2nc3c4ccc5ccc(N(c6ccccc6-c6ccccc6)c6cccc7oc8ccccc8c67)cc5c4c4ccccc4c3o2)cc1]

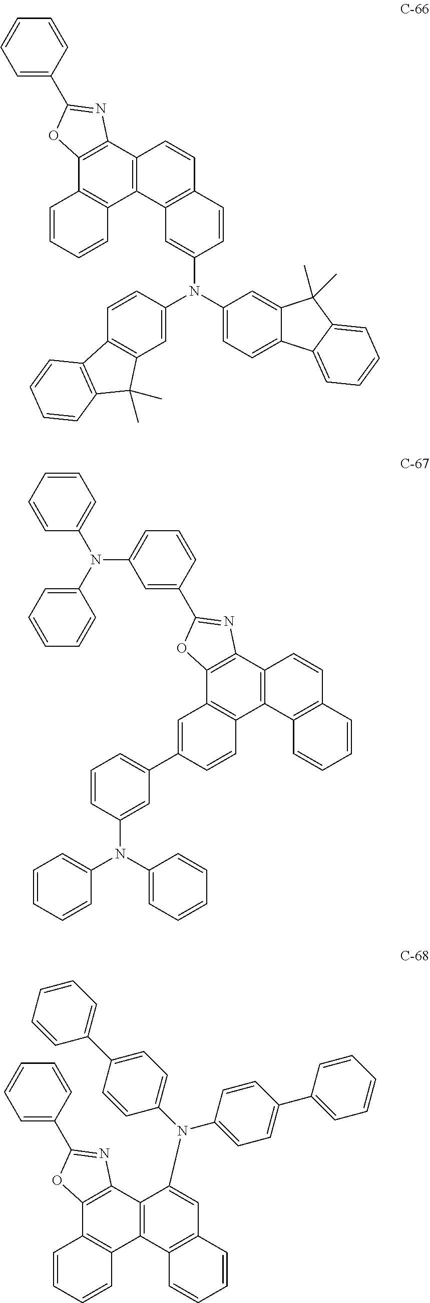 [SMILES: CC1(C)c2ccccc2-c2ccc(N(c3ccc4c(c3)C(C)(C)c3ccccc3-4)c3ccc4ccc5c6nc(-c7ccccc7)oc6c6ccccc6c5c4c3)cc21 ; c1ccc(N(c2ccccc2)c2cccc(-c3ccc4c(c3)c3oc(-c5cccc(N(c6ccccc6)c6ccccc6)c5)nc3c3ccc5ccccc5c43)c2)cc1 ; c1ccc(-c2ccc(N(c3ccc(-c4ccccc4)cc3)c3cc4ccccc4c4c5ccccc5c5oc(-c6ccccc6)nc5c34)cc2)cc1]

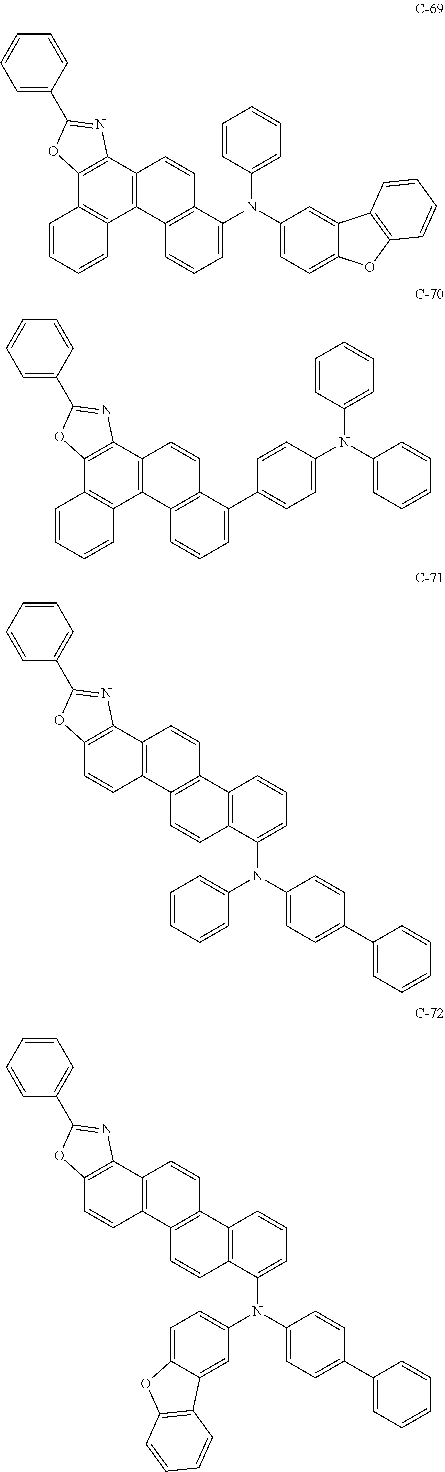 [SMILES: c1ccc(-c2nc3c4ccc5c(N(c6ccccc6)c6ccc7oc8ccccc8c7c6)cccc5c4c4ccccc4c3o2)cc1 ; c1ccc(-c2nc3c4ccc5c(-c6ccc(N(c7ccccc7)c7ccccc7)cc6)cccc5c4c4ccccc4c3o2)cc1 ; c1ccc(-c2ccc(N(c3ccccc3)c3cccc4c3ccc3c4ccc4c3ccc3oc(-c5ccccc5)nc34)cc2)cc1 ; c1ccc(-c2ccc(N(c3ccc4oc5ccccc5c4c3)c3cccc4c3ccc3c4ccc4c3ccc3oc(-c5ccccc5)nc34)cc2)cc1]

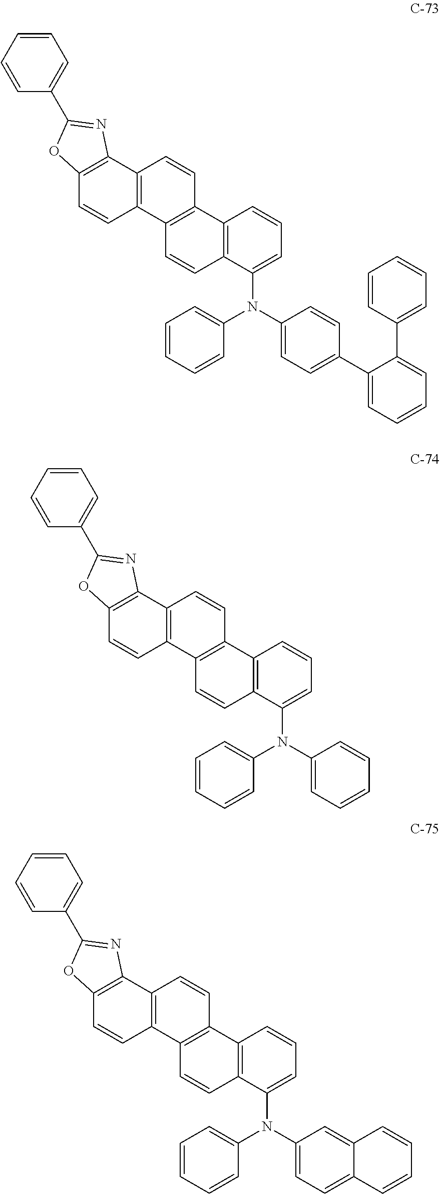 [SMILES: c1ccc(-c2nc3c(ccc4c5ccc6c(N(c7ccccc7)c7ccc(-c8ccccc8-c8ccccc8)cc7)cccc6c5ccc43)o2)cc1 ; c1ccc(-c2nc3c(ccc4c5ccc6c(N(c7ccccc7)c7ccccc7)cccc6c5ccc43)o2)cc1 ; c1ccc(-c2nc3c(ccc4c5ccc6c(N(c7ccccc7)c7ccc8ccccc8c7)cccc6c5ccc43)o2)cc1]

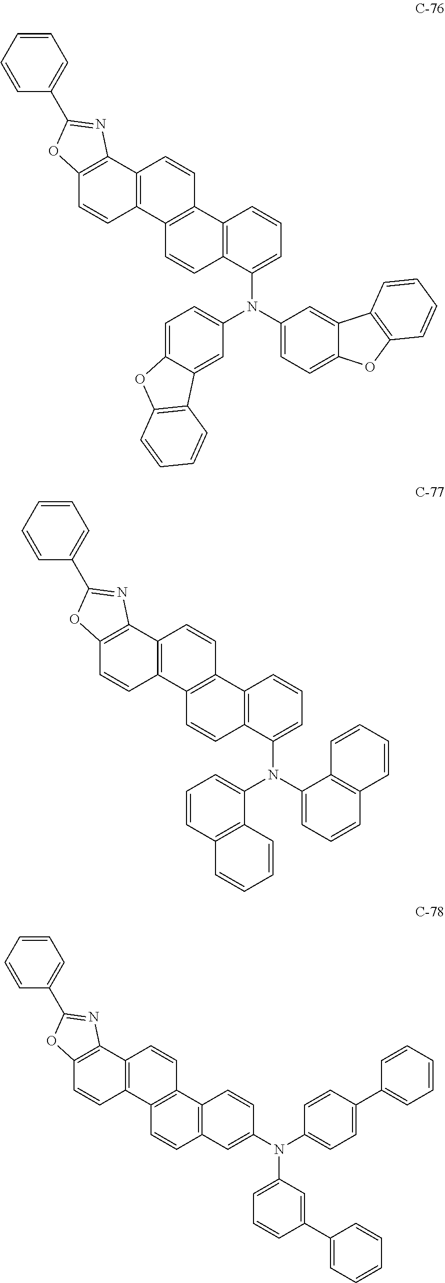 [SMILES: c1ccc(-c2nc3c(ccc4c5ccc6c(N(c7ccc8oc9ccccc9c8c7)c7ccc8oc9ccccc9c8c7)cccc6c5ccc43)o2)cc1 ; c1ccc(-c2nc3c(ccc4c5ccc6c(N(c7cccc8ccccc78)c7cccc8ccccc78)cccc6c5ccc43)o2)cc1 ; c1ccc(-c2ccc(N(c3cccc(-c4ccccc4)c3)c3ccc4c(ccc5c4ccc4c5ccc5oc(-c6ccccc6)nc54)c3)cc2)cc1]

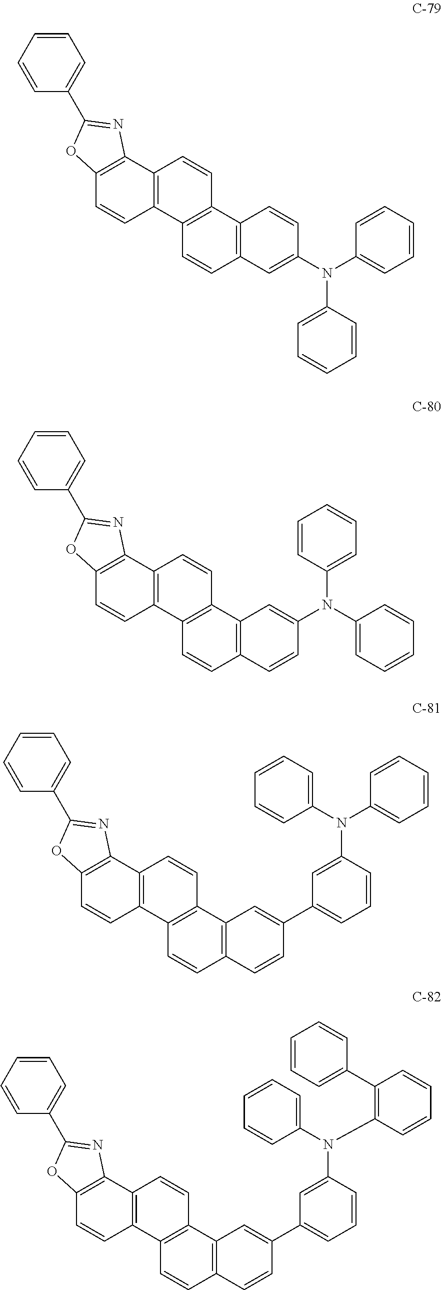 [SMILES: c1ccc(-c2nc3c(ccc4c5ccc6cc(N(c7ccccc7)c7ccccc7)ccc6c5ccc43)o2)cc1 ; c1ccc(-c2nc3c(ccc4c5ccc6ccc(N(c7ccccc7)c7ccccc7)cc6c5ccc43)o2)cc1 ; c1ccc(-c2nc3c(ccc4c5ccc6ccc(-c7cccc(N(c8ccccc8)c8ccccc8)c7)cc6c5ccc43)o2)cc1 ; c1ccc(-c2nc3c(ccc4c5ccc6ccc(-c7cccc(N(c8ccccc8)c8ccccc8-c8ccccc8)c7)cc6c5ccc43)o2)cc1]

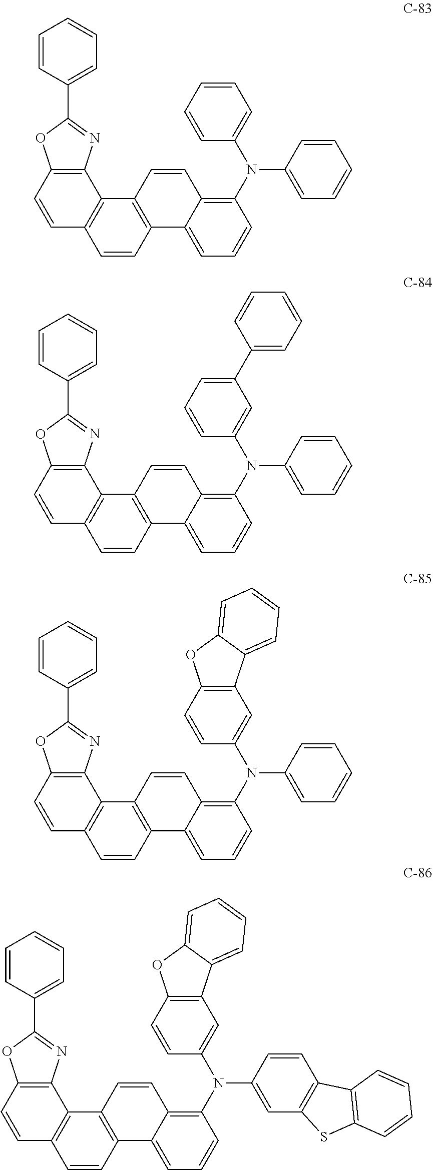

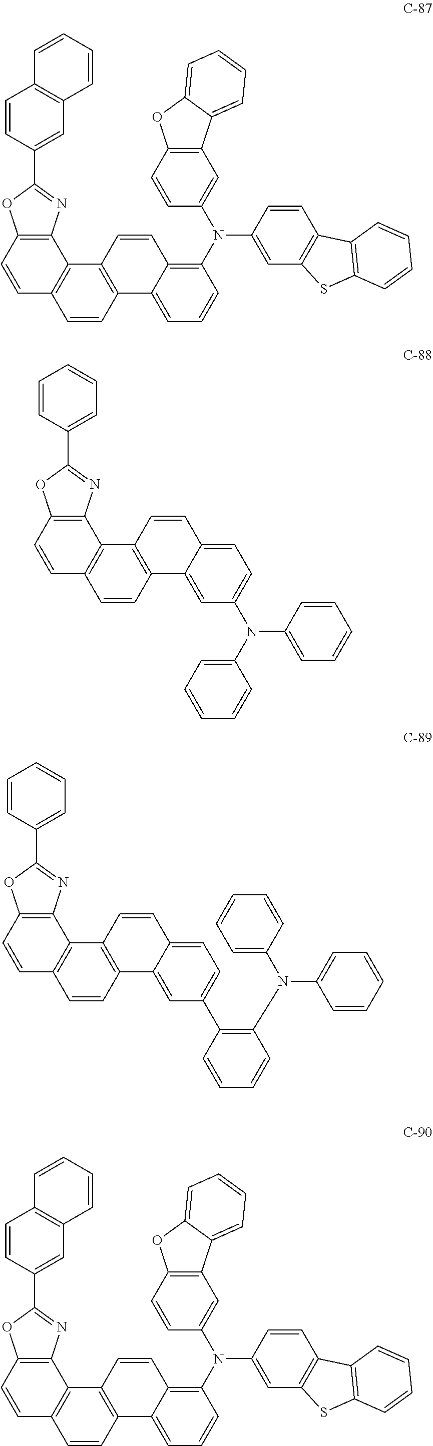

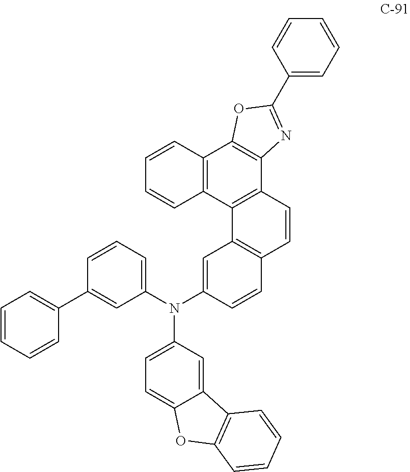 [SMILES: c1ccc(-c2cccc(N(c3ccc4oc5ccccc5c4c3)c3ccc4ccc5c6nc(-c7ccccc7)oc6c6ccccc6c5c4c3)c2)cc1]

The host compound of formula 1 according to the present disclosure may be prepared as represented by the following reaction scheme 1 or 2, but is not limited thereto; they may further be produced by a synthetic method known to a person skilled in the art.

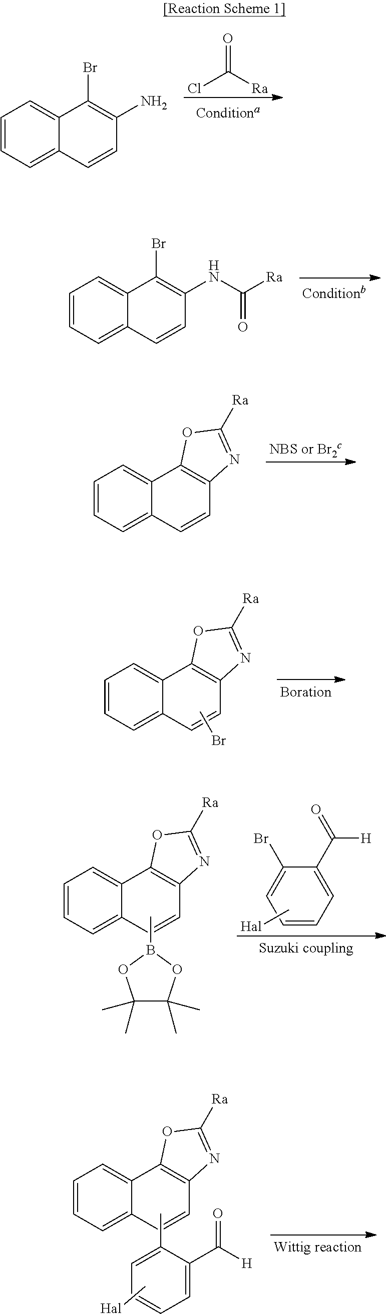

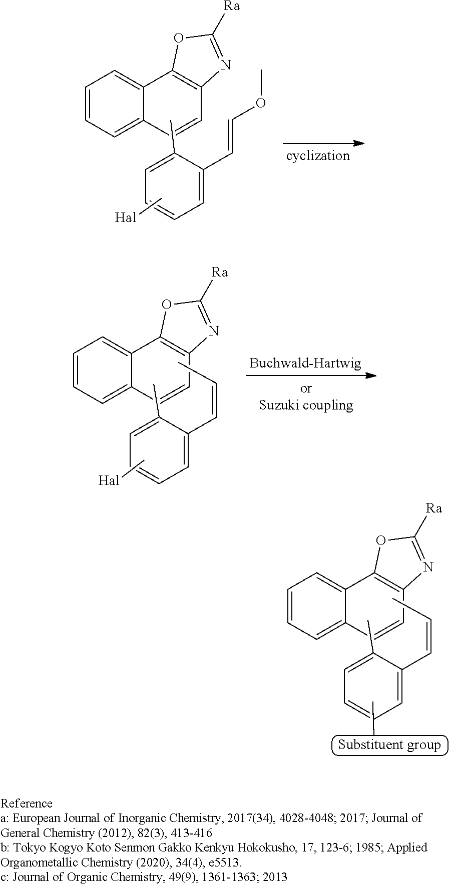

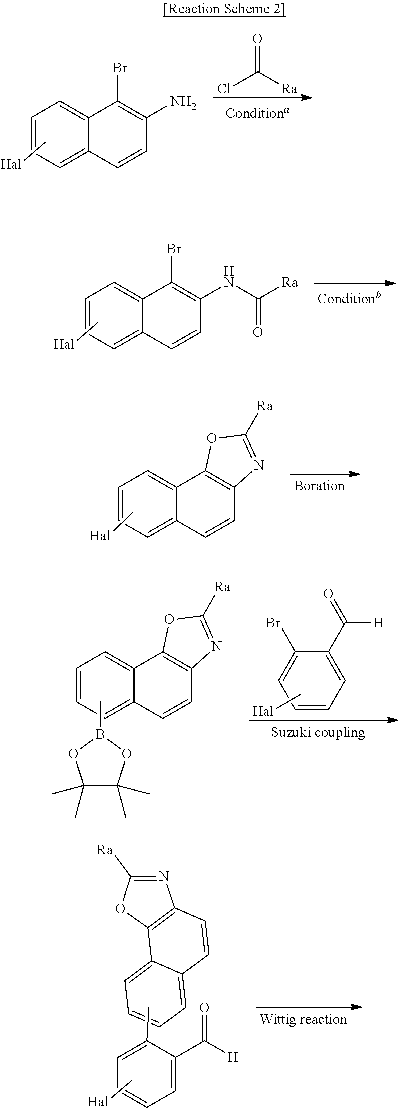

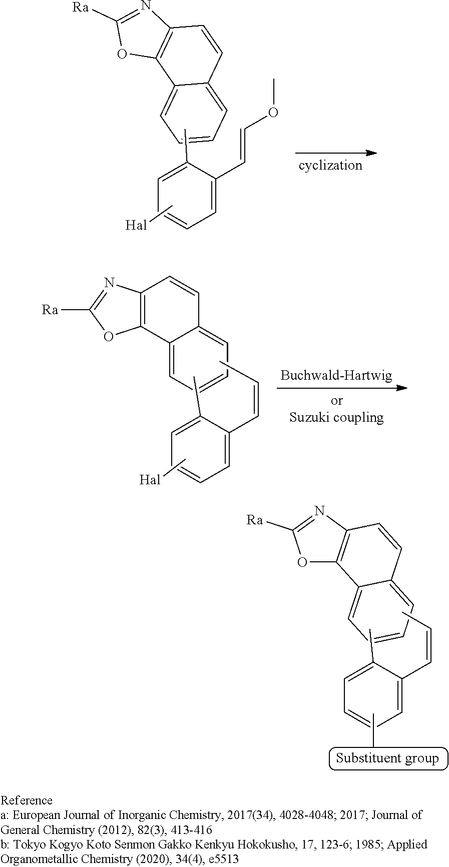

In reaction schemes 1 and 2, the definition of each of the substituents is as defined in formula 1, and Hal means a halogen atom.

As described above, exemplary synthesis examples of the compounds represented by formula 1 according to the present disclosure are described, but they are based on Suzuki cross-coupling reaction, Wittig reaction, Buchwald-Hartwig cross coupling reaction, Miyaura borylation reaction, N-arylation reaction, H-mont-mediated etherification reaction, Intramolecular acid-induced cyclization reaction, Pd(II)-catalyzed oxidative cyclization reaction, Grignard reaction, Heck reaction, Cyclic Dehydration reaction, SN₁ substitution reaction, SN₂ substitution reaction, and Phosphine-mediated reductive cyclization reaction, etc. It will be understood by one skilled in the art that the above reaction proceeds even if other substituents defined in the formula 1 other than the substituents described in the specific synthesis examples are bonded.

The second host compound as another host material according to one embodiment is represented by the following formula 2.

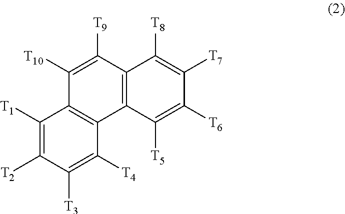

in formula 2,
T₅ and T₆ are linked to each other to form a ring of the following formula 3; or T₇ and Tₐ are linked to each other to form a ring of the following formula 3; or T₅ and T₆ are linked to each other to form a ring of the following formula 3, while T₇ and Tₐ are linked to each other to form a ring of the following formula 3; or T₅ and T₆ are linked to each other to form a ring of the following formula 3, while T₉ and T₁₀ are linked to each other to form a ring of the following formula 3-1; or T₇ and Tₐ are linked to each other to form a ring of the following formula 3, while T₉ and T₁₀ are linked to each other to form a ring of the following formula 3-1; or T₇ and Tₐ are linked to each other to form a ring of the following formula 3, while T₁ and T₂ are linked to each other to form a ring of the following formula 3-1; or T₁ and T₂ are linked to each other to form a ring of the following formula 3, while T₅ and T₆ are linked to each other to form a ring of the following formula 3-1; or T₉ and T₁₀ are linked to each other to form a ring of the following formula 3, while T₁ and T₂ are linked to each other to form a ring of the following formula 3-1; or T₅ and T₆ are linked to each other to form a ring of the following formula 3, while T₃ and T₄ are linked to each other to form a ring of the following formula 3-1;

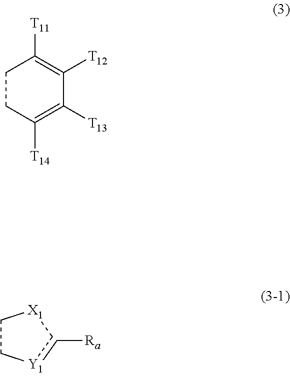

in formulas 2, 3, and 3-1,
T₁ to T₁₄, and T₁ to T₁₀ that do not form a ring, each independently represent, hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted fused ring of (C3-C30) aliphatic ring and (C6-C30) aromatic ring, —SiR₁₁R₁₂R₁₃, —NR₁₄R₁₅, or -L₂-Ar₂; provided that at least one of T₁ to T₁₄ is (are) -L₂-Ar₂;
X₁ and Y₁ each independently represent, —N═, —NR_{c}—, —O— or —S—; provided that any one of X₁ and Y₁ is —N═, and the other of X₁ and Y₁ is —NR_{c}—, —O— or —S—;
Rₐ and R_{c} each independently represent, a substituted or unsubstituted (C6-C30)aryl or a substituted or unsubstituted (3- to 30-membered)heteroaryl;
L₂ represents a single bond, a substituted or unsubstituted (C6-C30)arylene, or a substituted or unsubstituted (3- to 30-membered)heteroarylene;
Ar₂ represents a substituted or unsubstituted (C6-C30)aryl or a substituted or unsubstituted (3- to 30-membered)heteroaryl;
R₁₁ to R₁₅ each independently represent, a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl; and
[symbol] represents a fusing site with the formula 2.

In one embodiment, in the formula 2, T₅ and T₆ may be linked to each other to form a ring of formula 3, or T₇ and T₈ may be linked to each other to form a ring of formula 3.

In one embodiment, in the formula 2, T₅ and T₆ may be linked to each other to form a ring of formula 3, while T₉ and T₁₀ may be linked to each other to form a ring of formula 3-1.

In one embodiment, in the formula 2, T₇ and T₈ may be linked to each other to form a ring of formula 3, while T₉ and T₁₀ may be linked to each other to form a ring of formula 3-1.

In one embodiment, in the formula 2, T₇ and T₈ may be linked to each other to form a ring of formula 3, while T₁ and T₂ may be linked to each other to form a ring of formula 3-1.

In one embodiment, in the formula 2, T₁ and T₂ may be linked to each other to form a ring of formula 3, while T₅ and T₆ may be linked to each other to form a ring of formula 3-1.

In one embodiment, T₉ and T₁₀ may be linked to each other to form a ring of formula 3, while T₁ and T₂ may be linked to each other to form a ring of formula 3-1.

In one embodiment, T₅ and T₆ may be linked to each other to form a ring of formula 3, while T₃ and T₄ may be linked to each other to form a ring of formula 3-1.

In one embodiment, in the formula 3-1, any one of X₁ and Y₁ may be —N═, and the other of X₁ and Y₁ may be —O—.

In one embodiment, Rₐ may be a substituted or unsubstituted (C6-C30)aryl, preferably a substituted or unsubstituted (C6-C25)aryl, more preferably a substituted or unsubstituted (C6-C18)aryl. For example, Rₐ may be a substituted or unsubstituted phenyl.

In one embodiment, T₁ to T₁₄ each independently may be hydrogen, a substituted or unsubstituted (C6-C30)aryl, or -L₂-Ar₂, preferably hydrogen, a substituted or unsubstituted (C6-C25)aryl, or -L₂-Ar₂, more preferably hydrogen, a substituted or unsubstituted (C6-C18)aryl, or -L₂-Ar₂, provided that at least one of T₁ to T₁₄ may be -L₂-Ar₂. For example, T₁ to T₁₄ each independently may be hydrogen, phenyl, naphthyl, biphenyl, or -L₂-Ar₂.

In one embodiment, L₂ may be a single bond, or a substituted or unsubstituted (C6-C25)arylene, preferably a single bond or (C6-C18)arylene unsubstituted or substituted by (C6-C18)aryl. For example, L₂ may be a single bond, or phenylene, naphthylene, or biphenylene unsubstituted or substituted by phenyl.

In one embodiment, Ar₂ may be a substituted or unsubstituted (C6-C30)aryl or a substituted or unsubstituted (5- to 30-membered)heteroaryl, preferably a substituted or unsubstituted (C6-C25)aryl or a substituted or unsubstituted (5- to 25-membered)heteroaryl, more preferably a substituted or unsubstituted (5- to 25-membered)heteroaryl. For example, Ar₂ may be a substituted or unsubstituted pyridyl, a substituted or unsubstituted pyrimidinyl, a substituted or unsubstituted triazinyl, a substituted or unsubstituted pyrazinyl, a substituted or unsubstituted pyridazinyl, a substituted or unsubstituted quinazolinyl, a substituted or unsubstituted benzoquinazolinyl, a substituted or unsubstituted quinoxalinyl, a substituted or unsubstituted benzoquinoxalinyl, a substituted or unsubstituted quinolyl, a substituted or unsubstituted benzoquinolyl, a substituted or unsubstituted isoquinolyl, a substituted or unsubstituted benzoisoquinolyl, a substituted or unsubstituted triazolyl, a substituted or unsubstituted pyrazolyl, a substituted or unsubstituted naphthyridinyl, a substituted or unsubstituted benzothienopyrimidinyl, a substituted or unsubstituted benzoimidazolyl, a substituted or unsubstituted benzofuropyrimidinyl, a substituted or unsubstituted acenaphthopyrimidinyl, a substituted or unsubstituted benzopyrimidinyl, a substituted or unsubstituted benzothienoquinolyl, a substituted or unsubstituted dibenzoquinoxalinyl, or a substituted or unsubstituted phenanthroimidazolyl. For example, Ar₂ may be substituted pyrimidinyl; substituted triazinyl; benzoimidazolyl substituted by phenyl; quinolyl substituted by naphthyl; isoquinolyl substituted by phenyl; quinazolinyl substituted by one or more of phenyl and biphenyl; quinoxalinyl substituted by one or more of phenyl and biphenyl; naphthyridinyl substituted by phenyl; benzofuropyrimidinyl substituted by biphenyl; benzoquinoxalinyl substituted by biphenyl; acenaphthopyrimidinyl substituted by phenyl; benzopyrimidinyl substituted by one or more methyl; benzothienoquinolyl; dibenzoquinoxalinyl; phenanthroimidazolyl substituted by at least one of phenyl and biphenyl. For example, the substituents of the substituted groups may be at least one of phenyl; phenyl substituted by fluorine; phenyl substituted by tert-butyl; phenyl substituted by trimethylsilyl; phenyl substituted by carbazolyl; phenyl substituted by cyclohexyl; phenyl substituted by cyano; naphthyl; biphenyl; terphenyl; naphthylphenyl; phenanthrenyl; anthracenyl; chrysenyl; triphenylenyl; dimethylfluorenyl; diphenylfluorenyl; spirobifluorenyl; pyridyl substituted by phenyl; dibenzothiophenyl; dibenzofuranyl; dibenzofuranyl substituted by phenyl; dibenzofuranyl substituted by biphenyl; carbazolyl; carbazolyl substituted by phenyl; phenoxazinyl; benzothiophenyl; and naphthoxazolinyl substituted by phenyl.

According to one embodiment, Ar₂ may be represented by the following formula 2-a.

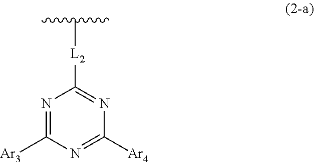

in formula 2-a,
L₂ is as defined in formula 2; and
Ar₃ and Ar₄ each independently represent, a substituted or unsubstituted (C6-C30)aryl, a substituted or unsubstituted (3- to 30-membered)heteroaryl, or a substituted or unsubstituted fused ring of (C3-C30) aliphatic ring and (C6-C30) aromatic ring.

In one embodiment, Ar₃ and Ar₄ each independently represent, a substituted or unsubstituted (C6-C30)aryl or a substituted or unsubstituted (5- to 30-membered)heteroaryl, preferably a substituted or unsubstituted (C6-C25)aryl or a substituted or unsubstituted (5- to 25-membered)heteroaryl, more preferably a substituted or unsubstituted (C6-C25)aryl or a substituted or unsubstituted (5- to 18-membered)heteroaryl. For example, Ar₃ and Ar₄ each independently may be a substituted or unsubstituted phenyl, a substituted or unsubstituted naphthyl, a substituted or unsubstituted p-biphenyl, a substituted or unsubstituted m-biphenyl, a substituted or unsubstituted o-biphenyl, a substituted or unsubstituted naphthylphenyl, a substituted or unsubstituted p-terphenyl, a substituted or unsubstituted m-terphenyl, a substituted or unsubstituted phenanthrenyl, a substituted or unsubstituted chrysenyl, a substituted or unsubstituted fluorenyl, a substituted or unsubstituted triphenylenyl, a substituted or unsubstituted C22 aryl, a substituted or unsubstituted spirobifluorenyl, a substituted or unsubstituted carbazolyl, a substituted or unsubstituted benzothiophenyl, a substituted or unsubstituted dibenzofuranyl, a substituted or unsubstituted dibenzothiophenyl, a substituted or unsubstituted phenoxazinyl, or a substituted or unsubstituted naphthoisoxazolyl. For example, the substituents of the substituted groups may be at least one of fluorenyl (F); cyano; methyl; tert-butyl; trimethylsilyl; phenyl; and biphenyl.

According to one embodiment, the host compound represented by formula 2 may be represented by any one of the following formulas 2-1 to 2-14.

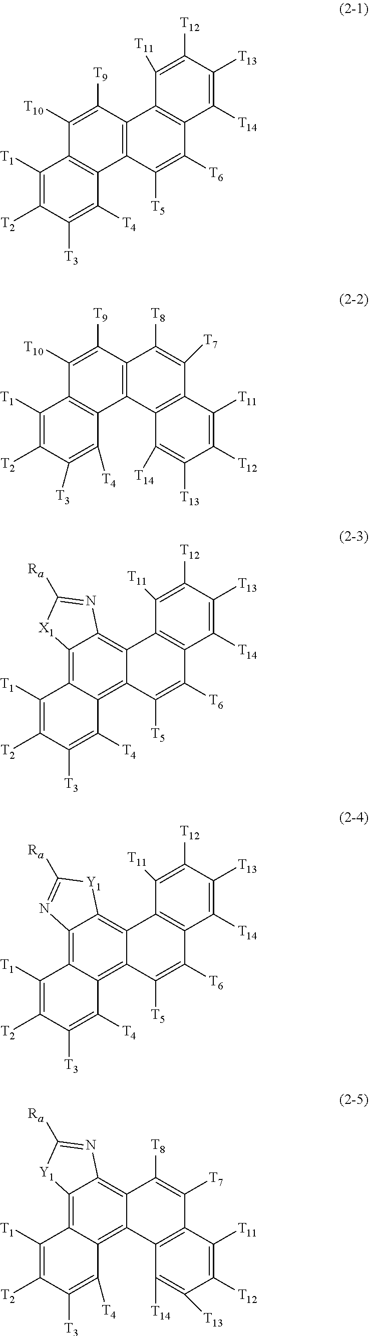

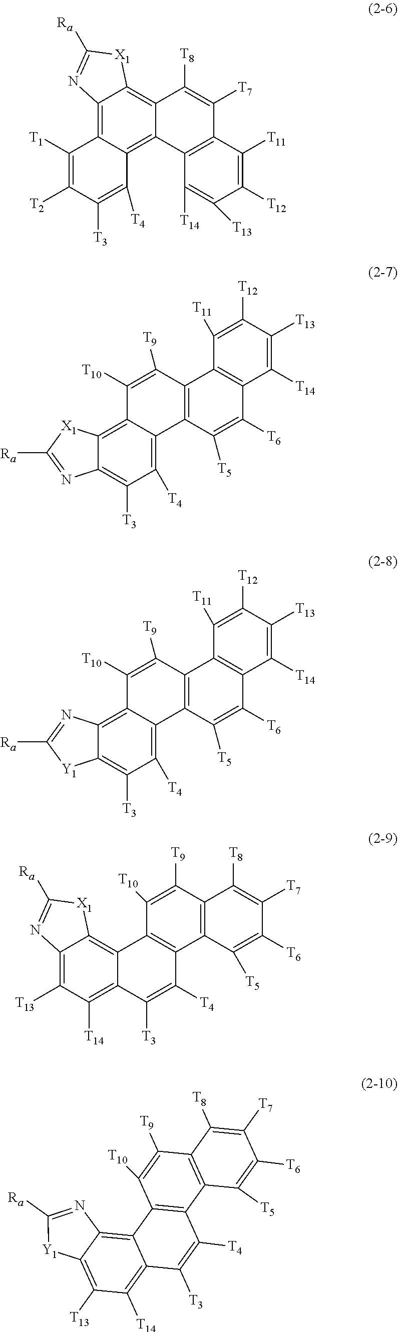

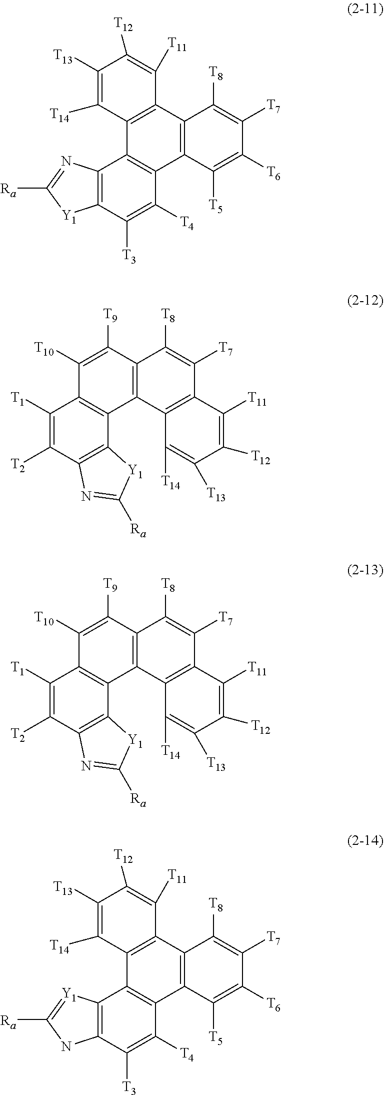

in formulas 2-1 to 2-14
T₁ to T₁₄, X₁, Y₁, and Rₐ are as defined in formula 2.

According to one embodiment, the second host compound represented by formula 2 may be more specifically illustrated by the following compounds, but is not limited thereto.

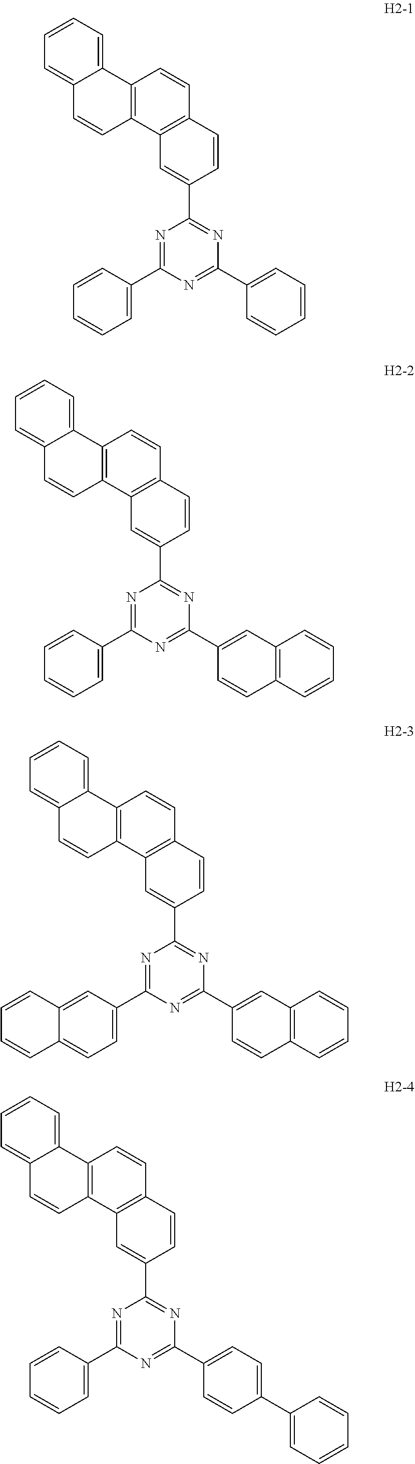

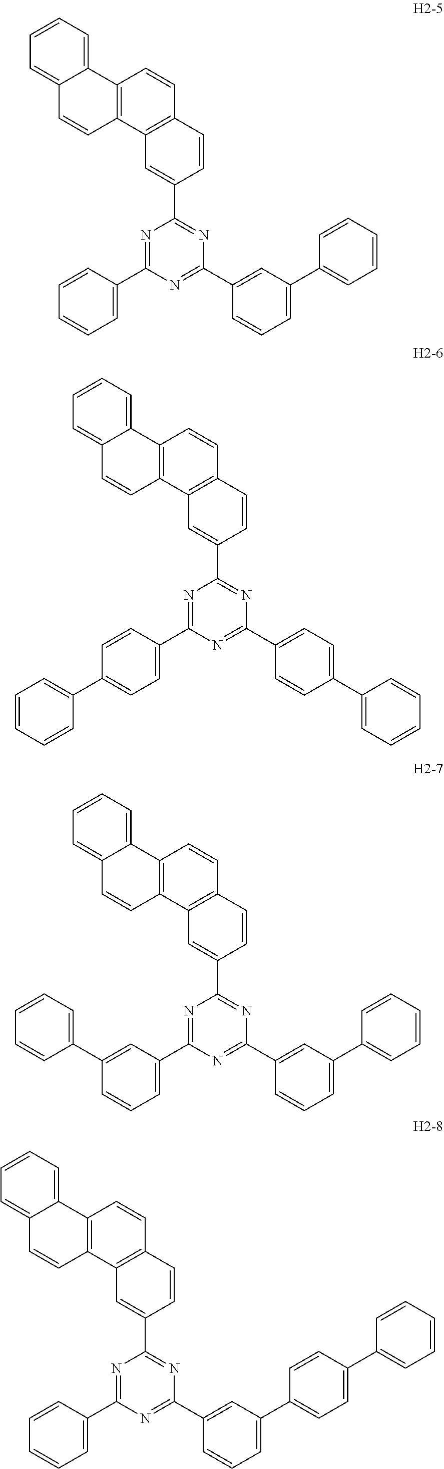

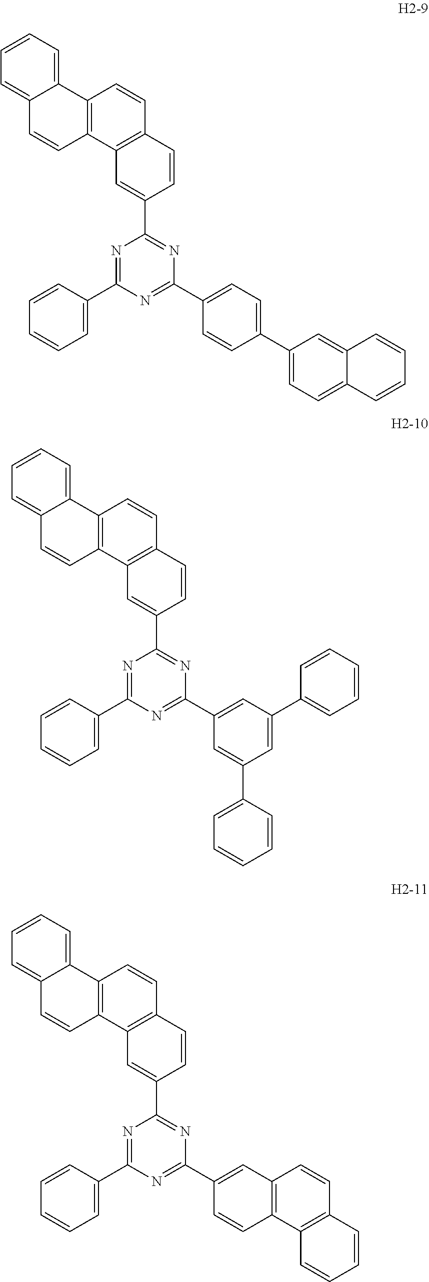 [SMILES: c1ccc(-c2nc(-c3ccc(-c4ccc5ccccc5c4)cc3)nc(-c3ccc4ccc5c6ccccc6ccc5c4c3)n2)cc1 ; c1ccc(-c2cc(-c3ccccc3)cc(-c3nc(-c4ccccc4)nc(-c4ccc5ccc6c7ccccc7ccc6c5c4)n3)c2)cc1 ; c1ccc(-c2nc(-c3ccc4c(ccc5ccccc54)c3)nc(-c3ccc4ccc5c6ccccc6ccc5c4c3)n2)cc1]

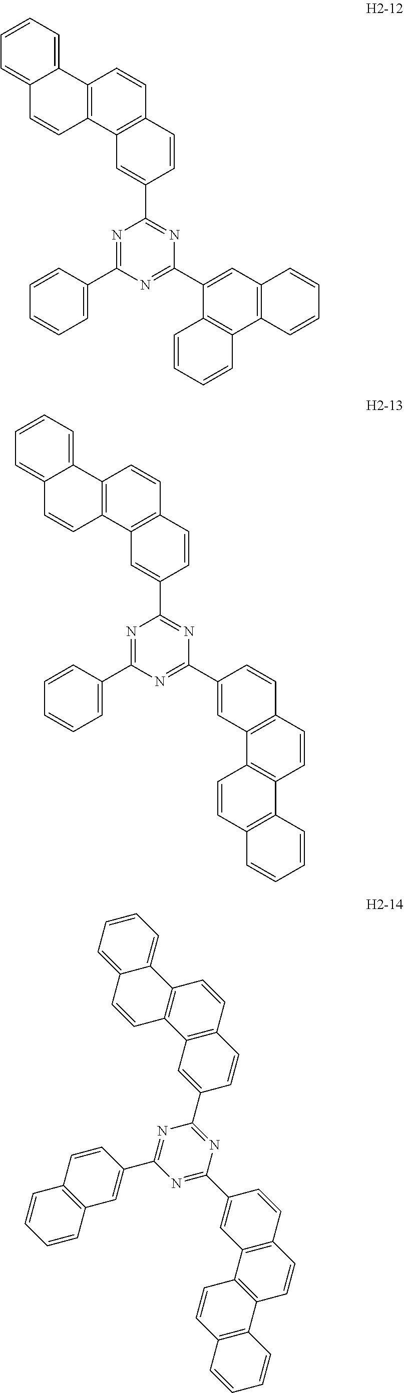 [SMILES: c1ccc(-c2nc(-c3ccc4ccc5c6ccccc6ccc5c4c3)nc(-c3cc4ccccc4c4ccccc34)n2)cc1 ; c1ccc(-c2nc(-c3ccc4ccc5c6ccccc6ccc5c4c3)nc(-c3ccc4ccc5c6ccccc6ccc5c4c3)n2)cc1 ; c1ccc2cc(-c3nc(-c4ccc5ccc6c7ccccc7ccc6c5c4)nc(-c4ccc5ccc6c7ccccc7ccc6c5c4)n3)ccc2c1]

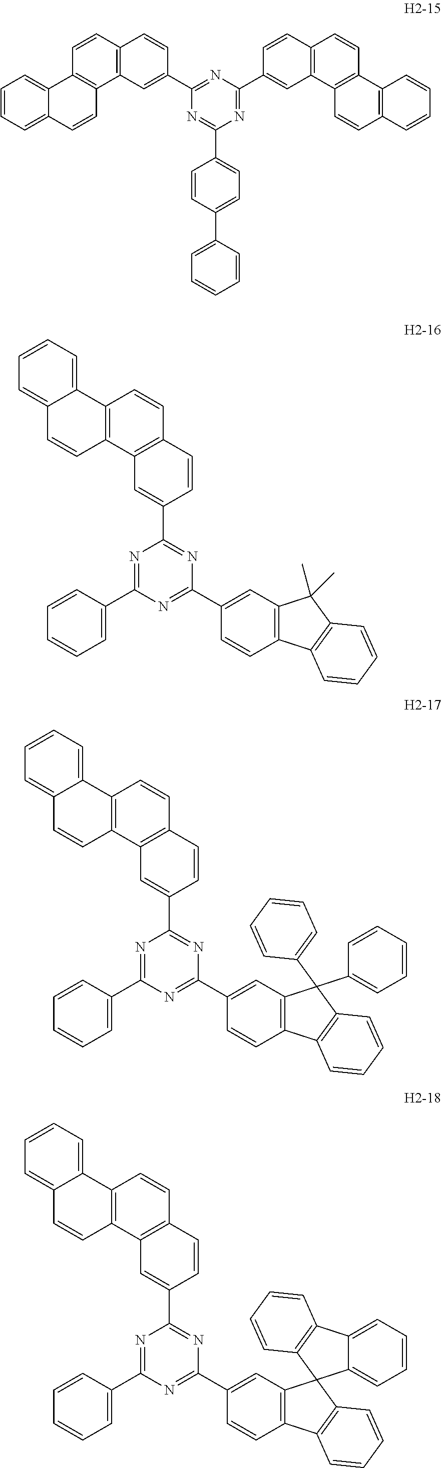 [SMILES: c1ccc(-c2ccc(-c3nc(-c4ccc5ccc6c7ccccc7ccc6c5c4)nc(-c4ccc5ccc6c7ccccc7ccc6c5c4)n3)cc2)cc1 ; CC1(C)c2ccccc2-c2ccc(-c3nc(-c4ccccc4)nc(-c4ccc5ccc6c7ccccc7ccc6c5c4)n3)cc21 ; c1ccc(-c2nc(-c3ccc4c(c3)C(c3ccccc3)(c3ccccc3)c3ccccc3-4)nc(-c3ccc4ccc5c6ccccc6ccc5c4c3)n2)cc1 ; c1ccc(-c2nc(-c3ccc4c(c3)C3(c5ccccc5-c5ccccc53)c3ccccc3-4)nc(-c3ccc4ccc5c6ccccc6ccc5c4c3)n2)cc1]

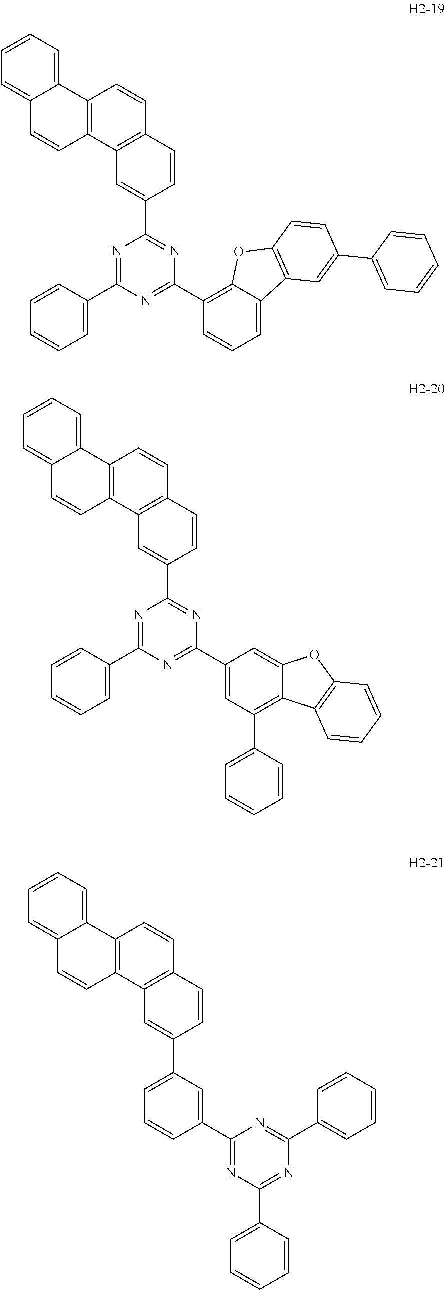 [SMILES: c1ccc(-c2ccc3oc4c(-c5nc(-c6ccccc6)nc(-c6ccc7ccc8c9ccccc9ccc8c7c6)n5)cccc4c3c2)cc1 ; c1ccc(-c2nc(-c3cc(-c4ccccc4)c4c(c3)oc3ccccc34)nc(-c3ccc4ccc5c6ccccc6ccc5c4c3)n2)cc1 ; c1ccc(-c2nc(-c3ccccc3)nc(-c3cccc(-c4ccc5ccc6c7ccccc7ccc6c5c4)c3)n2)cc1]

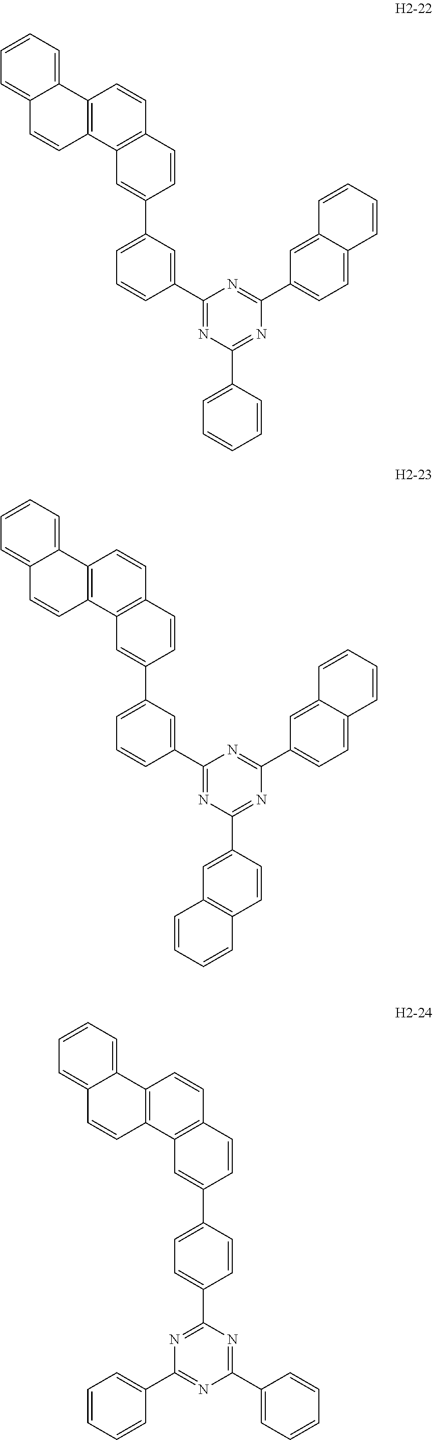 [SMILES: c1ccc(-c2nc(-c3cccc(-c4ccc5ccc6c7ccccc7ccc6c5c4)c3)nc(-c3ccc4ccccc4c3)n2)cc1 ; c1cc(-c2ccc3ccc4c5ccccc5ccc4c3c2)cc(-c2nc(-c3ccc4ccccc4c3)nc(-c3ccc4ccccc4c3)n2)c1 ; c1ccc(-c2nc(-c3ccccc3)nc(-c3ccc(-c4ccc5ccc6c7ccccc7ccc6c5c4)cc3)n2)cc1]

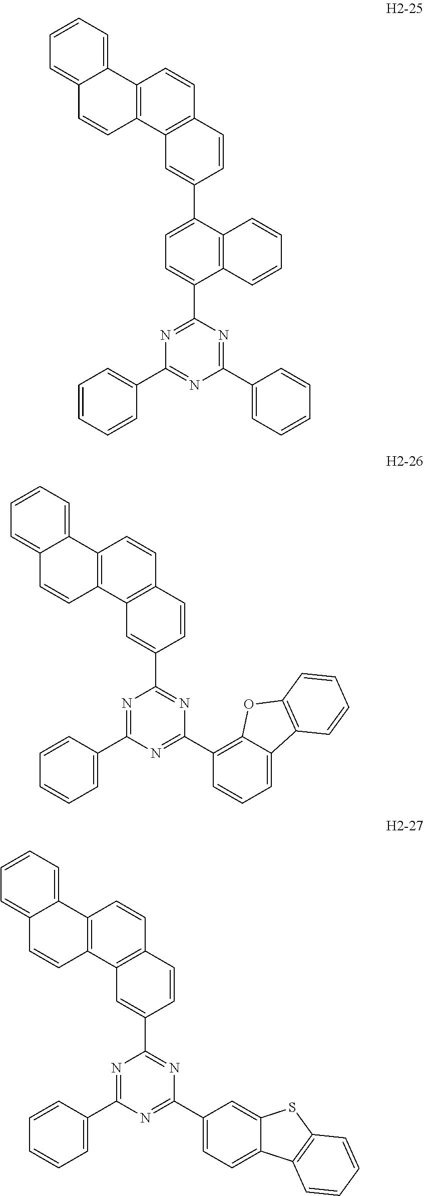 [SMILES: c1ccc(-c2nc(-c3ccccc3)nc(-c3ccc(-c4ccc5ccc6c7ccccc7ccc6c5c4)c4ccccc34)n2)cc1 ; c1ccc(-c2nc(-c3ccc4ccc5c6ccccc6ccc5c4c3)nc(-c3cccc4c3oc3ccccc34)n2)cc1 ; c1ccc(-c2nc(-c3ccc4c(c3)sc3ccccc34)nc(-c3ccc4ccc5c6ccccc6ccc5c4c3)n2)cc1]

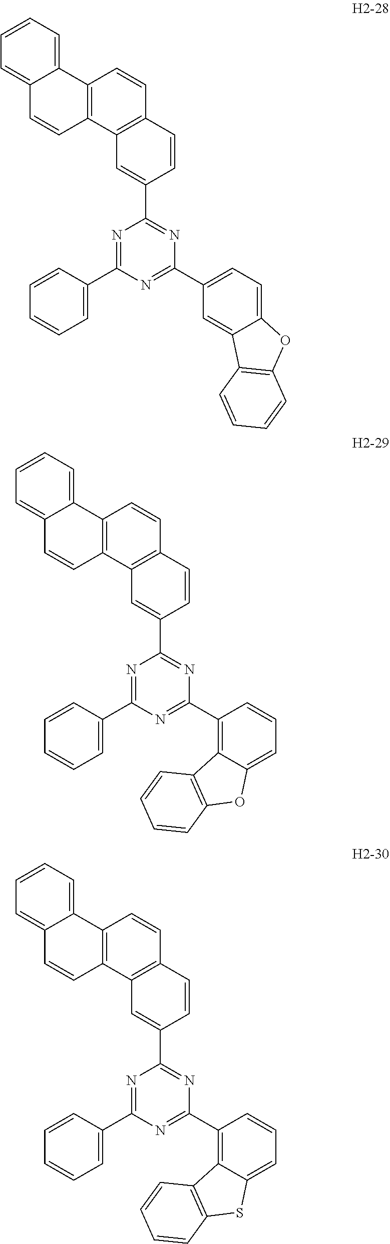 [SMILES: c1ccc(-c2nc(-c3ccc4ccc5c6ccccc6ccc5c4c3)nc(-c3ccc4oc5ccccc5c4c3)n2)cc1 ; c1ccc(-c2nc(-c3ccc4ccc5c6ccccc6ccc5c4c3)nc(-c3cccc4oc5ccccc5c34)n2)cc1 ; c1ccc(-c2nc(-c3ccc4ccc5c6ccccc6ccc5c4c3)nc(-c3cccc4sc5ccccc5c34)n2)cc1]

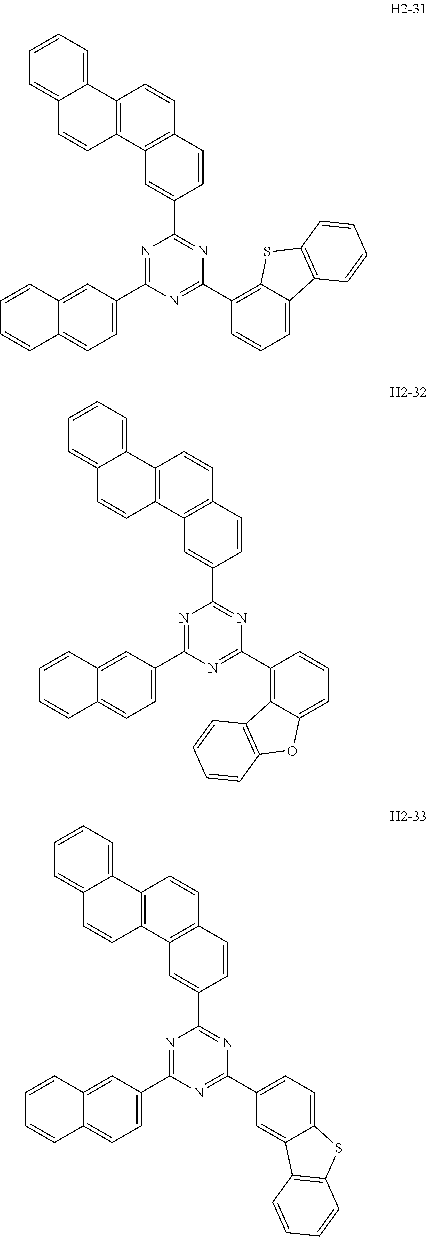 [SMILES: c1ccc2cc(-c3nc(-c4ccc5ccc6c7ccccc7ccc6c5c4)nc(-c4cccc5c4sc4ccccc45)n3)ccc2c1 ; c1ccc2cc(-c3nc(-c4ccc5ccc6c7ccccc7ccc6c5c4)nc(-c4cccc5oc6ccccc6c45)n3)ccc2c1 ; c1ccc2cc(-c3nc(-c4ccc5ccc6c7ccccc7ccc6c5c4)nc(-c4ccc5sc6ccccc6c5c4)n3)ccc2c1]

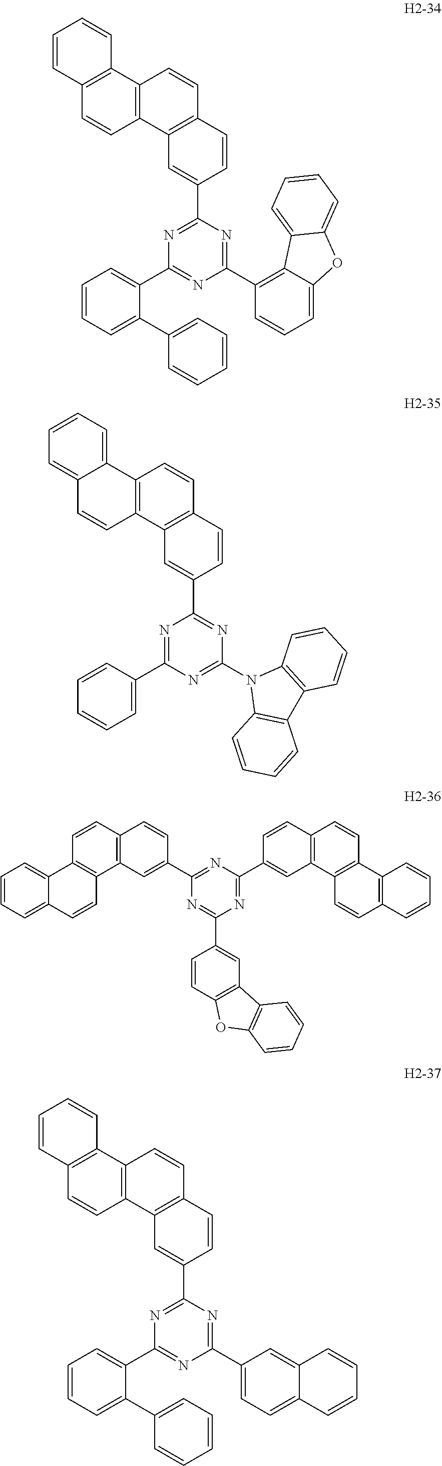 [SMILES: c1ccc(-c2ccccc2-c2nc(-c3ccc4ccc5c6ccccc6ccc5c4c3)nc(-c3cccc4oc5ccccc5c34)n2)cc1 ; c1ccc(-c2nc(-c3ccc4ccc5c6ccccc6ccc5c4c3)nc(-n3c4ccccc4c4ccccc43)n2)cc1 ; c1ccc2c(c1)ccc1c3cc(-c4nc(-c5ccc6ccc7c8ccccc8ccc7c6c5)nc(-c5ccc6oc7ccccc7c6c5)n4)ccc3ccc21 ; c1ccc(-c2ccccc2-c2nc(-c3ccc4ccccc4c3)nc(-c3ccc4ccc5c6ccccc6ccc5c4c3)n2)cc1]

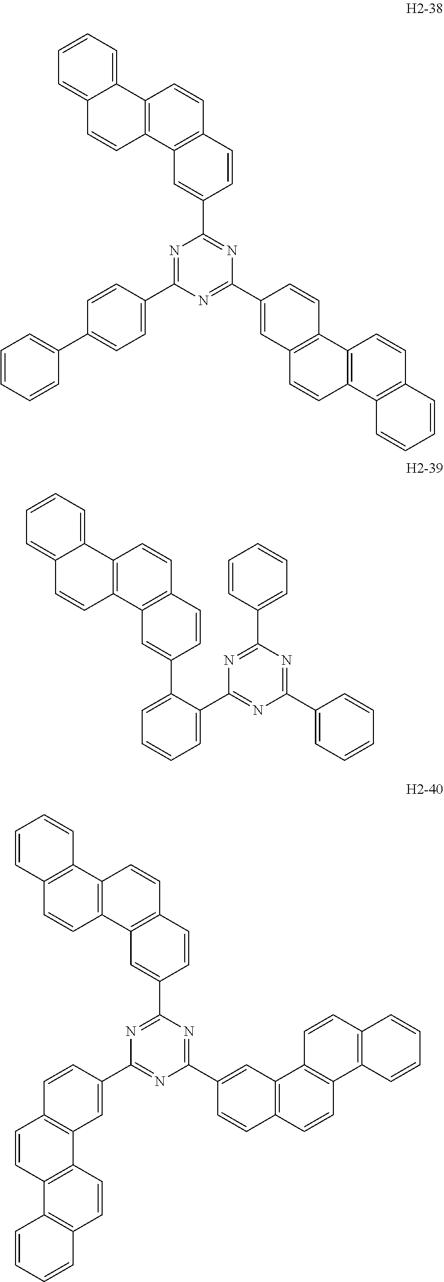 [SMILES: c1ccc(-c2ccc(-c3nc(-c4ccc5c(ccc6c7ccccc7ccc56)c4)nc(-c4ccc5ccc6c7ccccc7ccc6c5c4)n3)cc2)cc1 ; c1ccc(-c2nc(-c3ccccc3)nc(-c3ccccc3-c3ccc4ccc5c6ccccc6ccc5c4c3)n2)cc1 ; c1ccc2c(c1)ccc1c3cc(-c4nc(-c5ccc6ccc7c8ccccc8ccc7c6c5)nc(-c5ccc6ccc7c8ccccc8ccc7c6c5)n4)ccc3ccc21]

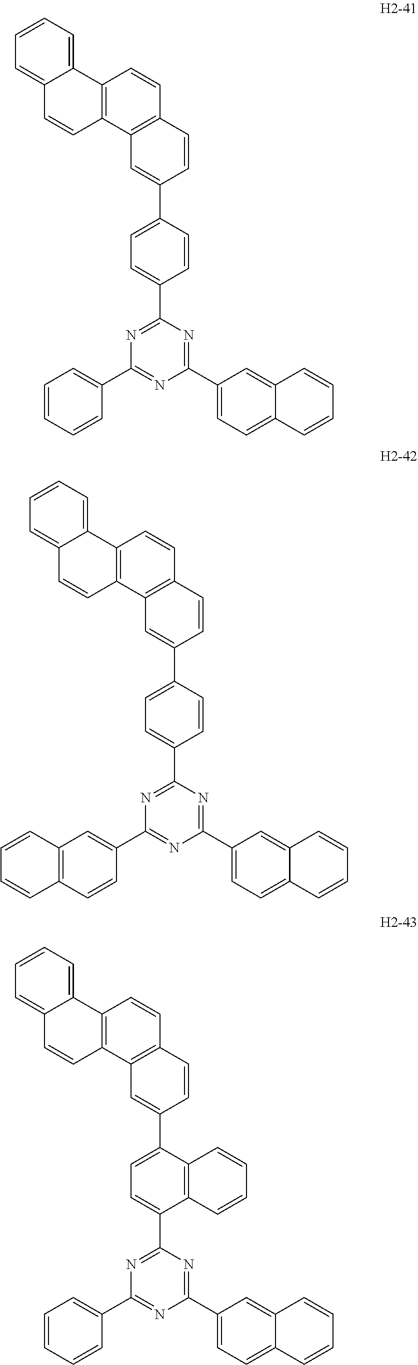 [SMILES: c1ccc(-c2nc(-c3ccc(-c4ccc5ccc6c7ccccc7ccc6c5c4)cc3)nc(-c3ccc4ccccc4c3)n2)cc1 ; c1ccc2cc(-c3nc(-c4ccc(-c5ccc6ccc7c8ccccc8ccc7c6c5)cc4)nc(-c4ccc5ccccc5c4)n3)ccc2c1 ; c1ccc(-c2nc(-c3ccc4ccccc4c3)nc(-c3ccc(-c4ccc5ccc6c7ccccc7ccc6c5c4)c4ccccc34)n2)cc1]

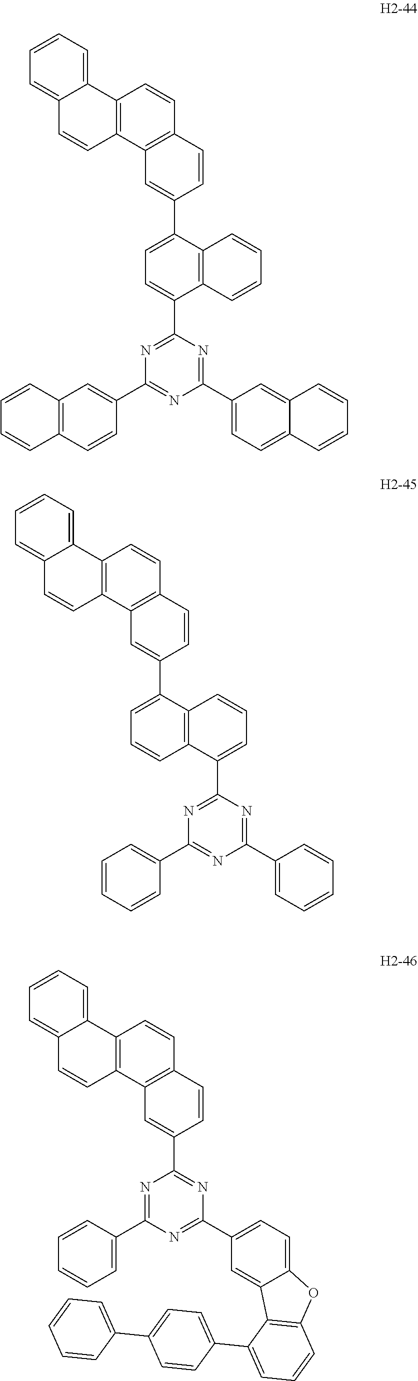

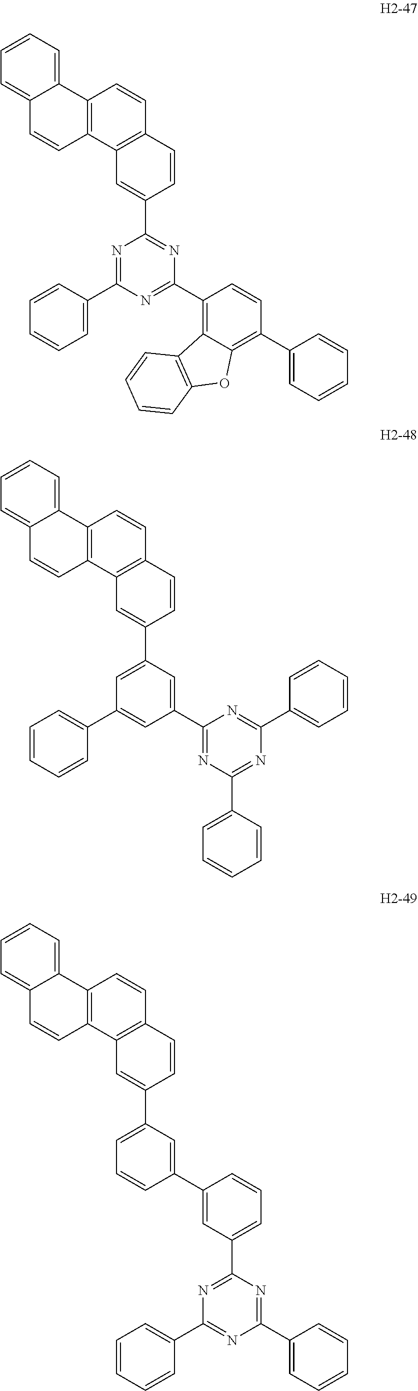 [SMILES: c1ccc(-c2nc(-c3ccc4ccc5c6ccccc6ccc5c4c3)nc(-c3ccc(-c4ccccc4)c4oc5ccccc5c34)n2)cc1 ; c1ccc(-c2cc(-c3ccc4ccc5c6ccccc6ccc5c4c3)cc(-c3nc(-c4ccccc4)nc(-c4ccccc4)n3)c2)cc1 ; c1ccc(-c2nc(-c3ccccc3)nc(-c3cccc(-c4cccc(-c5ccc6ccc7c8ccccc8ccc7c6c5)c4)c3)n2)cc1]

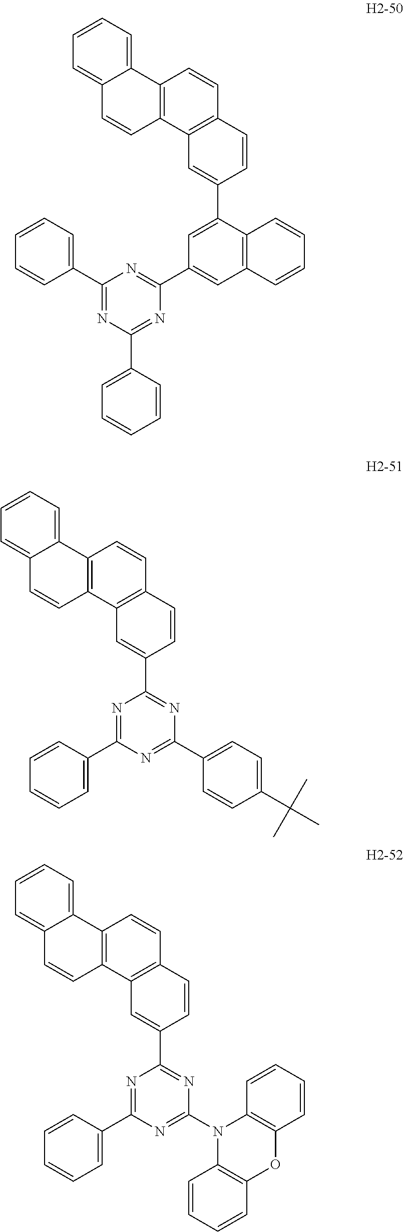 [SMILES: c1ccc(-c2nc(-c3ccccc3)nc(-c3cc(-c4ccc5ccc6c7ccccc7ccc6c5c4)c4ccccc4c3)n2)cc1 ; CC(C)(C)c1ccc(-c2nc(-c3ccccc3)nc(-c3ccc4ccc5c6ccccc6ccc5c4c3)n2)cc1 ; c1ccc(-c2nc(-c3ccc4ccc5c6ccccc6ccc5c4c3)nc(N3c4ccccc4Oc4ccccc43)n2)cc1]

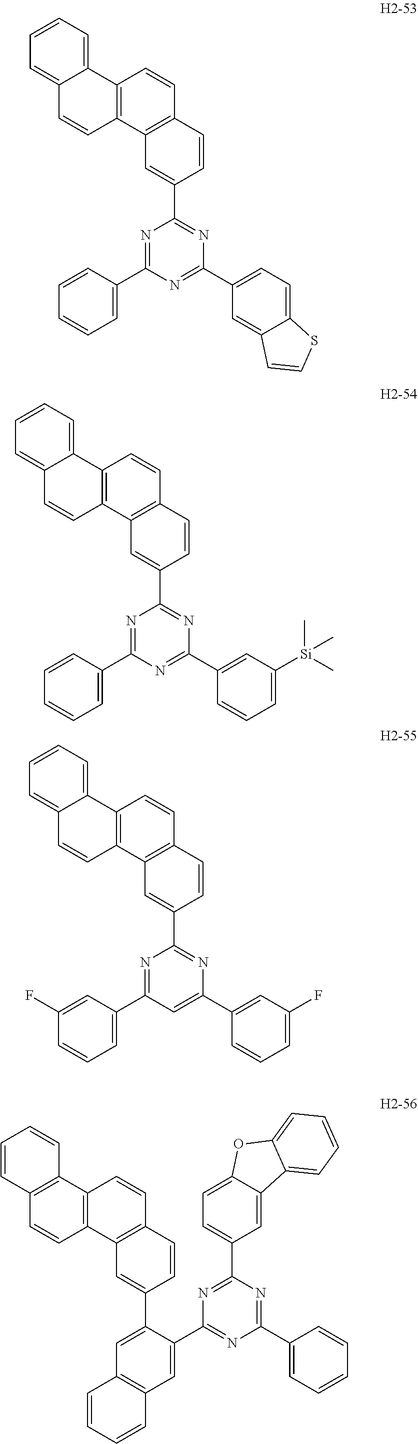

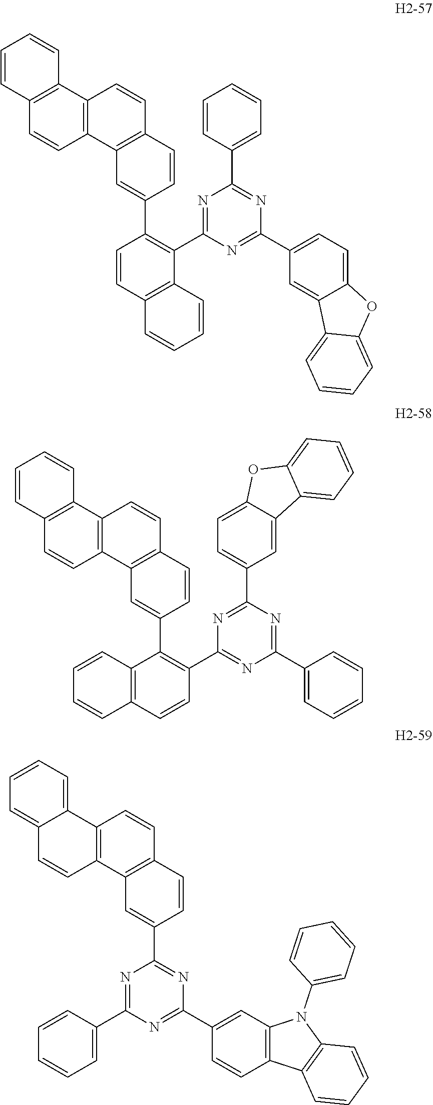 [SMILES: c1ccc(-c2nc(-c3ccc4oc5ccccc5c4c3)nc(-c3c(-c4ccc5ccc6c7ccccc7ccc6c5c4)ccc4ccccc34)n2)cc1 ; c1ccc(-c2nc(-c3ccc4oc5ccccc5c4c3)nc(-c3ccc4ccccc4c3-c3ccc4ccc5c6ccccc6ccc5c4c3)n2)cc1 ; c1ccc(-c2nc(-c3ccc4ccc5c6ccccc6ccc5c4c3)nc(-c3ccc4c5ccccc5n(-c5ccccc5)c4c3)n2)cc1]

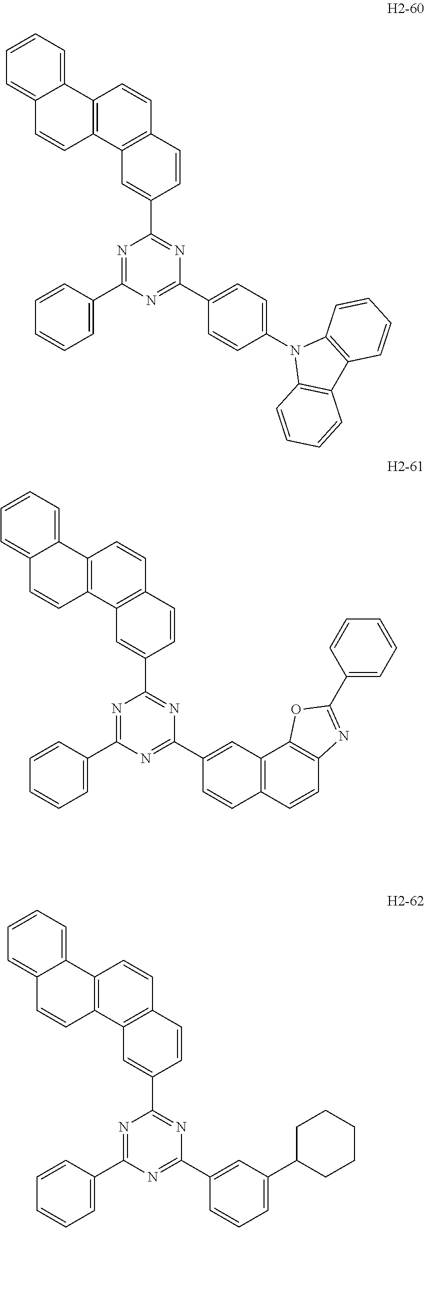

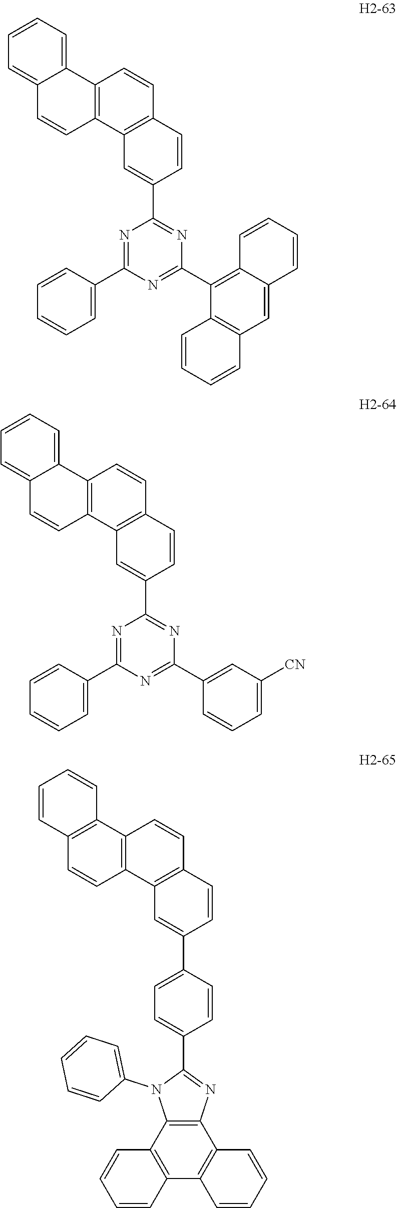

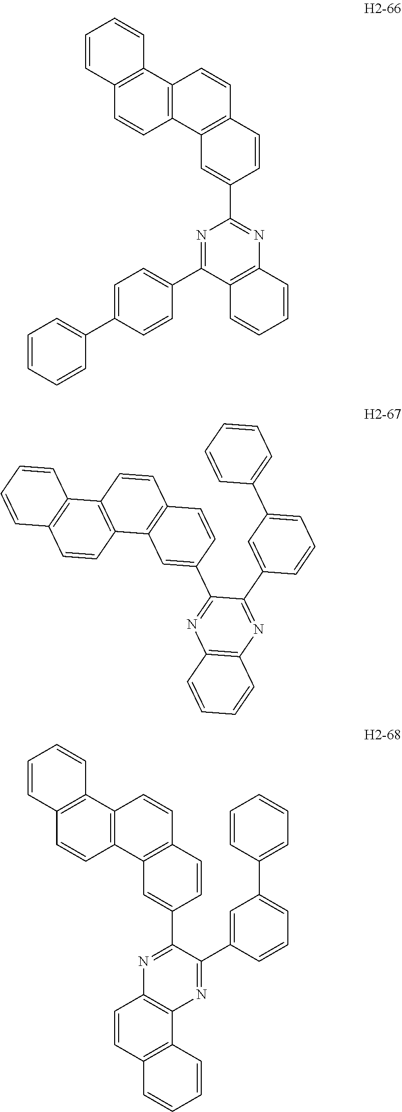 [SMILES: c1ccc(-c2ccc(-c3nc(-c4ccc5ccc6c7ccccc7ccc6c5c4)nc4ccccc34)cc2)cc1 ; c1ccc(-c2cccc(-c3nc4ccccc4nc3-c3ccc4ccc5c6ccccc6ccc5c4c3)c2)cc1 ; c1ccc(-c2cccc(-c3nc4c(ccc5ccccc54)nc3-c3ccc4ccc5c6ccccc6ccc5c4c3)c2)cc1]

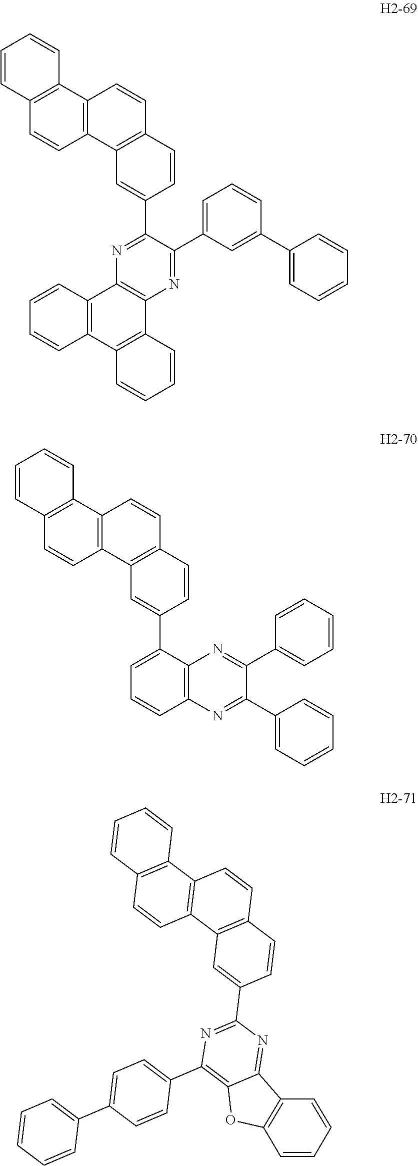 [SMILES: c1ccc(-c2cccc(-c3nc4c5ccccc5c5ccccc5c4nc3-c3ccc4ccc5c6ccccc6ccc5c4c3)c2)cc1 ; c1ccc(-c2nc3cccc(-c4ccc5ccc6c7ccccc7ccc6c5c4)c3nc2-c2ccccc2)cc1 ; c1ccc(-c2ccc(-c3nc(-c4ccc5ccc6c7ccccc7ccc6c5c4)nc4c3oc3ccccc34)cc2)cc1]

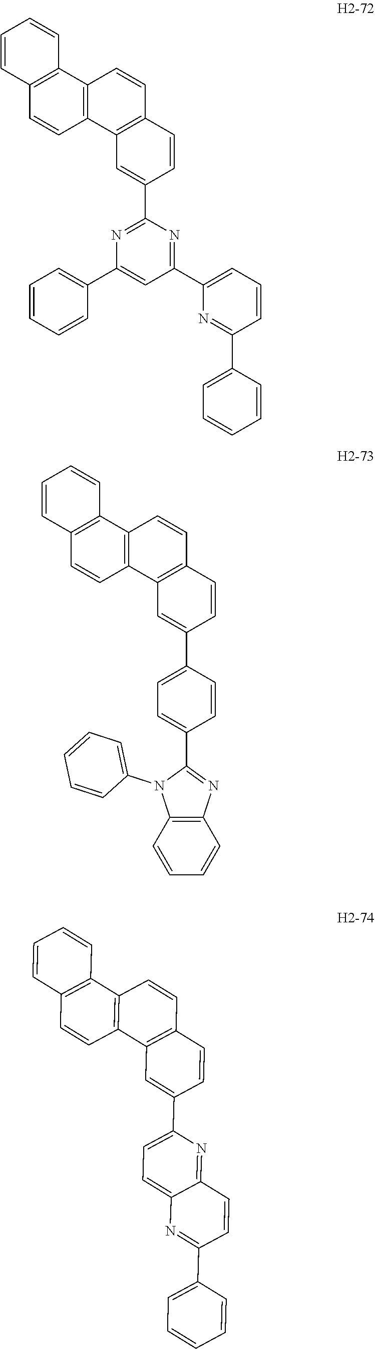 [SMILES: c1ccc(-c2cccc(-c3cc(-c4ccccc4)nc(-c4ccc5ccc6c7ccccc7ccc6c5c4)n3)n2)cc1 ; c1ccc(-n2c(-c3ccc(-c4ccc5ccc6c7ccccc7ccc6c5c4)cc3)nc3ccccc32)cc1 ; c1ccc(-c2ccc3nc(-c4ccc5ccc6c7ccccc7ccc6c5c4)ccc3n2)cc1]

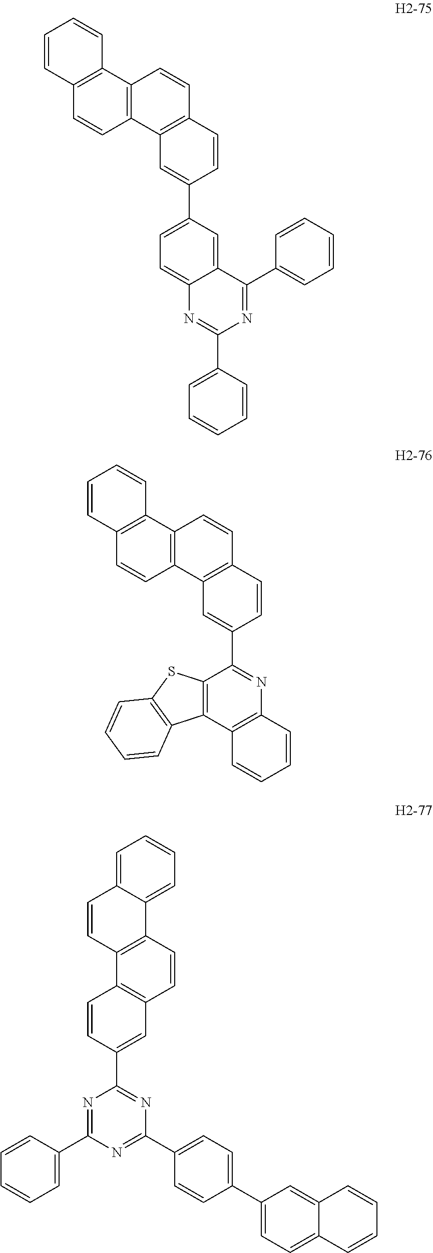 [SMILES: c1ccc(-c2nc(-c3ccccc3)c3cc(-c4ccc5ccc6c7ccccc7ccc6c5c4)ccc3n2)cc1 ; c1ccc2c(c1)ccc1c3cc(-c4nc5ccccc5c5c4sc4ccccc45)ccc3ccc21 ; c1ccc(-c2nc(-c3ccc(-c4ccc5ccccc5c4)cc3)nc(-c3ccc4c(ccc5c6ccccc6ccc45)c3)n2)cc1]

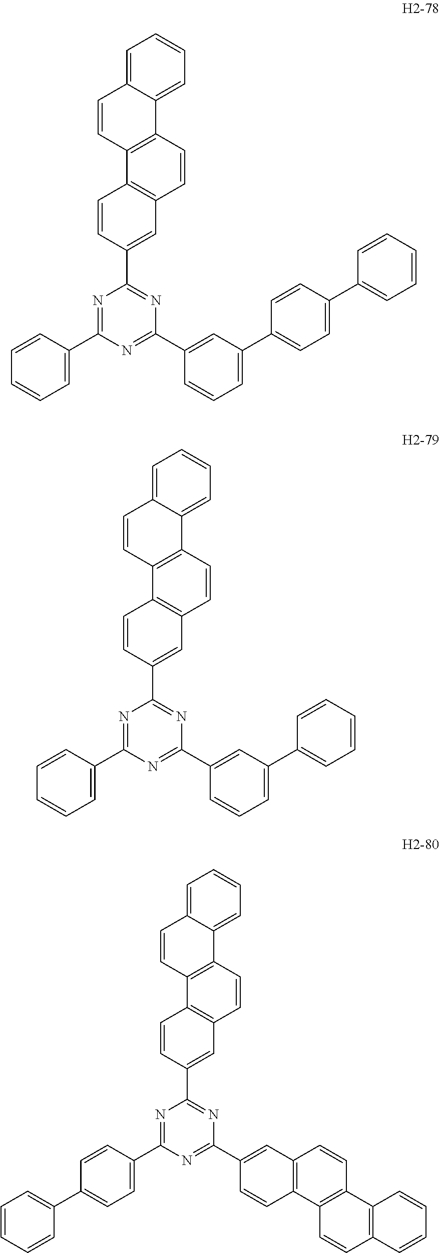 [SMILES: c1ccc(-c2ccc(-c3cccc(-c4nc(-c5ccccc5)nc(-c5ccc6c(ccc7c8ccccc8ccc67)c5)n4)c3)cc2)cc1 ; c1ccc(-c2cccc(-c3nc(-c4ccccc4)nc(-c4ccc5c(ccc6c7ccccc7ccc56)c4)n3)c2)cc1 ; c1ccc(-c2ccc(-c3nc(-c4ccc5c(ccc6c7ccccc7ccc56)c4)nc(-c4ccc5c(ccc6c7ccccc7ccc56)c4)n3)cc2)cc1]

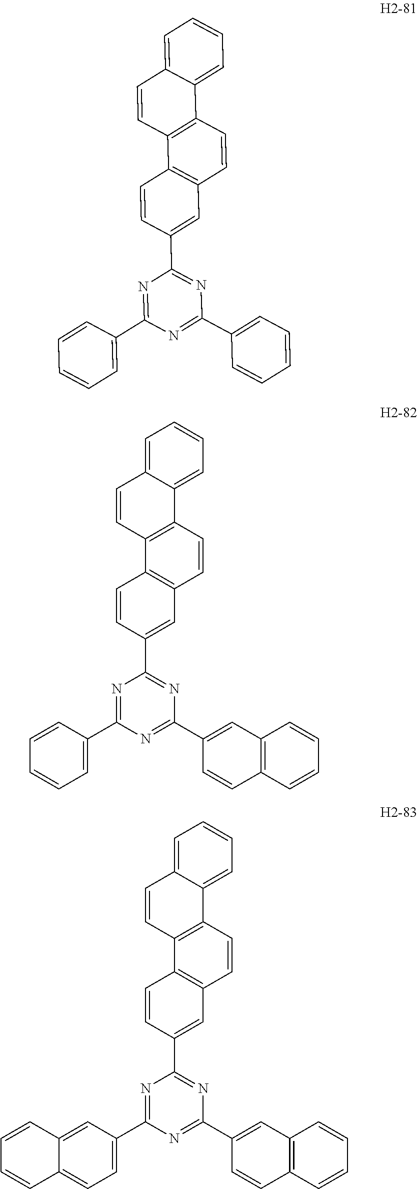

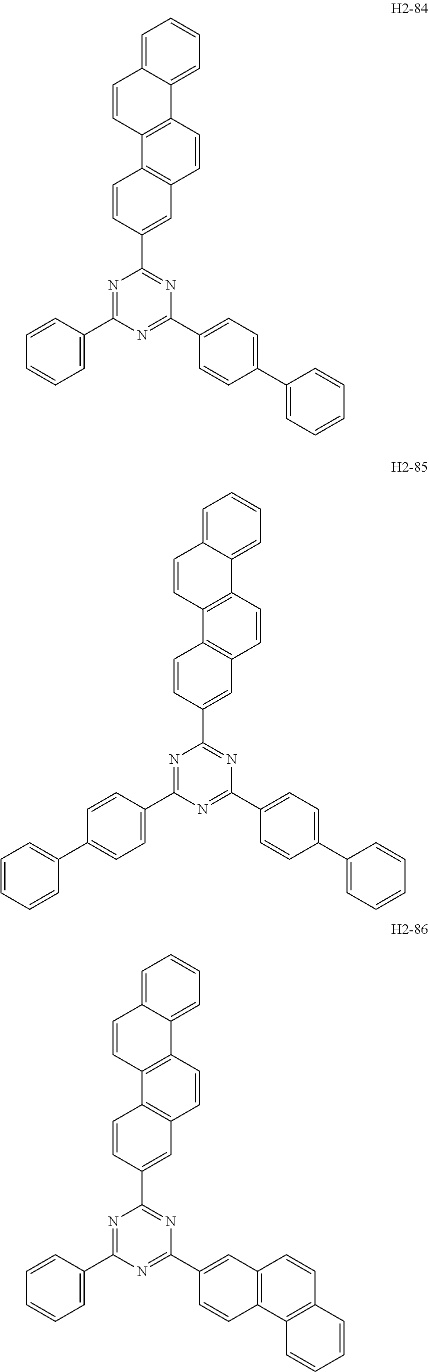 [SMILES: c1ccc(-c2ccc(-c3nc(-c4ccccc4)nc(-c4ccc5c(ccc6c7ccccc7ccc56)c4)n3)cc2)cc1 ; c1ccc(-c2ccc(-c3nc(-c4ccc(-c5ccccc5)cc4)nc(-c4ccc5c(ccc6c7ccccc7ccc56)c4)n3)cc2)cc1 ; c1ccc(-c2nc(-c3ccc4c(ccc5ccccc54)c3)nc(-c3ccc4c(ccc5c6ccccc6ccc45)c3)n2)cc1]

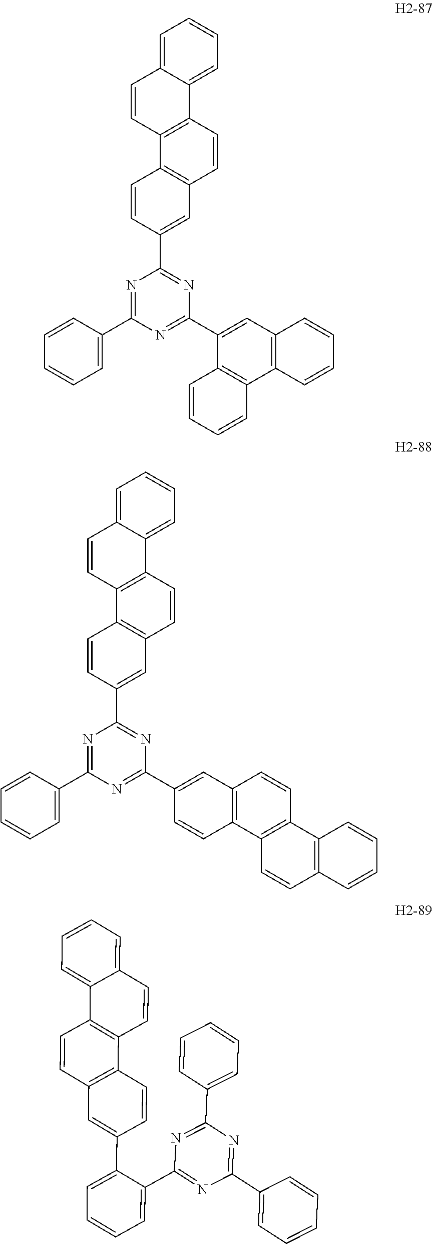 [SMILES: c1ccc(-c2nc(-c3ccc4c(ccc5c6ccccc6ccc45)c3)nc(-c3cc4ccccc4c4ccccc34)n2)cc1 ; c1ccc(-c2nc(-c3ccc4c(ccc5c6ccccc6ccc45)c3)nc(-c3ccc4c(ccc5c6ccccc6ccc45)c3)n2)cc1 ; c1ccc(-c2nc(-c3ccccc3)nc(-c3ccccc3-c3ccc4c(ccc5c6ccccc6ccc45)c3)n2)cc1]

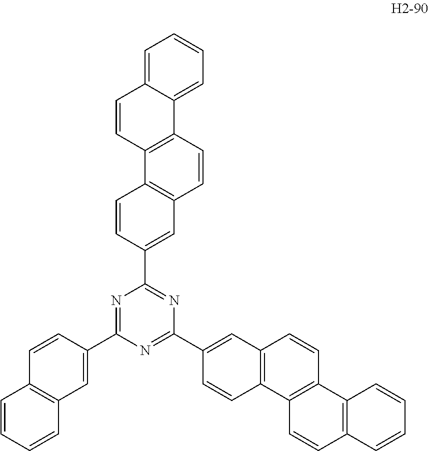 [SMILES: c1ccc2cc(-c3nc(-c4ccc5c(ccc6c7ccccc7ccc56)c4)nc(-c4ccc5c(ccc6c7ccccc7ccc56)c4)n3)ccc2c1]

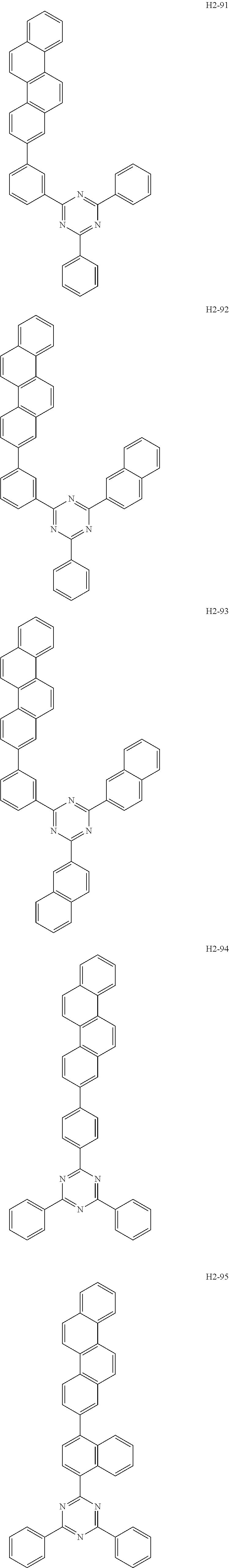 [SMILES: c1ccc(-c2nc(-c3ccccc3)nc(-c3cccc(-c4ccc5c(ccc6c7ccccc7ccc56)c4)c3)n2)cc1 ; c1ccc(-c2nc(-c3cccc(-c4ccc5c(ccc6c7ccccc7ccc56)c4)c3)nc(-c3ccc4ccccc4c3)n2)cc1 ; c1cc(-c2ccc3c(ccc4c5ccccc5ccc34)c2)cc(-c2nc(-c3ccc4ccccc4c3)nc(-c3ccc4ccccc4c3)n2)c1 ; c1ccc(-c2nc(-c3ccccc3)nc(-c3ccc(-c4ccc5c(ccc6c7ccccc7ccc56)c4)cc3)n2)cc1 ; c1ccc(-c2nc(-c3ccccc3)nc(-c3ccc(-c4ccc5c(ccc6c7ccccc7ccc56)c4)c4ccccc34)n2)cc1]

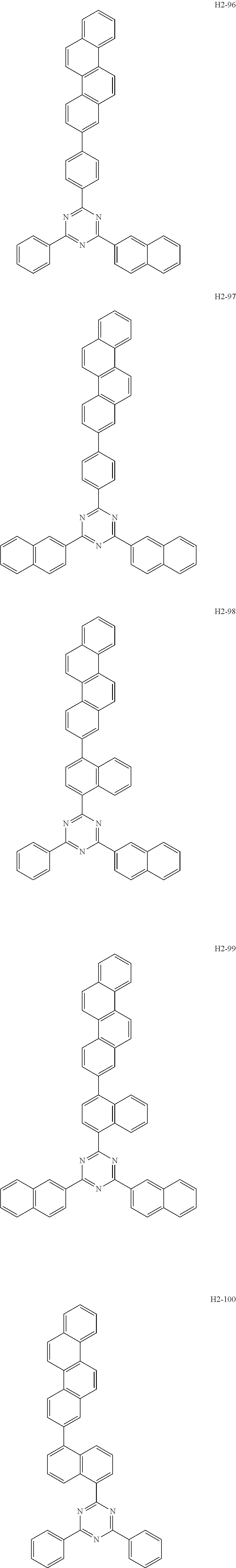 [SMILES: c1ccc(-c2nc(-c3ccc(-c4ccc5c(ccc6c7ccccc7ccc56)c4)cc3)nc(-c3ccc4ccccc4c3)n2)cc1 ; c1ccc2cc(-c3nc(-c4ccc(-c5ccc6c(ccc7c8ccccc8ccc67)c5)cc4)nc(-c4ccc5ccccc5c4)n3)ccc2c1 ; c1ccc(-c2nc(-c3ccc4ccccc4c3)nc(-c3ccc(-c4ccc5c(ccc6c7ccccc7ccc56)c4)c4ccccc34)n2)cc1 ; c1ccc2cc(-c3nc(-c4ccc5ccccc5c4)nc(-c4ccc(-c5ccc6c(ccc7c8ccccc8ccc67)c5)c5ccccc45)n3)ccc2c1 ; c1ccc(-c2nc(-c3ccccc3)nc(-c3cccc4c(-c5ccc6c(ccc7c8ccccc8ccc67)c5)cccc34)n2)cc1]

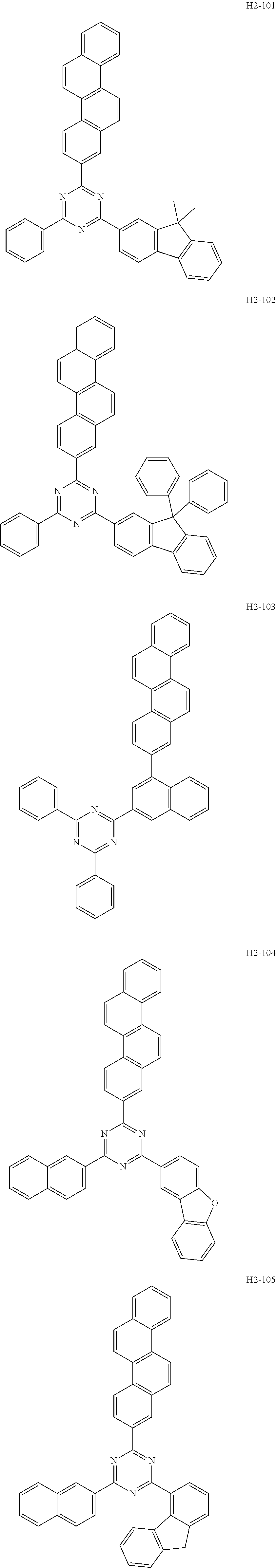 [SMILES: CC1(C)c2ccccc2-c2ccc(-c3nc(-c4ccccc4)nc(-c4ccc5c(ccc6c7ccccc7ccc56)c4)n3)cc21 ; c1ccc(-c2nc(-c3ccc4c(c3)C(c3ccccc3)(c3ccccc3)c3ccccc3-4)nc(-c3ccc4c(ccc5c6ccccc6ccc45)c3)n2)cc1 ; c1ccc(-c2nc(-c3ccccc3)nc(-c3cc(-c4ccc5c(ccc6c7ccccc7ccc56)c4)c4ccccc4c3)n2)cc1 ; c1ccc2cc(-c3nc(-c4ccc5c(ccc6c7ccccc7ccc56)c4)nc(-c4ccc5oc6ccccc6c5c4)n3)ccc2c1 ; c1ccc2c(c1)Cc1cccc(-c3nc(-c4ccc5ccccc5c4)nc(-c4ccc5c(ccc6c7ccccc7ccc56)c4)n3)c1-2]

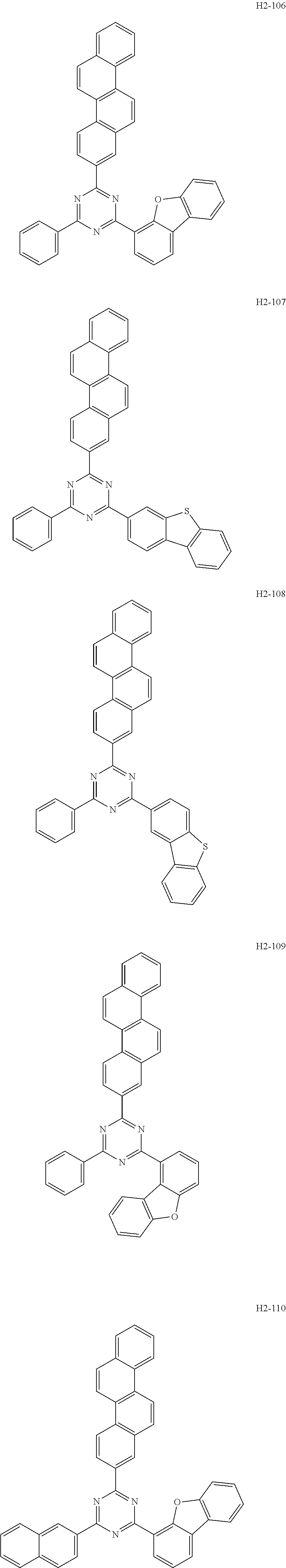 [SMILES: c1ccc(-c2nc(-c3ccc4c(ccc5c6ccccc6ccc45)c3)nc(-c3cccc4c3oc3ccccc34)n2)cc1 ; c1ccc(-c2nc(-c3ccc4c(ccc5c6ccccc6ccc45)c3)nc(-c3ccc4c(c3)sc3ccccc34)n2)cc1 ; c1ccc(-c2nc(-c3ccc4c(ccc5c6ccccc6ccc45)c3)nc(-c3ccc4sc5ccccc5c4c3)n2)cc1 ; c1ccc(-c2nc(-c3ccc4c(ccc5c6ccccc6ccc45)c3)nc(-c3cccc4oc5ccccc5c34)n2)cc1 ; c1ccc2cc(-c3nc(-c4ccc5c(ccc6c7ccccc7ccc56)c4)nc(-c4cccc5c4oc4ccccc45)n3)ccc2c1]

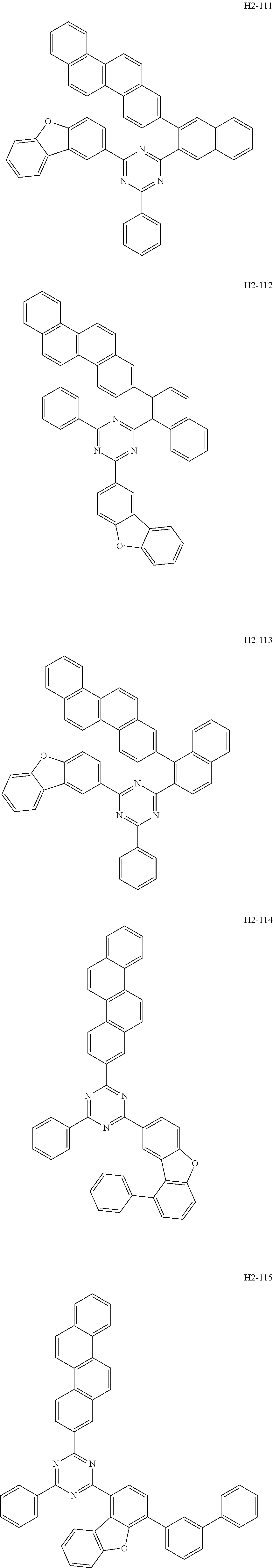 [SMILES: c1ccc(-c2nc(-c3ccc4oc5ccccc5c4c3)nc(-c3cc4ccccc4cc3-c3ccc4c(ccc5c6ccccc6ccc45)c3)n2)cc1 ; c1ccc(-c2nc(-c3ccc4oc5ccccc5c4c3)nc(-c3c(-c4ccc5c(ccc6c7ccccc7ccc56)c4)ccc4ccccc34)n2)cc1 ; c1ccc(-c2nc(-c3ccc4oc5ccccc5c4c3)nc(-c3ccc4ccccc4c3-c3ccc4c(ccc5c6ccccc6ccc45)c3)n2)cc1 ; c1ccc(-c2nc(-c3ccc4c(ccc5c6ccccc6ccc45)c3)nc(-c3ccc4oc5cccc(-c6ccccc6)c5c4c3)n2)cc1 ; c1ccc(-c2cccc(-c3ccc(-c4nc(-c5ccccc5)nc(-c5ccc6c(ccc7c8ccccc8ccc67)c5)n4)c4c3oc3ccccc34)c2)cc1]

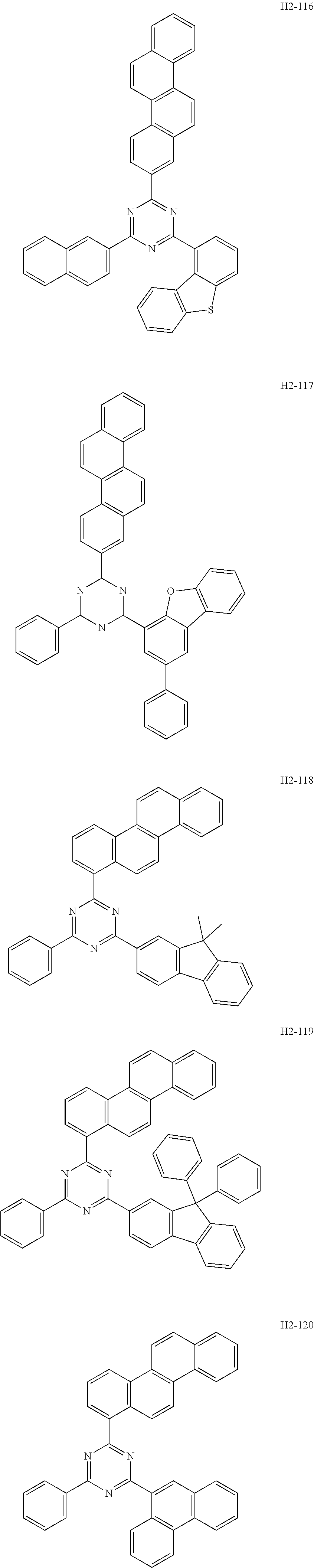

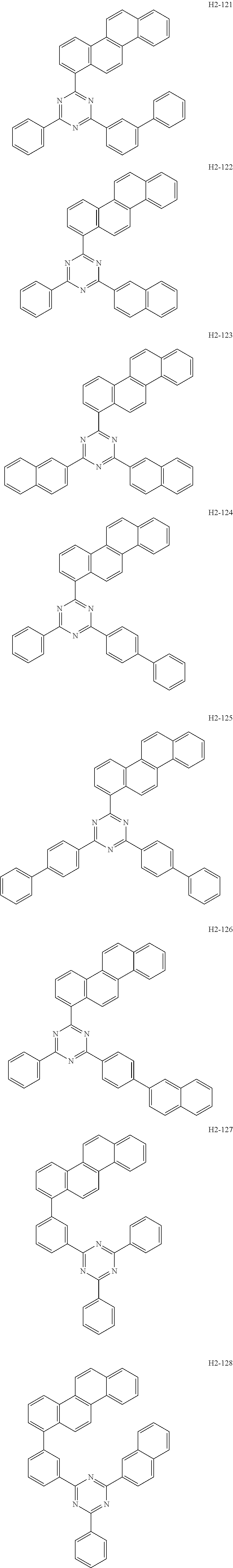

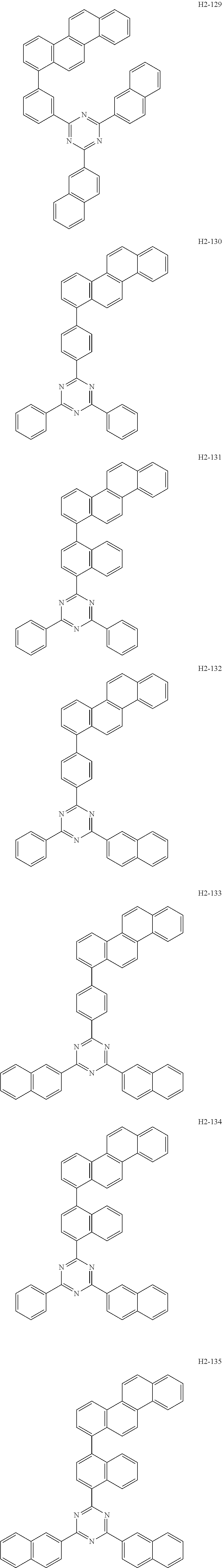

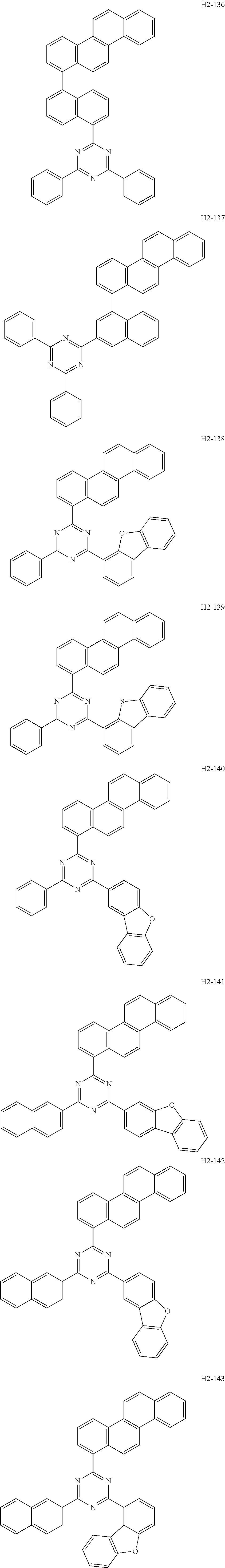

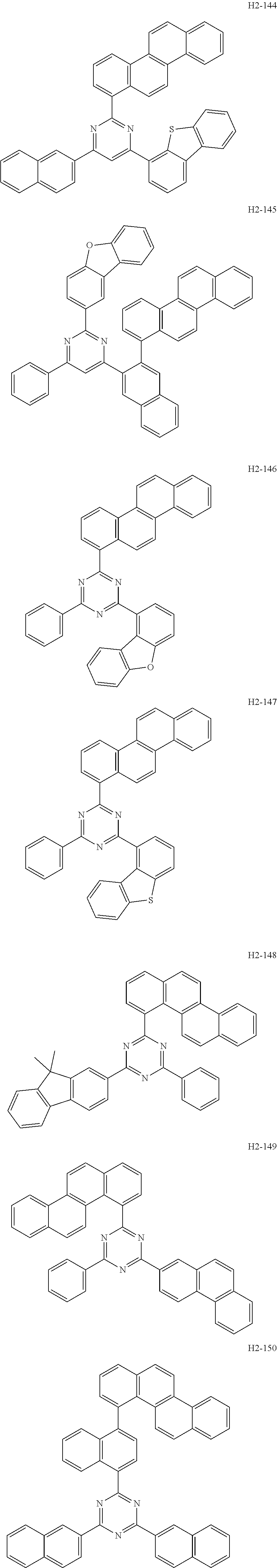

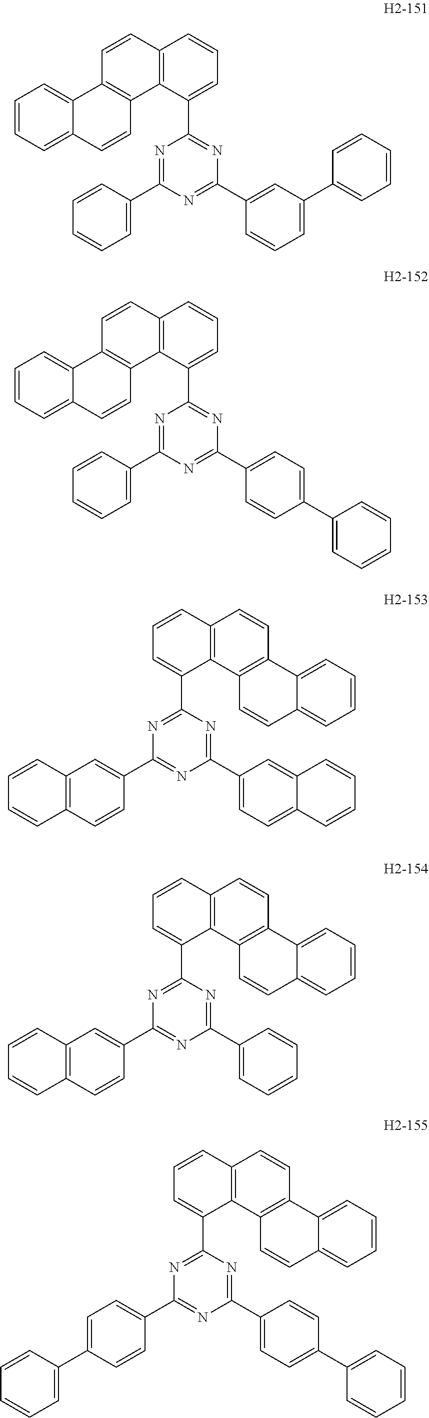 [SMILES: c1ccc(-c2cccc(-c3nc(-c4ccccc4)nc(-c4cccc5ccc6c7ccccc7ccc6c45)n3)c2)cc1 ; c1ccc(-c2ccc(-c3nc(-c4ccccc4)nc(-c4cccc5ccc6c7ccccc7ccc6c45)n3)cc2)cc1 ; c1ccc2cc(-c3nc(-c4ccc5ccccc5c4)nc(-c4cccc5ccc6c7ccccc7ccc6c45)n3)ccc2c1 ; c1ccc(-c2nc(-c3ccc4ccccc4c3)nc(-c3cccc4ccc5c6ccccc6ccc5c34)n2)cc1 ; c1ccc(-c2ccc(-c3nc(-c4ccc(-c5ccccc5)cc4)nc(-c4cccc5ccc6c7ccccc7ccc6c45)n3)cc2)cc1]

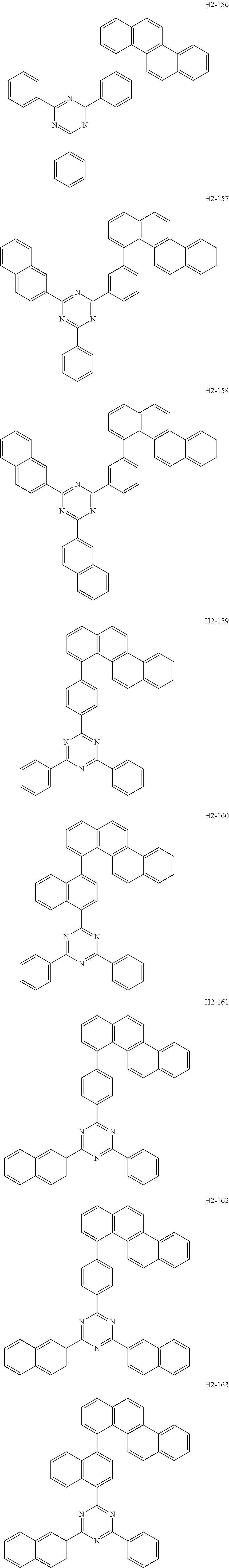

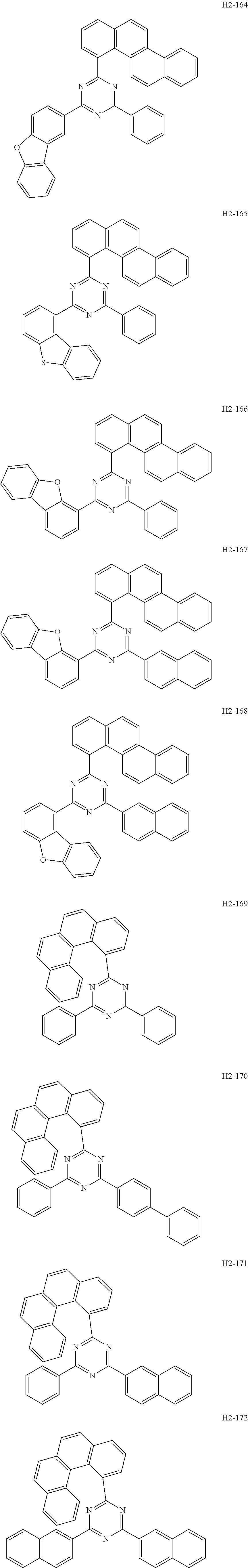

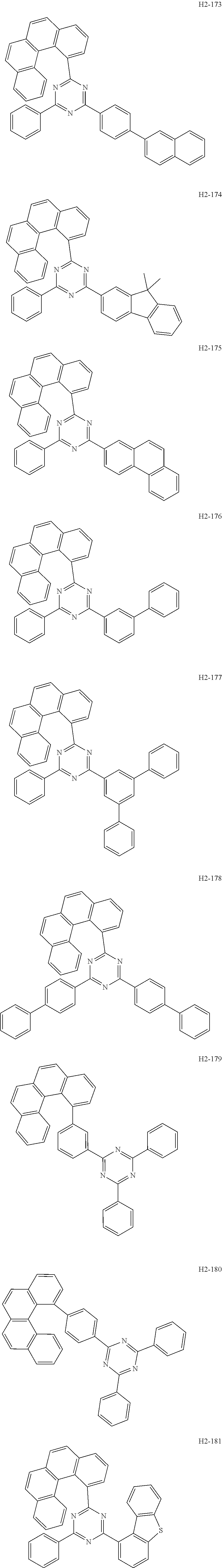

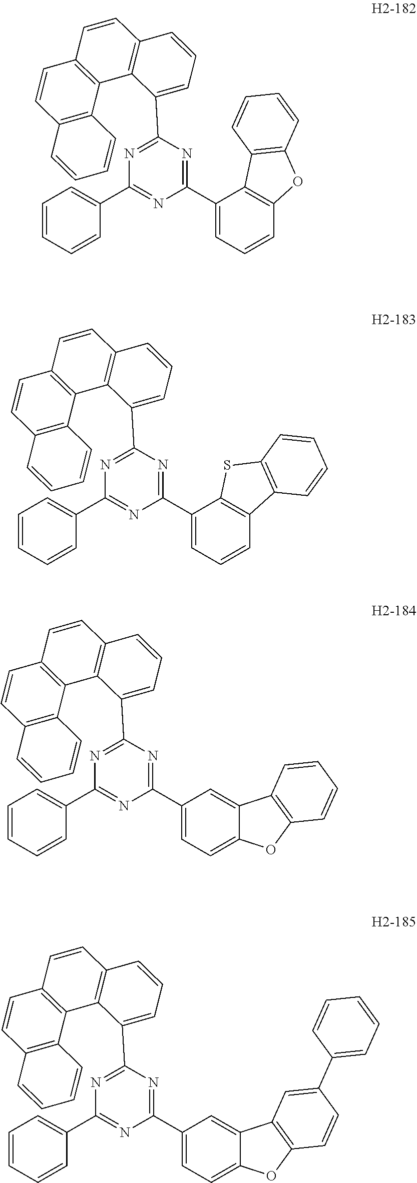 [SMILES: c1ccc(-c2nc(-c3cccc4oc5ccccc5c34)nc(-c3cccc4ccc5ccc6ccccc6c5c34)n2)cc1 ; c1ccc(-c2nc(-c3cccc4c3sc3ccccc34)nc(-c3cccc4ccc5ccc6ccccc6c5c34)n2)cc1 ; c1ccc(-c2nc(-c3ccc4oc5ccccc5c4c3)nc(-c3cccc4ccc5ccc6ccccc6c5c34)n2)cc1 ; c1ccc(-c2ccc3oc4ccc(-c5nc(-c6ccccc6)nc(-c6cccc7ccc8ccc9ccccc9c8c67)n5)cc4c3c2)cc1]

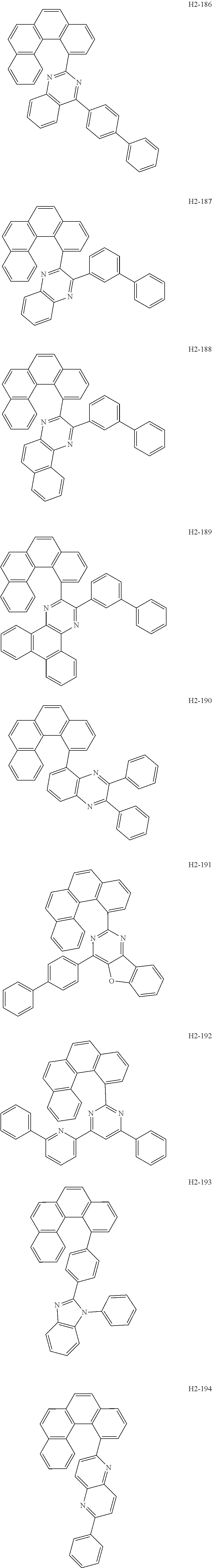

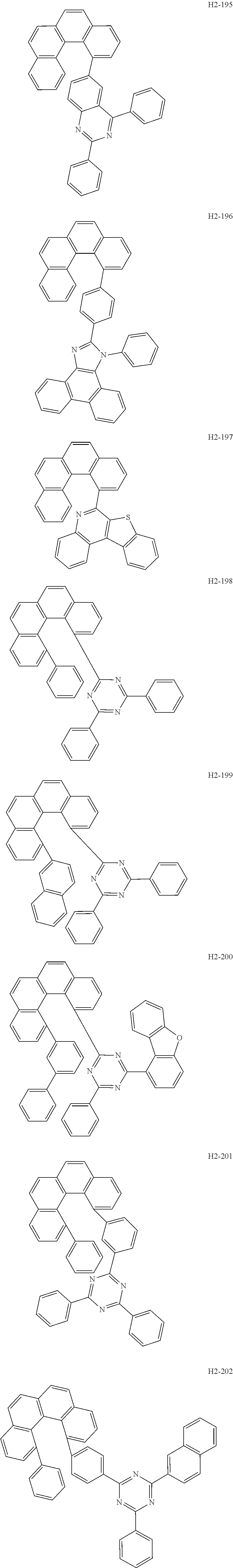

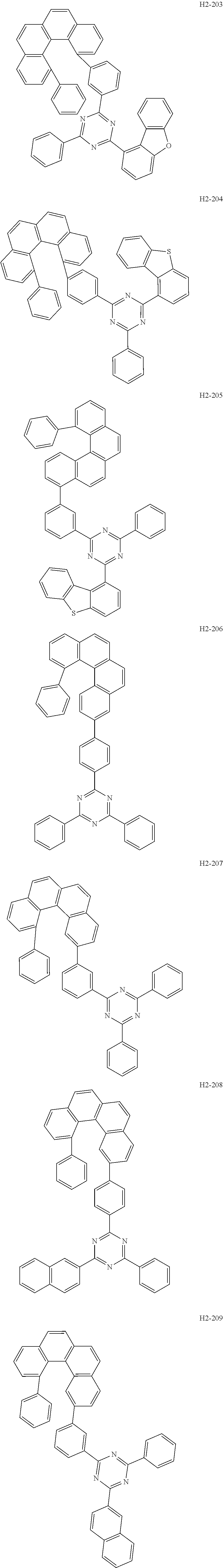

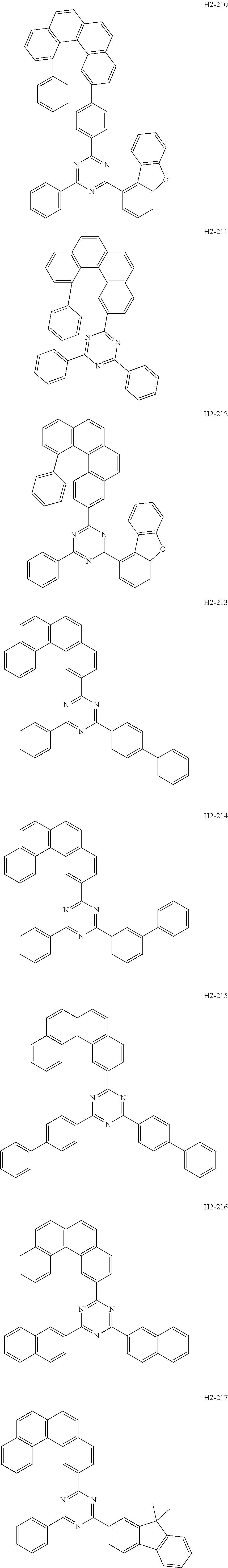

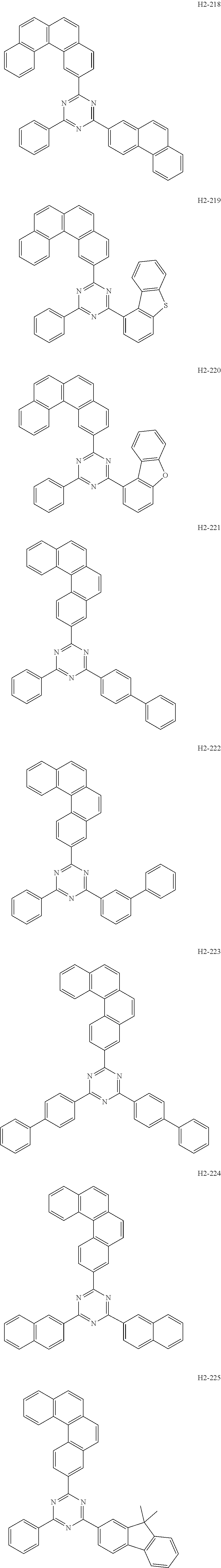

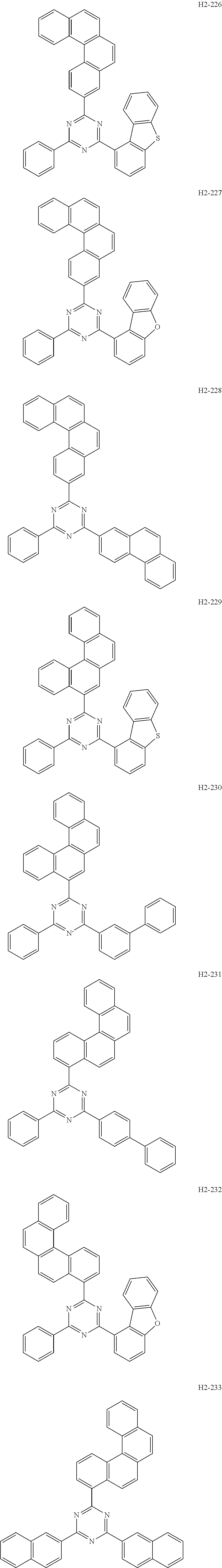

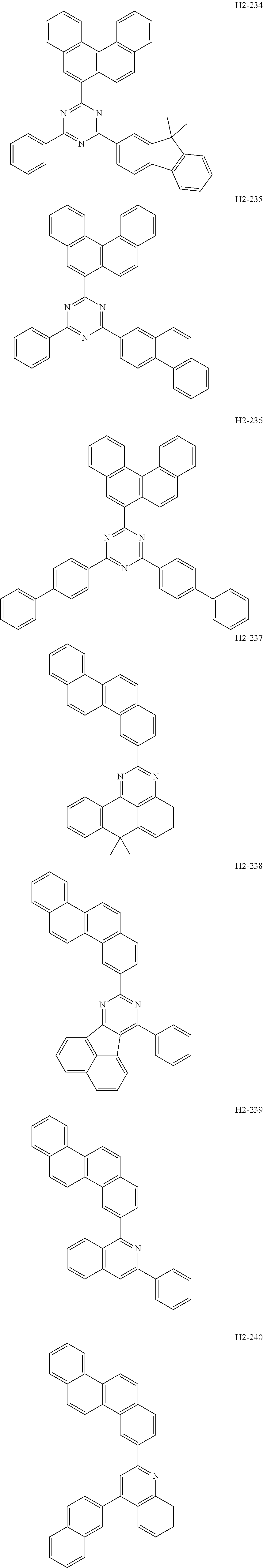

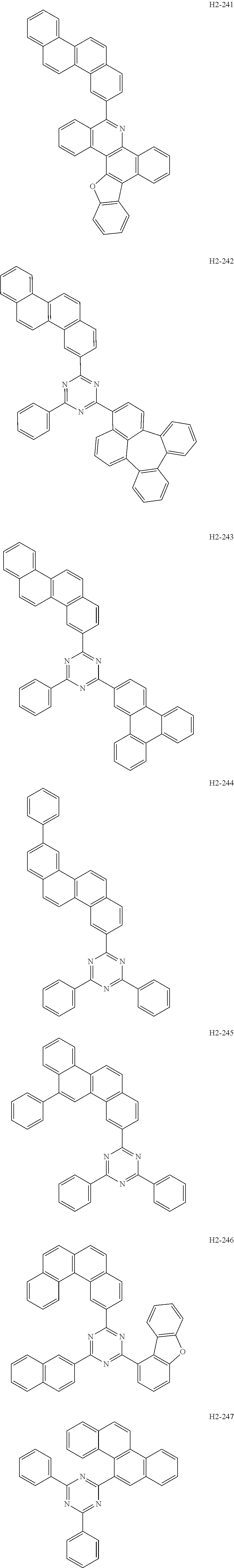

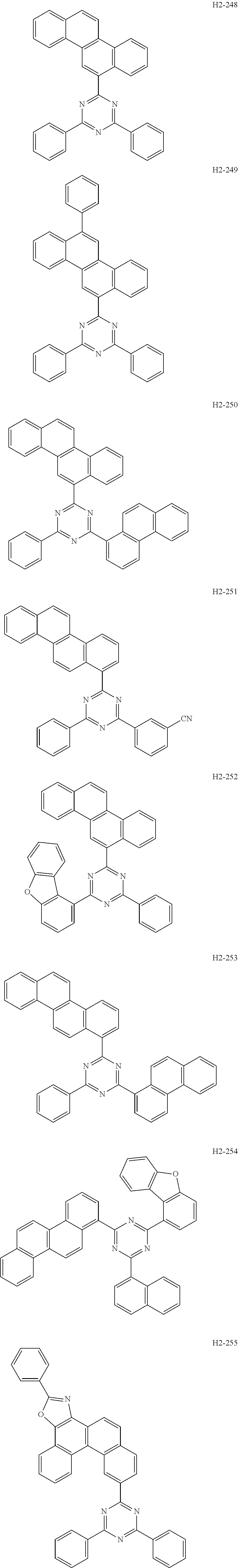

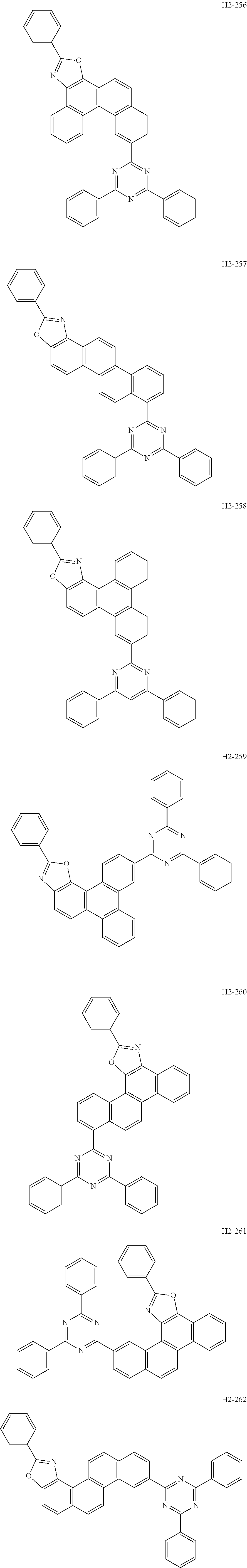

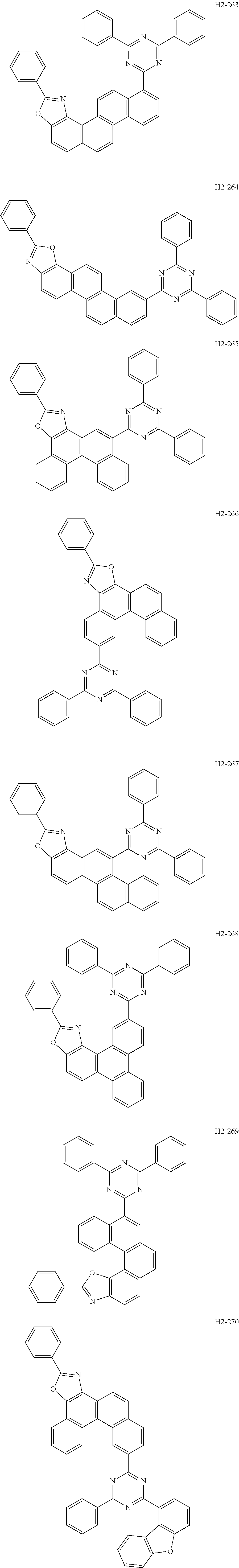

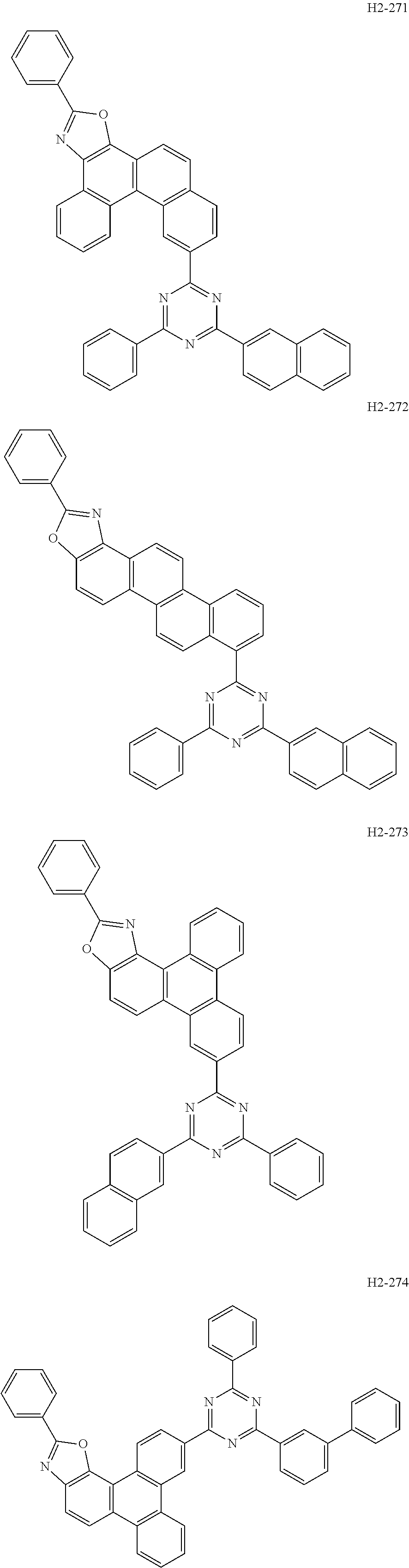 [SMILES: c1ccc(-c2nc(-c3ccc4ccccc4c3)nc(-c3ccc4ccc5c6oc(-c7ccccc7)nc6c6ccccc6c5c4c3)n2)cc1 ; c1ccc(-c2nc(-c3ccc4ccccc4c3)nc(-c3cccc4c3ccc3c4ccc4c3ccc3oc(-c5ccccc5)nc34)n2)cc1 ; c1ccc(-c2nc(-c3ccc4ccccc4c3)nc(-c3ccc4c5ccccc5c5c(ccc6oc(-c7ccccc7)nc65)c4c3)n2)cc1 ; c1ccc(-c2cccc(-c3nc(-c4ccccc4)nc(-c4ccc5c(c4)c4ccccc4c4ccc6nc(-c7ccccc7)oc6c45)n3)c2)cc1]

The host compound represented by formula 2 according to the present disclosure may be prepared by a synthetic method known to those skilled in the art, and may be prepared, for example, as shown in the following reaction schemes.

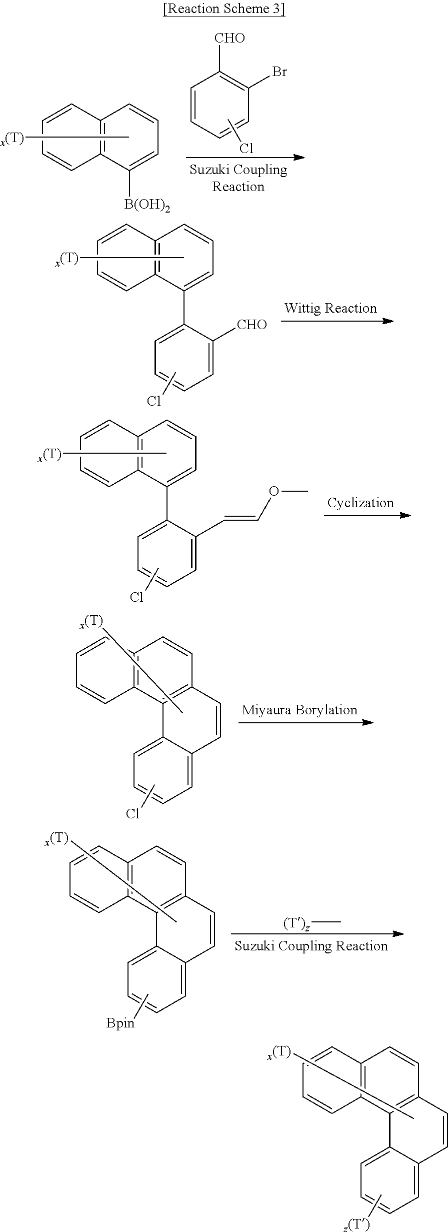

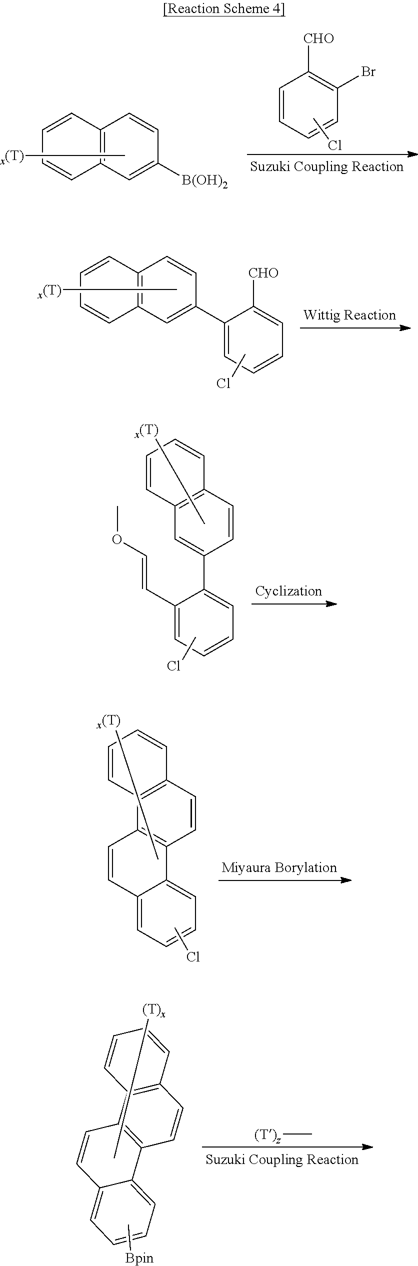

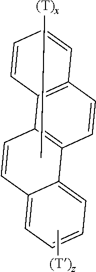

In reaction schemes 3 and 4, T and T′ each independently are as defined as T₁ to T₁₄ in formula 2, x represents an integer of 1 to 7, and z represents an integer of 1 to 4, when x and z are integers of 2 or more, each of T and each of T′ may be the same or different.

As described above, exemplary synthesis examples of the compounds represented by formula 2 are described, but they are based on Buchwald-Hartwig cross coupling reaction, N-arylation reaction, H-mont-mediated etherification reaction, Miyaura borylation reaction, Suzuki cross-coupling reaction, Intramolecular acid-induced cyclization reaction, Pd(II)-catalyzed oxidative cyclization reaction, Grignard reaction, Heck reaction, Cyclic Dehydration reaction, SN₁ substitution reaction, SN₂ substitution reaction, and Phosphine-mediated reductive cyclization reaction, etc. It will be understood by one skilled in the art that the above reaction proceeds even if other substituents defined in formula 2, other than the substituents described in the specific synthesis examples, are bonded.

According to another embodiment of the present disclosure, the present disclosure provides an organic electroluminescent compound represented by the following formula 1′.

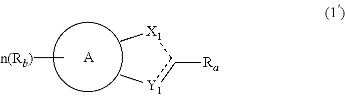

in formula 1′
ring A represents a substituted or unsubstituted aromatic ring in which 4 benzene rings are sequentially fused;
X₁ and Y₁ each independently represent, —N═, —NR_{c}—, —O— or —S—; provided that any one of X₁ and Y₁ is —N═, and the other of X₁ and Y₁ is —NR_{c}—, —O— or —S—;
Rₐ and R_{c} each independently represent, a substituted or unsubstituted (C6-C30)aryl, a substituted or unsubstituted (3- to 30-membered)heteroaryl, -L′₁—NR′₁R′₂, or -L′₁-HAr;
R_{b} represents hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted fused ring of (C3-C30) aliphatic ring and (C6-C30) aromatic ring, —SiR′₁R′₂R′₃, -L′₁—NR′₁R′₂, or -L′₁-HAr;
provided that at least one of Rₐ and R_{b} is (are) -L′₁—NR′₁R′₂ or -L′₁-HAr;
L′₁ represents a single bond, a substituted or unsubstituted (C6-C30)arylene, or a substituted or unsubstituted (3- to 30-membered)heteroarylene;
HAr represents a substituted or unsubstituted (3- to 30-membered)heteroaryl;
R′₁ to R′₃ each independently represent, a substituted or unsubstituted (C1-C30)alkyl, a substituted or unsubstituted (C2-C30)alkenyl, a substituted or unsubstituted (C6-C30)aryl, a substituted or unsubstituted (3- to 30-membered)heteroaryl, or a substituted or unsubstituted fused ring of (C3-C30) aliphatic ring and (C6-C30) aromatic ring; and
n represents an integer of 1 to 10, when n is an integer of 2 or more, each of R_{b} may be the same or different.

According to one embodiment, the organic electroluminescent compound represented by formula 1′ may be represented by the following formula 1′-1.

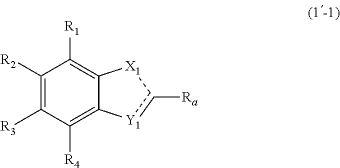

in formula 1′-1
X₁, Y₁, and Rₐ are as defined in formula 1′; and
one of R₁ and R₂, and R₃ and R₄ is linked to each other to form the following formula 1A, or the other is linked to each other to form the following formula 1B; or any one of R₁ and R₂, R₂ and R₃, and R₃ and R₄ is linked to each other to form the following formula 1C or 1D;

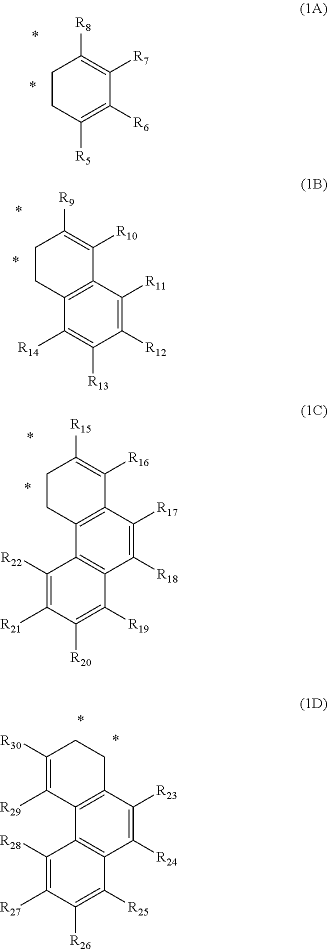

In formulas 1′-1 and 1A to 1D,
R₁ to R₄ which do not form the formula 1C or 1D, and R₅ to R₃₀ are as defined as R_{b} in formula 1′.

According to one embodiment, the compound represented by formula 1′-1 may be represented by any one of the following formulas 11′-1 to 11′-7.

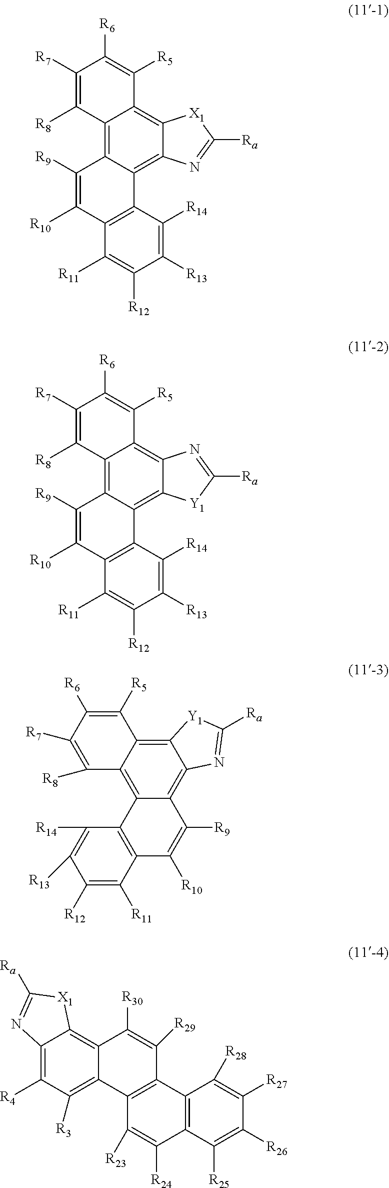

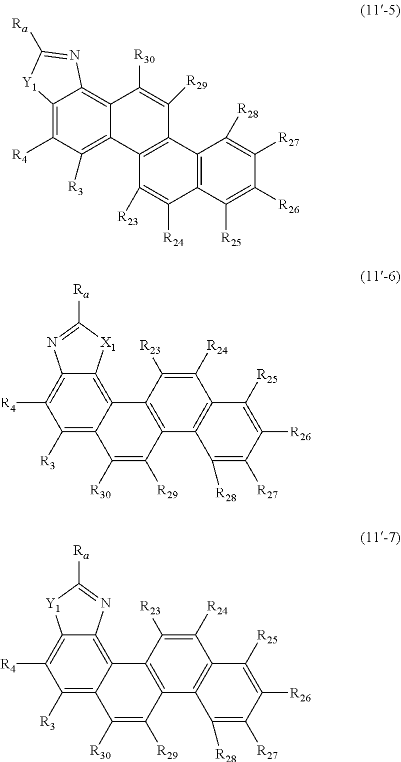

in formulas 11′-1 to 11′-7,
X₁, Y₁, Rₐ, R₃ to R₁₄, and R₂₃ to R₃₀ are as defined in formula 1′-1.

In one embodiment, at least one of Rₐ, R₃ to R₁₄, and R₂₃ to R₃₀ may be a substituent represented by the following formula R_{b}-1.

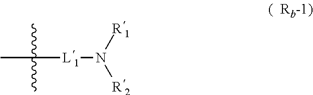

in formula R_{b}-1
L′₁ represents a single bond, a substituted or unsubstituted (C6-C30)arylene, or a substituted or unsubstituted (3- to 30-membered)heteroarylene; and
R′₁ and R′₂ each independently represent, a substituted or unsubstituted (C6-C30)aryl, a substituted or unsubstituted (3- to 30-membered)heteroaryl, or a substituted or unsubstituted fused ring of (C3-C30) aliphatic ring and (C6-C30) aromatic ring.

In one embodiment, L′₁ may be a single bond, a substituted or unsubstituted (C6-C30)arylene, or a substituted or unsubstituted (5- to 30-membered)heteroarylene, preferably a single bond, a substituted or unsubstituted (C6-C25)arylene, or a substituted or unsubstituted (5- to 25-membered)heteroarylene, more preferably a single bond, a substituted or unsubstituted (C6-C18)arylene, or a substituted or unsubstituted (5- to 18-membered)heteroarylene. For example, L′₁ may be a single bond, a substituted or unsubstituted phenylene, a substituted or unsubstituted naphthalenylene, or a substituted or unsubstituted dibenzofuranylene.

In one embodiment, R′₁ and R′₂ each independently may be a substituted or unsubstituted (C6-C30)aryl, a substituted or unsubstituted (5- to 30-membered)heteroaryl, or a substituted or unsubstituted fused ring of (C3-C30) aliphatic ring and (C6-C30) aromatic ring, preferably, a substituted or unsubstituted (C6-C25)aryl, or a substituted or unsubstituted (5- to 25-membered)heteroaryl, more preferably a substituted or unsubstituted (C6-C18)aryl, or a substituted or unsubstituted (5- to 18-membered)heteroaryl. For example, R′₁ and R′₂ each independently may be a substituted or unsubstituted phenyl, a substituted or unsubstituted biphenyl, a substituted or unsubstituted naphthyl, a substituted or unsubstituted terphenyl, a substituted or unsubstituted tetraphenyl, a substituted or unsubstituted phenanthrenyl, a substituted or unsubstituted fluorenyl, a substituted or unsubstituted dibenzofuranyl, a substituted or unsubstituted dibenzothiophenyl, a substituted or unsubstituted dibenzoselenophenyl, or a substituted or unsubstituted pyridinyl. For example, the substituents of the substituted groups may be deuterium, cyano, methyl, phenyl, naphthyl, biphenyl, terphenyl, triphenylsilane, or dibenzofuranyl.

According to one embodiment, the organic electroluminescent compound represented by formula 1′ may be more specifically illustrated by the following compounds, but is not limited thereto.

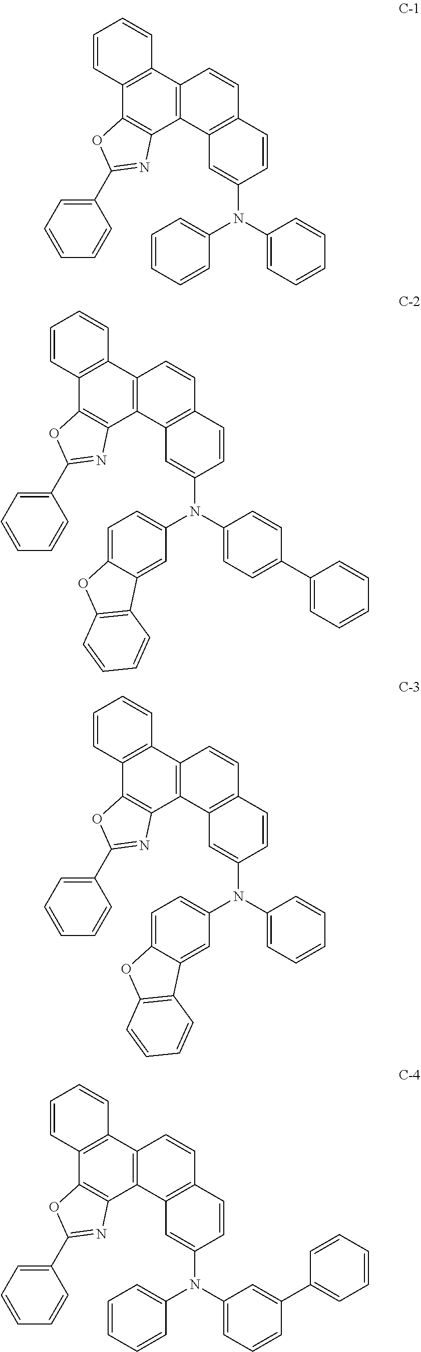

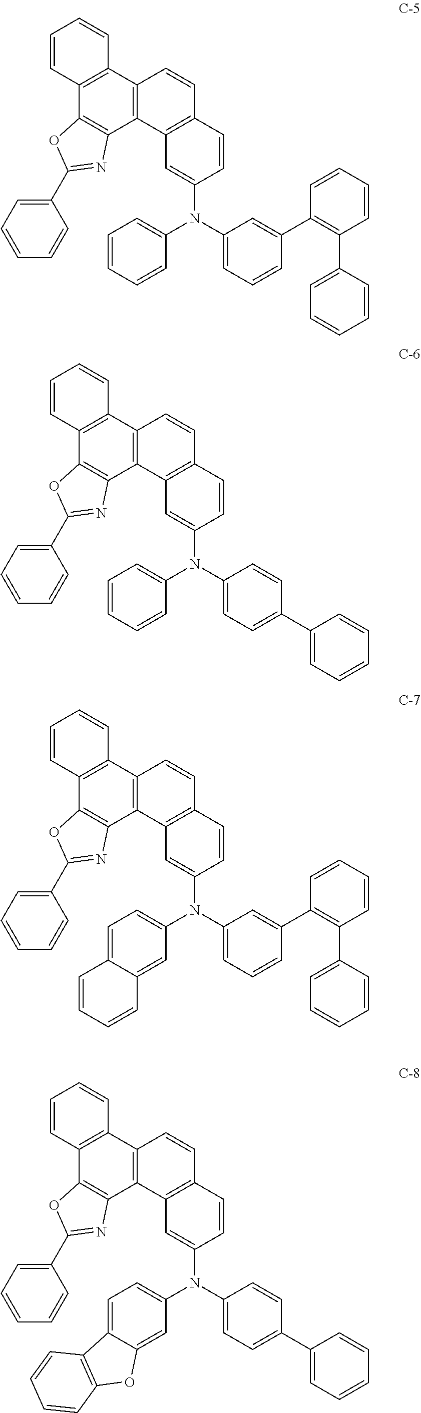 [SMILES: c1ccc(-c2nc3c(o2)c2ccccc2c2ccc4ccc(N(c5ccccc5)c5cccc(-c6ccccc6-c6ccccc6)c5)cc4c23)cc1 ; c1ccc(-c2ccc(N(c3ccccc3)c3ccc4ccc5c6ccccc6c6oc(-c7ccccc7)nc6c5c4c3)cc2)cc1 ; c1ccc(-c2nc3c(o2)c2ccccc2c2ccc4ccc(N(c5cccc(-c6ccccc6-c6ccccc6)c5)c5ccc6ccccc6c5)cc4c23)cc1 ; c1ccc(-c2ccc(N(c3ccc4c(c3)oc3ccccc34)c3ccc4ccc5c6ccccc6c6oc(-c7ccccc7)nc6c5c4c3)cc2)cc1]

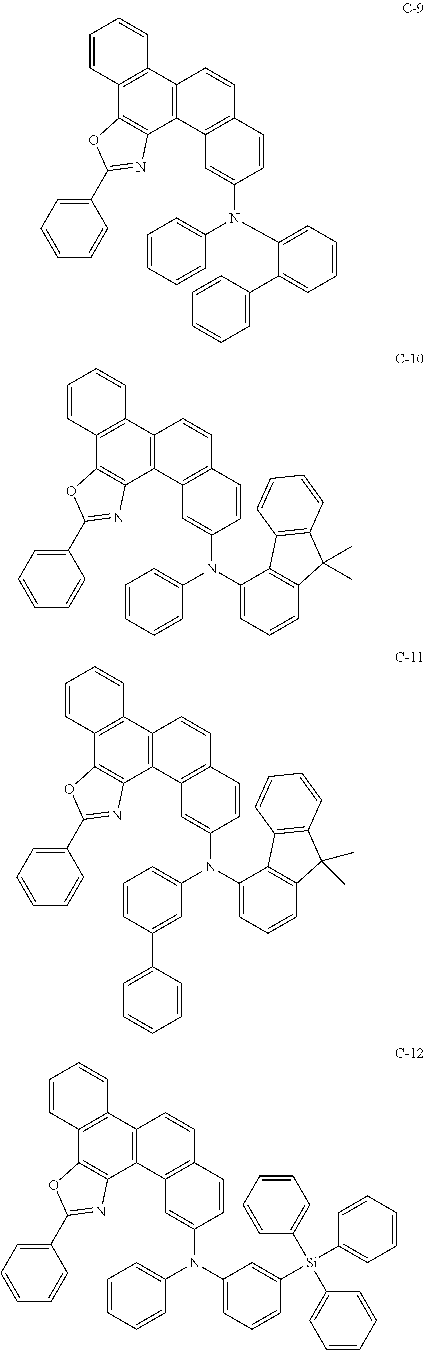 [SMILES: c1ccc(-c2nc3c(o2)c2ccccc2c2ccc4ccc(N(c5ccccc5)c5ccccc5-c5ccccc5)cc4c23)cc1 ; CC1(C)c2ccccc2-c2c(N(c3ccccc3)c3ccc4ccc5c6ccccc6c6oc(-c7ccccc7)nc6c5c4c3)cccc21 ; CC1(C)c2ccccc2-c2c(N(c3cccc(-c4ccccc4)c3)c3ccc4ccc5c6ccccc6c6oc(-c7ccccc7)nc6c5c4c3)cccc21 ; c1ccc(-c2nc3c(o2)c2ccccc2c2ccc4ccc(N(c5ccccc5)c5cccc([Si](c6ccccc6)(c6ccccc6)c6ccccc6)c5)cc4c23)cc1]

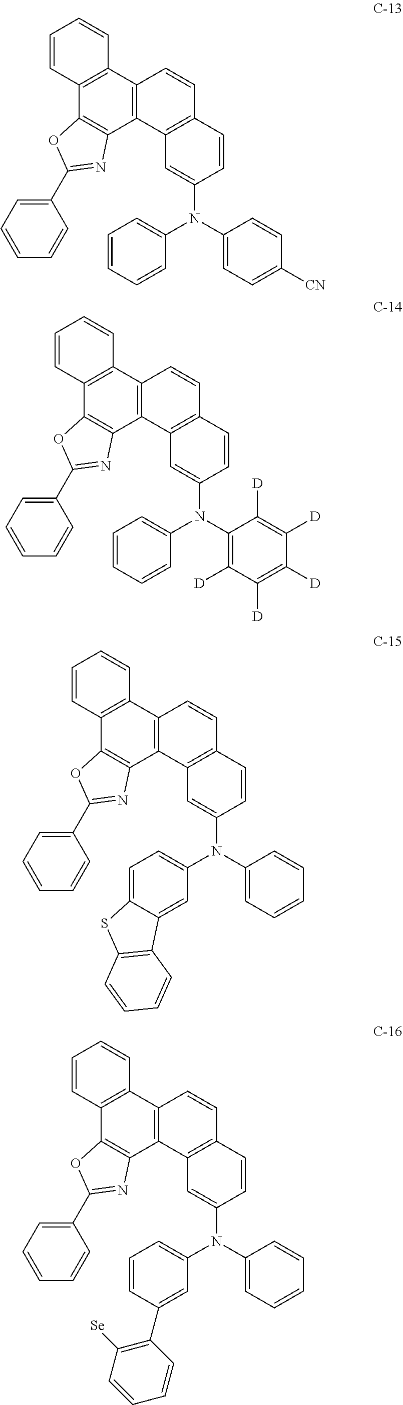

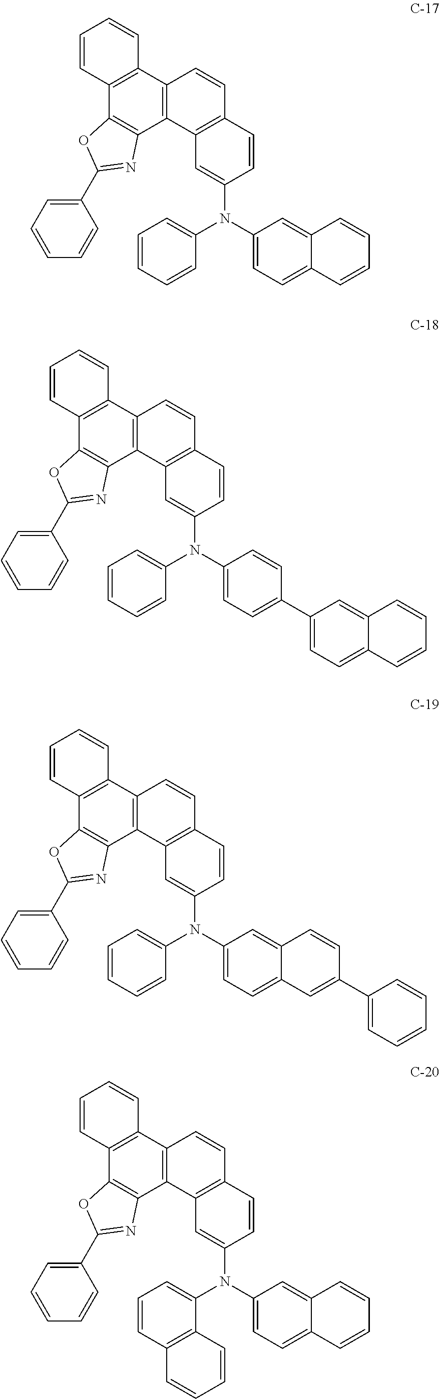 [SMILES: c1ccc(-c2nc3c(o2)c2ccccc2c2ccc4ccc(N(c5ccccc5)c5ccc6ccccc6c5)cc4c23)cc1 ; c1ccc(-c2nc3c(o2)c2ccccc2c2ccc4ccc(N(c5ccccc5)c5ccc(-c6ccc7ccccc7c6)cc5)cc4c23)cc1 ; c1ccc(-c2ccc3cc(N(c4ccccc4)c4ccc5ccc6c7ccccc7c7oc(-c8ccccc8)nc7c6c5c4)ccc3c2)cc1 ; c1ccc(-c2nc3c(o2)c2ccccc2c2ccc4ccc(N(c5ccc6ccccc6c5)c5cccc6ccccc56)cc4c23)cc1]

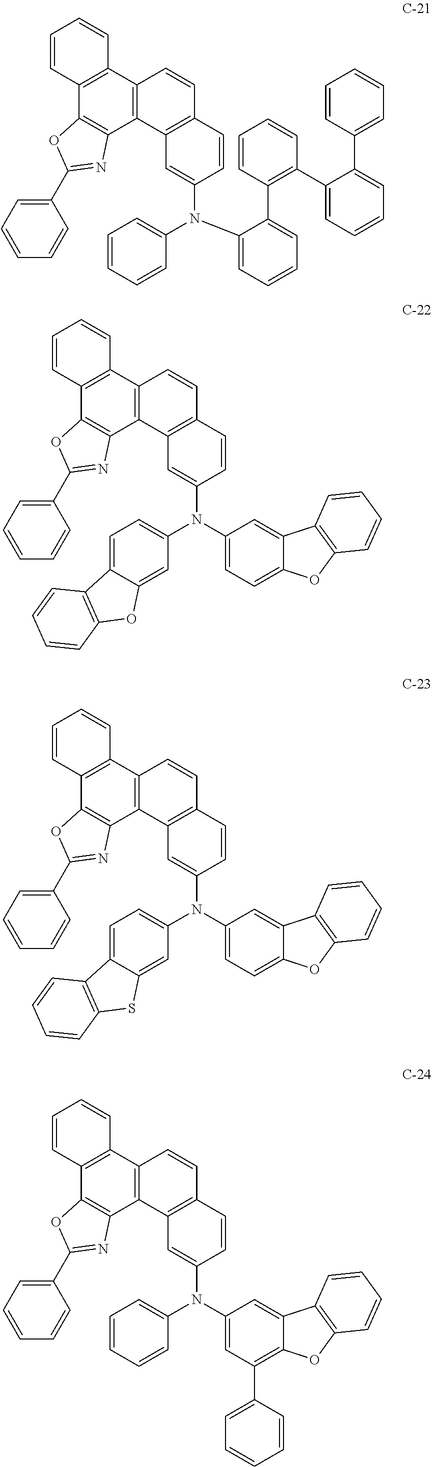 [SMILES: c1ccc(-c2nc3c(o2)c2ccccc2c2ccc4ccc(N(c5ccccc5)c5ccccc5-c5ccccc5-c5ccccc5-c5ccccc5)cc4c23)cc1 ; c1ccc(-c2nc3c(o2)c2ccccc2c2ccc4ccc(N(c5ccc6c(c5)oc5ccccc56)c5ccc6oc7ccccc7c6c5)cc4c23)cc1 ; c1ccc(-c2nc3c(o2)c2ccccc2c2ccc4ccc(N(c5ccc6c(c5)sc5ccccc56)c5ccc6oc7ccccc7c6c5)cc4c23)cc1 ; c1ccc(-c2nc3c(o2)c2ccccc2c2ccc4ccc(N(c5ccccc5)c5cc(-c6ccccc6)c6oc7ccccc7c6c5)cc4c23)cc1]

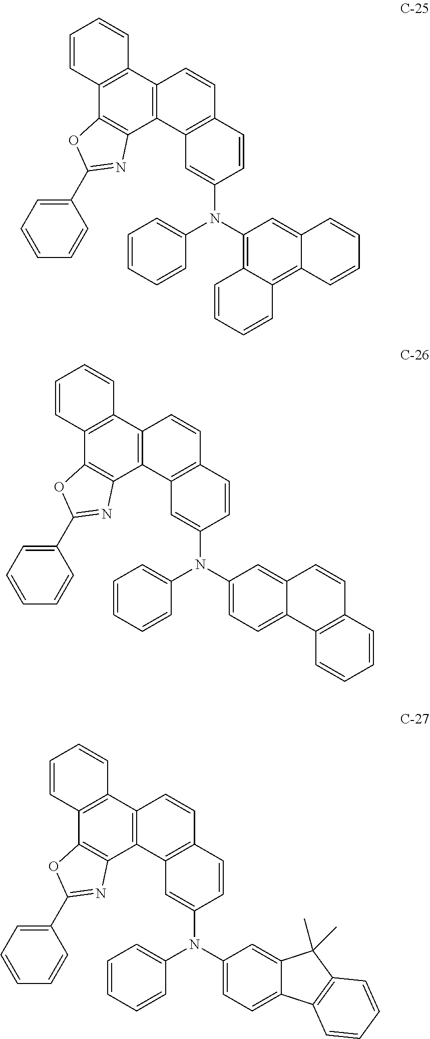 [SMILES: c1ccc(-c2nc3c(o2)c2ccccc2c2ccc4ccc(N(c5ccccc5)c5cc6ccccc6c6ccccc56)cc4c23)cc1 ; c1ccc(-c2nc3c(o2)c2ccccc2c2ccc4ccc(N(c5ccccc5)c5ccc6c(ccc7ccccc76)c5)cc4c23)cc1 ; CC1(C)c2ccccc2-c2ccc(N(c3ccccc3)c3ccc4ccc5c6ccccc6c6oc(-c7ccccc7)nc6c5c4c3)cc21]

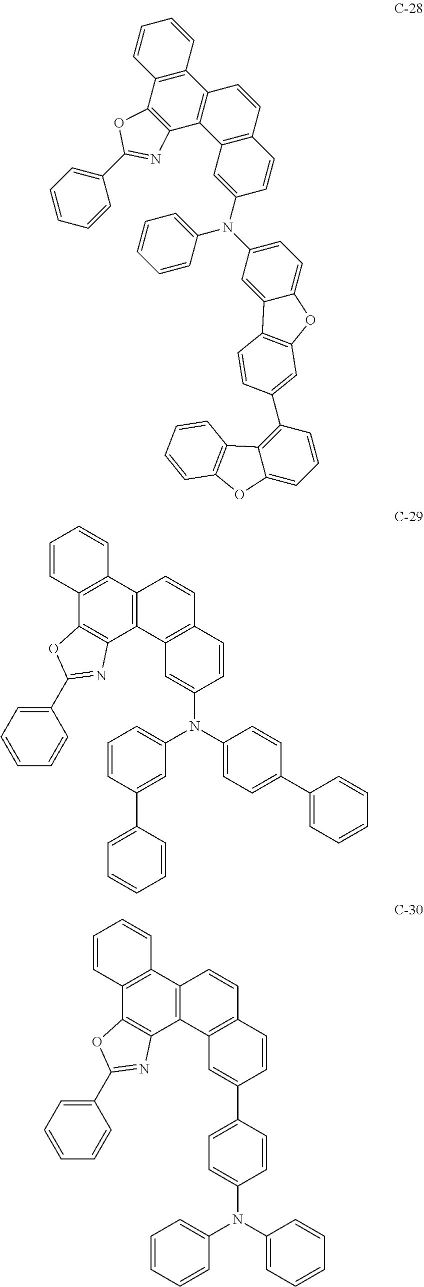

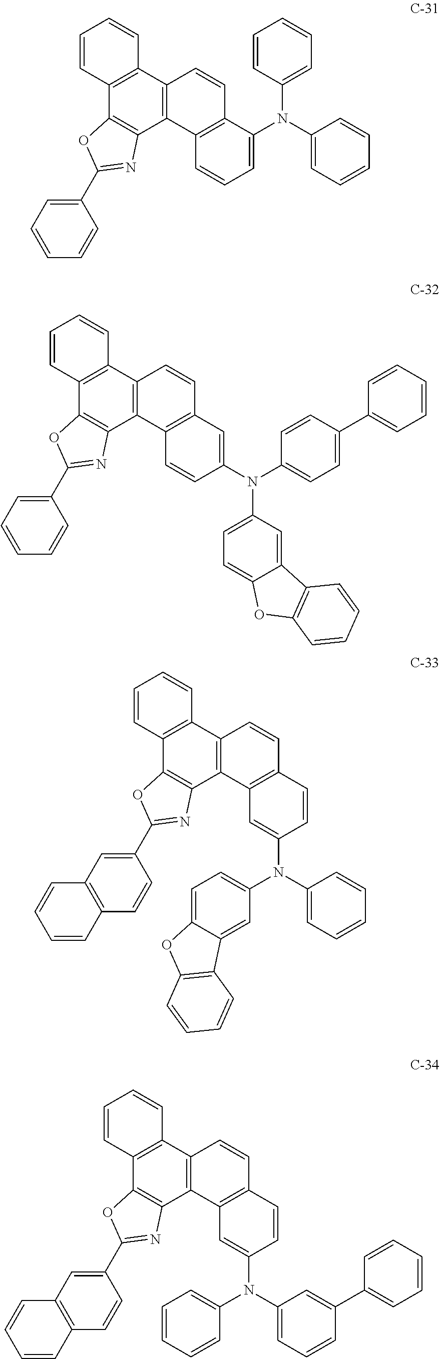 [SMILES: c1ccc(-c2nc3c(o2)c2ccccc2c2ccc4c(N(c5ccccc5)c5ccccc5)cccc4c23)cc1 ; c1ccc(-c2ccc(N(c3ccc4c(ccc5c6ccccc6c6oc(-c7ccccc7)nc6c45)c3)c3ccc4oc5ccccc5c4c3)cc2)cc1 ; c1ccc(N(c2ccc3oc4ccccc4c3c2)c2ccc3ccc4c5ccccc5c5oc(-c6ccc7ccccc7c6)nc5c4c3c2)cc1 ; c1ccc(-c2cccc(N(c3ccccc3)c3ccc4ccc5c6ccccc6c6oc(-c7ccc8ccccc8c7)nc6c5c4c3)c2)cc1]

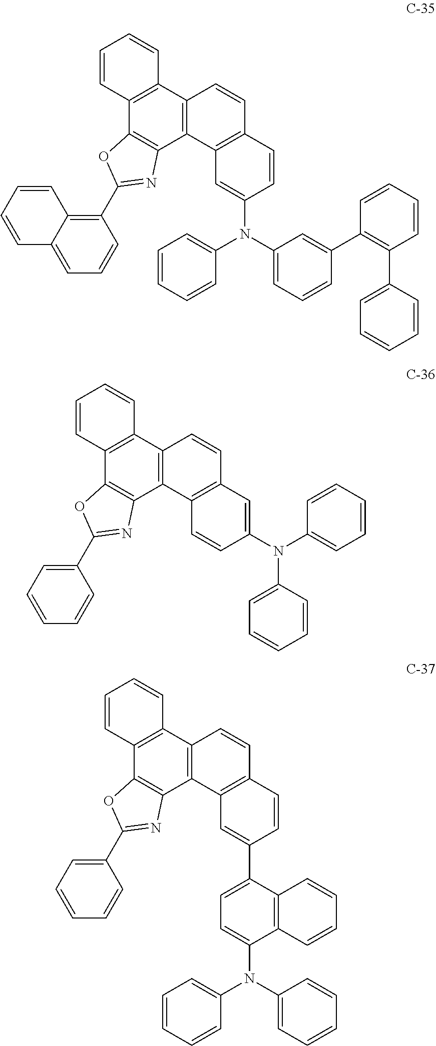 [SMILES: c1ccc(-c2ccccc2-c2cccc(N(c3ccccc3)c3ccc4ccc5c6ccccc6c6oc(-c7cccc8ccccc78)nc6c5c4c3)c2)cc1 ; c1ccc(-c2nc3c(o2)c2ccccc2c2ccc4cc(N(c5ccccc5)c5ccccc5)ccc4c23)cc1 ; c1ccc(-c2nc3c(o2)c2ccccc2c2ccc4ccc(-c5ccc(N(c6ccccc6)c6ccccc6)c6ccccc56)cc4c23)cc1]

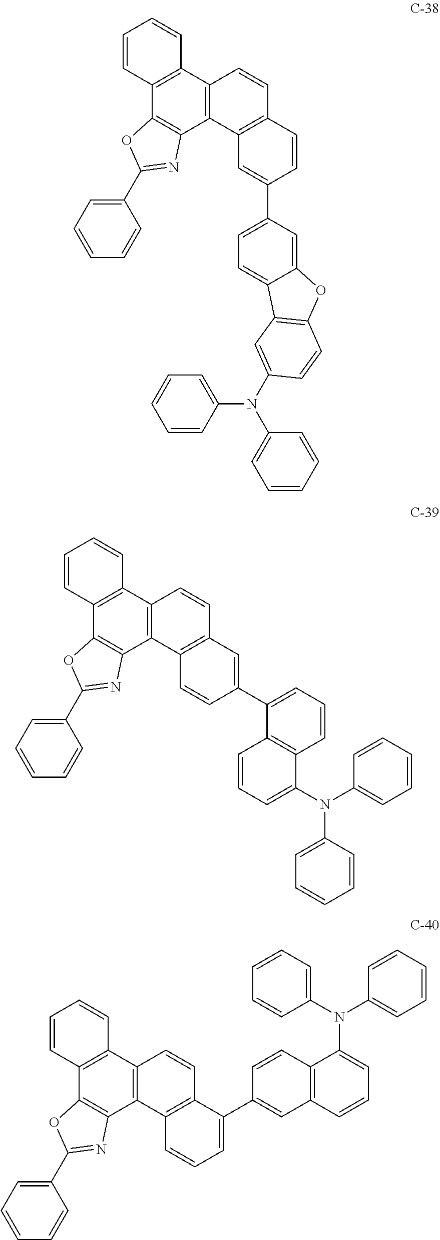 [SMILES: c1ccc(-c2nc3c(o2)c2ccccc2c2ccc4ccc(-c5ccc6c(c5)oc5ccc(N(c7ccccc7)c7ccccc7)cc56)cc4c23)cc1 ; c1ccc(-c2nc3c(o2)c2ccccc2c2ccc4cc(-c5cccc6c(N(c7ccccc7)c7ccccc7)cccc56)ccc4c23)cc1 ; c1ccc(-c2nc3c(o2)c2ccccc2c2ccc4c(-c5ccc6c(N(c7ccccc7)c7ccccc7)cccc6c5)cccc4c23)cc1]

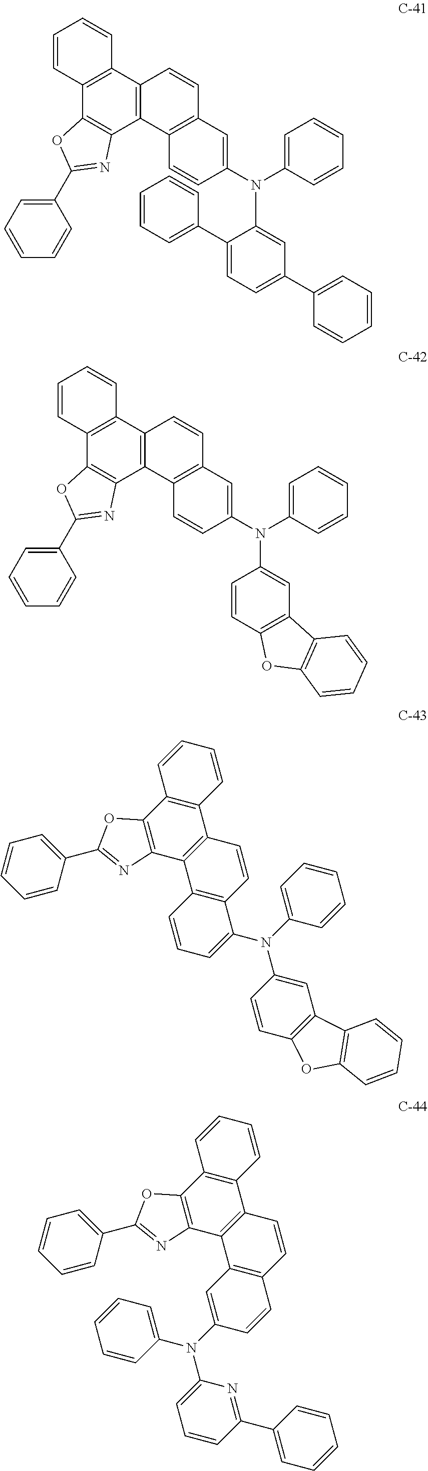 [SMILES: c1ccc(-c2ccc(-c3ccccc3)c(N(c3ccccc3)c3ccc4c(ccc5c6ccccc6c6oc(-c7ccccc7)nc6c45)c3)c2)cc1 ; c1ccc(-c2nc3c(o2)c2ccccc2c2ccc4cc(N(c5ccccc5)c5ccc6oc7ccccc7c6c5)ccc4c23)cc1 ; c1ccc(-c2nc3c(o2)c2ccccc2c2ccc4c(N(c5ccccc5)c5ccc6oc7ccccc7c6c5)cccc4c23)cc1 ; c1ccc(-c2cccc(N(c3ccccc3)c3ccc4ccc5c6ccccc6c6oc(-c7ccccc7)nc6c5c4c3)n2)cc1]

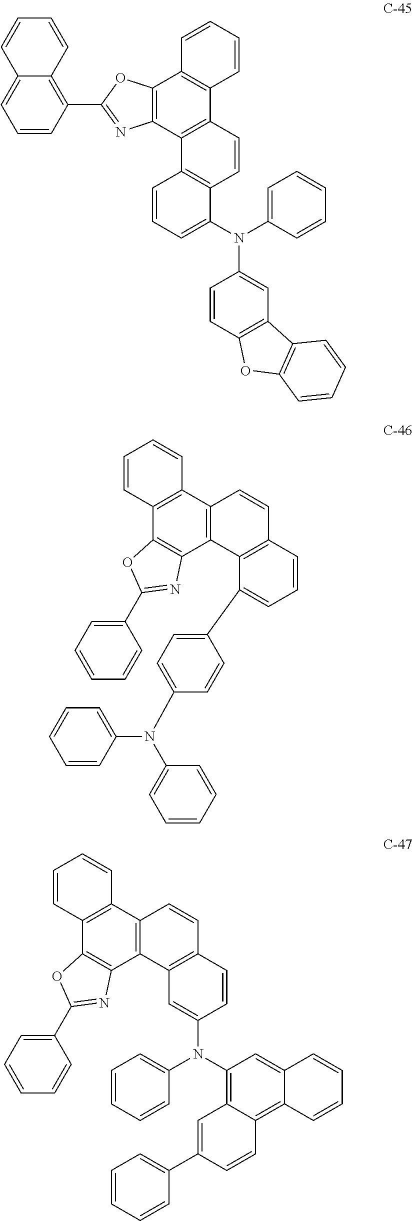 [SMILES: c1ccc(N(c2ccc3oc4ccccc4c3c2)c2cccc3c2ccc2c4ccccc4c4oc(-c5cccc6ccccc56)nc4c32)cc1 ; c1ccc(-c2nc3c(o2)c2ccccc2c2ccc4cccc(-c5ccc(N(c6ccccc6)c6ccccc6)cc5)c4c23)cc1 ; c1ccc(-c2ccc3c(c2)c(N(c2ccccc2)c2ccc4ccc5c6ccccc6c6oc(-c7ccccc7)nc6c5c4c2)cc2ccccc23)cc1]

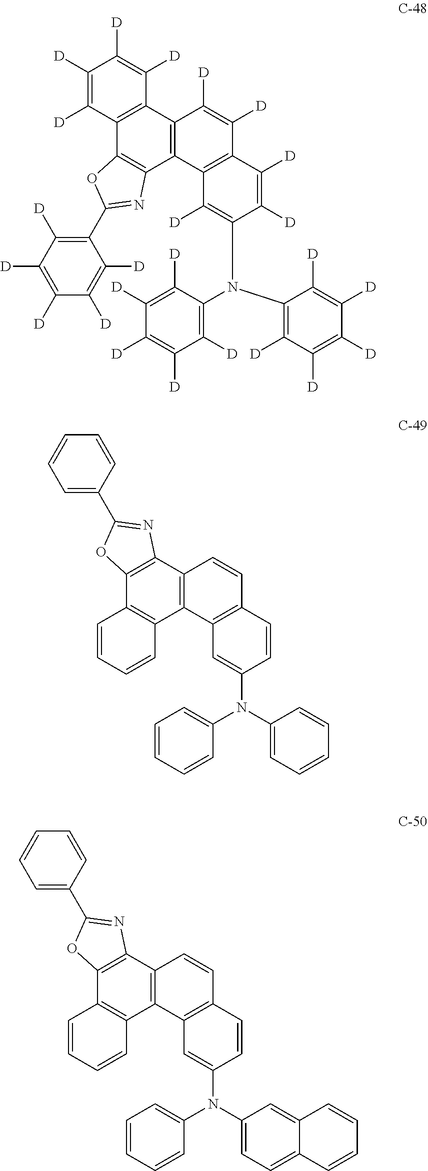 [SMILES: [2H]c1c([2H])c([2H])c(-c2nc3c(o2)c2c([2H])c([2H])c([2H])c([2H])c2c2c([2H])c([2H])c4c([2H])c([2H])c(N(c5c([2H])c([2H])c([2H])c([2H])c5[2H])c5c([2H])c([2H])c([2H])c([2H])c5[2H])c([2H])c4c32)c([2H])c1[2H] ; c1ccc(-c2nc3c4ccc5ccc(N(c6ccccc6)c6ccccc6)cc5c4c4ccccc4c3o2)cc1 ; c1ccc(-c2nc3c4ccc5ccc(N(c6ccccc6)c6ccc7ccccc7c6)cc5c4c4ccccc4c3o2)cc1]

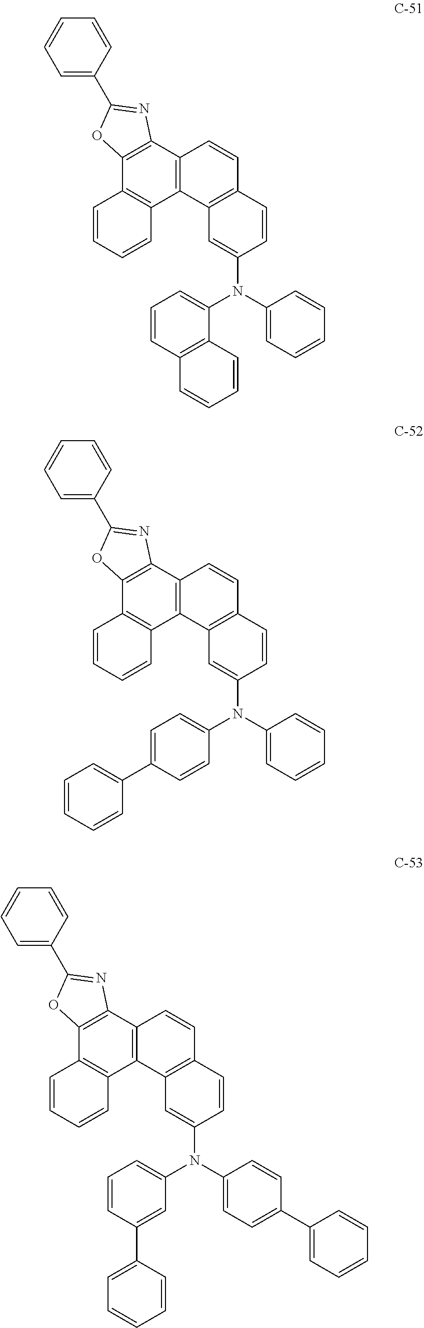 [SMILES: c1ccc(-c2nc3c4ccc5ccc(N(c6ccccc6)c6cccc7ccccc67)cc5c4c4ccccc4c3o2)cc1 ; c1ccc(-c2ccc(N(c3ccccc3)c3ccc4ccc5c6nc(-c7ccccc7)oc6c6ccccc6c5c4c3)cc2)cc1 ; c1ccc(-c2ccc(N(c3cccc(-c4ccccc4)c3)c3ccc4ccc5c6nc(-c7ccccc7)oc6c6ccccc6c5c4c3)cc2)cc1]

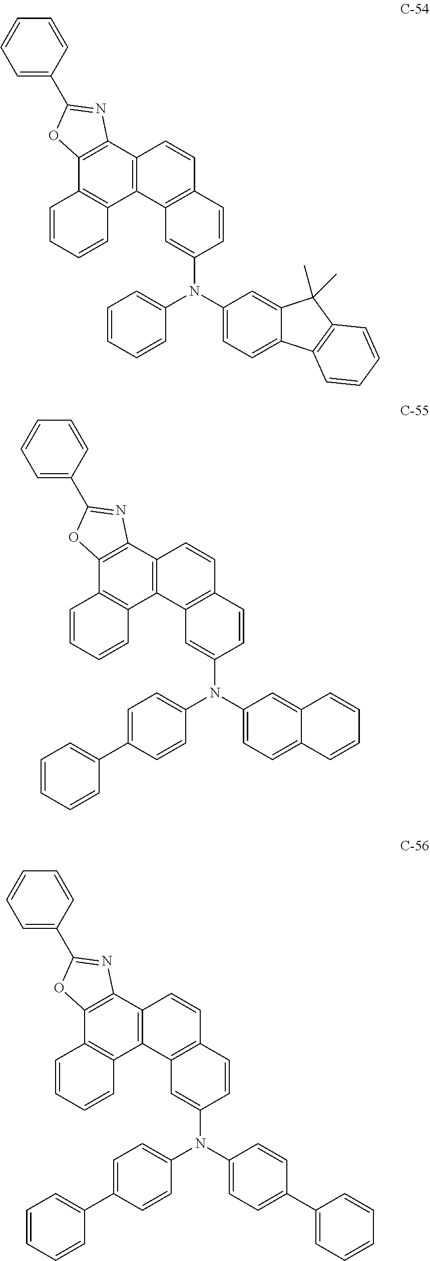 [SMILES: CC1(C)c2ccccc2-c2ccc(N(c3ccccc3)c3ccc4ccc5c6nc(-c7ccccc7)oc6c6ccccc6c5c4c3)cc21 ; c1ccc(-c2ccc(N(c3ccc4ccccc4c3)c3ccc4ccc5c6nc(-c7ccccc7)oc6c6ccccc6c5c4c3)cc2)cc1 ; c1ccc(-c2ccc(N(c3ccc(-c4ccccc4)cc3)c3ccc4ccc5c6nc(-c7ccccc7)oc6c6ccccc6c5c4c3)cc2)cc1]

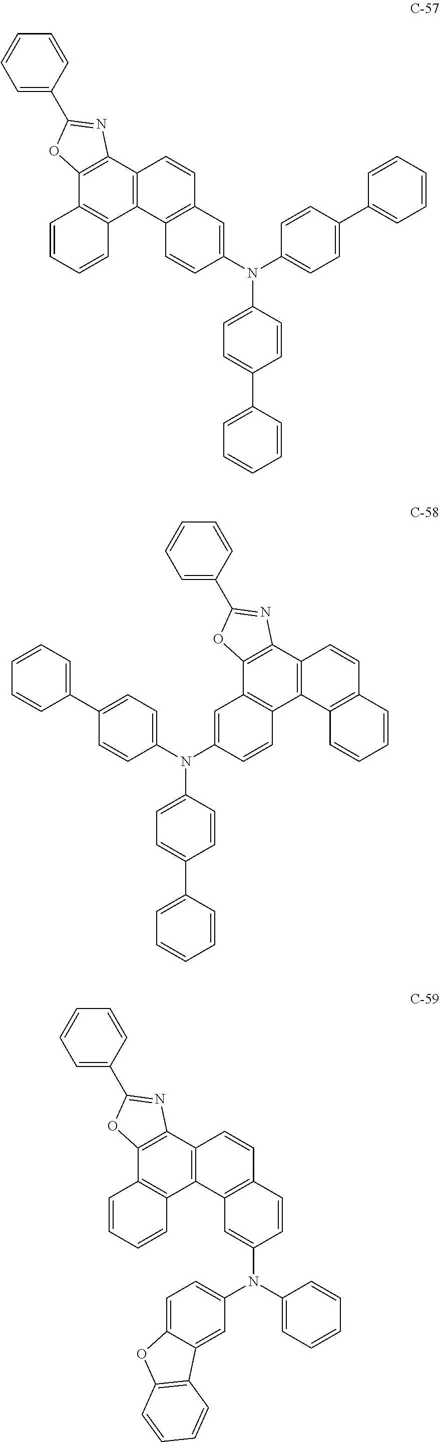 [SMILES: c1ccc(-c2ccc(N(c3ccc(-c4ccccc4)cc3)c3ccc4c(ccc5c6nc(-c7ccccc7)oc6c6ccccc6c45)c3)cc2)cc1 ; c1ccc(-c2ccc(N(c3ccc(-c4ccccc4)cc3)c3ccc4c(c3)c3oc(-c5ccccc5)nc3c3ccc5ccccc5c43)cc2)cc1 ; c1ccc(-c2nc3c4ccc5ccc(N(c6ccccc6)c6ccc7oc8ccccc8c7c6)cc5c4c4ccccc4c3o2)cc1]

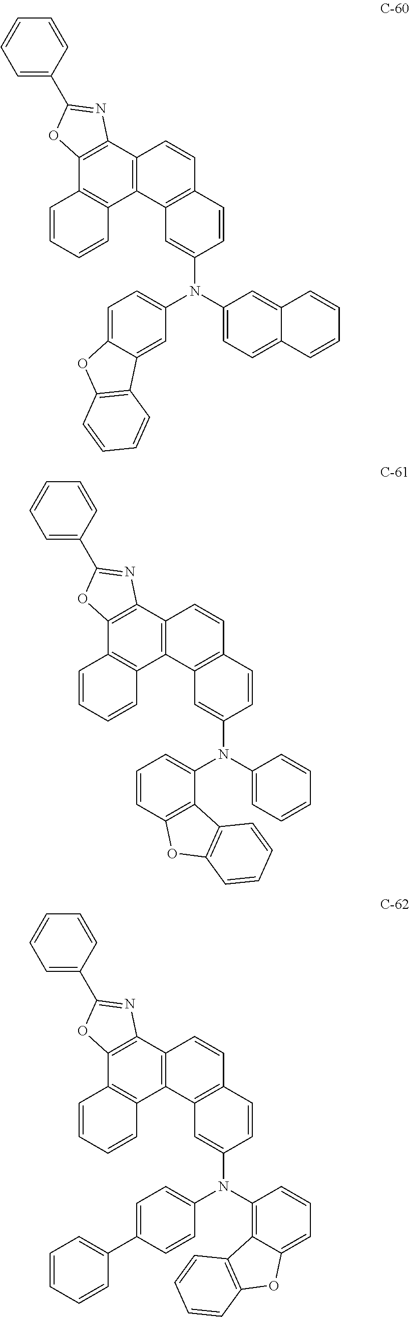

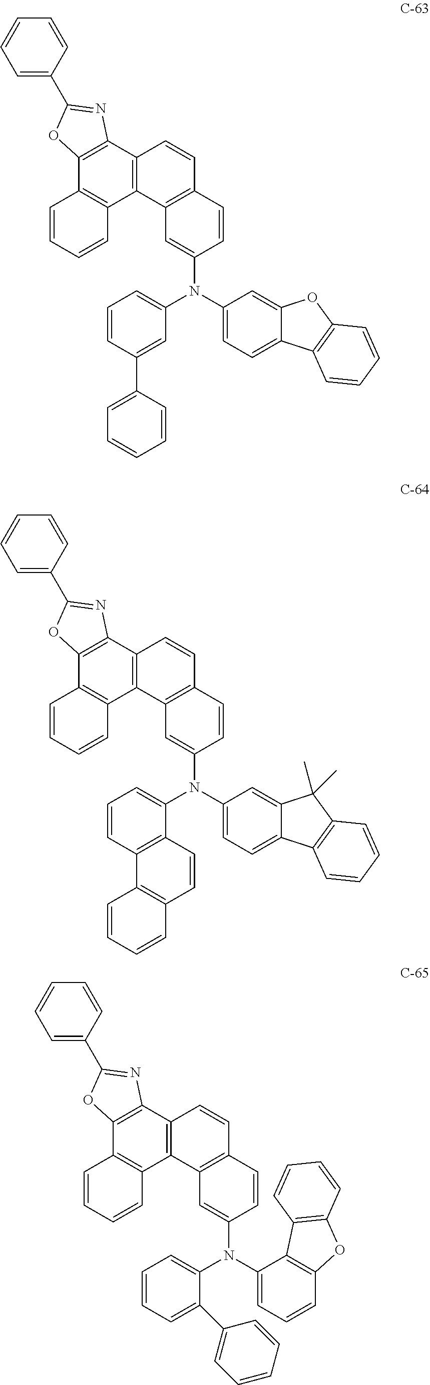 [SMILES: c1ccc(-c2cccc(N(c3ccc4c(c3)oc3ccccc34)c3ccc4ccc5c6nc(-c7ccccc7)oc6c6ccccc6c5c4c3)c2)cc1 ; CC1(C)c2ccccc2-c2ccc(N(c3ccc4ccc5c6nc(-c7ccccc7)oc6c6ccccc6c5c4c3)c3cccc4c3ccc3ccccc34)cc21 ; c1ccc(-c2nc3c4ccc5ccc(N(c6ccccc6-c6ccccc6)c6cccc7oc8ccccc8c67)cc5c4c4ccccc4c3o2)cc1]

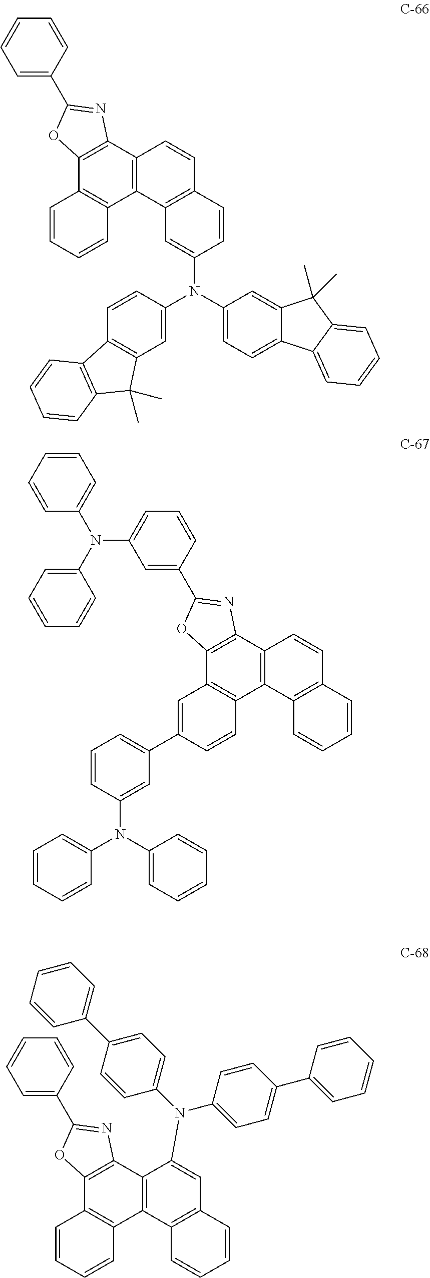

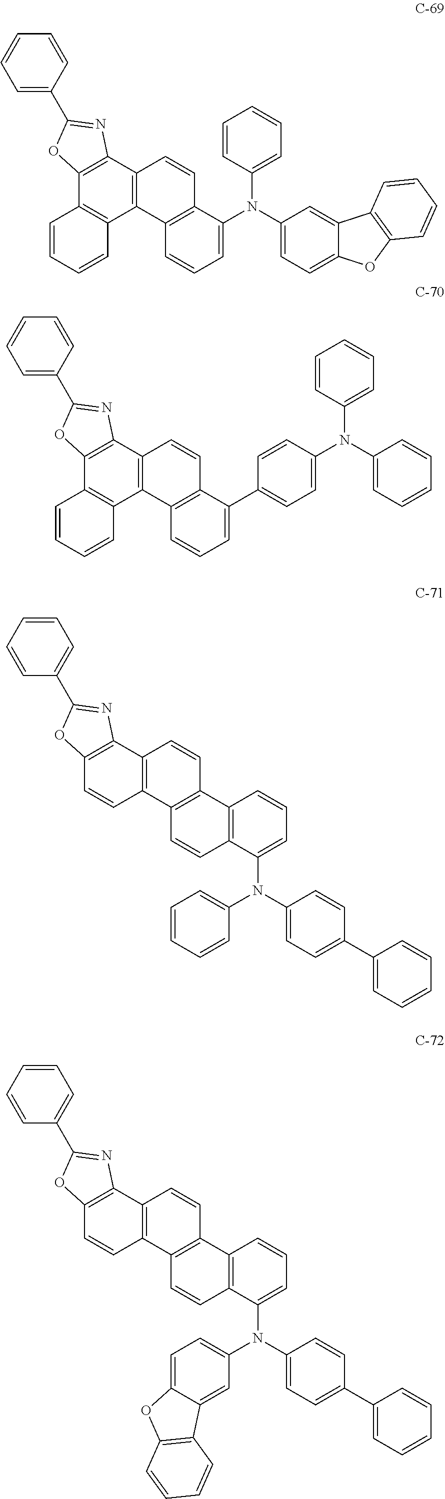 [SMILES: c1ccc(-c2nc3c4ccc5c(N(c6ccccc6)c6ccc7oc8ccccc8c7c6)cccc5c4c4ccccc4c3o2)cc1 ; c1ccc(-c2nc3c4ccc5c(-c6ccc(N(c7ccccc7)c7ccccc7)cc6)cccc5c4c4ccccc4c3o2)cc1 ; c1ccc(-c2ccc(N(c3ccccc3)c3cccc4c3ccc3c4ccc4c3ccc3oc(-c5ccccc5)nc34)cc2)cc1 ; c1ccc(-c2ccc(N(c3ccc4oc5ccccc5c4c3)c3cccc4c3ccc3c4ccc4c3ccc3oc(-c5ccccc5)nc34)cc2)cc1]

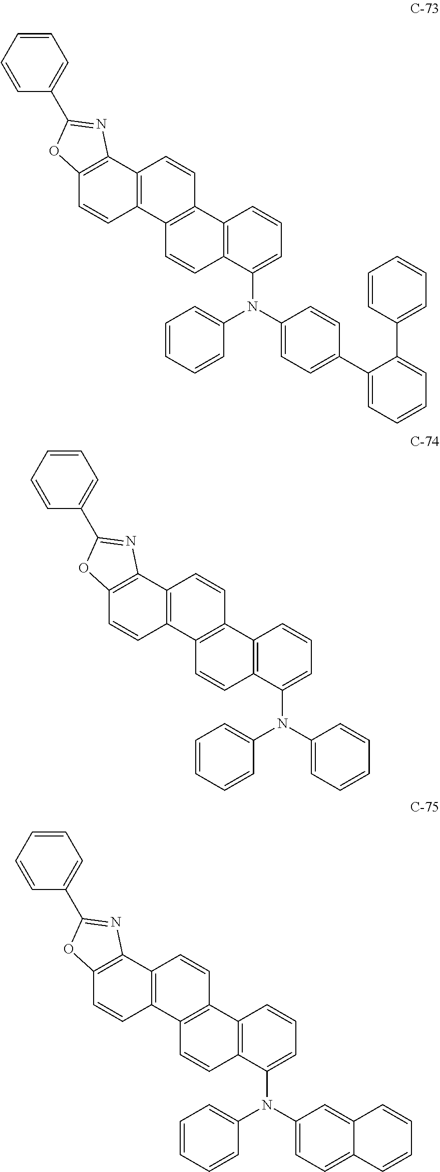 [SMILES: c1ccc(-c2nc3c(ccc4c5ccc6c(N(c7ccccc7)c7ccc(-c8ccccc8-c8ccccc8)cc7)cccc6c5ccc43)o2)cc1 ; c1ccc(-c2nc3c(ccc4c5ccc6c(N(c7ccccc7)c7ccccc7)cccc6c5ccc43)o2)cc1 ; c1ccc(-c2nc3c(ccc4c5ccc6c(N(c7ccccc7)c7ccc8ccccc8c7)cccc6c5ccc43)o2)cc1]

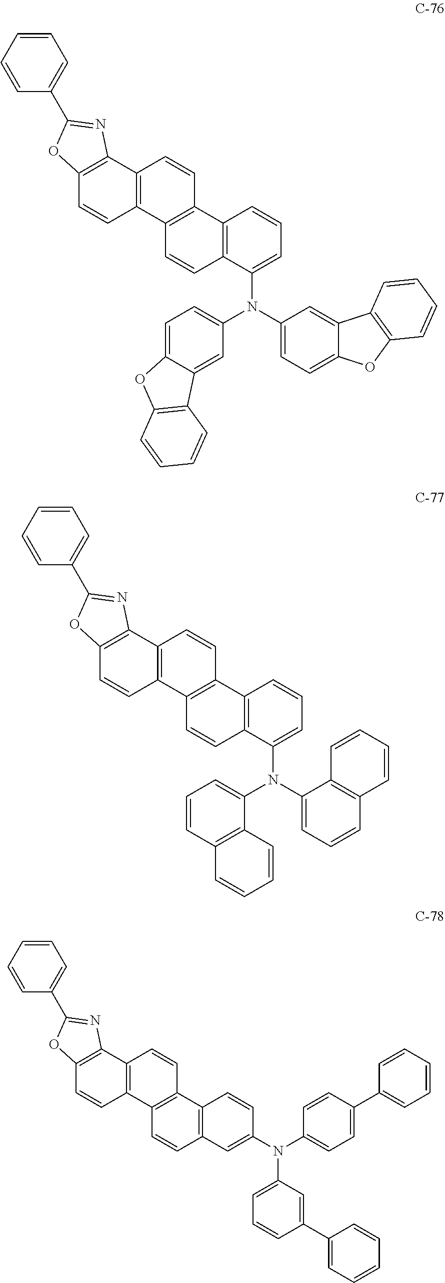 [SMILES: c1ccc(-c2nc3c(ccc4c5ccc6c(N(c7ccc8oc9ccccc9c8c7)c7ccc8oc9ccccc9c8c7)cccc6c5ccc43)o2)cc1 ; c1ccc(-c2nc3c(ccc4c5ccc6c(N(c7cccc8ccccc78)c7cccc8ccccc78)cccc6c5ccc43)o2)cc1 ; c1ccc(-c2ccc(N(c3cccc(-c4ccccc4)c3)c3ccc4c(ccc5c4ccc4c5ccc5oc(-c6ccccc6)nc54)c3)cc2)cc1]

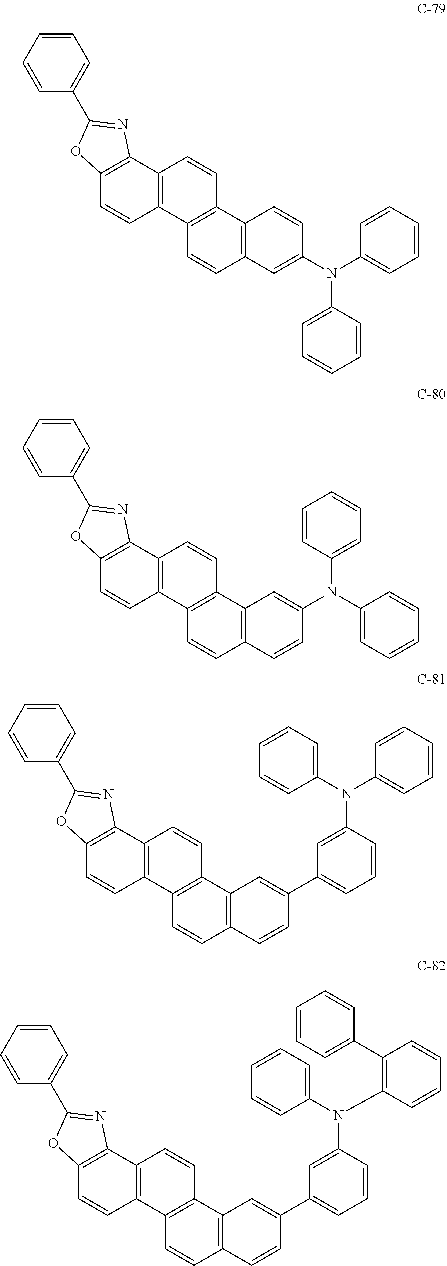 [SMILES: c1ccc(-c2nc3c(ccc4c5ccc6cc(N(c7ccccc7)c7ccccc7)ccc6c5ccc43)o2)cc1 ; c1ccc(-c2nc3c(ccc4c5ccc6ccc(N(c7ccccc7)c7ccccc7)cc6c5ccc43)o2)cc1 ; c1ccc(-c2nc3c(ccc4c5ccc6ccc(-c7cccc(N(c8ccccc8)c8ccccc8)c7)cc6c5ccc43)o2)cc1 ; c1ccc(-c2nc3c(ccc4c5ccc6ccc(-c7cccc(N(c8ccccc8)c8ccccc8-c8ccccc8)c7)cc6c5ccc43)o2)cc1]

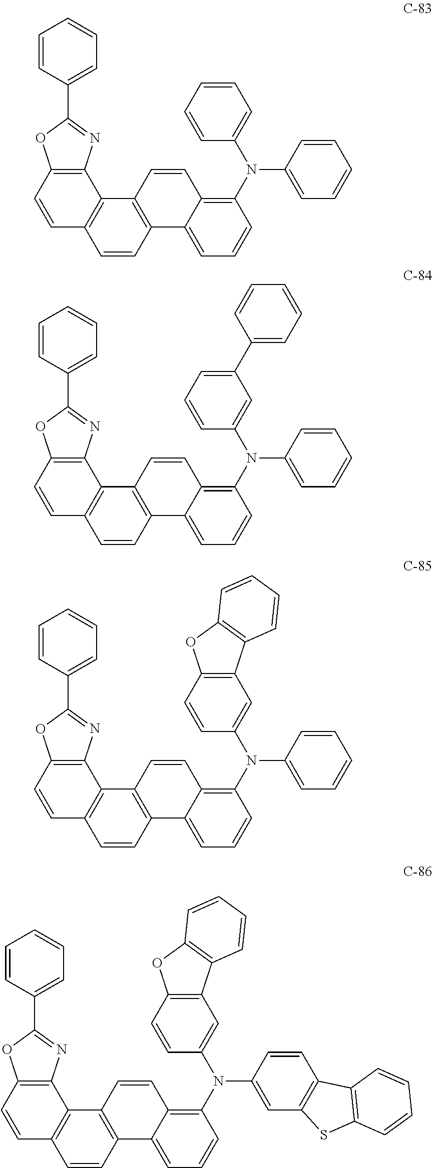

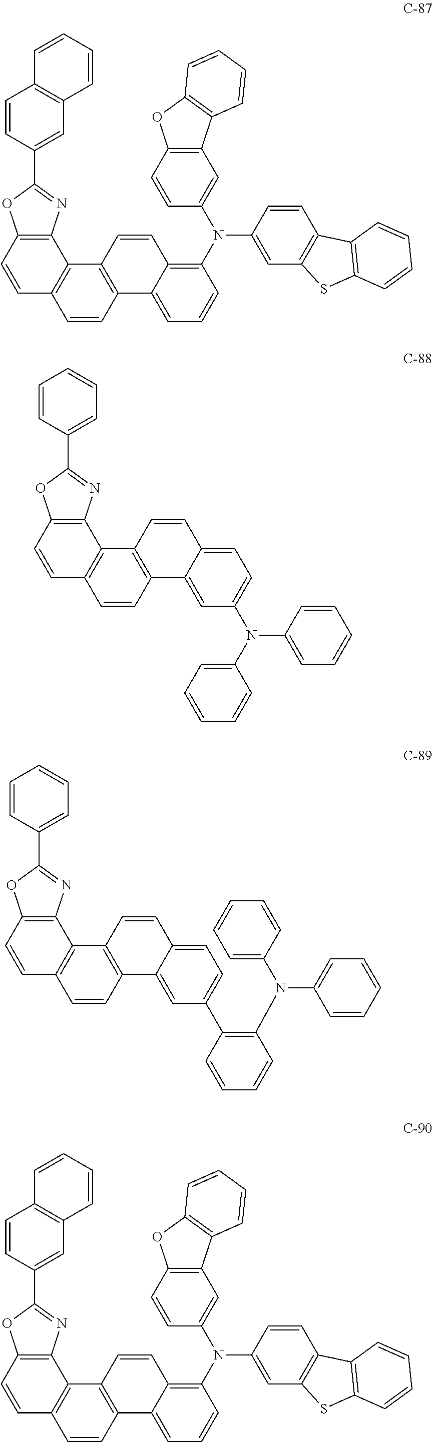

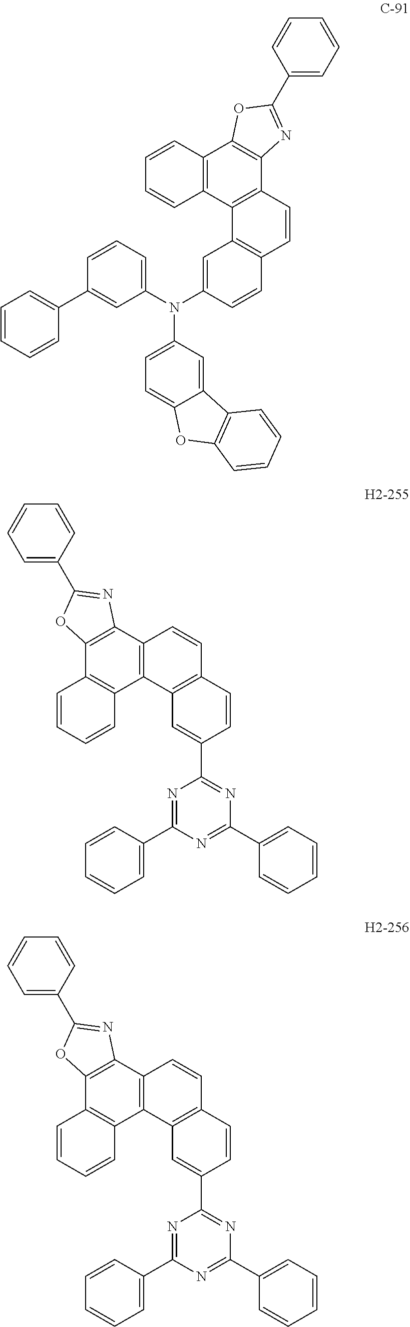 [SMILES: c1ccc(-c2cccc(N(c3ccc4oc5ccccc5c4c3)c3ccc4ccc5c6nc(-c7ccccc7)oc6c6ccccc6c5c4c3)c2)cc1 ; c1ccc(-c2nc(-c3ccccc3)nc(-c3ccc4ccc5c6nc(-c7ccccc7)oc6c6ccccc6c5c4c3)n2)cc1 ; c1ccc(-c2nc(-c3ccccc3)nc(-c3ccc4ccc5c6nc(-c7ccccc7)oc6c6ccccc6c5c4c3)n2)cc1]

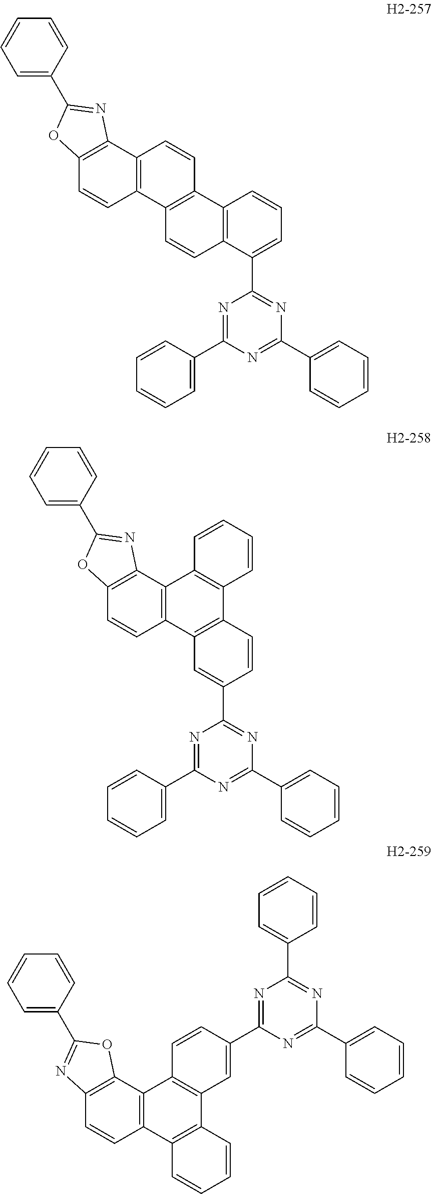

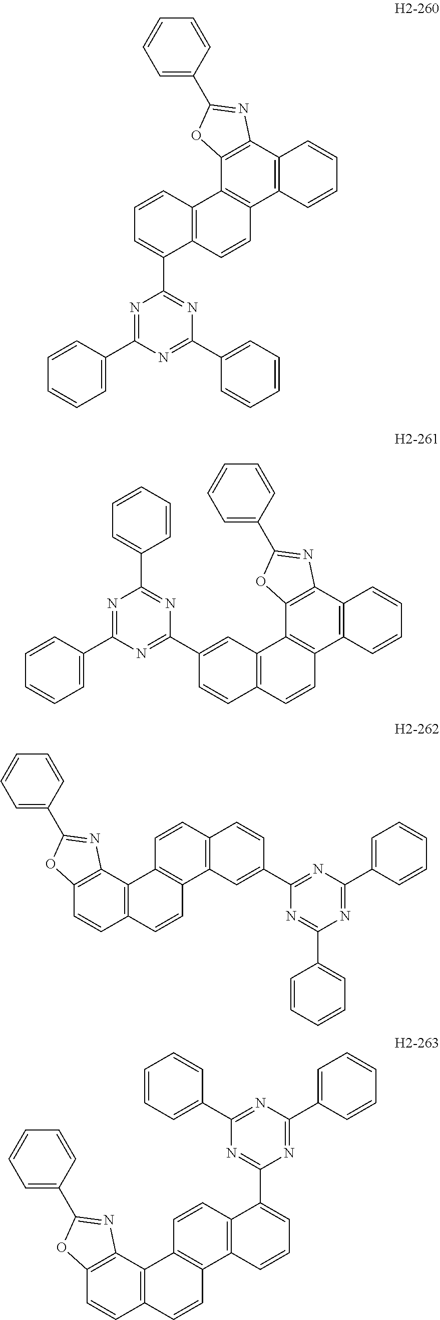

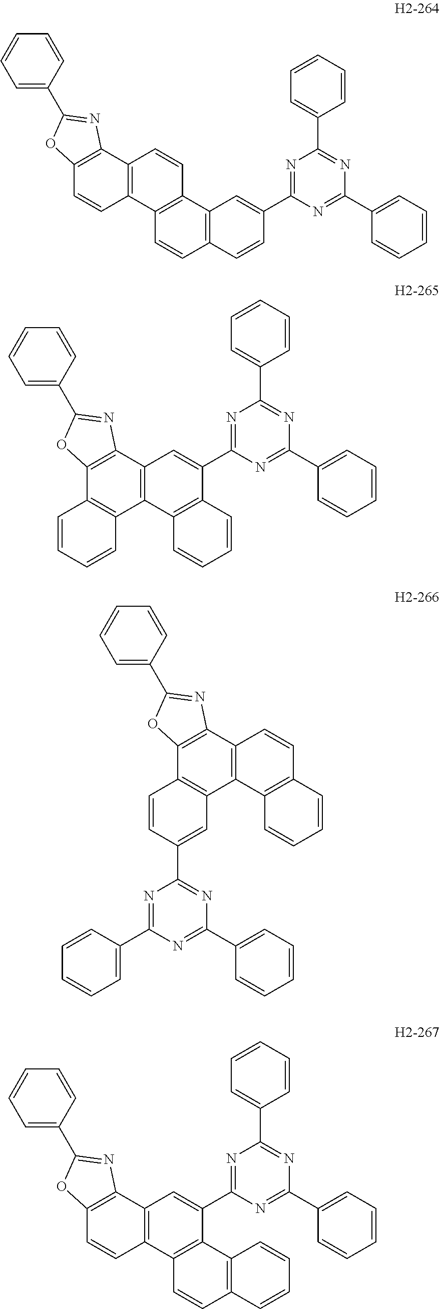

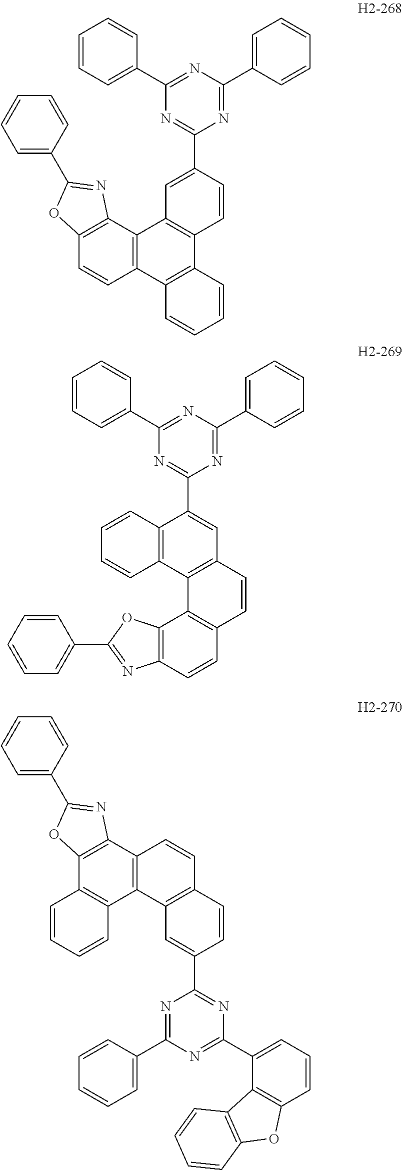

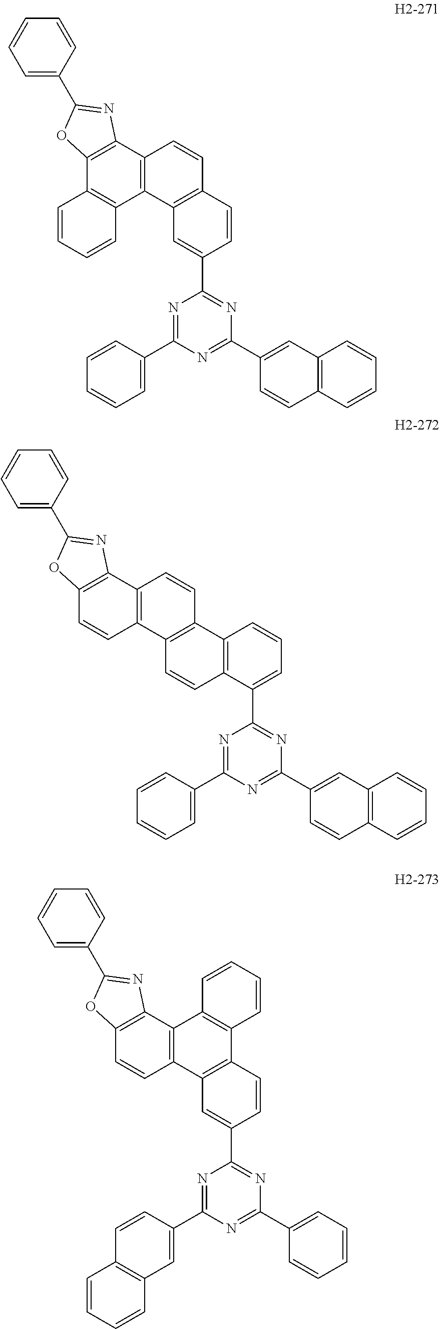 [SMILES: c1ccc(-c2nc(-c3ccc4ccccc4c3)nc(-c3ccc4ccc5c6nc(-c7ccccc7)oc6c6ccccc6c5c4c3)n2)cc1 ; c1ccc(-c2nc(-c3ccc4ccccc4c3)nc(-c3cccc4c3ccc3c4ccc4c3ccc3oc(-c5ccccc5)nc34)n2)cc1 ; c1ccc(-c2nc(-c3ccc4ccccc4c3)nc(-c3ccc4c5ccccc5c5c(ccc6oc(-c7ccccc7)nc65)c4c3)n2)cc1]

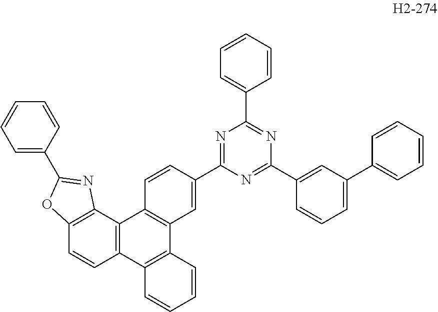 [SMILES: c1ccc(-c2cccc(-c3nc(-c4ccccc4)nc(-c4ccc5c(c4)c4ccccc4c4ccc6oc(-c7ccccc7)nc6c45)n3)c2)cc1]

Hereinafter, an organic electroluminescent device to which the aforementioned plurality of host materials and/or organic electroluminescent compound is (are) applied, will be described.

The organic electroluminescent device according to one embodiment includes a first electrode; a second electrode; and at least one organic layer(s) interposed between the first electrode and the second electrode. The organic layer may include a hole transport layer and a light-emitting layer, and the light-emitting layer may comprise a plurality of host materials comprising at least one first host material represented by formula 1 and at least one second host material represented by formula 2.

According to another embodiment, the hole transport layer may include organic electroluminescent compound represented by formula 1′.

According to one embodiment, the organic electroluminescent material of the present disclosure comprises at least one compound(s) of compounds C-1 to C-91, which is a first host material, and at least one compound(s) of compounds H2-1 to H2-274 which is a second host material. The plurality of host materials may be included in the same organic layer, for example the same light-emitting layer, or may be included in different light-emitting layers, respectively.

According to one embodiment, the hole transport layer of the present disclosure may comprises at least one compound(s) of compounds C-1 to C-91 and H2-255 to H2-274 represented by formula 1′ as a material for the hole transport layer.

The organic layer may further comprise at least one layer selected from a hole injection layer, a hole auxiliary layer, a light-emitting auxiliary layer, an electron transport layer, an electron injection layer, an interlayer, a hole blocking layer, an electron blocking layer, and an electron buffer layer in addition to the hole transport layer and the light-emitting layer. The organic layer may further comprise an amine-based compound and/or an azine-based compound other than the light-emitting material according to the present disclosure. Specifically, the hole injection layer, the hole transport layer, the hole auxiliary layer, the light-emitting layer, the light-emitting auxiliary layer, or the electron blocking layer may contain the amine-based compound, e.g., an arylamine-based compound and a styrylarylamine-based compound, etc., as a hole injection material, a hole transport material, a hole auxiliary material, a light-emitting material, a light-emitting auxiliary material, or an electron blocking material. In addition, the electron transport layer, the electron injection layer, the electron buffer layer, or the hole blocking layer may contain the azine-based compound as an electron transport material, an electron injection material, an electron buffer material, or a hole blocking material. Further, the organic layer may further comprise at least one metal selected from the group consisting of metals of Group 1, metals of Group 2, transition metals of the 4^{th} period, transition metals of the 5^{th} period, lanthanides, and organic metals of the d-transition elements of the Periodic Table, or at least one complex compound comprising such a metal.

The plurality of host materials according to one embodiment may be used as light-emitting materials for a white organic light-emitting device. The white organic light-emitting device has suggested various structures such as a parallel side-by-side arrangement method, a stacking arrangement method, or CCM (color conversion material) method, etc., according to the arrangement of R (Red), G (Green), YG (yellowish green), or B (blue) light-emitting units. In addition, the plurality of host materials according to one embodiment may also be applied to the organic electroluminescent device comprising a QD (quantum dot).

One of the first electrode and the second electrode may be an anode and the other may be a cathode. Wherein, the first electrode and the second electrode may each be formed as a transmissive conductive material, a transflective conductive material, or a reflective conductive material. The organic electroluminescent device may be a top emission type, a bottom emission type, or a both-sides emission type according to the kinds of the material forming the first electrode and the second electrode.

A hole injection layer, a hole transport layer, an electron blocking layer, or a combination thereof can be used between the anode and the light-emitting layer. The hole injection layer may be multi-layers in order to lower the hole injection barrier (or hole injection voltage) from the anode to the hole transport layer or the electron blocking layer, wherein each of the multi-layers may use two compounds simultaneously. Also, the hole injection layer may be doped as a p-dopant. Also, the electron blocking layer may be placed between the hole transport layer (or hole injection layer) and the light-emitting layer, and can confine the excitons within the light-emitting layer by blocking the overflow of electrons from the light-emitting layer to prevent a light-emitting leakage. The hole transport layer or the electron blocking layer may be multi-layers, and wherein each layer may use a plurality of compounds.

An electron buffer layer, a hole blocking layer, an electron transport layer, an electron injection layer, or a combination thereof can be used between the light-emitting layer and the cathode. The electron buffer layer may be multi-layers in order to control the injection of the electron and improve the interfacial properties between the light-emitting layer and the electron injection layer, wherein each of the multi-layers may use two compounds simultaneously. The hole blocking layer may be placed between the electron transport layer (or electron injection layer) and the light-emitting layer, and blocks the arrival of holes to the cathode, thereby improving the probability of recombination of electrons and holes in the light-emitting layer. The hole blocking layer or the electron transport layer may also be multi-layers, wherein each layer may use a plurality of compounds. In addition, the electron injection layer may be doped as an n-dopant.

The light-emitting auxiliary layer may be placed between the anode and the light-emitting layer, or between the cathode and the light-emitting layer. When the light-emitting auxiliary layer is placed between the anode and the light-emitting layer, it can be used for promoting the hole injection and/or the hole transport, or for preventing the overflow of electrons. When the light-emitting auxiliary layer is placed between the cathode and the light-emitting layer, it can be used for promoting the electron injection and/or the electron transport, or for preventing the overflow of holes. In addition, the hole auxiliary layer may be placed between the hole transport layer (or hole injection layer) and the light-emitting layer, and may be effective to promote or block the hole transport rate (or the hole injection rate), thereby enabling the charge balance to be controlled. When an organic electroluminescent device includes two or more hole transport layers, the hole transport layer, which is further included, may be used as the hole auxiliary layer or the electron blocking layer. The light-emitting auxiliary layer, the hole auxiliary layer, or the electron blocking layer may have an effect of improving the efficiency and/or the lifespan of the organic electroluminescent device.

In the organic electroluminescent device of the present disclosure, preferably, at least one layer (hereinafter, “a surface layer”) selected from a chalcogenide layer, a halogenated metal layer, and a metal oxide layer may be placed on an inner surface(s) of one or both of a pair of electrodes. Specifically, a chalcogenide (including oxides) layer of silicon and aluminum is preferably, placed on an anode surface of an electroluminescent medium layer, and a halogenated metal layer or a metal oxide layer is preferably, placed on a cathode surface of an electroluminescent medium layer. The operation stability for the organic electroluminescent device may be obtained by the surface layer. Preferably, the chalcogenide includes SiOₓ(1≤X≤2), AlOₓ(1≤X≤1.5), SiON, SiAION, etc.; the halogenated metal includes LiF, MgF₂, CaF₂, a rare earth metal fluoride, etc.; and the metal oxide includes Cs₂O, Li₂O, MgO, SrO, BaO, CaO, etc.

In addition, in the organic electroluminescent device of the present disclosure, a mixed region of an electron transport compound and a reductive dopant, or a mixed region of a hole transport compound and an oxidative dopant may be placed on at least one surface of a pair of electrodes. In this case, the electron transport compound is reduced to an anion, and thus it becomes easier to inject and transport electrons from the mixed region to an electroluminescent medium. Furthermore, the hole transport compound is oxidized to a cation, and thus it becomes easier to inject and transport holes from the mixed region to the electroluminescent medium. Preferably, the oxidative dopant includes various Lewis acids and acceptor compounds, and the reductive dopant includes alkali metals, alkali metal compounds, alkaline earth metals, rare-earth metals, and mixtures thereof. In addition, a reductive dopant layer may be employed as a charge generating layer to prepare an organic electroluminescent device having two or more light-emitting layers and emitting white light.

An organic electroluminescent device according to one embodiment may further comprise at least one dopant in the light-emitting layer.

The dopant comprised in the organic electroluminescent device of the present disclosure may be at least one phosphorescent or fluorescent dopant, preferably, a phosphorescent dopant. The phosphorescent dopant material applied to the organic electroluminescent device of the present disclosure is not particularly limited, but may be preferably, a metallated complex compound(s) of a metal atom(s) selected from iridium (Ir), osmium (Os), copper (Cu), and platinum (Pt), more preferably, an ortho-metallated complex compound(s) of a metal atom(s) selected from iridium (Ir), osmium (Os), copper (Cu), and platinum (Pt), and even more preferably, ortho-metallated iridium complex compound(s).

The dopant comprised in the organic electroluminescent device of the present disclosure may use the compound represented by the following formula 101, but is not limited thereto.

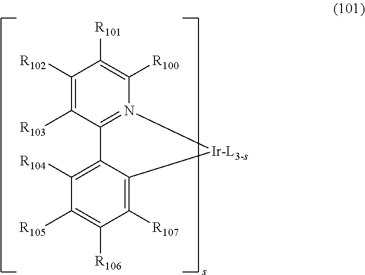

in formula 101,
L is selected from the following structures 1 to 3;

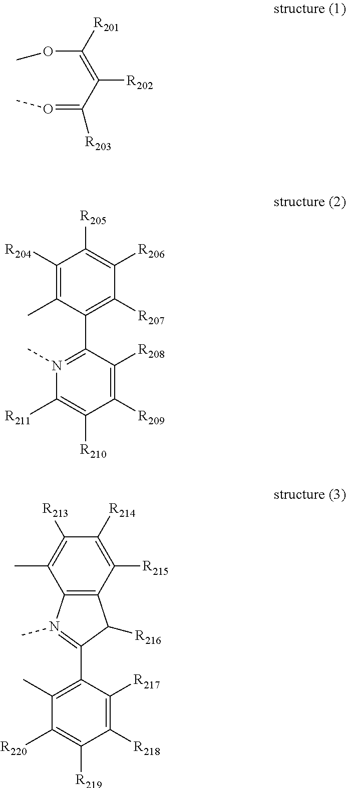

R₁₀₀ to R₁₀₃ each independently represent, hydrogen, deuterium, halogen, (C1-C30)alkyl unsubstituted or substituted by deuterium and/or halogen, a substituted or unsubstituted (C3-C30)cycloalkyl, a substituted or unsubstituted (C6-C30)aryl, cyano, a substituted or unsubstituted (3- to 30-membered)heteroaryl, or a substituted or unsubstituted (C1-C30)alkoxy; or may be linked to the adjacent substituents to form a ring(s), for example, to form a ring(s) with a pyridine, e.g., a substituted or unsubstituted quinoline, a substituted or unsubstituted benzofuropyridine, a substituted or unsubstituted benzothienopyridine, a substituted or unsubstituted indenopyridine, a substituted or unsubstituted benzofuroquinoline, a substituted or unsubstituted benzothienoquinoline, or a substituted or unsubstituted indenoquinoline;

R₁₀₄ to R₁₀₇ each independently represent, hydrogen, deuterium, halogen, (C1-C30)alkyl unsubstituted or substituted by deuterium and/or halogen, a substituted or unsubstituted (C3-C30)cycloalkyl, a substituted or unsubstituted (C6-C30)aryl, a substituted or unsubstituted (3- to 30-membered)heteroaryl, cyano, or a substituted or unsubstituted (C1-C30)alkoxy; or may be linked to an adjacent substituent(s) to form a substituted or unsubstituted ring(s), for example, to form a ring(s) with a benzene, e.g., a substituted or unsubstituted naphthalene, a substituted or unsubstituted fluorene, a substituted or unsubstituted dibenzothiophene, a substituted or unsubstituted dibenzofuran, a substituted or unsubstituted indenopyridine, a substituted or unsubstituted benzofuropyridine, or a substituted or unsubstituted benzothienopyridine;

R₂₀₁ to R₂₂₀ each independently represent, hydrogen, deuterium, halogen, a substituted or unsubstituted (C1-C30)alkyl unsubstituted or substituted by deuterium and/or halogen, a substituted or unsubstituted (C3-C30)cycloalkyl, or a substituted or unsubstituted (C6-C30)aryl; or may be linked to an adjacent substituent(s) to form a substituted or unsubstituted ring(s); and
s represents an integer of 1 to 3.

Specifically, the specific examples of the dopant compound include the following, but are not limited thereto.

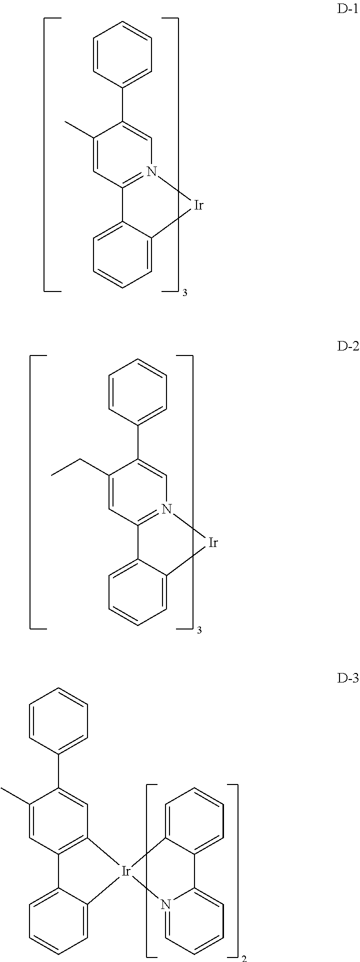

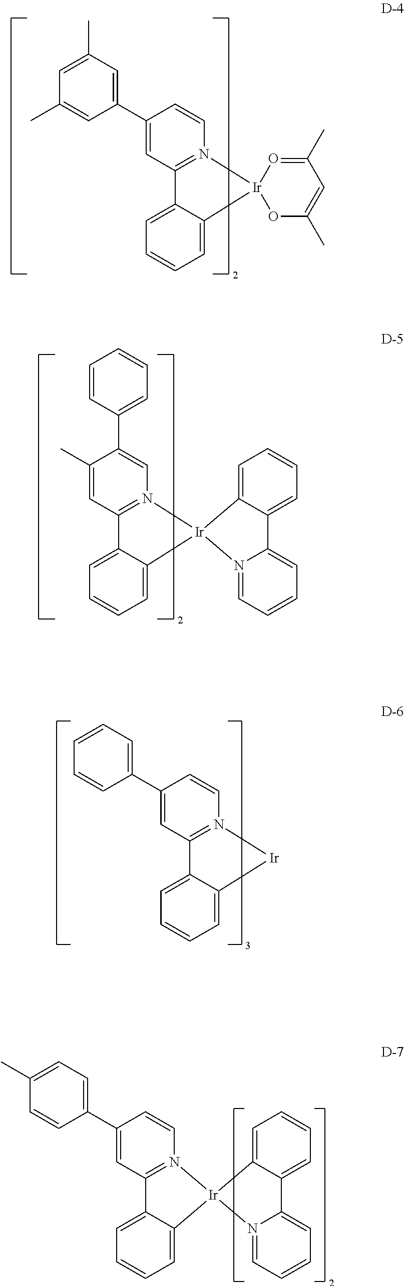

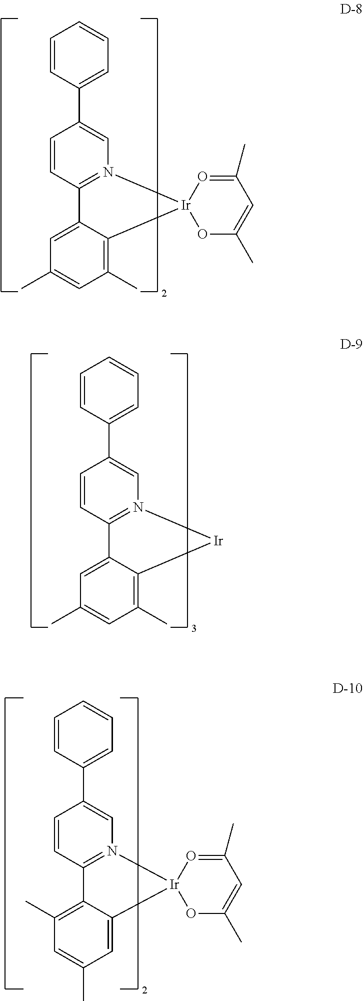

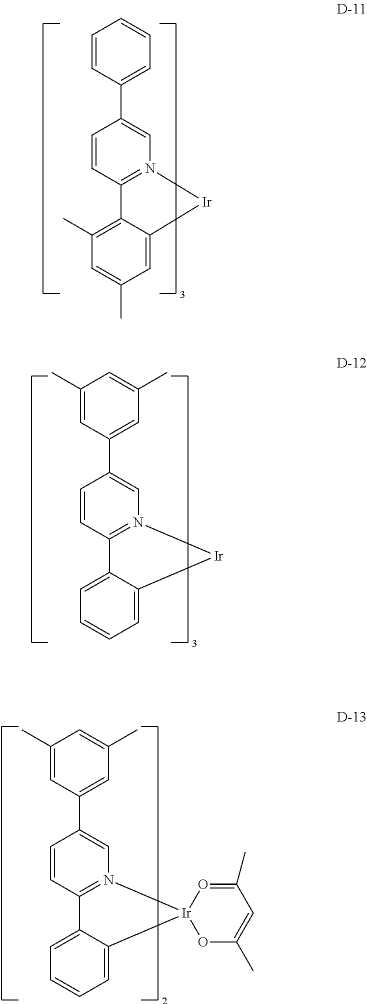

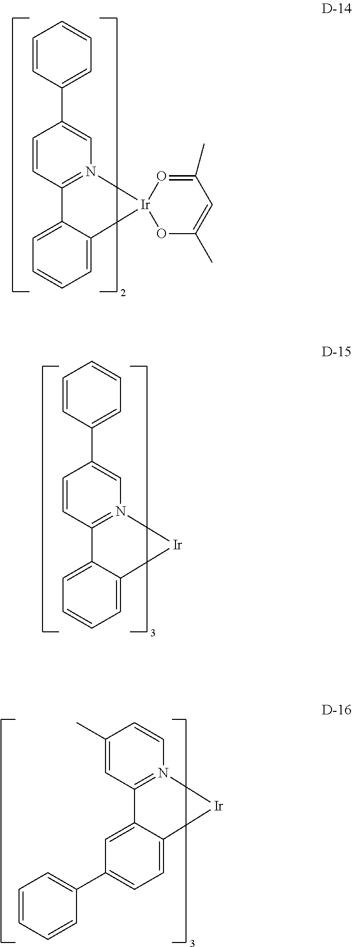

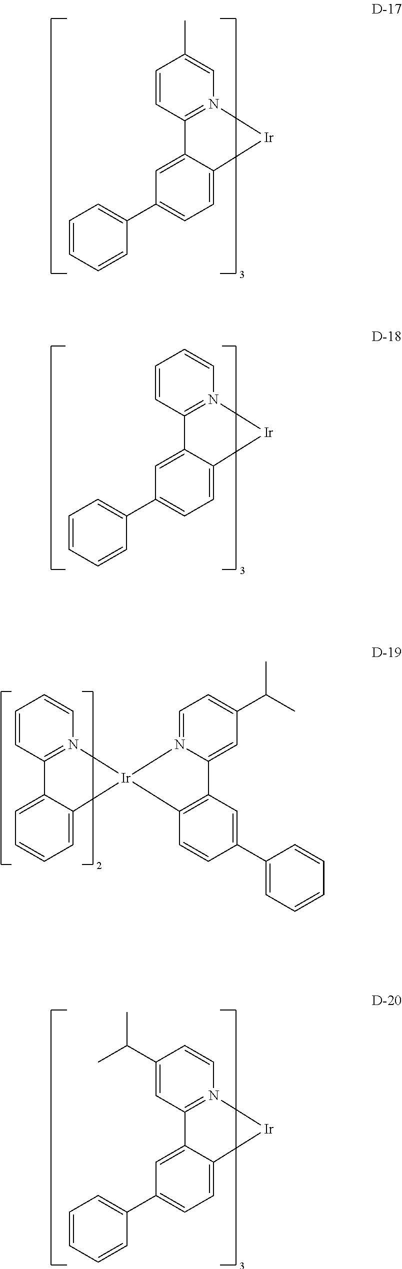

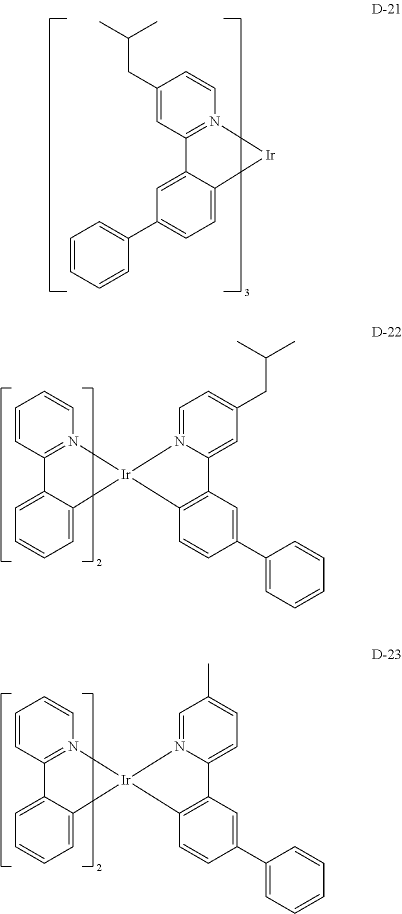

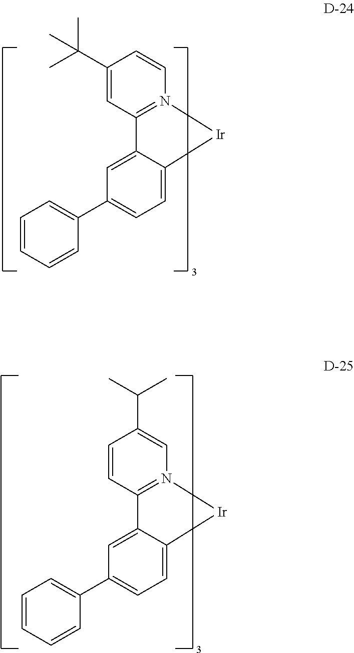

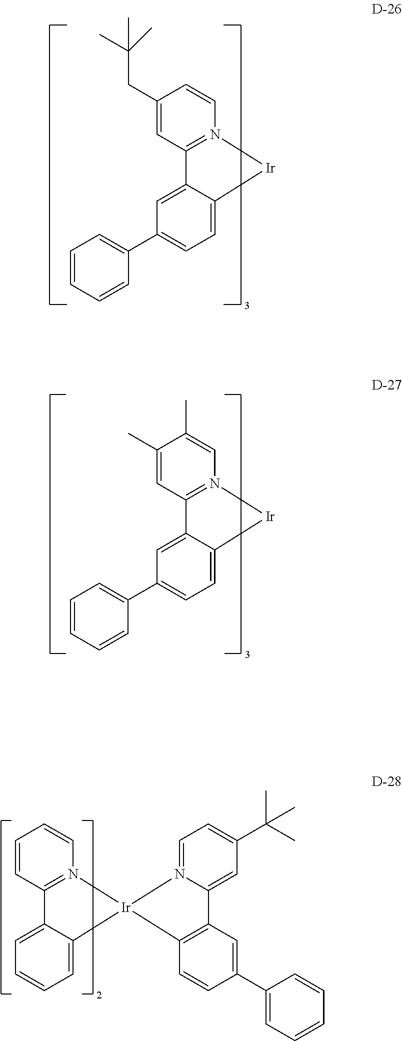

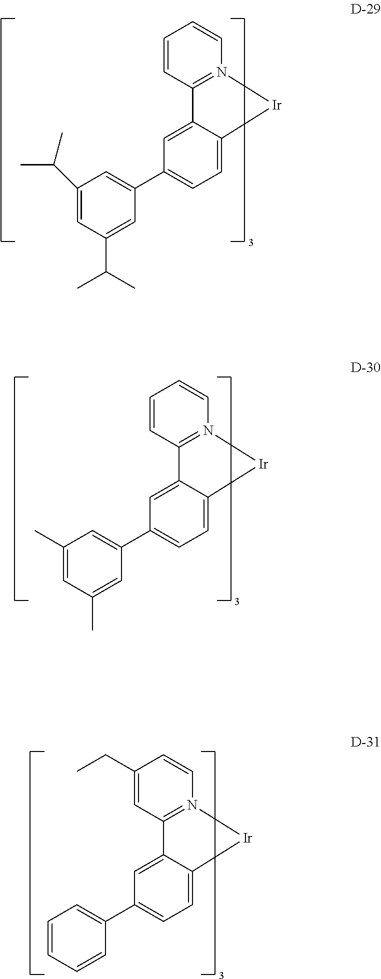

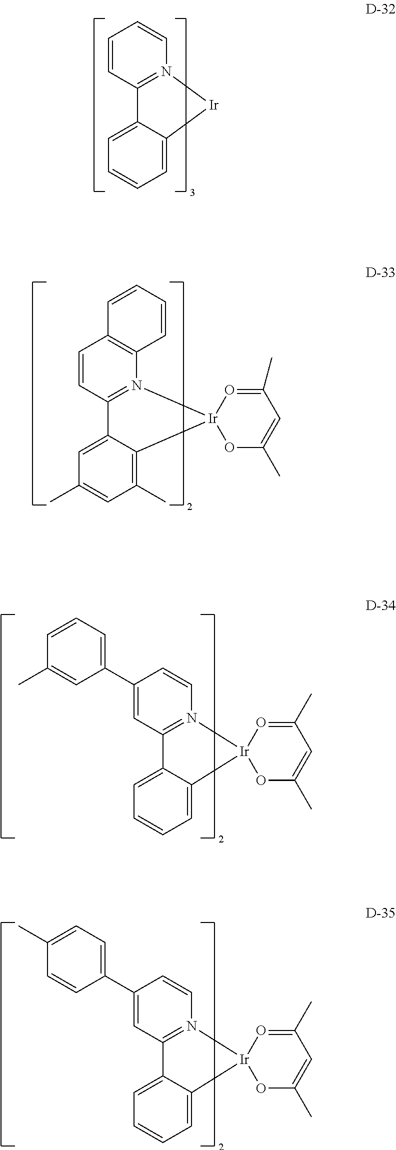

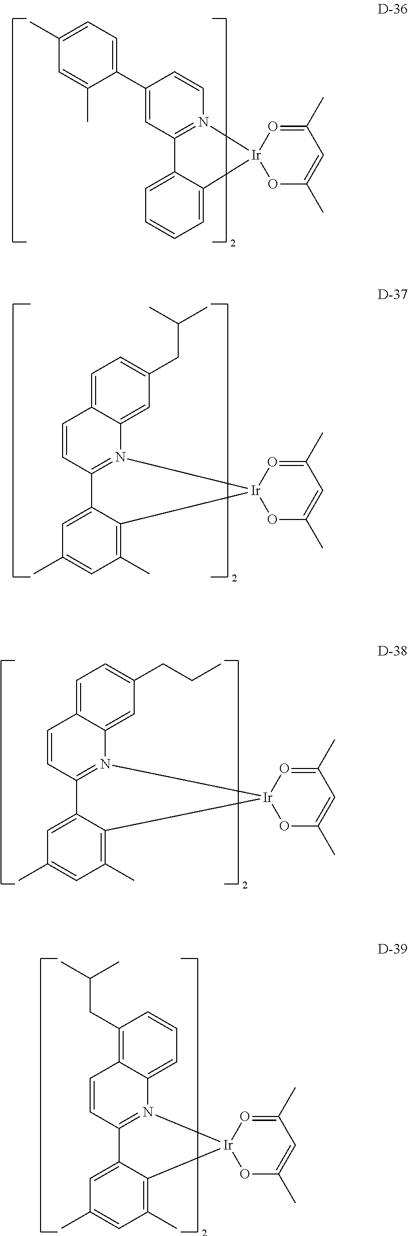

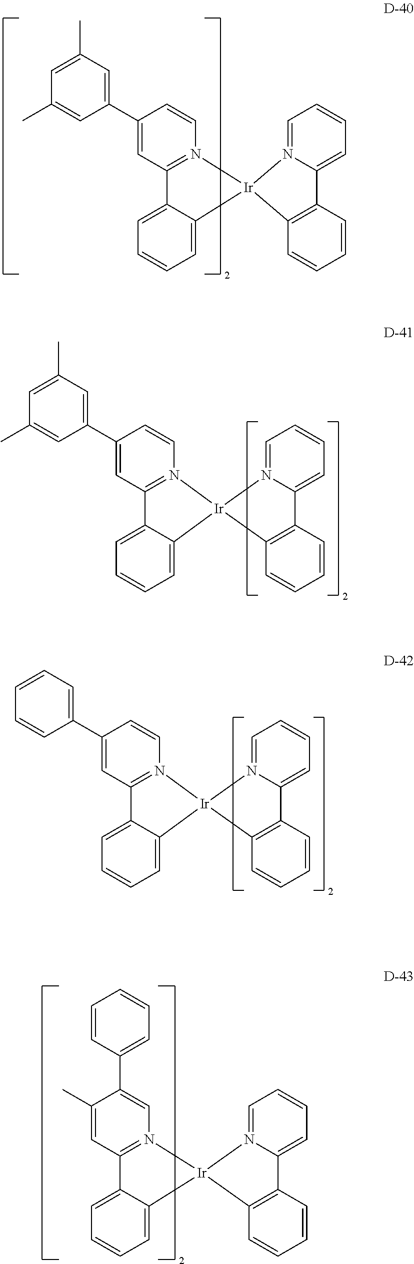

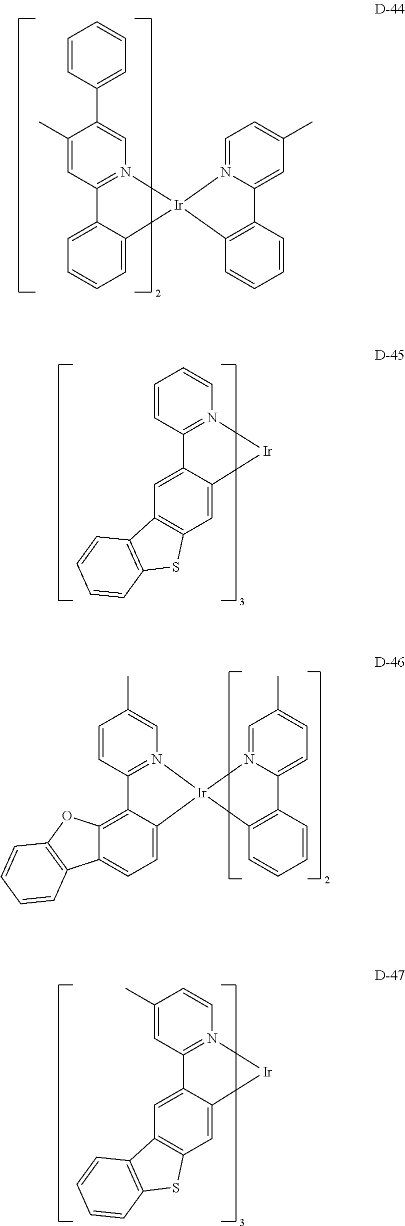

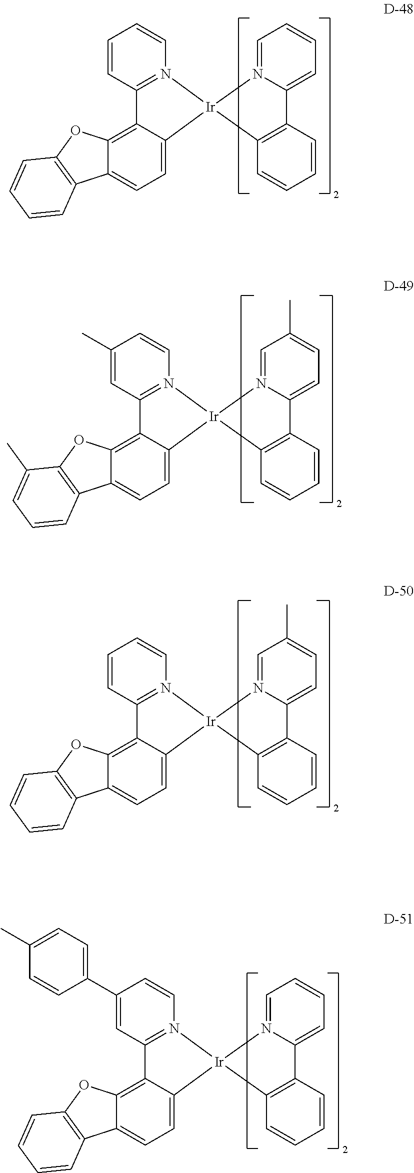

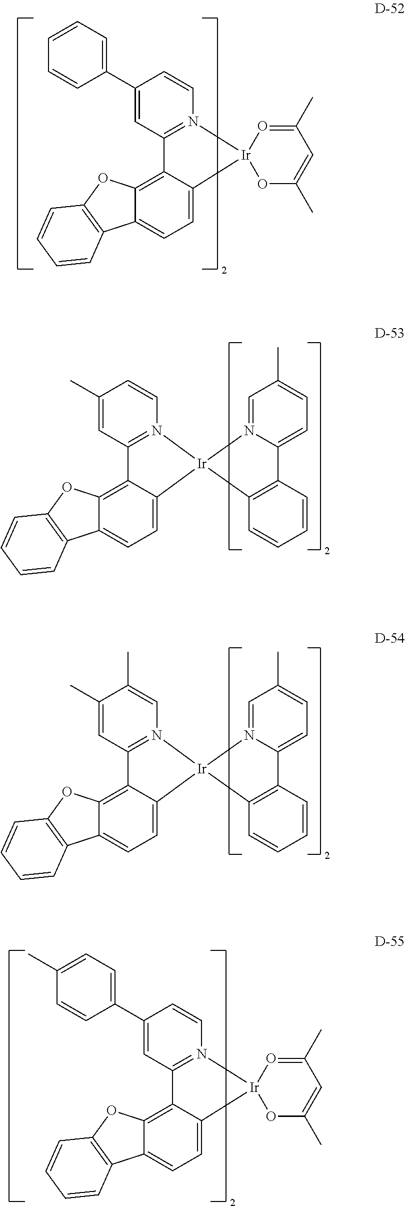

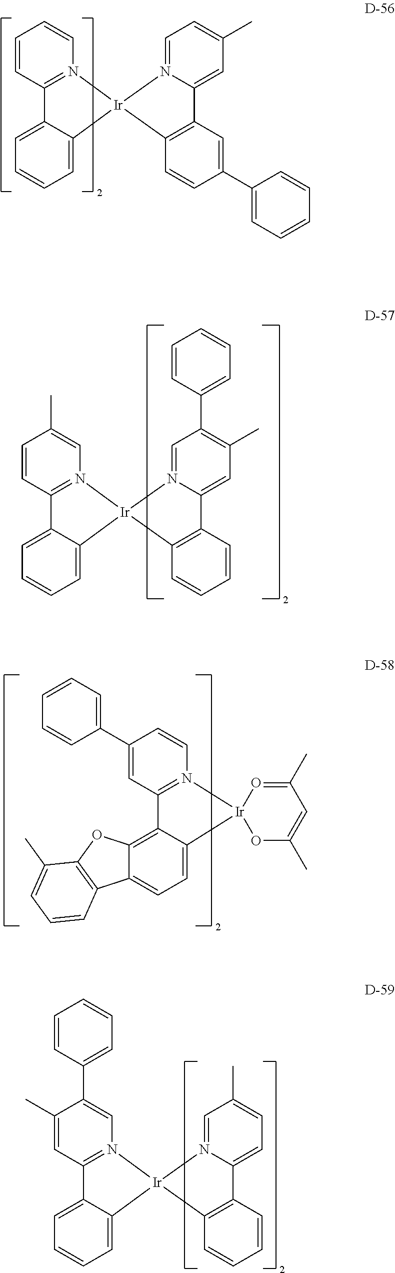

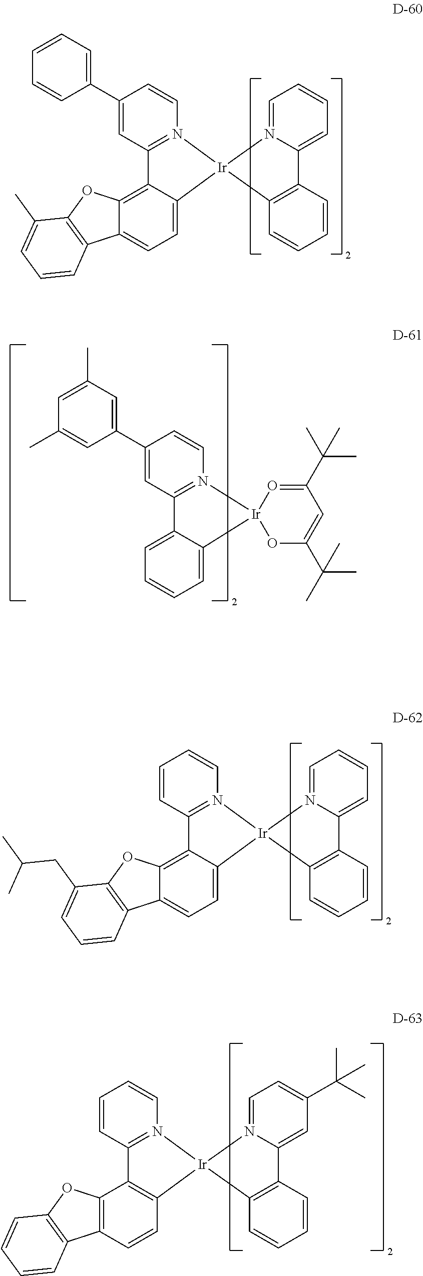

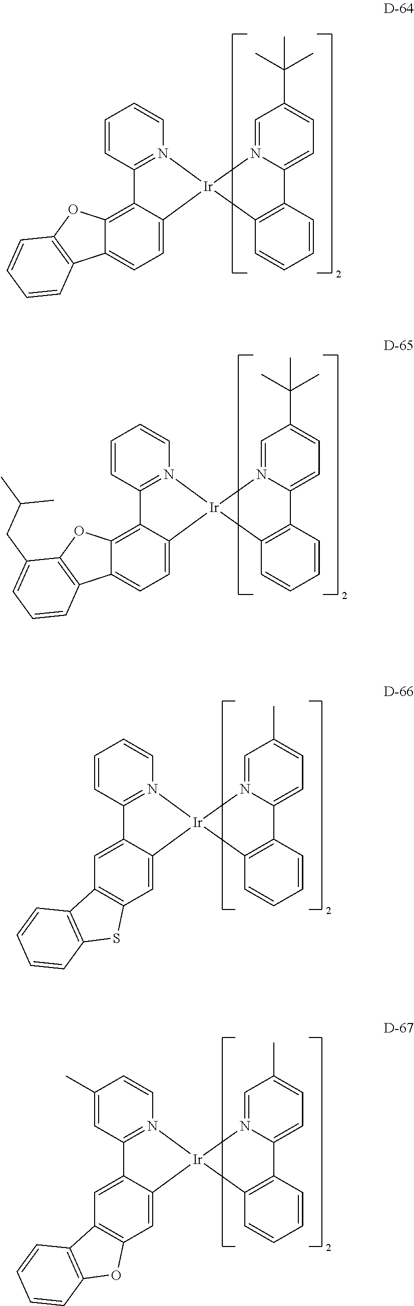

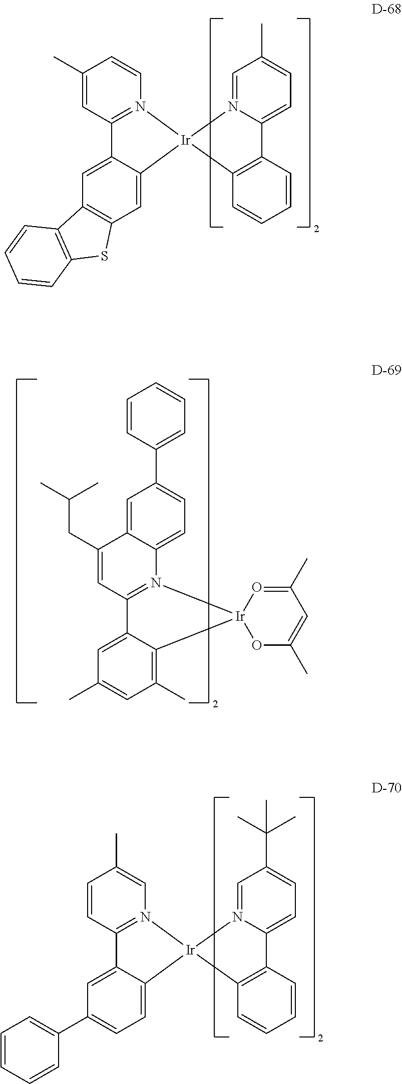

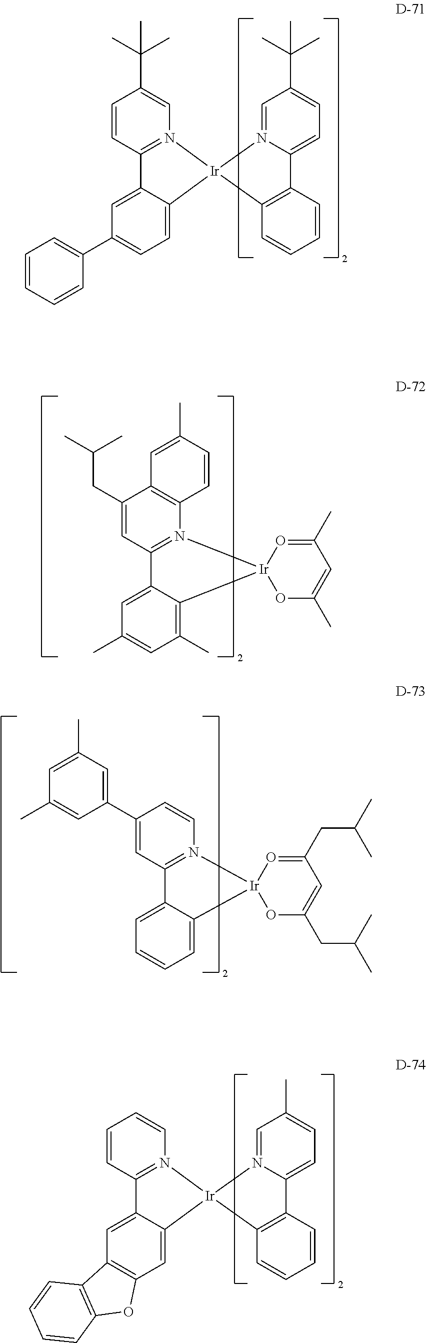

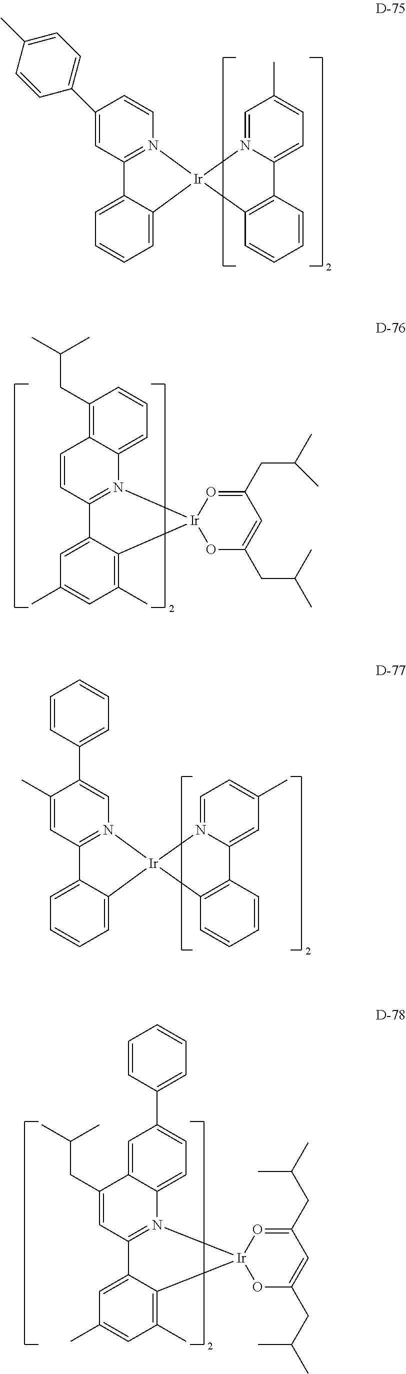

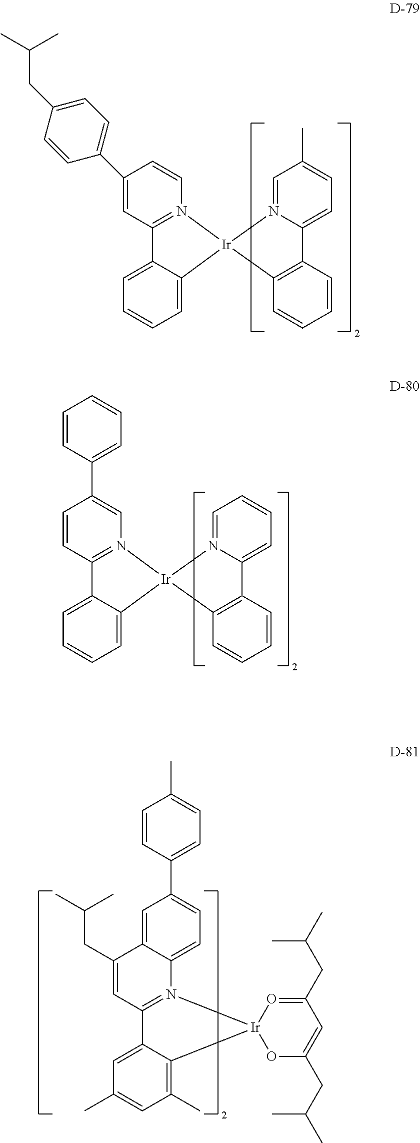

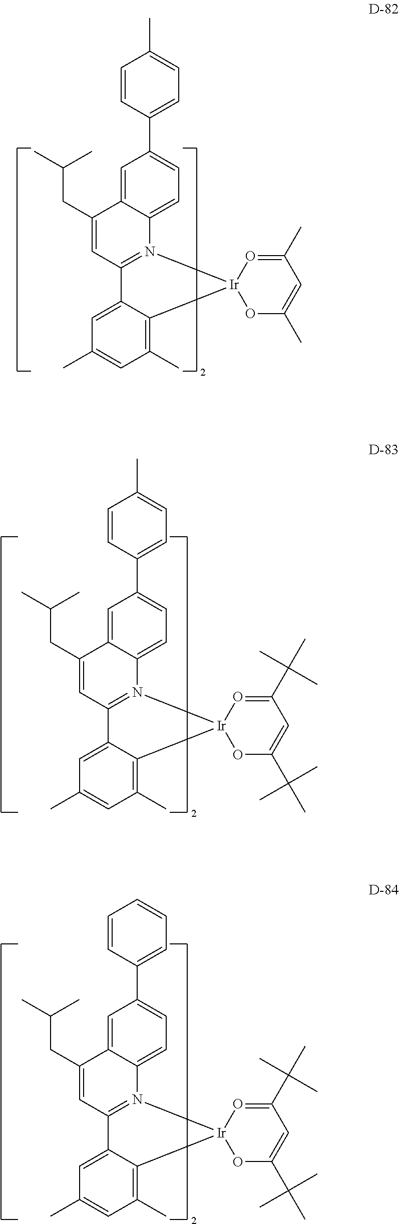

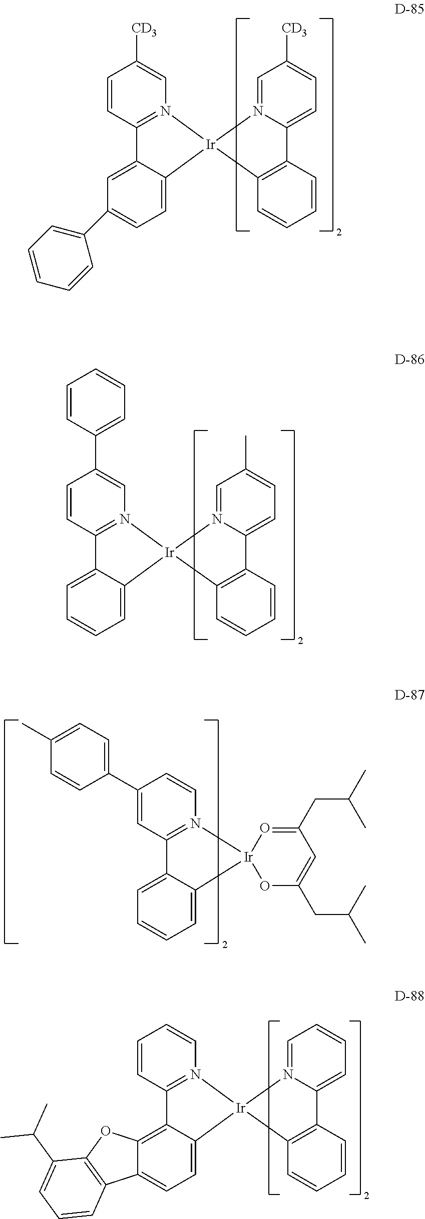

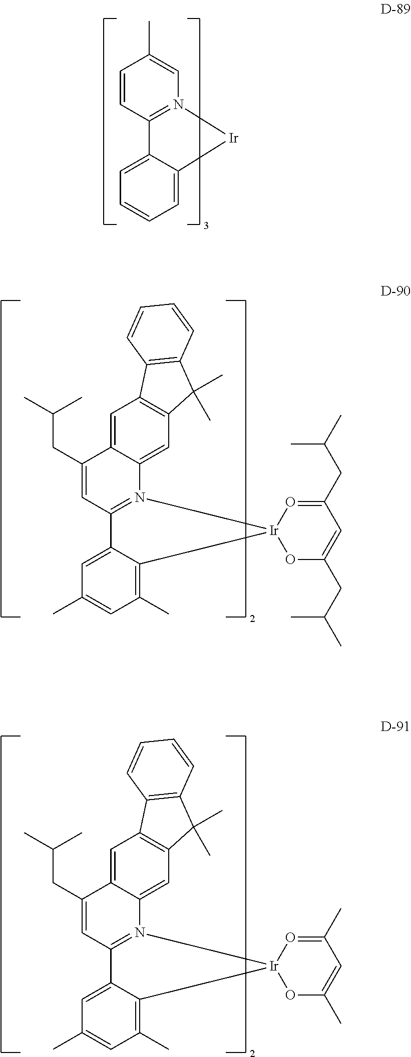

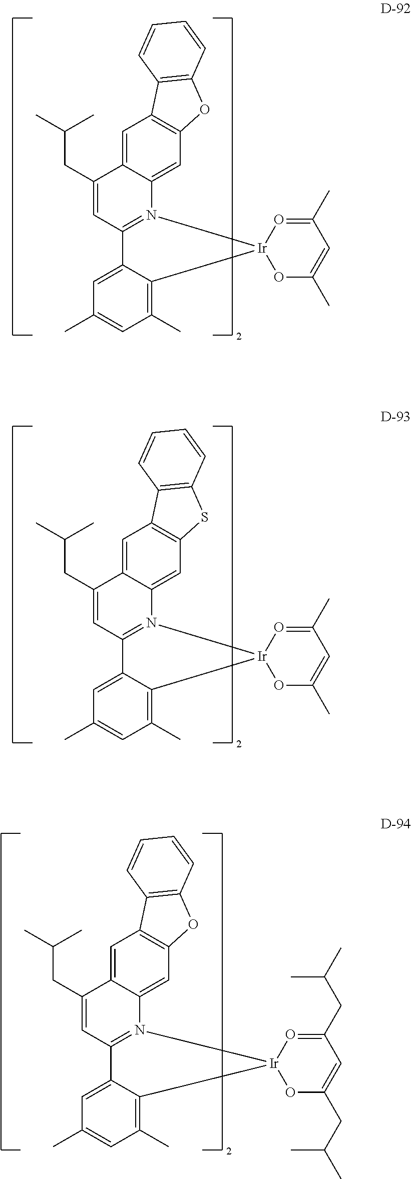

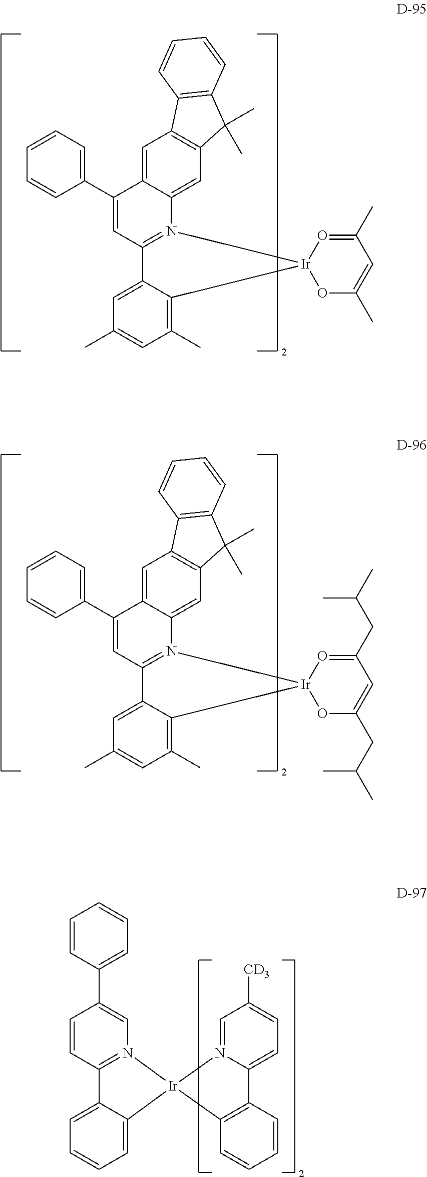

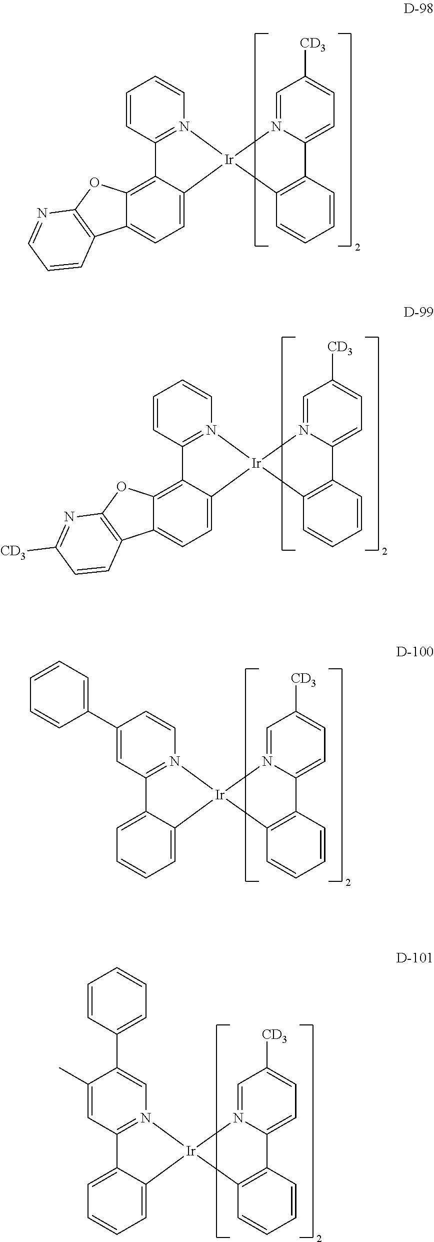

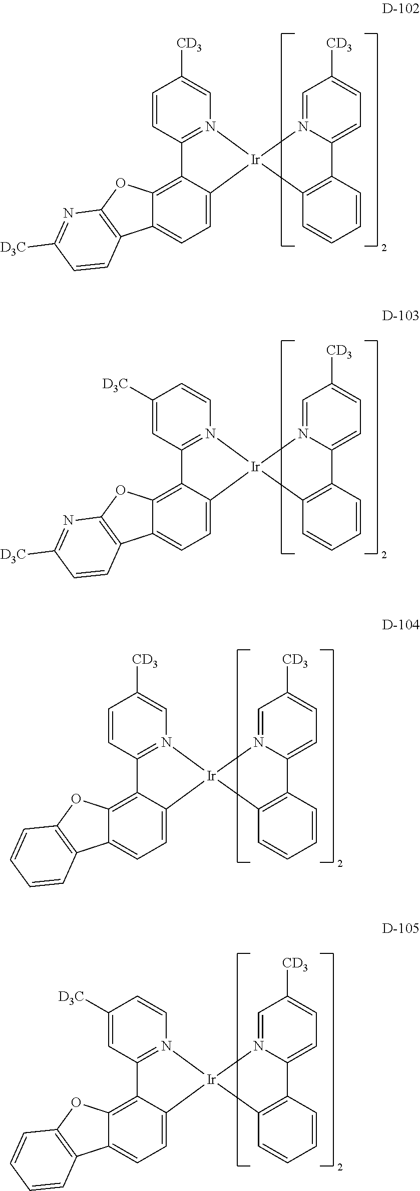

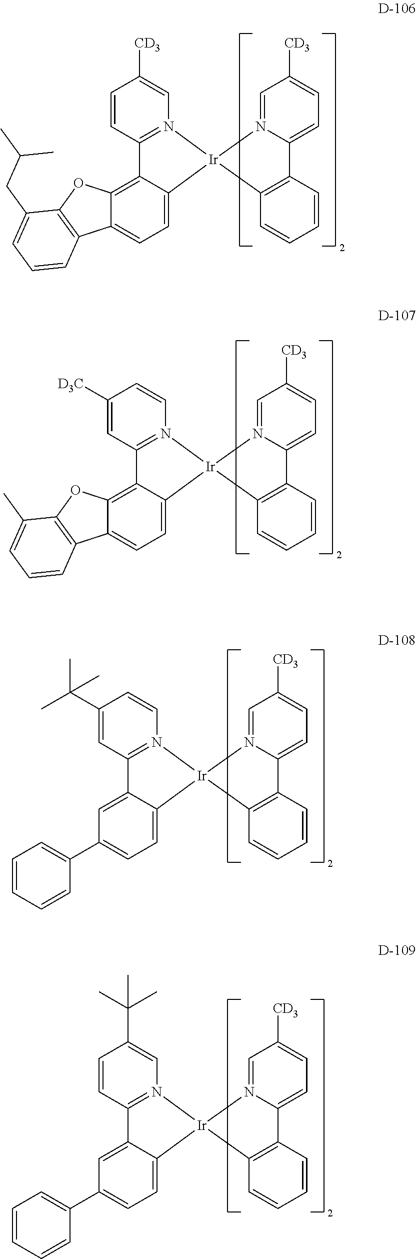

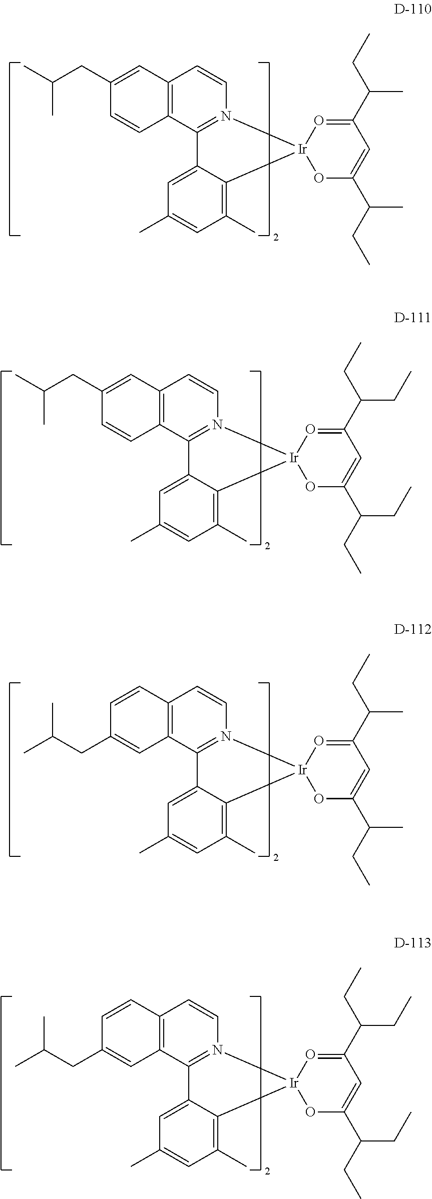

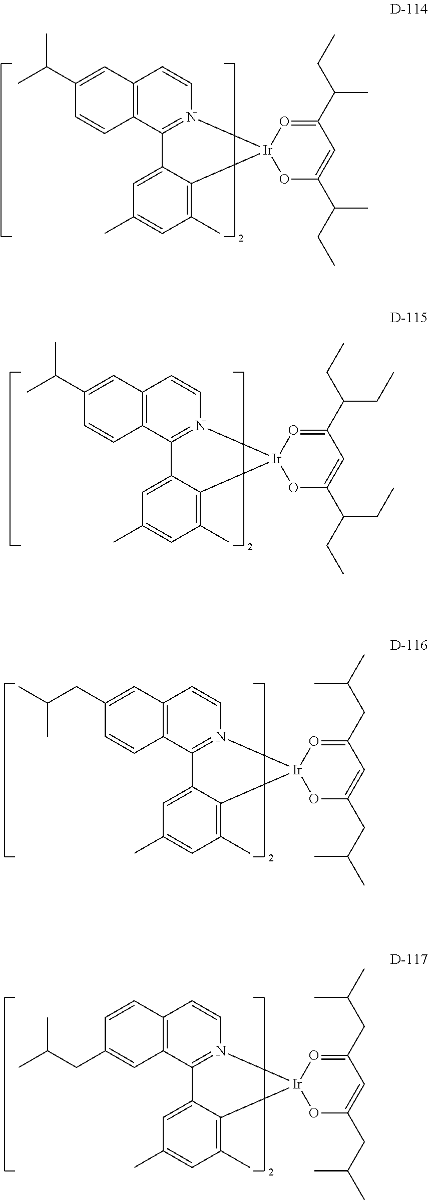

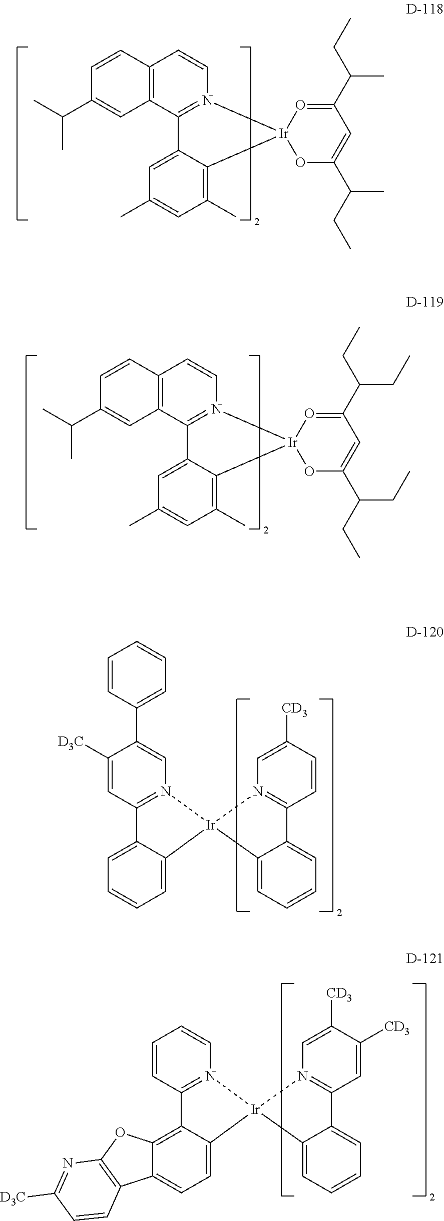

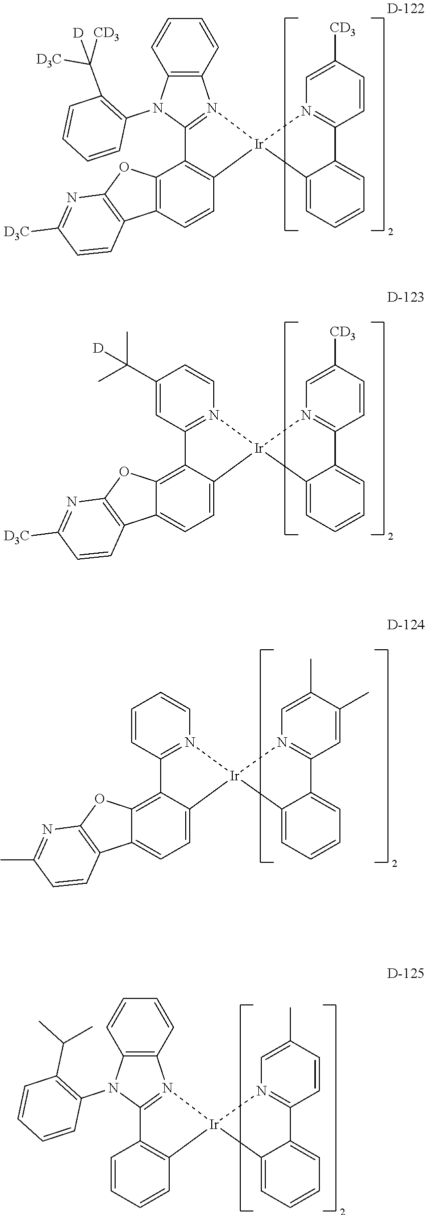

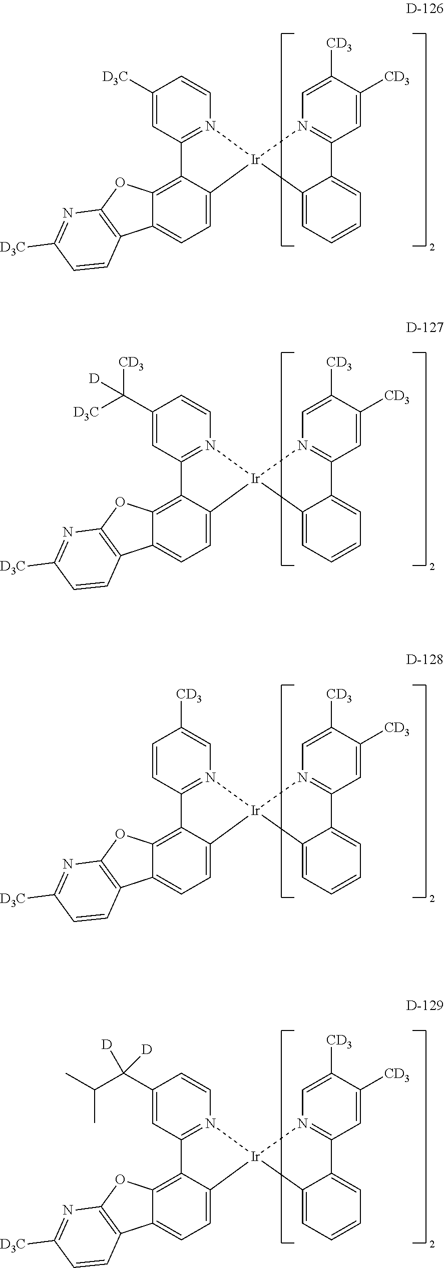

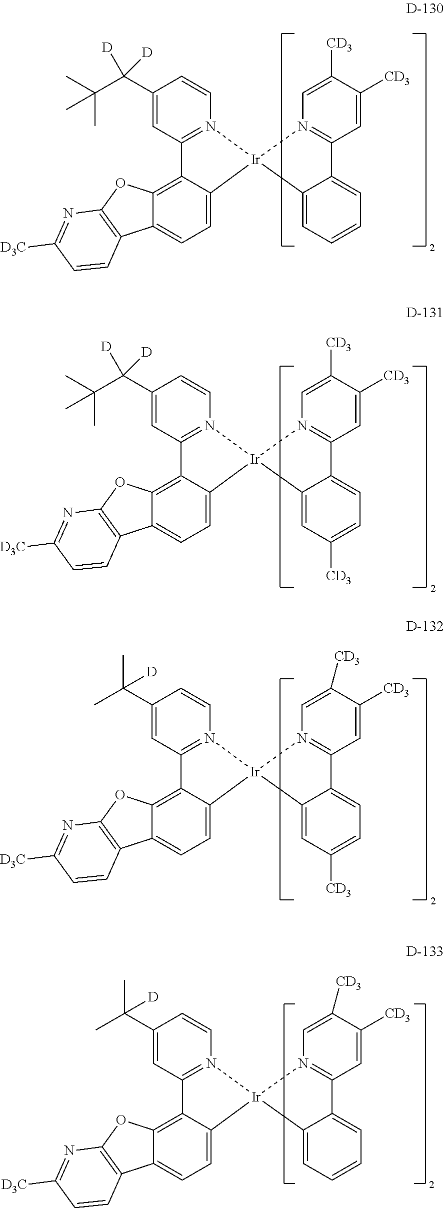

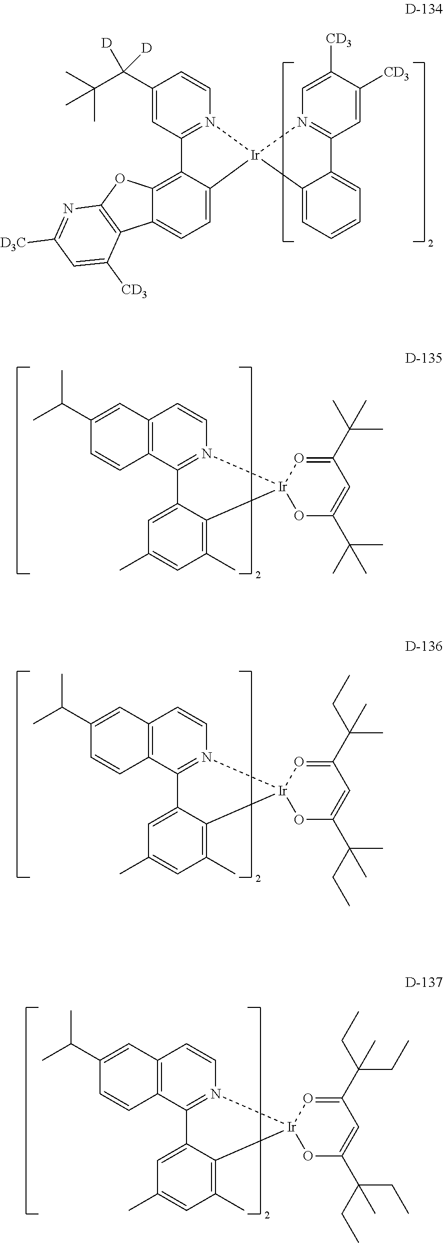

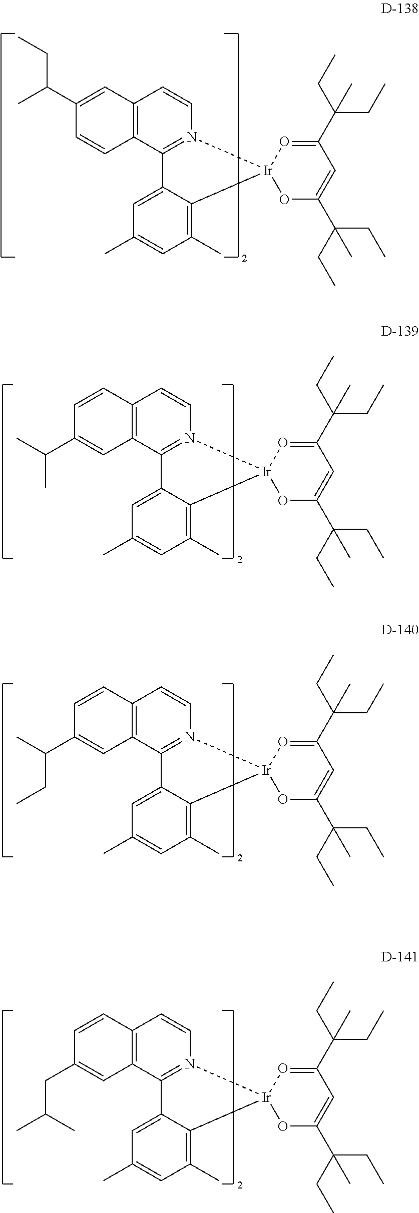

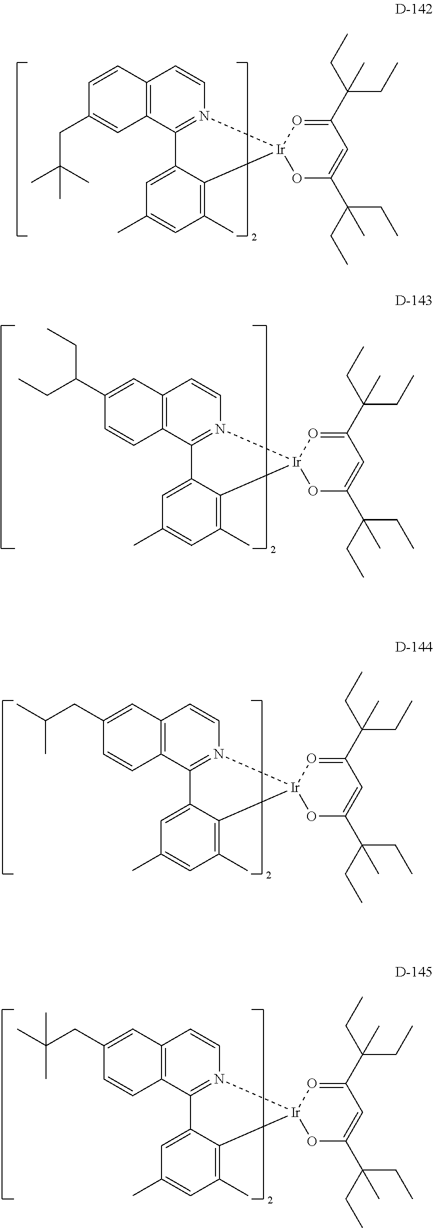

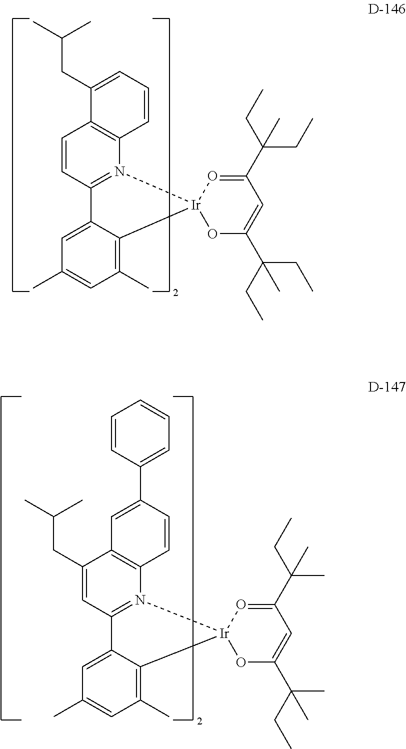

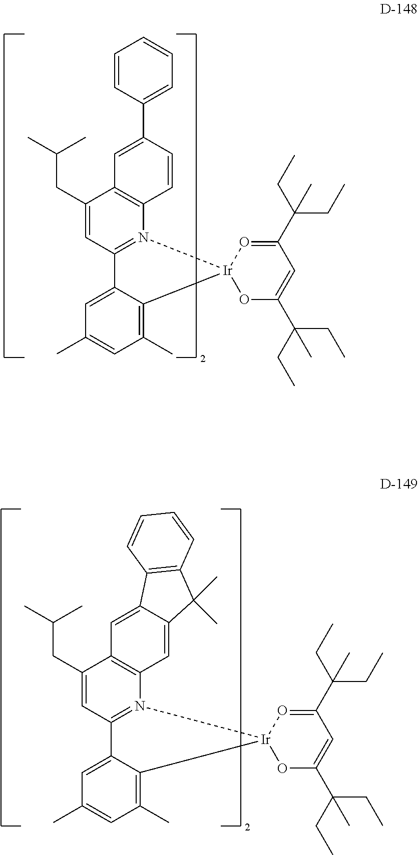

In order to form each layer of the organic electroluminescent device of the present disclosure, dry film-forming methods such as vacuum evaporation, sputtering, plasma, ion plating methods, etc., or wet film-forming methods such as spin coating, dip coating, flow coating methods, etc., can be used. When using a wet film-forming method, a thin film may be formed by dissolving or diffusing materials forming each layer into any suitable solvent such as ethanol, chloroform, tetrahydrofuran, dioxane, etc. The solvent may be any solvent where the materials forming each layer can be dissolved or diffused, and where there are no problems in film-formation capability.

When forming a layer by the first host compound and the second host compound according to one embodiment, the layer can be formed by the above-listed methods, and can often be formed by co-deposition or mixture-deposition. The co-deposition is a mixed deposition method in which two or more materials are put into respective individual crucible sources and a current is applied to both cells simultaneously to evaporate the materials and to perform mixed deposition; and the mixed deposition is a mixed deposition method in which two or more materials are mixed in one crucible source before deposition, and then a current is applied to one cell to evaporate the materials.

According to one embodiment, when the first host compound and the second host compound exist in the same layer or different layers in the organic electroluminescent device, the layers by the two host compounds may be separately formed. For example, after depositing the first host compound, a second host compound may be deposited.

According to one embodiment, the present disclosure can provide display devices comprising a plurality of host materials comprising a first host compound represented by formula 1 and a second host compound represented by formula 2. In addition, the organic electroluminescent device of the present disclosure can be used for the manufacture of display devices such as smartphones, tablets, notebooks, PCs, TVs, or display devices for vehicles, or lighting devices such as outdoor or indoor lighting.

Hereinafter, the preparation method of host compounds according to the present disclosure will be explained with reference to the synthesis method of a representative compound or intermediate compound in order to understand the present disclosure in detail.

### [Example 1] Preparation of Compound C-2

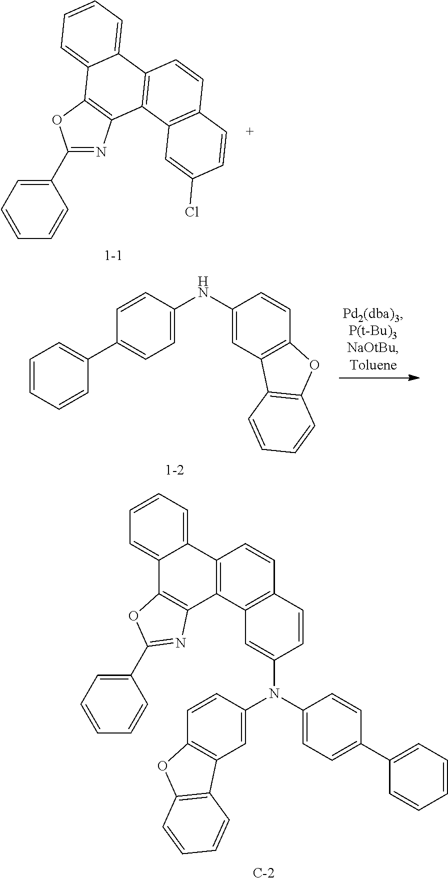

Compound 1-1 (4.0 g, 10.5 mmol), compound 1-2 (3.5 g, 10.5 mmol), tris(dibenzylideneacetone)dipalladium (Pd₂(dba)₃) (0.5 g, 0.53 mmol), P(t-bu)₃ (0.5 mL, 1.05 mmol), sodium tert-butoxide (NaOtBu) (1.5 g, 15.7 mmol), and 53 mL of toluene were added to a flask, and then dissolved. Next, it was stirred under reflux for 6 hours. After completion of the reaction, the organic layer was extracted with EA/H₂O. Next, it was separated by column chromatography to obtain compound C-2 (4.85 g, yield: 68%).

| | MW | M.P |
|---|---|---|
| C-2 | 678.8 | 242° C. |

### [Example 2] Preparation of Compound C-1

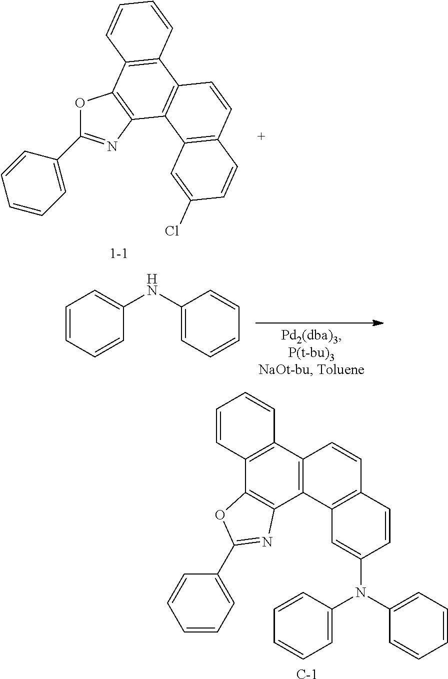

Compound 1-1 (7.0 g, 18.4 mmol), diphenylamine (4.0 g, 23.9 mmol), Pd₂(dba)₃ (0.84 g, 0.92 mmol), P(t-bu)₃ (0.9 mL, 1.84 mmol), NaOt-bu (3.53 g, 36.8 mmol) and 100 mL of toluene were added to a flask, and then stirred at 150° C. After completion of the reaction, MeOH and H₂O were added thereto, and then stirred. Next, the solvent was removed by filtration under reduced pressure, and then separated by column chromatography. Next, MeOH was added thereto, and the resulting solid was filtered under reduced pressure to obtain compound C-1 (5 g, yield: 53%).

| | MW | Color | M.P |
|---|---|---|---|
| C-1 | 512.61 | Yellow | 280° C. |

### [Example 3] Preparation of Compound C-3

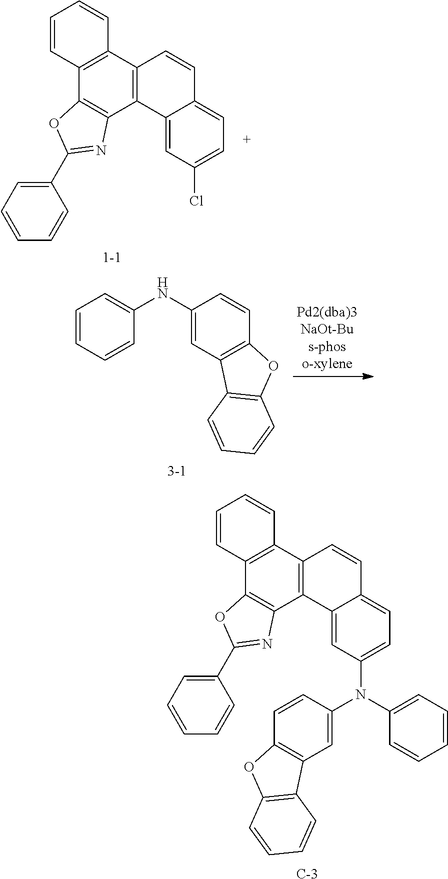

Compound 1-1 (4.6 g, 12.2 mmol), compound 3-1 (3.4 g, 13.4 mmol), Pd₂(dba)₃ (0.6 g, 0.6 mmol), 2-dicyclohexylphosphino-2′,6′-dimethoxybiphenyl(s-phos) (0.5 g, 1.2 mmol), NaOtBu (3 g, 30.5 mmol), and 150 mL of o-xylene were added to a flask, and then dissolved. Next, it was stirred under reflux for 3 hours. After completion of the reaction, the organic layer was extracted with ethyl acetate. Next, it was separated by column chromatography to obtain compound compound C-3 (2.6 g, yield: 35%).

| | MW | M.P |
|---|---|---|
| C-3 | 602.69 | 140° C. |

### [Example 4] Preparation of Compound H2-216

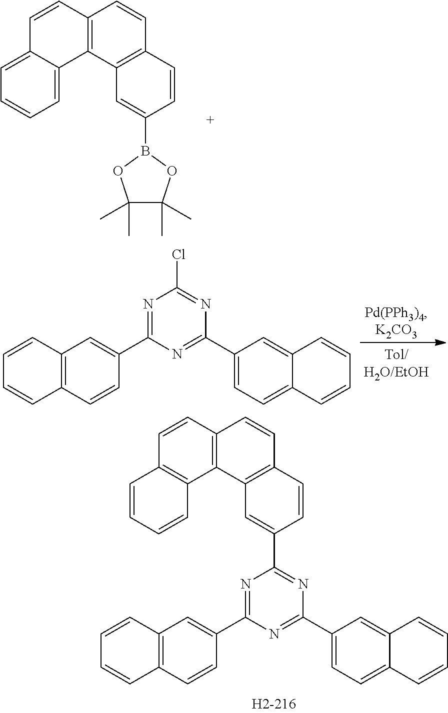

2-Benzo[c]phenanthren-2-yl-4,4,5,5-tetramethyl (1,3,2-dioxaborolane) (3.5 g, 9.8 mmol), 2-chloro-2,4-dinaphthalenyl-1,3,5-triazine (4.7 g, 12.8 mmol), Pd(PPh₃)₄ (0.56 g, 0.49 mmol), and K₂CO₃ (3.4 g, 24.5 mmol) in a flask were dissolved in 50 mL of toluene, 25 mL of ethanol, and 25 mL of H₂O, and then refluxed at 130° C. for 24 hours. After completion of the reaction, the organic layer was extracted with ethyl acetate, and the residual moisture was removed with magnesium sulfate. Next, it was dried and separated using column chromatography to obtain compound H2-216 (2.5 g, yield: 49.6%).

| | MW | M.P. |
|---|---|---|
| H2-216 | 559.20 | 242.4° C. |

### [Example 5] Preparation of Compound H2-246

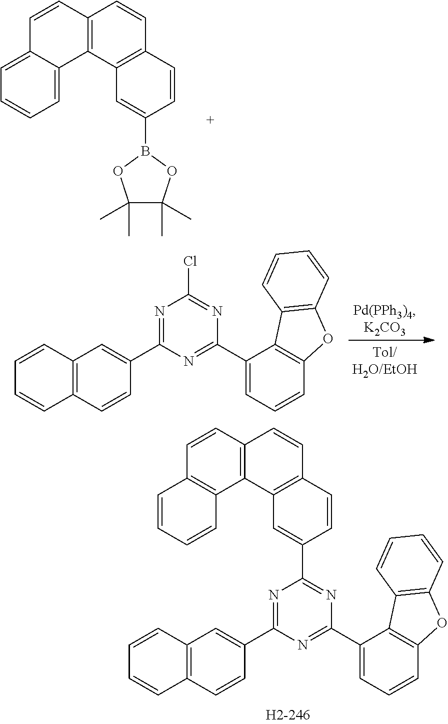

2-Benzo[c]phenanthren-2-yl-4,4,5,5-tetramethyl (1,3,2-dioxaborolan) (3.5 g, 9.8 mmol), 2-chloro-4-dibenzo[d,b]furan-1-yl-6-(naphthalen-2-yl)-1,3,5-triazine (3.3 g, 8.2 mmol), Pd(PPh₃)₄ (0.47 g, 0.47 mmol), and K₂CO₃ (2.8 g, 20.5 mmol) in a flask were dissolved in 50 mL of toluene, 25 mL of ethanol, and 25 mL of H₂O, and then refluxted at 130° C. for 4 hours. After completion of the reaction, the organic layer was extracted with ethyl acetate, and the residual moisture was removed with magnesium sulfate. Next, it was dried and separated using column chromatography to obtain compound H2-246 (2.5 g, yield: 50.8%).

| | MW | M.P. |
|---|---|---|
| H2-246 | 559.30 | 274.9° C. |

### [Example 6] Preparation of Compound H2-32

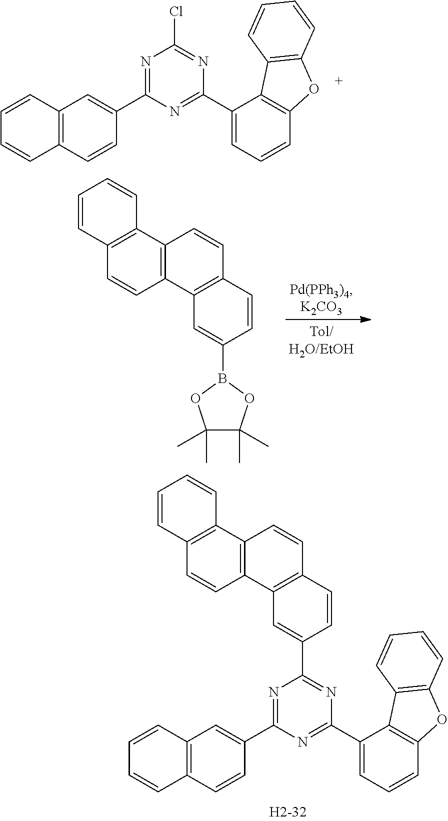

2-Chloro-4-(dibenzo[b,d]furan-1-yl-6-(naphthalen-2-yl)-1,3,5-triazine (3.8 g, 9.4 mmol), 2-chrysen-3-yl-4,4,5,5-tetramethyl-(1,3,2-dioxaborolane) (4 g, 11.3 mmol), Pd(PPh₃)₄ (0.54 g, 0.47 mmol), and K₂CO₃ (3.3 g, 23.5 mmol) in a flask were dissolved in 50 mL of toluene, 25 mL of ethanol, and 25 mL of H₂O, and then refluxed at 130° C. for 4 hours. After completion of the reaction, the organic layer was extracted with ethyl acetate, and the residual moisture was removed with magnesium sulfate. Next, it was dried and separated using column chromatography to obtain compound H2-32 (5 g, yield: 94%).

| | MW | M.P. |
|---|---|---|
| H2-32 | 559.30 | 292.8° C. |

### [Example 7] Preparation of Compound H2-29

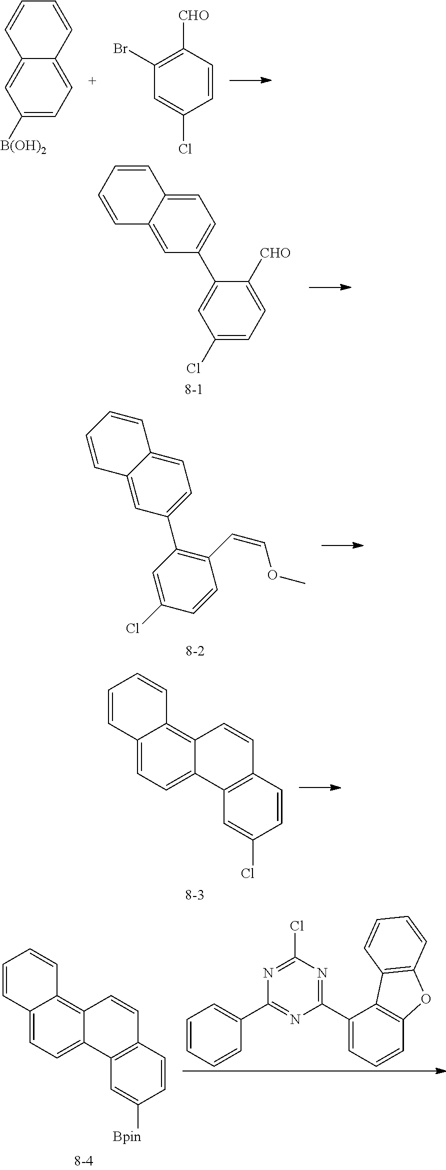

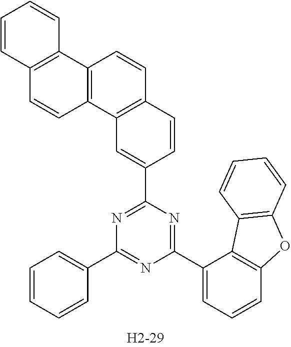 [SMILES: c1ccc(-c2nc(-c3ccc4ccc5c6ccccc6ccc5c4c3)nc(-c3cccc4oc5ccccc5c34)n2)cc1]

### 1) Synthesis of Compound 8-1

Naphthalene-2-ylboronic acid (50 g, 291 mmol), 2-bromo-4-chlorobenzaldehyde (63 g, 291 mmol), Pd(PPh₃)₄ (16.8 g, 14.5 mmol), sodium carbonate (77 g, 727 mmol), toluene (1,080 mL), ethanol (240 mL), and distilled water (360 mL) were added to the reaction container, and then stirred at 140° C. for 5 hours. After completion of the reaction, the precipitated solid was washed with distilled water and methanol. Next, it was purified by column chromatography to obtain compound 8-1 (71 g, yield: 92%).

### 2) Synthesis of Compound 8-2

Compound 8-1 (71 g, 268 mmol), (methoxymethyl)triphenylphosphonium chloride (110 g, 321 mmol), and THF (1,300 mL) were added to the reaction container, and then the reaction mixture was stirred for 10 minutes. Next, potassium tert-butoxide (1M in THF, 300 mL) was slowly added dropwise under the condition of 0° C. The temperature was slowly raised and stirred at room temperature for 3 hours. Distilled water was added to the reaction solution to terminate the reaction, and the organic layer was extracted with ethyl acetate. After drying the extracted organic layer with magnesium sulfate, the solvent was removed using a rotary evaporator. Next, it was purified by column chromatography to obtain compound 8-2 (71 g, yield: 90%).
3) Synthesis of Compound 8-3

Compound 8-2 (70 g, 238 mmol), Eaton's reagent (7 mL), and chlorobenzene (1,180 mL) were added to the reaction container, and then refluxed for 1 hour. After completion of the reaction, the reaction mixture was cooled to room temperature, and the organic layer was extracted with methylene chloride (MC). After drying the extracted organic layer with magnesium sulfate, the solvent was removed using a rotary evaporator. Next, it was purified by column chromatography to obtain compound 8-3 (60 g, yield: 96%).

### 4) Synthesis of Compound 8-4

Compound 8-3 (35 g, 133.2 mmol), bis(pinacolato)diborane (44 g, 173 mmol), Pd₂(dba)₃ (6.1 g, 6.66 mmol), s-phos (5.5 g, 13.3 mmol), KOAc (39.2 g, 400 mmol) and 1,4-dioxane (666 mL) were added to the reaction container, and then stirred at 150° C. for 3 hours. After completion of the reaction, the reaction mixture was cooled to room temperature, and the organic layer was extracted with ethyl acetate. After drying the extracted organic layer with magnesium sulfate, the solvent was removed using a rotary evaporator. Next, it was purified by column chromatography to obtain compound 8-4 (38 g, yield: 81%).

### 5) Synthesis of Compound H2-29

Compound 8-4 (5 g, 14.1 mmol), 2-chloro-4-(dibenzo[b,d]furan-1-yl)-6-phenyl-1,3,5-triazine (6.6 g, 18.3 mmol), Pd(PPh₃)₄ (0.8 g, 0.7 mmol), calcium carbonate (3.9 g, 28.2 mmol), toluene (42 mL), ethanol (10 mL), and distilled water (14 mL) were added to the reaction container, and then stirred at 140° C. for 8 hours. After completion of the reaction, the mixture was added dropwise to methanol, and the resulting solid was filtered. The resulting solid was purified by column chromatography to obtain compound H2-29 (6.8 g, yield: 88%).

| | MW | M.P. |
|---|---|---|
| H2-29 | 549.6 | 267° C. |

### [Example 8] Preparation of Compound H2-220

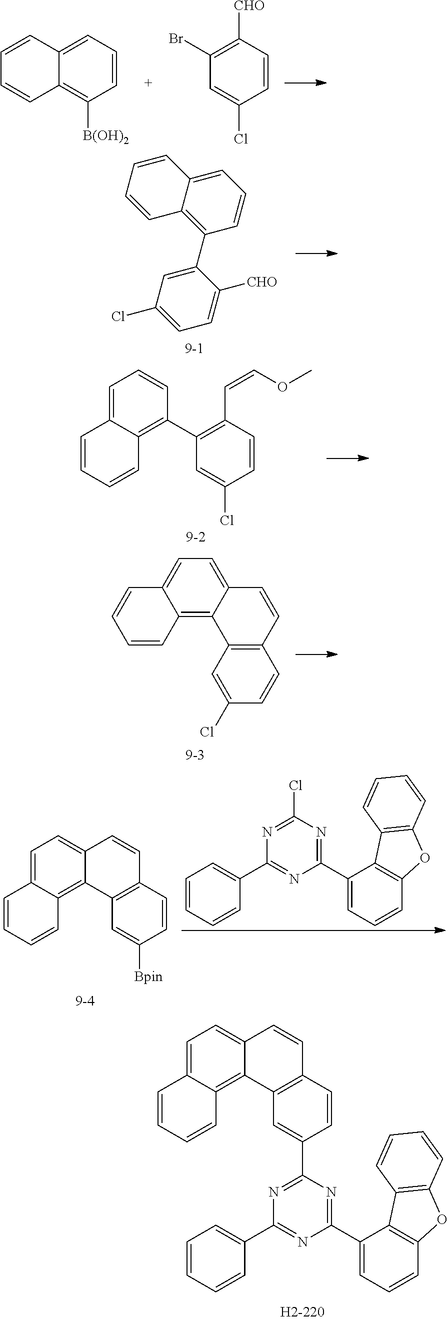

### 1) Synthesis of Compound 9-1

Naphthalene-1-ylboronic acid (40 g, 232 mmol), 2-bromo-4-chlorobenzaldehyde (51 g, 232 mmol), Pd(PPh₃)₄ (13.4 g, 11.6 mmol), sodium carbonate (62 g, 582 mmol), toluene (900 mL), ethanol (200 mL), and distilled water (300 mL) were added to the reaction container, and then stirred at 140° C. for 5 hours. After completion of the reaction, the precipitated solid was washed with distilled water and methanol. Next, it was purified by column chromatography to obtain compound 9-1 (50 g, yield: 80%).

### 2) Synthesis of Compound 9-2

Compound 9-1 (50 g, 187.5 mmol), (methoxymethyl)triphenylphosphonium chloride (83 g, 243.7 mmol), and THF (935 mL) were added to the reaction container, and then the reaction mixture was stirred for 10 minutes. Next, potassium tert-butoxide (1M in THF, 250 mL) was slowly added dropwise under the condition of 0° C. The temperature was slowly raised and stirred at room temperature for 3 hours. The reaction was terminated by adding distilled water to the reaction solution, and the organic layer was extracted with ethyl acetate. After drying the extracted organic layer with magnesium sulfate, the solvent was removed using a rotary evaporator. Next, it was purified by column chromatography to obtain compound 9-2 (52 g, yield: 95%).

### 3) Synthesis of Compound 9-3

Compound 9-2 (62 g, 210 mmol), Eaton's reagent (21 mL), and chlorobenzene (1,000 mL) were added to the reaction container, and then refluxed for 2 hours. After completion of the reaction, the reaction mixture was cooled to room temperature, and the organic layer was extracted with methylene chloride (MC). After drying the extracted organic layer with magnesium sulfate, the solvent was removed using a rotary evaporator. Next, it was purified by column chromatography to obtain compound 9-3 (12.5 g, yield: 23%).

### 4) Synthesis of Compound 9-4

Compound 9-3 (12.5 g, 47.6 mmol), bis(pinacolato)diborane (15.7 g, 61.9 mmol), Pd₂(dba)₃ (2.2 g, 2.38 mmol), s-phos (1.96 g, 4.76 mmol), KOAc (14 g, 143 mmol), and 1,4-dioxane (240 mL) were added to the reaction container, and then stirred at 150° C. for 3 hours. After completion of the reaction, the reaction mixture was cooled to room temperature, and the organic layer was extracted with ethyl acetate. After drying the extracted organic layer with magnesium sulfate, the solvent was removed using a rotary evaporator. Next, it was purified by column chromatography to obtain compound 9-4 (11.1 g, yield: 66%).

### 5) Synthesis of Compound H2-220

Compound 9-4 (4 g, 11.3 mmol), 2-chloro-4-(dibenzo[b,d]furan-1-yl)-6-phenyl-1,3,5-triazine (5.3 g, 14.7 mmol), Pd(PPh₃) (0.65 g, 0.6 mmol), calcium carbonate (3.1 g, 22.6 mmol), toluene (33 mL), ethanol (5 mL) and distilled water (11 mL) were added to the reaction container, and then stirred at 140° C. for 7 hours. After completion of the reaction, the mixture was added dropwise to methanol, and the resulting solid was filtered. The resulting solid was purified by column chromatography to obtain compound H2-220 (4.1 g, yield: 66%).

| | MW | M.P. |
|---|---|---|
| H2-220 | 549.6 | 208° C. |

### [Example 9] Preparation of Compound H2-146

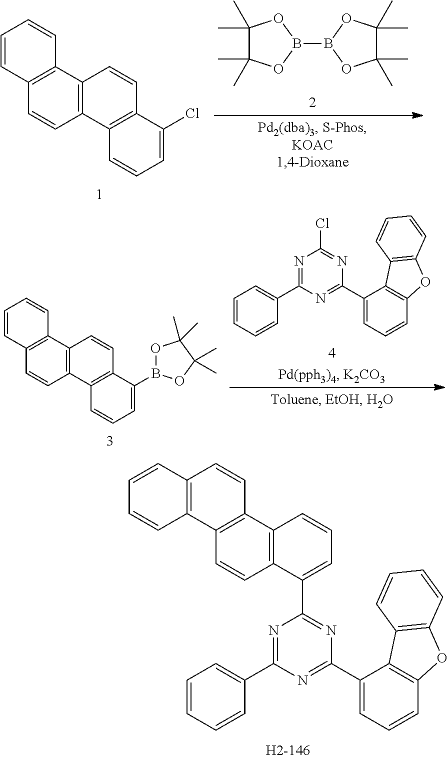

### 1) Synthesis of Compound 3

Compound 1 (10.0 g, 38.07 mmol), compound 2 (19.3 g, 76.13 mmol), Pd₂(dba)₃ (1.7 g, 1.90 mmol), s-phos (1.6 g, 3.81 mmol), and KOAC (9.3 g, 95.17 mmol) were added to the reaction container, and then dissolved in 190 mL of 1,4-dioxane. Next, it was stirred under reflux for 3 hours. After completion of the reaction, the mixture was cooled to room temperature, and separated through a Celite filter and then a silica filter, thereby forming a solid to obtain compound 3 (9.8 g, yield: 72.70%).

### 2) Synthesis of Compound H2-146

Compound 3 (8.8 g, 24.84 mmol), compound 4 (11.6 g, 32.29 mmol), Pd(pph₃)₄ (1.4 g, 1.24 mmol), and K₂CO₃ (6.9 g, 49.68 mmol) in the reaction container were dissolved in 125 mL of toluene, 31 mL of EtOH, and 31 mL of H₂O, and then stirred under reflux for 6 hours. After completion of the reaction, the mixture was cooled to room temperature, filtered, and separated with a silica filter to form a solid. Next, it was recrystallized to obtain compound H2-146 (10.4 g, yield: 76.47%).

| | MW | M.P |
|---|---|---|
| H2-146 | 549.63 | 281° C. |

### [Example 10] Preparation of Compound C-91

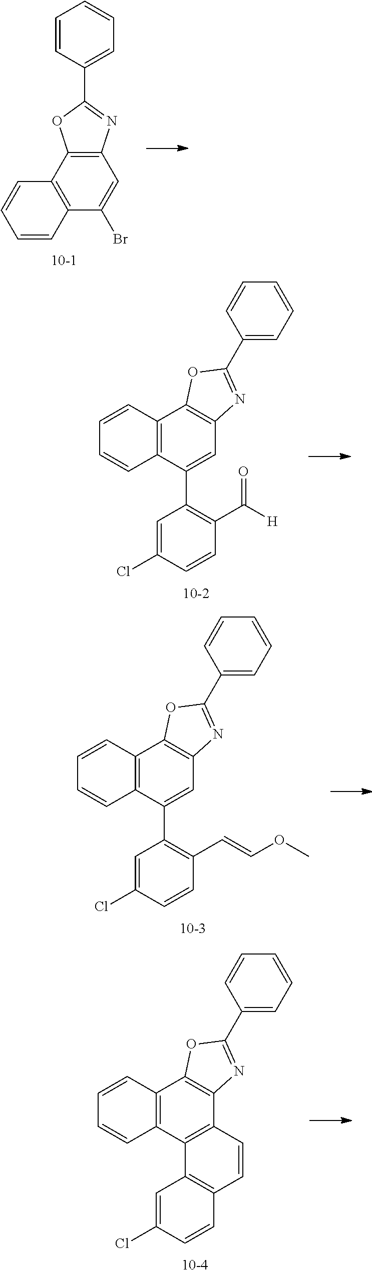 [SMILES: Brc1cc2nc(-c3ccccc3)oc2c2ccccc12 ; O=Cc1ccc(Cl)cc1-c1cc2nc(-c3ccccc3)oc2c2ccccc12 ; CO/C=C/c1ccc(Cl)cc1-c1cc2nc(-c3ccccc3)oc2c2ccccc12 ; Clc1ccc2ccc3c4nc(-c5ccccc5)oc4c4ccccc4c3c2c1]

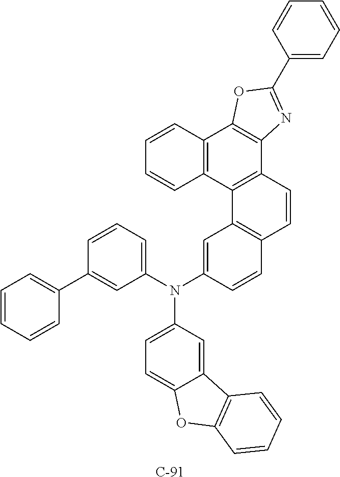

### 1) Synthesis of Compound 10-2

Compound 10-1 (10 g, 15.5 mmol), (5-chloro-2-formylphenyl)boronic acid (6.3 g, 17 mmol), K₂CO₃ (8.6 g, 31 mmol), and Pd(PPh₃)₄ (1.79 g, 0.77 mmol) in a flask were dissolved in 100 mL of toluene, 35 mL of ethanol, and 35 mL of H₂O, and then refluxed at 120° C. for 2 hours. After completion of the reaction, the organic layer was extracted with ethyl acetate, and the residual moisture was removed with magnesium sulfate. Next, it was dried and separated using column chromatography to obtain compound 10-2 (8.8 g, yield: 87%).

### 2) Synthesis of Compound 10-3

Compound 10-2 (5.2 g, 13.6 mmol), (methoxymethyl)triphenyl phosphonium chloride (5.6 g, 16.3 mmol), potassium tert-butoxide (KOtBu) (17 mL, 16.3 mmol), and 60 mL of THF were added to a flask, and then dissolved. Next, it was stirred at 0° C., and then stirred at room temperature. After completion of the reaction, the organic layer was extracted with ethyl acetate, and the residual moisture was removed with magnesium sulfate. Next, it was dried and separated using column chromatography to obtain compound 10-3 (4.2 g, yield: 75%).

### 3) Synthesis of Compound 10-4

Compound 10-3 (4.2 g, 10.3 mmol), phosphorus pentoxide (7.7 wt % in methanesulfonic acid) (4.5 mL, 11.3 mmol), and 35 mL of chlorobenzene were added to a flask, and then dissolved. Next, it was stirred under reflux at 100° C. After completion of the reaction, the organic layer was extracted with ethyl acetate, and the residual moisture was removed with magnesium sulfate. Next, it was dried and separated using column chromatography to obtain compound 10-4 (4.2 g, yield: 75%).

### 4) Synthesis of Compound C-91

Compound 10-4 (2.6 g, 6.9 mmol), N-([1,1′-biphenyl]-3-yl)dibenzo[b,d]furan-2-amine (2.6 g, 7.6 mmol), Pd₂(dba)₃ (0.32 g, 0.35 mmol), s-phos (0.29 g, 0.69 mmol), NaOtBu (1.7 g, 17 mmol), and 30 mL of o-xylene were added to a flask, and then dissolved. Next, it was stirred under reflux at 150° C. After completion of the reaction, the organic layer was extracted with ethyl acetate, and the residual moisture was removed with magnesium sulfate. Next, it was dried and separated using column chromatography to obtain compound C-91 (1.1 g, yield: 23%).

| | MW | M.P |
|---|---|---|
| C-91 | 678.79 | 260° C. |

### [Example 11] Preparation of Compound H2-255

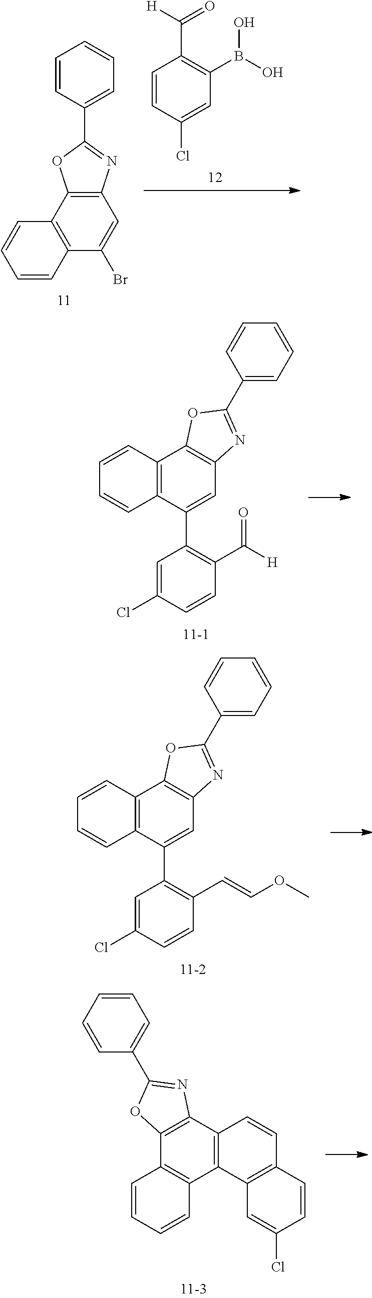

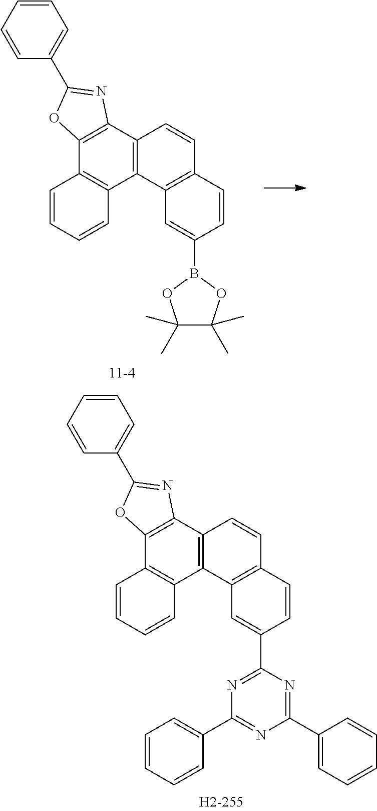 [SMILES: CC1(C)OB(c2ccc3ccc4c5nc(-c6ccccc6)oc5c5ccccc5c4c3c2)OC1(C)C ; c1ccc(-c2nc(-c3ccccc3)nc(-c3ccc4ccc5c6nc(-c7ccccc7)oc6c6ccccc6c5c4c3)n2)cc1]

### 1) Synthesis of Compound 11-1

Compound 11 (10 g, 15.5 mmol), compound 12 (6.3 g, 17 mmol), K₂CO₃ (8.6 g, 31 mmol), Pd(PPh₃)₄ (1.79 g, 0.77 mmol), 100 mL of toluene, 35 mL of ethanol, and 35 mL of H₂O were added to a flask, and then dissolved. Next, it was refluxed at 120° C. for 2 hours. After completion of the reaction, the organic layer was extracted with ethyl acetate, and the residual moisture was removed with magnesium sulfate. Next, it was dried and separated using column chromatography to obtain compound 11-1 (8.8 g yield: 87%).

### 2) Synthesis of Compound 11-2

Compound 11-1 (5.2 g, 13.6 mmol), (methoxymethyl)triphenyl phosphonium chloride (5.6 g, 16.3 mmol), potassium tert-butoxide (17 mL, 16.3 mmol), and 60 mL of THF were added to a flask, and then dissolved. Next, it was stirred at 0° C., and then stirred at room temperature. After completion of the reaction, the organic layer was extracted with ethyl acetate, and the residual moisture was removed with magnesium sulfate. Next, it was dried and separated using column chromatography to obtain compound 11-2 (4.2 g, yield: 75%).

### 3) Synthesis of Compound 11-3

Compound 11-2 (4.2 g, 10.3 mmol), phosphorus pentoxide (7.7 wt % in methanesulfonic acid) (4.5 mL, 11.3 mmol), and 35 mL of chlorobenzene were added to a flask, and then dissolved. Next, it was stirred under reflux at 100° C. After completion of the reaction, the organic layer was extracted with ethyl acetate, and the residual moisture was removed with magnesium sulfate. Next, it was dried and separated using column chromatography to obtain compound 11-3 (4.2 g, yield: 75%).

### 4) Synthesis of Compound 11-4

Compound 11-3 (4 g, 10.53 mmol), bis(pinacolato)diborane (4.1 g, 15.7 mmol), KOAc (2.6 g, 26.3 mmol), s-phos (13 g, 31.5 mmol), and Pd₂(dba)₃ (0.5 g, 0.53 mmol) were added to a flask, and then dissolved in 200 mL of dioxane. Next, it was refluxed at 120° C. for 2 hours. After completion of the reaction, the organic layer was extracted with ethyl acetate, and the residual moisture was removed with magnesium sulfate. Next, it was dried and separated using column chromatography to obtain compound 11-4 (6 g, yield: 83%).

### 5) Synthesis of Compound H2-255

Compound 11-4 (5.1 g, 19 mmol), Pd(PPh₃)₄ (0.73 g, 0.7 mmol), K₂CO₃ (3.5 g, 25 mmol), 100 mL of toluene, 20 mL of ethanol, and 20 mL of H₂O were added to a flask, and then dissolved. Next, it was refluxted at 120° C. for 2 hours. After completion of the reaction, the organic layer was extracted with ethyl acetate, and the residual moisture was removed with magnesium sulfate. Next, it was dried and separated using column chromatography to obtain compound H2-255 (2.3 g, yield: 31%).

| | MW | M.P |
|---|---|---|
| H2-255 | 576.66 | 350° C. |

Hereinafter, the preparation method of an organic electroluminescent device comprising the plurality of host materials and/or the organic electroluminescent compound according to the present disclosure, and the property thereof will be explained in order to understand the present disclosure in detail.

### [Device Examples 1 to 3] Preparation of OLEDs by Co-Deposition of the First Host Compound and the Second Host Compound According to the Present Disclosure

OLEDs according to the present disclosure were produced. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and thereafter was stored in isopropanol and then used. Thereafter, the ITO substrate was mounted on a substrate holder of a vacuum vapor deposition apparatus. Then, compound HI-1 was introduced into a cell of the vacuum vapor deposition apparatus, and compound HT-1 was introduced into another cell of the vacuum vapor deposition apparatus. The two materials were evaporated at different rates and compound HI-1 was deposited in a doping amount of 3 wt % based on the total amount of compound HI-1 and compound HT-1 to form a hole injection layer having a thickness of 10 nm. Next, compound HT-1 was deposited as a first hole transport layer having a thickness of 80 nm on the hole injection layer. Compound HT-2 was then introduced into another cell of the vacuum vapor deposition apparatus and was evaporated by applying an electric current to the cell, thereby forming a second hole transport layer having a thickness of 60 nm on the first hole transport layer. After forming the hole injection layer and the hole transport layers, a light-emitting layer was formed thereon as follows: each of the first host compound and the second host compound described in the following Table 1 were introduced into two cells of the vacuum vapor deposition apparatus as hosts, respectively, and compound D-39 was introduced into another cell as a dopant. The two host materials were evaporated at a rate of 1:1 and the dopant material was evaporated at a different rate, simultaneously, and was deposited in a doping amount of 3 wt % based on the total amount of the hosts and dopant to form a light-emitting layer having a thickness of 40 nm on the second hole transport layer. Next, compounds ET-1 and EI-1 as electron transport materials were deposited at a weight ratio of 50:50 to form an electron transport layer having a thickness of 35 nm on the light-emitting layer. After depositing compound EI-1 as an electron injection layer having a thickness of 2 nm on the electron transport layer, an AI cathode having a thickness of 80 nm was deposited on the electron injection layer by another vacuum vapor deposition apparatus. Thus, OLEDs were produced. Each compound used for all the materials was purified by vacuum sublimation under 10⁻⁶ torr.

### [Comparative Example 1] Preparation of an OLED Comprising a Single Host Compound

An OLED was produced in the same manner as in Device Example 1, except that the second host compound of the following Table 1 alone was used as a host of the light-emitting layer.

The driving voltage, the luminous efficiency, and the light-emitting color at a luminance of 1,000 nits, and the time taken for luminance to decrease from 100% to 95% at a luminance of 10,000 nits (lifespan; T95) of the organic electroluminescent devices according to Device Examples 1 to 3 and Comparative Example 1 produced as described above, are measured, and the results thereof are shown in Table 1 below:

TABLE 1

| | | | Driving | Luminous | Light- | |
|---|---|---|---|---|---|---|
| | First | Second | voltage | efficiency | emitting | Lifespan |
| | host | host | (V) | (cd/A) | color | T95(hr) |
| Comparative | — | H2-146 | 3.5 | 31.8 | Red | 17.7 |
| Example 1 | | | | | | |
| Device | C-1 | H2-146 | 3.2 | 32.9 | Red | 275 |
| Example 1 | | | | | | |
| Device | C-3 | H2-146 | 3.1 | 36.6 | Red | 168 |
| Example 2 | | | | | | |
| Device | C-91 | H2-146 | 3.0 | 34.9 | Red | 230 |
| Example 3 | | | | | | |

From Table 1 above, it can be confirmed that the organic electroluminescent device comprising a specific combination of compounds according to the present disclosure as host materials has low driving voltage, high luminous efficiency, and particularly significantly improved lifespan characteristics.

### [Device Examples 4 to 6] Preparation of OLEDs Comprising the Organic Electroluminescent Compound According to the Present Disclosure as a Material for Hole Transport Layer

OLEDs were produced in the same manner as in Device Example 1, except that the compound shown in the following Table 2 was used as the material for the second hole transport layer, and the compound Host 1 and compound H2-146 were used as the hosts.

The driving voltage, the luminous efficiency, and the light-emitting color at a luminance of 1,000 nits, and the time taken for luminance to decrease from 100% to 95% at a luminance of 10,000 nits (lifespan; T95) of the organic electroluminescent devices according to Device Examples 4 to 6 produced as described above, are measured, and the results thereof are shown in Table 2 below:

TABLE 2

| | Material for | | | | |
|---|---|---|---|---|---|
| | the second | Driving | Luminous | | |
| | hole transport | Voltage | Efficiency | Light-Emitting | Lifespan |
| | layer | (V) | (cd/A) | Color | T95(hr) |
| Device | C-1 | 4.0 | 29.5 | Red | 52 |
| Example 4 | | | | | |
| Device | C-2 | 3.0 | 29.5 | Red | 146 |
| Example 5 | | | | | |
| Device | C-3 | 3.2 | 29.9 | Red | 92 |
| Example 6 | | | | | |

### [Device Example 7] Preparation of an OLED by Co-Deposition of the First Host Compound and the Second Host Compound According to the Present Disclosure

An OLED was produced in the same manner as in Device Example 1, except that the first host and second host of the following Table 3 were used as the hosts of the light-emitting layer.

### [Comparative Example 2] Preparation of an OLED Comprising a Conventional Compound as a Host

An OLED was produced in the same manner as in Device Example 1, except that the first host compound of the following Table 3 one was used as the host of the light-emitting layer.

The driving voltage, the luminous efficiency, and the light-emitting color at a luminance of 1,000 nits, and the time taken for luminance to decrease from 100% to 95% at a luminance of 10,000 nits (lifespan; T95) of the organic electroluminescent devices according to Device Example 7 and Comparative Example 2 produced as described above, are measured, and the results thereof are shown in Table 3 below:

TABLE 3

| | | | Driving | Luminous | Light- | Life- |
|---|---|---|---|---|---|---|
| | First | Second | Voltage | Efficiency | Emitting | span |
| | host | host | (V) | (cd/A) | Color | T95(hr) |
| Device | T-1 | H2-255 | 3.0 | 30.9 | Red | 79 |
| Example 7 | | | | | | |
| Comparative | T-1 | — | 4.3 | 7.4 | Red | 3.4 |
| Example 2 | | | | | | |

The compounds used in Device Examples and Comparative Examples above are shown in the following Table 4:

TABLE 4

| | |
|---|---|
| Hole Injection Layer/Hole Transport Layer | 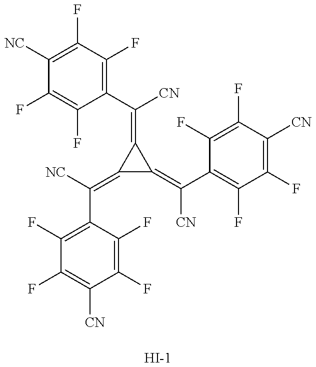 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; [I-]] |
| | 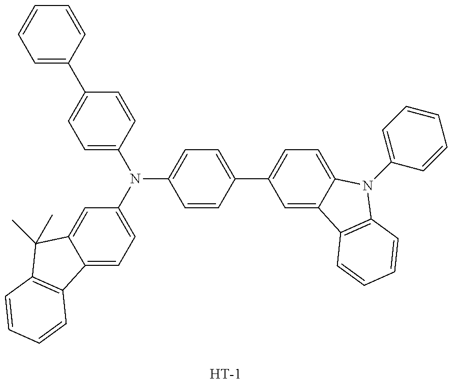 |
| | 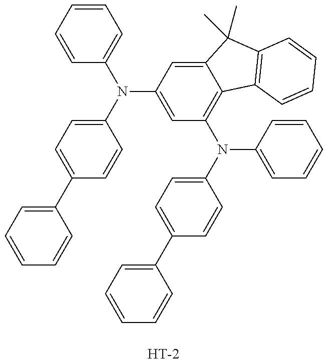 |
| | 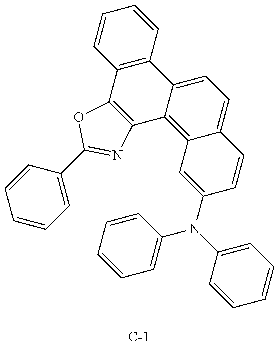 |
| | 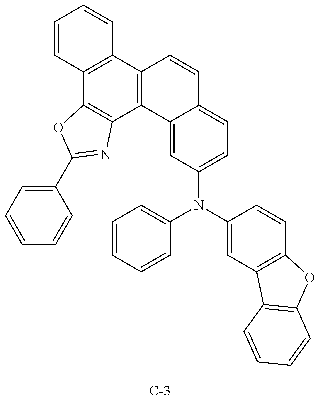 |
| | 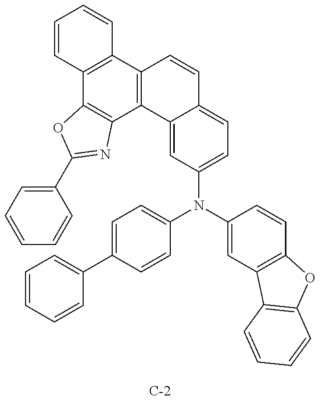 |
| Light-Emitting Layer/ Electron Buffer Layer | 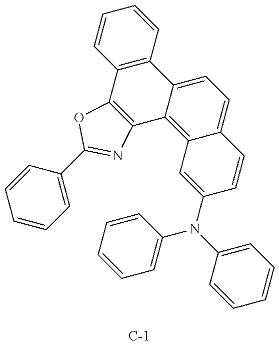 |
| | 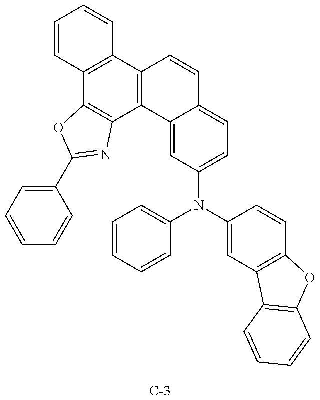 |
| | 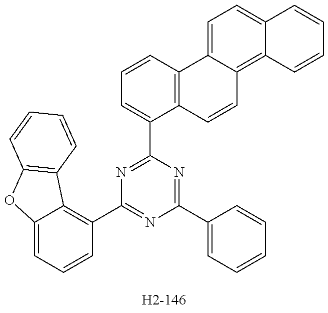 [SMILES: c1ccc(-c2nc(-c3cccc4c3ccc3c5ccccc5ccc43)nc(-c3cccc4oc5ccccc5c34)n2)cc1] |
| | 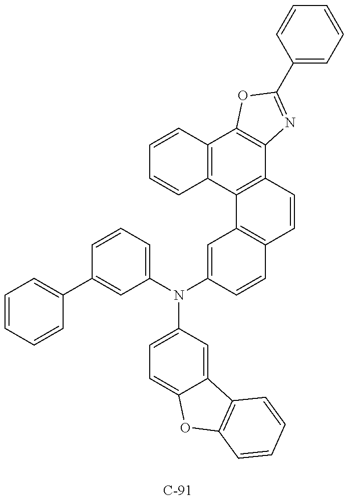 |
| | 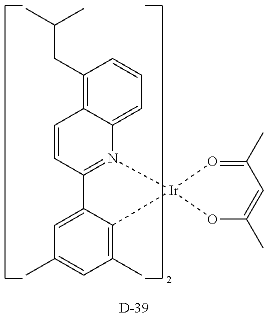 |
| | 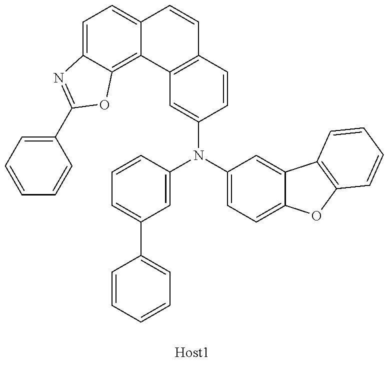 [SMILES: c1ccc(-c2cccc(N(c3ccc4oc5ccccc5c4c3)c3ccc4ccc5ccc6nc(-c7ccccc7)oc6c5c4c3)c2)cc1] |
| | 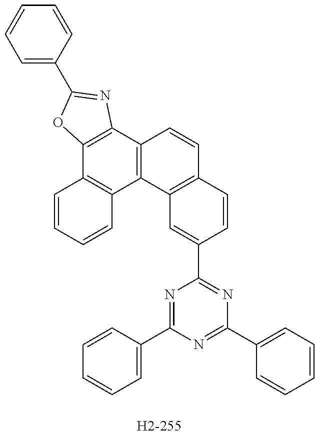 [SMILES: c1ccc(-c2nc(-c3ccccc3)nc(-c3ccc4ccc5c6nc(-c7ccccc7)oc6c6ccccc6c5c4c3)n2)cc1] |
| | 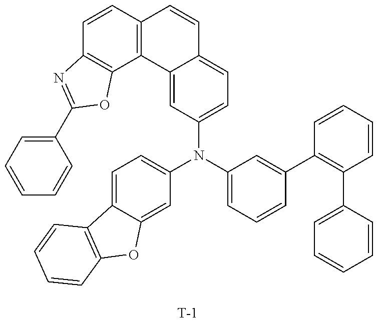 |
| Electron Transport Layer/ Electron Injection Layer | 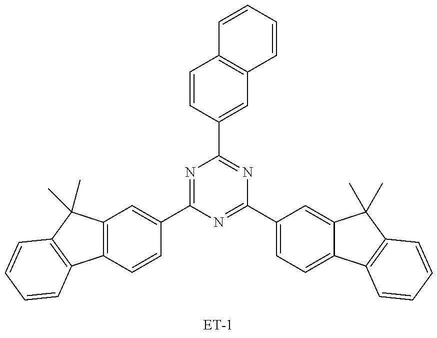 [SMILES: CC1(C)c2ccccc2-c2ccc(-c3nc(-c4ccc5c(c4)C(C)(C)c4ccccc4-5)nc(-c4ccc5ccccc5c4)n3)cc21] |
| | 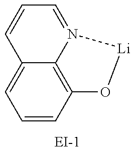 |

1. A plurality of host materials comprising at least one first host compound and at least one second host compound, which is different from the first host compound, wherein the first host compound is represented by the following formula 1 and the second host compound is represented by the following formula 2: 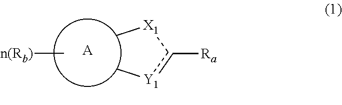
wherein,
ring A represents a substituted or unsubstituted aromatic ring in which 4 benzene rings are sequentially fused;
X₁ and Y₁ each independently represent, —N═, —NR_{c}—, —O— or —S—; provided that any one of X₁ and Y₁ is —N═, and the other of X₁ and Y₁ is —NR_{c}—, —O— or —S—;
Rₐ and R_{c} each independently represent, a substituted or unsubstituted (C6-C30)aryl or a substituted or unsubstituted (3- to 30-membered)heteroaryl;
R_{b} represents hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted fused ring of (C3-C30) aliphatic ring and (C6-C30) aromatic ring, —SiR′₁R′₂R′₃, or -L′₁—NR′₁R′₂; provided that at least one of R_{b} is (are) -L′₁—NR′₁R′₂;
L′₁ represents a single bond, a substituted or unsubstituted (C6-C30)arylene, or a substituted or unsubstituted (3- to 30-membered)heteroarylene;
R′₁ to R′₃ each independently represent, a substituted or unsubstituted (C1-C30)alkyl, a substituted or unsubstituted (C2-C30)alkenyl, a substituted or unsubstituted (C6-C30)aryl, a substituted or unsubstituted (3- to 30-membered)heteroaryl, or a substituted or unsubstituted fused ring of (C3-C30) aliphatic ring and (C6-C30) aromatic ring; and
n represents an integer of 1 to 10, when n is an integer of 2 or more, each of R_{b} may be the same or different; 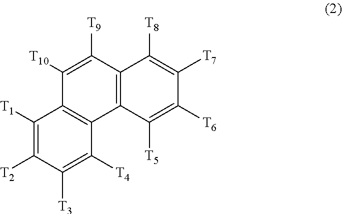
wherein
T₅ and T₆ are linked to each other to form a ring of the following formula 3; or T₇ and Tₐ are linked to each other to form a ring of the following formula 3; or T₅ and T₆ are linked to each other to form a ring of the following formula 3, while T₇ and Tₐ are linked to each other to form a ring of the following formula 3; or T₅ and T₆ are linked to each other to form a ring of the following formula 3, while T₉ and T₁₀ are linked to each other to form a ring of the following formula 3-1; or T₇ and Tₐ are linked to each other to form a ring of the following formula 3, while T₉ and T₁₀ are linked to each other to form a ring of the following formula 3-1; or T₇ and Tₐ are linked to each other to form a ring of the following formula 3, while T₁ and T₂ are linked to each other to form a ring of the following formula 3-1; or T₁ and T₂ are linked to each other to form a ring of the following formula 3, while T₅ and T₆ are linked to each other to form a ring of the following formula 3-1; or T₉ and T₁₀ are linked to each other to form a ring of the following formula 3, while T₁ and T₂ are linked to each other to form a ring of the following formula 3-1; or T₅ and T₆ are linked to each other to form a ring of the following formula 3, while T₃ and T₄ are linked to each other to form a ring of the following formula 3-1; 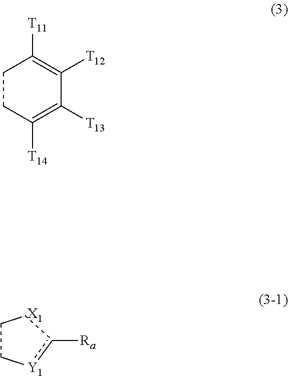
wherein
T₁ to T₁₄, and T₁ to T₁₀ that do not form a ring, each independently represent, hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted fused ring of (C3-C30) aliphatic ring and (C6-C30) aromatic ring, —SiR₁₁R₁₂R₁₃, —NR₁₄R₁₅, or -L₂-Ar₂; provided that at least one of T₁ to T₁₄ is (are) -L₂-Ar₂;
X₁ and Y₁ each independently represent, —N═, —NR_{c}—, —O— or —S—; provided that any one of X₁ and Y₁ is —N═, and the other of X₁ and Y₁ is —NR_{c}—, —O— or —S—;
Rₐ and R_{c} each independently represent, a substituted or unsubstituted (C6-C30)aryl or a substituted or unsubstituted (3- to 30-membered)heteroaryl;
L₂ represents a single bond, a substituted or unsubstituted (C6-C30)arylene, or a substituted or unsubstituted (3- to 30-membered)heteroarylene;
Ar₂ represents a substituted or unsubstituted (C6-C30)aryl or a substituted or unsubstituted (3- to 30-membered)heteroaryl;
R₁₁ to R₁₅ each independently represent, a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl; and [symbol]
represents a fusing site with the formula 2.

2. The plurality of host materials according to claim 1, wherein the formula 1 is represented by the following formula 1-1: 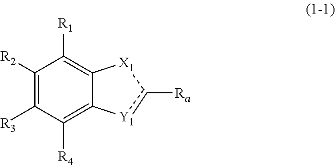
wherein,
X₁, Y₁, and Rₐ are as defined in claim 1; and
one of R₁ and R₂, and R₃ and R₄ is linked to each other to form the following formula 1A, and the other of R₁ and R₂, and R₃ and R₄ is linked to each other to form the following formula 1B; or any one of R₁ and R₂, R₂ and R₃, and R₃ and R₄ is linked to each other to form the following formula 1C or 1D; 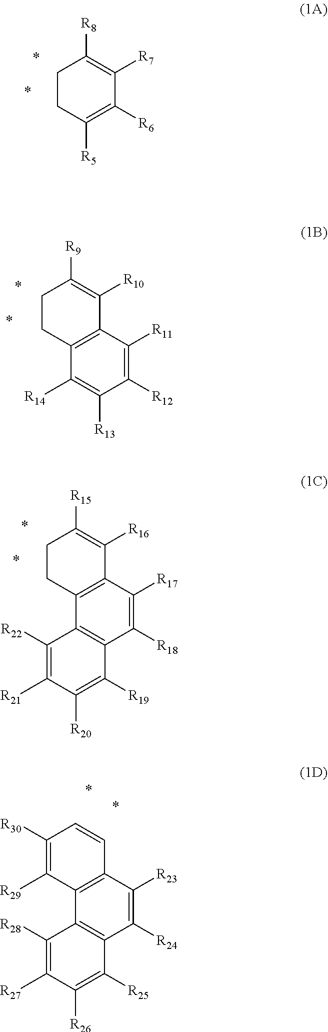
wherein
R₁ to R₄ which do not form the formula 1C or 1D, and R₅ to R₃₀ are as defined as R_{b} in claim 1; provided that at least one of R₅ to R₁₄ and at least one of R₁₅ to R₃₀ are -L′₁—NR′₁R′₂.

3. The plurality of host materials according to claim 2, wherein the formula 1-1 is represented by any one of the following formulas 11-1 to 11-4: 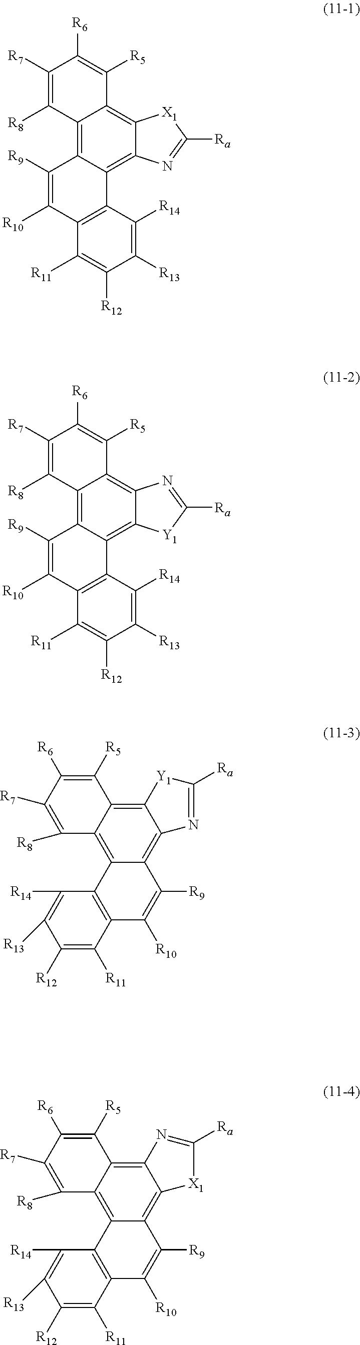
wherein
X₁, Y₁, Rₐ and R₅ to R₁₄ are as defined in claim 2.

4. The plurality of host materials according to claim 2, wherein the formula 1 is represented by any one of the following formulas 11-5 to 11-8: 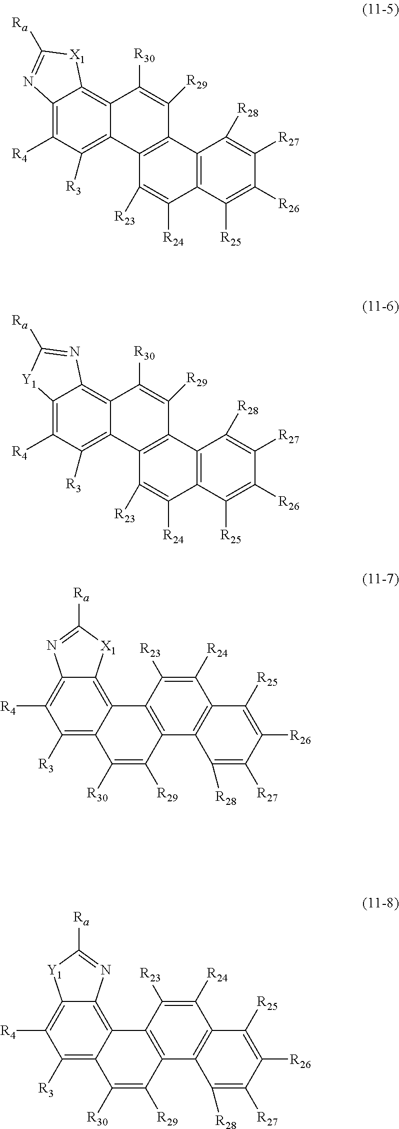
wherein
X₁, Y₁, Rₐ, R₃, R₄, and R₂₃ to R₃₀ are as defined in claim 2.

5. The plurality of host materials according to claim 1, wherein R a, R′₁ and R′₂ each independently represent, a substituted or unsubstituted phenyl, a substituted or unsubstituted naphthyl, a substituted or unsubstituted biphenyl, a substituted or unsubstituted terphenyl, a substituted or unsubstituted phenanthrenyl, a substituted or unsubstituted fluorenyl, a substituted or unsubstituted benzofluorenyl, a substituted or unsubstituted triphenylenyl, a substituted or unsubstituted spirobifluorenyl, a substituted or unsubstituted pyridyl, a substituted or unsubstituted triazinyl, a substituted or unsubstituted pyrimidinyl, a substituted or unsubstituted quinolyl, a substituted or unsubstituted quinazolinyl, a substituted or unsubstituted quinoxalinyl, a substituted or unsubstituted benzoquinazolinyl, a substituted or unsubstituted benzoquinoxalinyl, a substituted or unsubstituted benzofuropyrimidinyl, a substituted or unsubstituted carbazolyl, a substituted or unsubstituted dibenzothiophenyl, a substituted or unsubstituted benzothiophenyl, a substituted or unsubstituted dibenzofuranyl, a substituted or unsubstituted benzofuranyl, a substituted or unsubstituted naphthyridinyl, a substituted or unsubstituted benzonaphthofuranyl, or a substituted or unsubstituted benzonaphthothiophenyl.

6. The plurality of host materials according to claim 1, wherein the formula 2 is represented by any one of the following formulas 2-1 to 2-14: 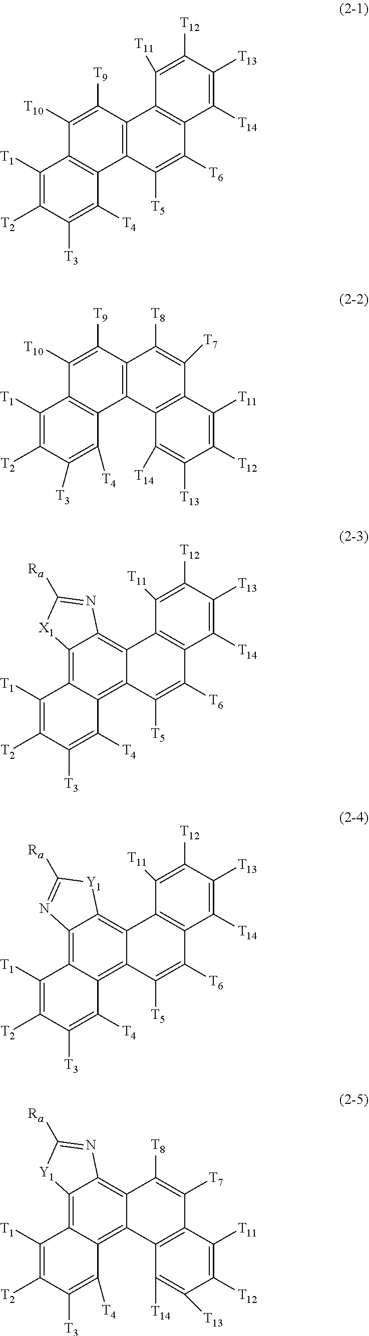 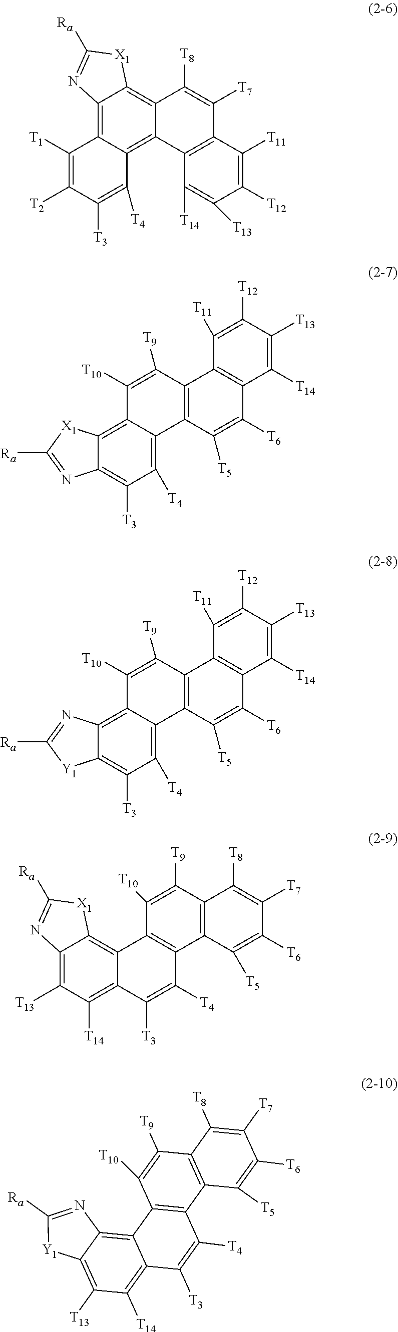 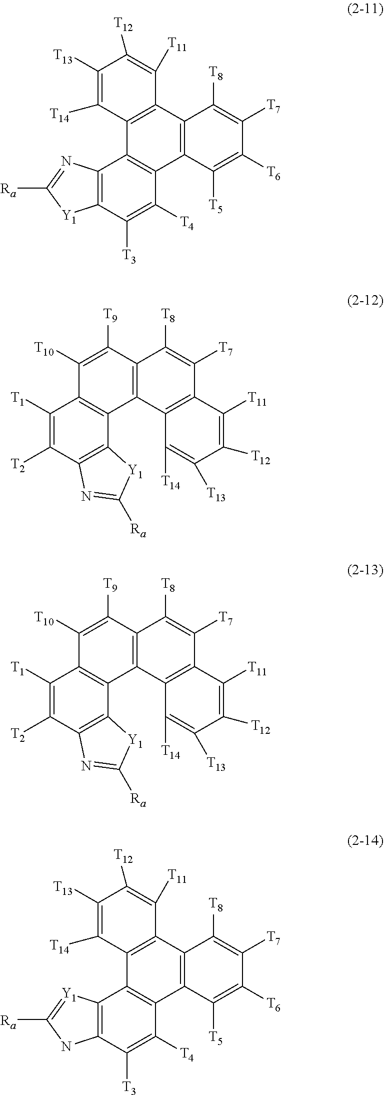
wherein
T₁ to T₁₄, X₁, Y₁, and Rₐ are as defined in claim 1.

7. The plurality of host materials according to claim 1, wherein Ar₂ represents a substituted or unsubstituted pyridyl, a substituted or unsubstituted pyrimidinyl, a substituted or unsubstituted triazinyl, a substituted or unsubstituted pyrazinyl, a substituted or unsubstituted pyridazinyl, a substituted or unsubstituted quinazolinyl, a substituted or unsubstituted benzoquinazolinyl, a substituted or unsubstituted quinoxalinyl, a substituted or unsubstituted benzoquinoxalinyl, a substituted or unsubstituted quinolyl, a substituted or unsubstituted benzoquinolyl, a substituted or unsubstituted isoquinolyl, a substituted or unsubstituted benzoisoquinolyl, a substituted or unsubstituted triazolyl, a substituted or unsubstituted pyrazolyl, a substituted or unsubstituted naphthyridinyl, a substituted or unsubstituted benzothienopyrimidinyl, a substituted or unsubstituted benzoimidazolyl, a substituted or unsubstituted benzofuropyrimidinyl, a substituted or unsubstituted acenaphthopyrimidinyl, a substituted or unsubstituted benzopyrimidinyl, a substituted or unsubstituted benzothienoquinolyl, a substituted or unsubstituted dibenzoquinoxalinyl, or a substituted or unsubstituted phenanthroimidazolyl.

8. The plurality of host materials according to claim 1, wherein Ar₂ is represented by the following formula 2-a: 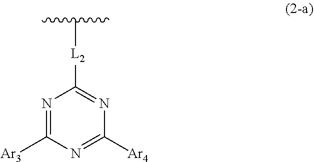
wherein,
L₂ is as defined in claim 1; and
Ar₃ and Ar₄ each independently represent, a substituted or unsubstituted (C6-C30)aryl, a substituted or unsubstituted (3- to 30-membered)heteroaryl, or a substituted or unsubstituted fused ring of (C3-C30) aliphatic ring and (C6-C30) aromatic ring.

9. The plurality of host materials according to claim 1, wherein the compound represented by the formula 1 is selected from the following compounds:

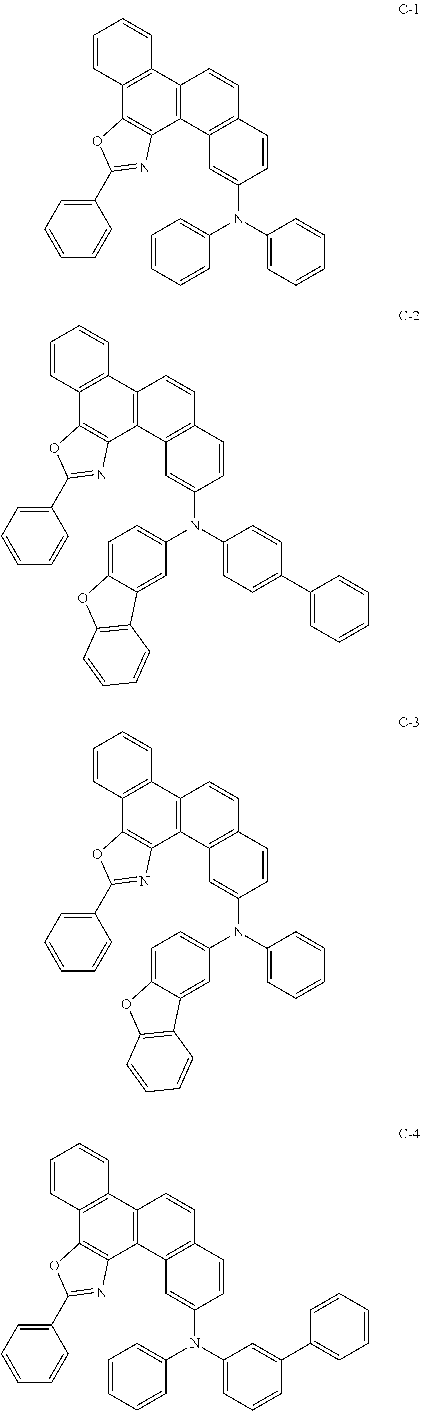 [SMILES: c1ccc(-c2nc3c(o2)c2ccccc2c2ccc4ccc(N(c5ccccc5)c5ccccc5)cc4c23)cc1 ; c1ccc(-c2ccc(N(c3ccc4oc5ccccc5c4c3)c3ccc4ccc5c6ccccc6c6oc(-c7ccccc7)nc6c5c4c3)cc2)cc1 ; c1ccc(-c2nc3c(o2)c2ccccc2c2ccc4ccc(N(c5ccccc5)c5ccc6oc7ccccc7c6c5)cc4c23)cc1 ; c1ccc(-c2cccc(N(c3ccccc3)c3ccc4ccc5c6ccccc6c6oc(-c7ccccc7)nc6c5c4c3)c2)cc1]

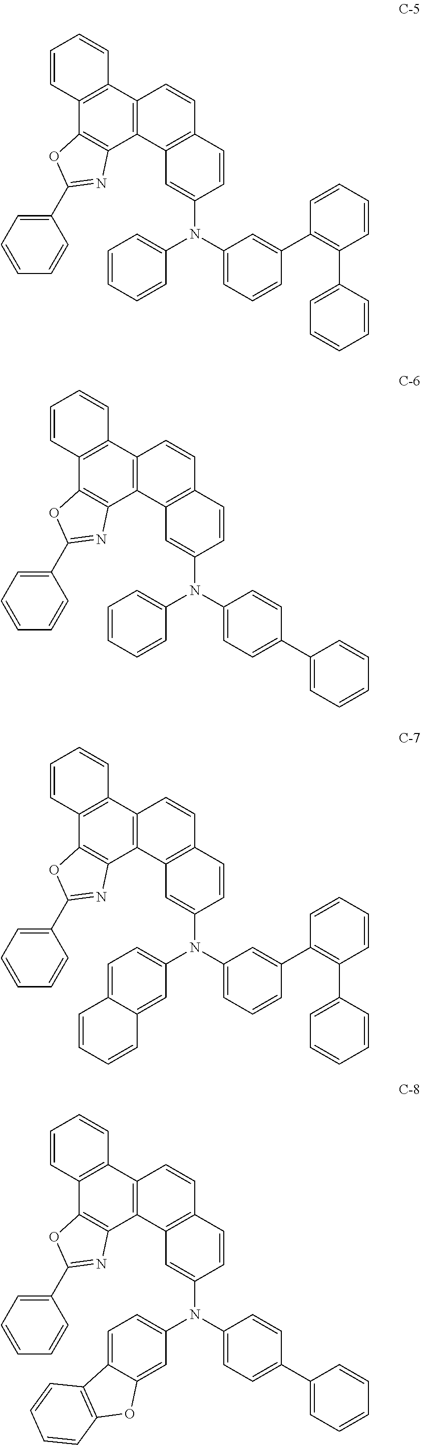 [SMILES: c1ccc(-c2nc3c(o2)c2ccccc2c2ccc4ccc(N(c5ccccc5)c5cccc(-c6ccccc6-c6ccccc6)c5)cc4c23)cc1 ; c1ccc(-c2ccc(N(c3ccccc3)c3ccc4ccc5c6ccccc6c6oc(-c7ccccc7)nc6c5c4c3)cc2)cc1 ; c1ccc(-c2nc3c(o2)c2ccccc2c2ccc4ccc(N(c5cccc(-c6ccccc6-c6ccccc6)c5)c5ccc6ccccc6c5)cc4c23)cc1 ; c1ccc(-c2ccc(N(c3ccc4c(c3)oc3ccccc34)c3ccc4ccc5c6ccccc6c6oc(-c7ccccc7)nc6c5c4c3)cc2)cc1]

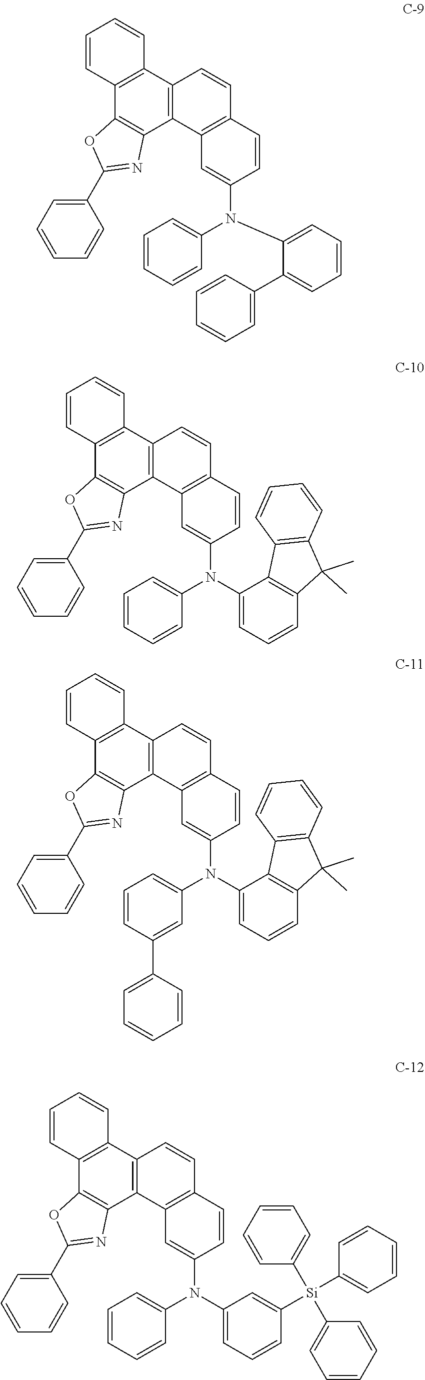 [SMILES: c1ccc(-c2nc3c(o2)c2ccccc2c2ccc4ccc(N(c5ccccc5)c5ccccc5-c5ccccc5)cc4c23)cc1 ; CC1(C)c2ccccc2-c2c(N(c3ccccc3)c3ccc4ccc5c6ccccc6c6oc(-c7ccccc7)nc6c5c4c3)cccc21 ; CC1(C)c2ccccc2-c2c(N(c3cccc(-c4ccccc4)c3)c3ccc4ccc5c6ccccc6c6oc(-c7ccccc7)nc6c5c4c3)cccc21 ; c1ccc(-c2nc3c(o2)c2ccccc2c2ccc4ccc(N(c5ccccc5)c5cccc([Si](c6ccccc6)(c6ccccc6)c6ccccc6)c5)cc4c23)cc1]

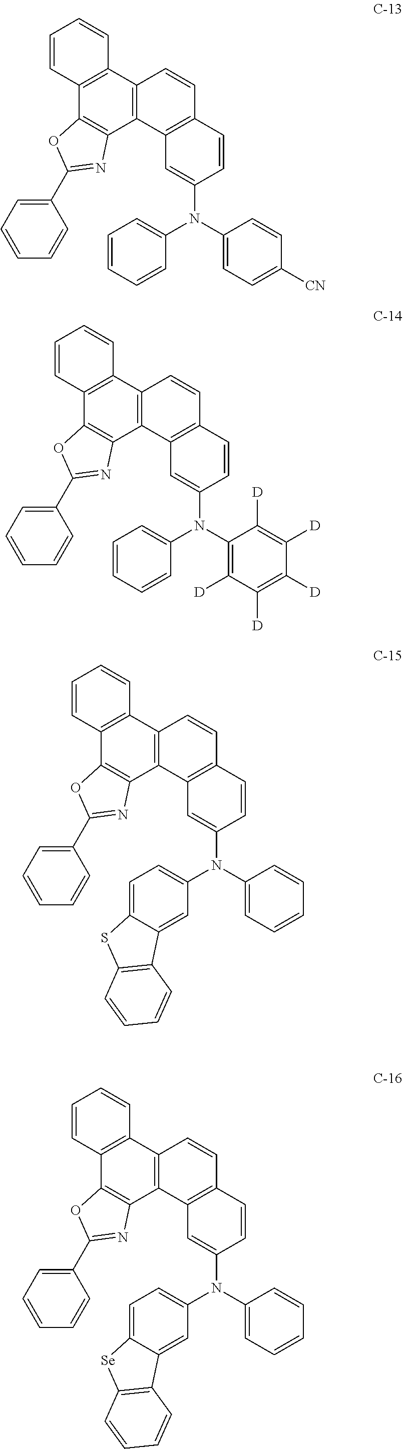 [SMILES: N#Cc1ccc(N(c2ccccc2)c2ccc3ccc4c5ccccc5c5oc(-c6ccccc6)nc5c4c3c2)cc1 ; [2H]c1c([2H])c([2H])c(N(c2ccccc2)c2ccc3ccc4c5ccccc5c5oc(-c6ccccc6)nc5c4c3c2)c([2H])c1[2H] ; c1ccc(-c2nc3c(o2)c2ccccc2c2ccc4ccc(N(c5ccccc5)c5ccc6sc7ccccc7c6c5)cc4c23)cc1 ; c1ccc(-c2nc3c(o2)c2ccccc2c2ccc4ccc(N(c5ccccc5)c5ccc6[se]c7ccccc7c6c5)cc4c23)cc1]

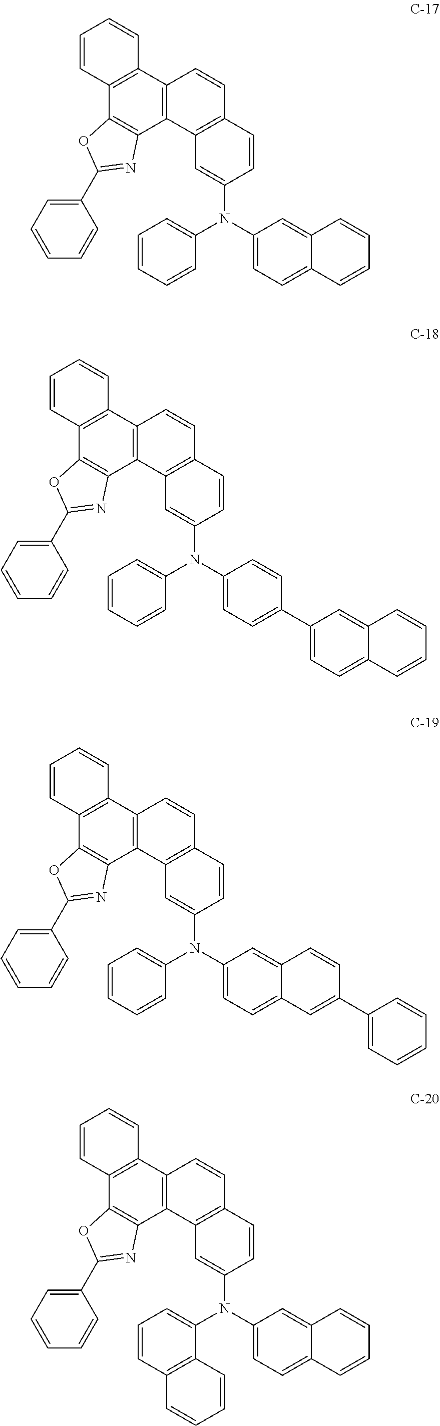 [SMILES: c1ccc(-c2nc3c(o2)c2ccccc2c2ccc4ccc(N(c5ccccc5)c5ccc6ccccc6c5)cc4c23)cc1 ; c1ccc(-c2nc3c(o2)c2ccccc2c2ccc4ccc(N(c5ccccc5)c5ccc(-c6ccc7ccccc7c6)cc5)cc4c23)cc1 ; c1ccc(-c2ccc3cc(N(c4ccccc4)c4ccc5ccc6c7ccccc7c7oc(-c8ccccc8)nc7c6c5c4)ccc3c2)cc1 ; c1ccc(-c2nc3c(o2)c2ccccc2c2ccc4ccc(N(c5ccc6ccccc6c5)c5cccc6ccccc56)cc4c23)cc1]

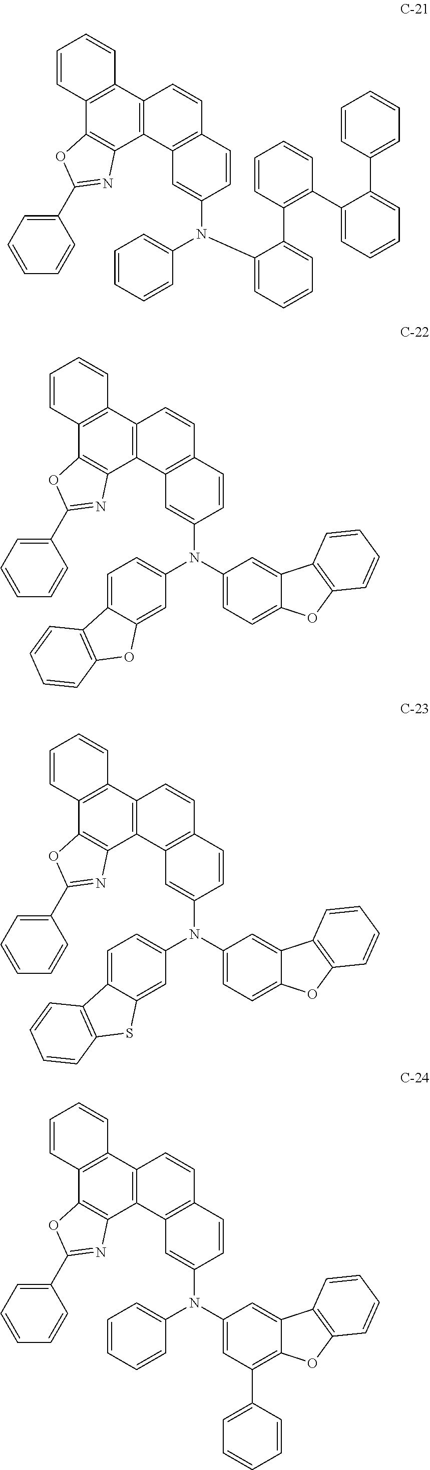

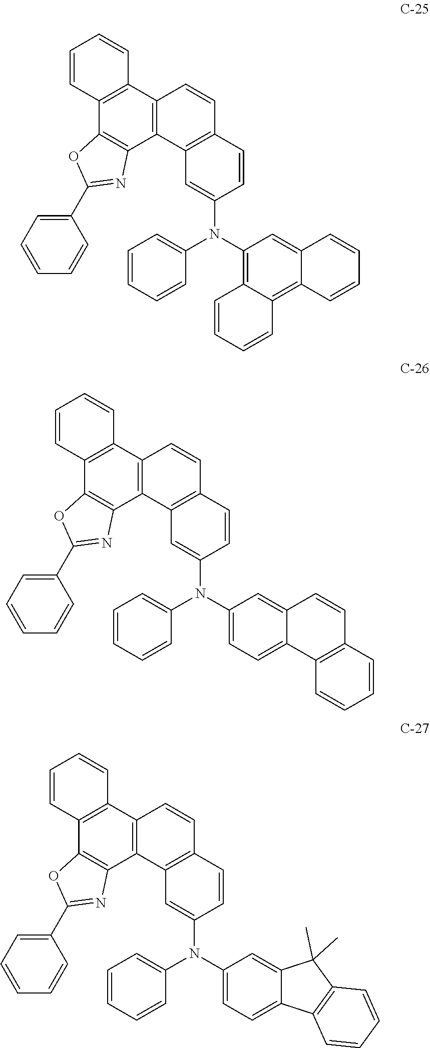 [SMILES: c1ccc(-c2nc3c(o2)c2ccccc2c2ccc4ccc(N(c5ccccc5)c5cc6ccccc6c6ccccc56)cc4c23)cc1 ; c1ccc(-c2nc3c(o2)c2ccccc2c2ccc4ccc(N(c5ccccc5)c5ccc6c(ccc7ccccc76)c5)cc4c23)cc1 ; CC1(C)c2ccccc2-c2ccc(N(c3ccccc3)c3ccc4ccc5c6ccccc6c6oc(-c7ccccc7)nc6c5c4c3)cc21]

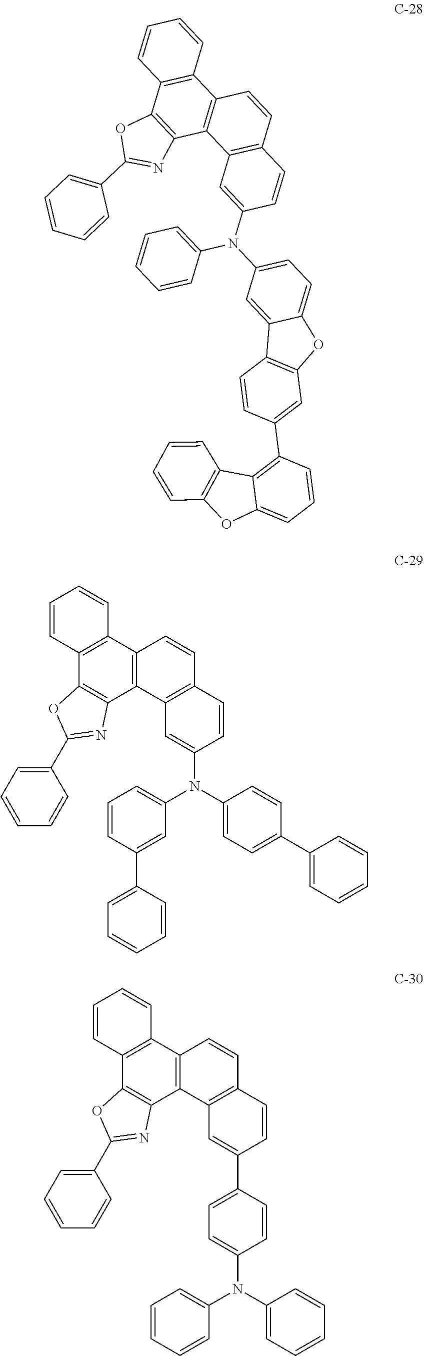

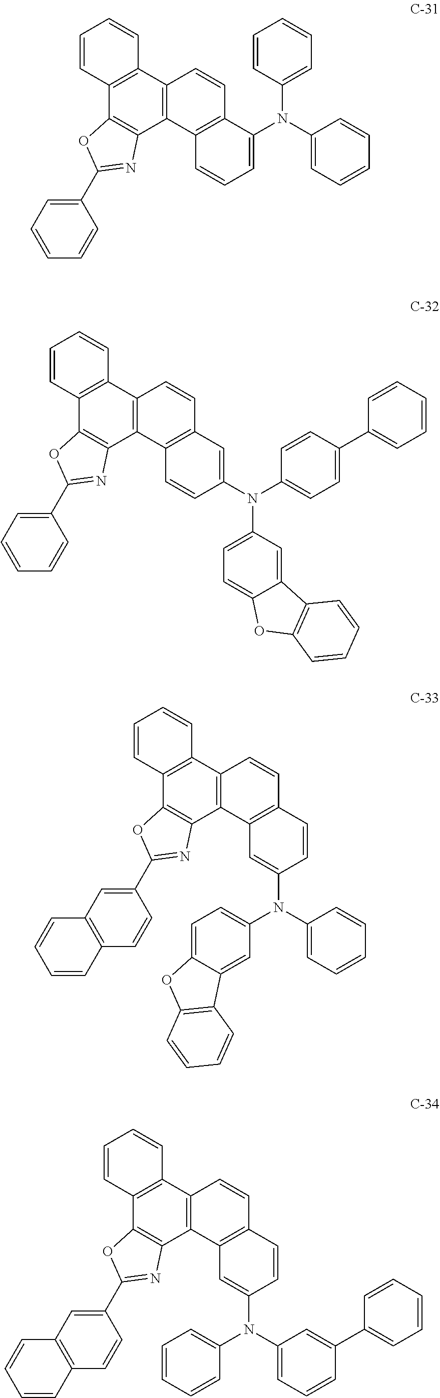 [SMILES: c1ccc(-c2nc3c(o2)c2ccccc2c2ccc4c(N(c5ccccc5)c5ccccc5)cccc4c23)cc1 ; c1ccc(-c2ccc(N(c3ccc4c(ccc5c6ccccc6c6oc(-c7ccccc7)nc6c45)c3)c3ccc4oc5ccccc5c4c3)cc2)cc1 ; c1ccc(N(c2ccc3oc4ccccc4c3c2)c2ccc3ccc4c5ccccc5c5oc(-c6ccc7ccccc7c6)nc5c4c3c2)cc1 ; c1ccc(-c2cccc(N(c3ccccc3)c3ccc4ccc5c6ccccc6c6oc(-c7ccc8ccccc8c7)nc6c5c4c3)c2)cc1]

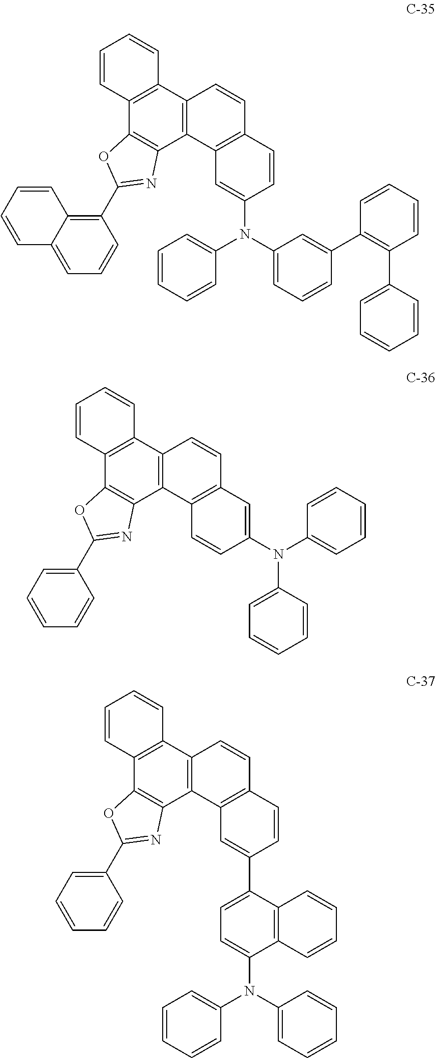 [SMILES: c1ccc(-c2ccccc2-c2cccc(N(c3ccccc3)c3ccc4ccc5c6ccccc6c6oc(-c7cccc8ccccc78)nc6c5c4c3)c2)cc1 ; c1ccc(-c2nc3c(o2)c2ccccc2c2ccc4cc(N(c5ccccc5)c5ccccc5)ccc4c23)cc1 ; c1ccc(-c2nc3c(o2)c2ccccc2c2ccc4ccc(-c5ccc(N(c6ccccc6)c6ccccc6)c6ccccc56)cc4c23)cc1]

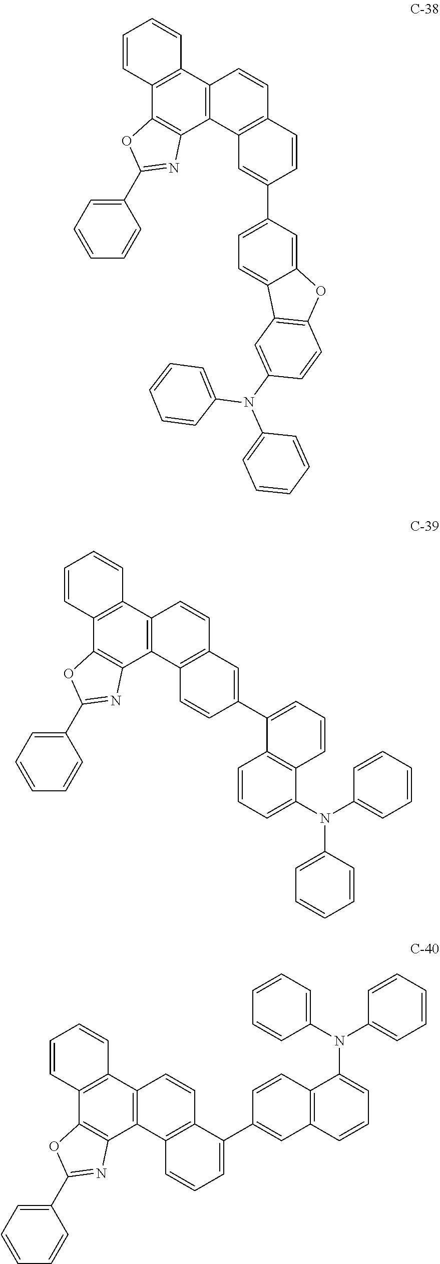 [SMILES: c1ccc(-c2nc3c(o2)c2ccccc2c2ccc4ccc(-c5ccc6c(c5)oc5ccc(N(c7ccccc7)c7ccccc7)cc56)cc4c23)cc1 ; c1ccc(-c2nc3c(o2)c2ccccc2c2ccc4cc(-c5cccc6c(N(c7ccccc7)c7ccccc7)cccc56)ccc4c23)cc1 ; c1ccc(-c2nc3c(o2)c2ccccc2c2ccc4c(-c5ccc6c(N(c7ccccc7)c7ccccc7)cccc6c5)cccc4c23)cc1]

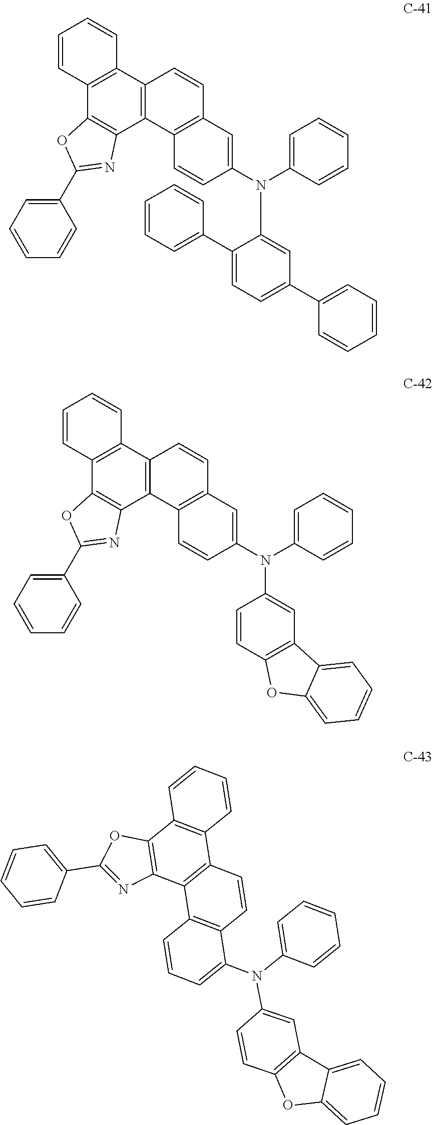 [SMILES: c1ccc(-c2ccc(-c3ccccc3)c(N(c3ccccc3)c3ccc4c(ccc5c6ccccc6c6oc(-c7ccccc7)nc6c45)c3)c2)cc1 ; c1ccc(-c2nc3c(o2)c2ccccc2c2ccc4cc(N(c5ccccc5)c5ccc6oc7ccccc7c6c5)ccc4c23)cc1 ; c1ccc(-c2nc3c(o2)c2ccccc2c2ccc4c(N(c5ccccc5)c5ccc6oc7ccccc7c6c5)cccc4c23)cc1]

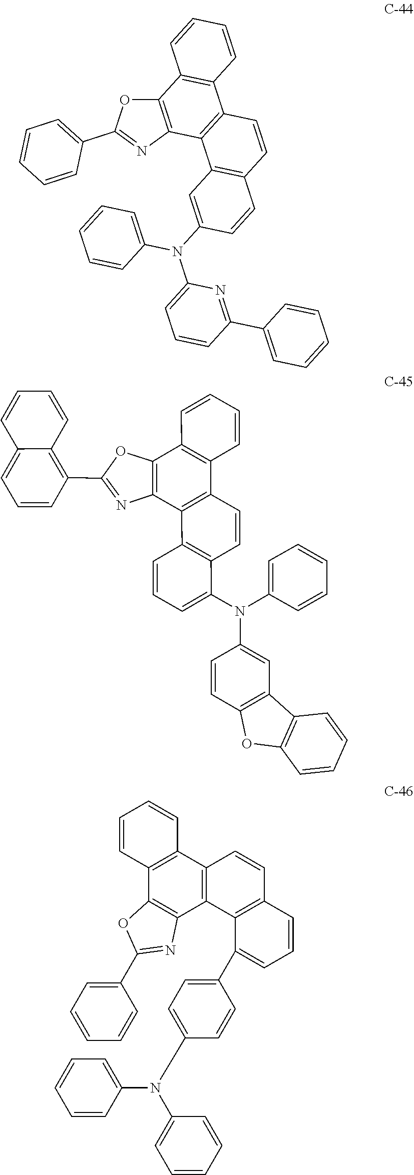 [SMILES: c1ccc(-c2cccc(N(c3ccccc3)c3ccc4ccc5c6ccccc6c6oc(-c7ccccc7)nc6c5c4c3)n2)cc1 ; c1ccc(N(c2ccc3oc4ccccc4c3c2)c2cccc3c2ccc2c4ccccc4c4oc(-c5cccc6ccccc56)nc4c32)cc1 ; c1ccc(-c2nc3c(o2)c2ccccc2c2ccc4cccc(-c5ccc(N(c6ccccc6)c6ccccc6)cc5)c4c23)cc1]

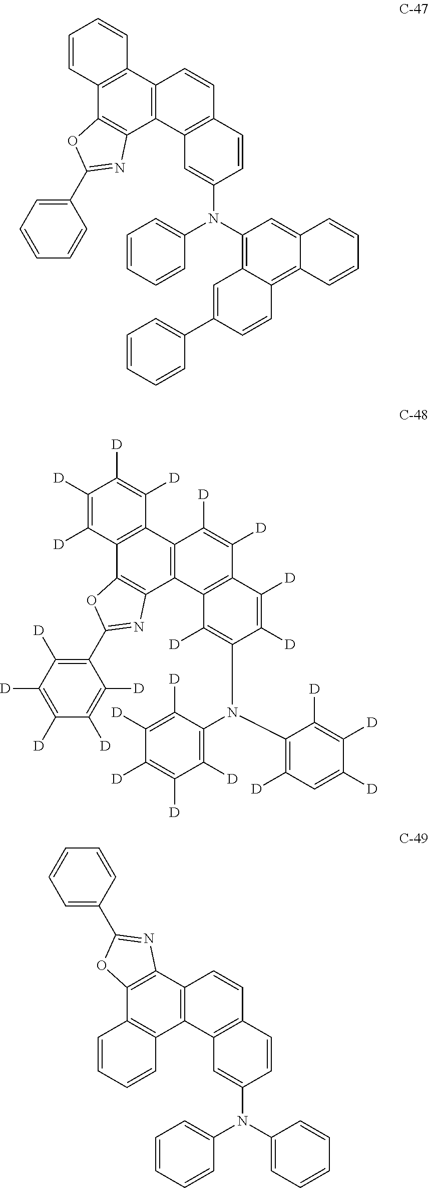 [SMILES: c1ccc(-c2ccc3c(c2)c(N(c2ccccc2)c2ccc4ccc5c6ccccc6c6oc(-c7ccccc7)nc6c5c4c2)cc2ccccc23)cc1 ; [2H]c1cc([2H])c(N(c2c([2H])c([2H])c([2H])c([2H])c2[2H])c2c([2H])c([2H])c3c([2H])c([2H])c4c5c([2H])c([2H])c([2H])c([2H])c5c5oc(-c6c([2H])c([2H])c([2H])c([2H])c6[2H])nc5c4c3c2[2H])c([2H])c1[2H] ; c1ccc(-c2nc3c4ccc5ccc(N(c6ccccc6)c6ccccc6)cc5c4c4ccccc4c3o2)cc1]

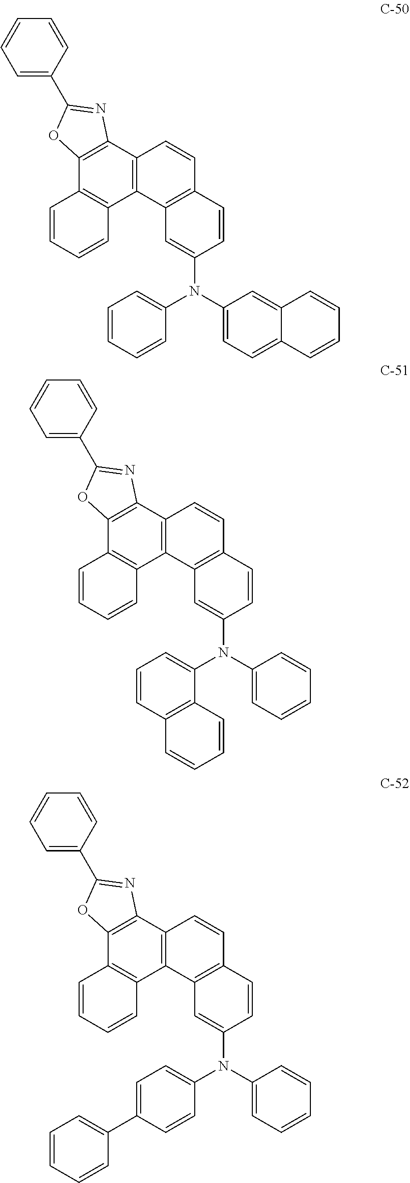 [SMILES: c1ccc(-c2nc3c4ccc5ccc(N(c6ccccc6)c6ccc7ccccc7c6)cc5c4c4ccccc4c3o2)cc1 ; c1ccc(-c2nc3c4ccc5ccc(N(c6ccccc6)c6cccc7ccccc67)cc5c4c4ccccc4c3o2)cc1 ; c1ccc(-c2ccc(N(c3ccccc3)c3ccc4ccc5c6nc(-c7ccccc7)oc6c6ccccc6c5c4c3)cc2)cc1]

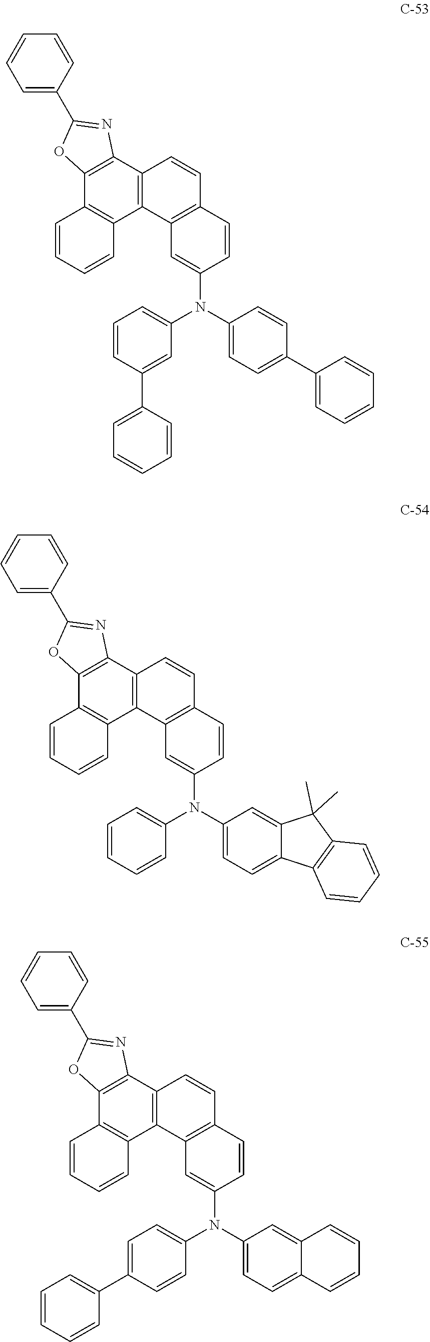 [SMILES: c1ccc(-c2ccc(N(c3cccc(-c4ccccc4)c3)c3ccc4ccc5c6nc(-c7ccccc7)oc6c6ccccc6c5c4c3)cc2)cc1 ; CC1(C)c2ccccc2-c2ccc(N(c3ccccc3)c3ccc4ccc5c6nc(-c7ccccc7)oc6c6ccccc6c5c4c3)cc21 ; c1ccc(-c2ccc(N(c3ccc4ccccc4c3)c3ccc4ccc5c6nc(-c7ccccc7)oc6c6ccccc6c5c4c3)cc2)cc1]

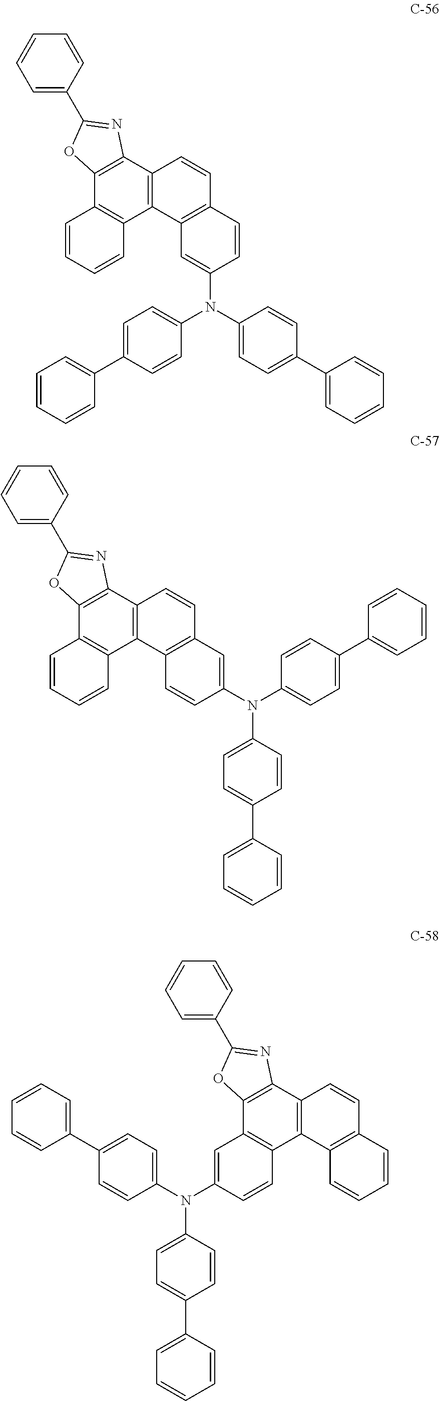

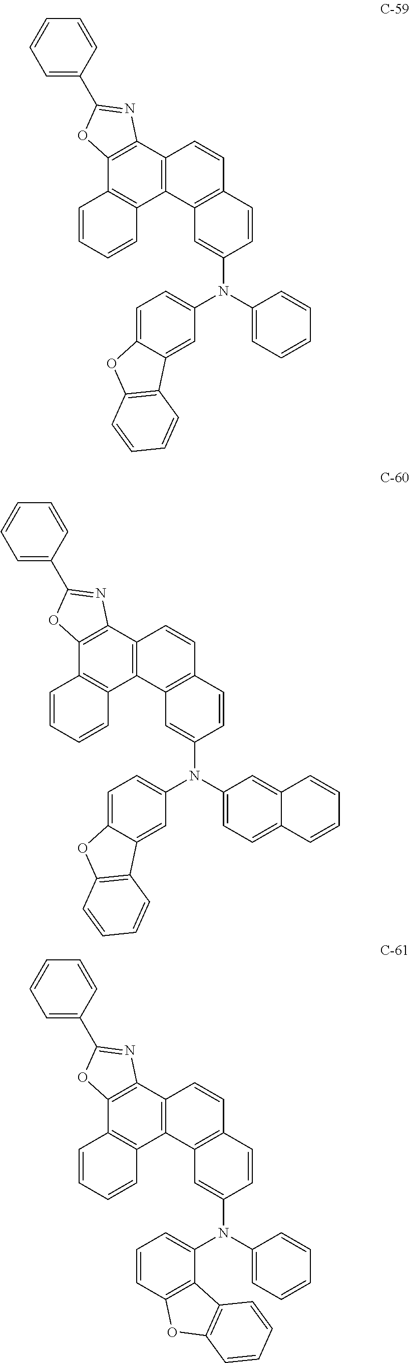

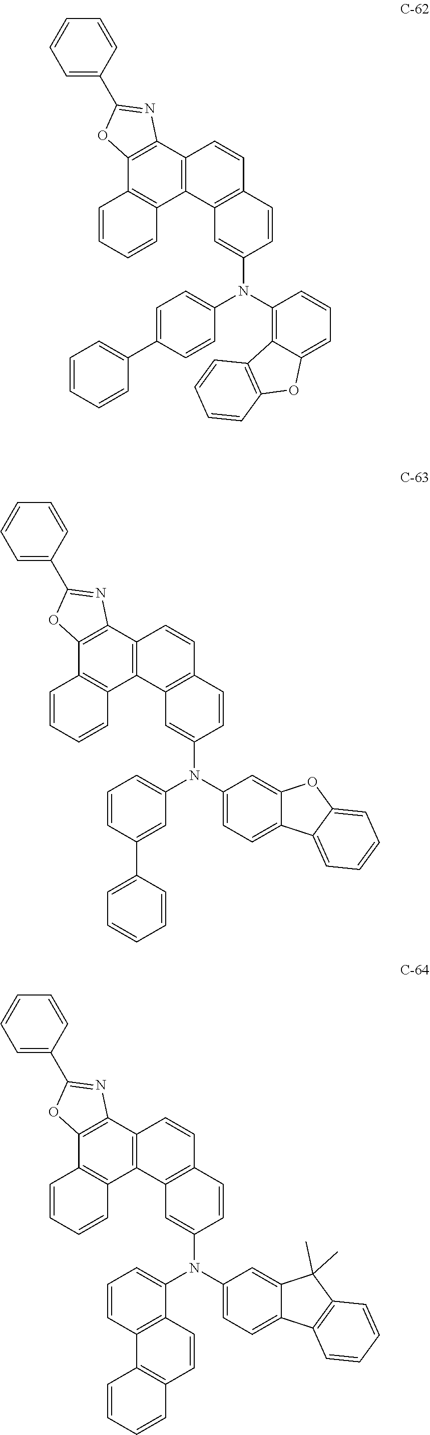 [SMILES: c1ccc(-c2ccc(N(c3ccc4ccc5c6nc(-c7ccccc7)oc6c6ccccc6c5c4c3)c3cccc4oc5ccccc5c34)cc2)cc1 ; c1ccc(-c2cccc(N(c3ccc4c(c3)oc3ccccc34)c3ccc4ccc5c6nc(-c7ccccc7)oc6c6ccccc6c5c4c3)c2)cc1 ; CC1(C)c2ccccc2-c2ccc(N(c3ccc4ccc5c6nc(-c7ccccc7)oc6c6ccccc6c5c4c3)c3cccc4c3ccc3ccccc34)cc21]

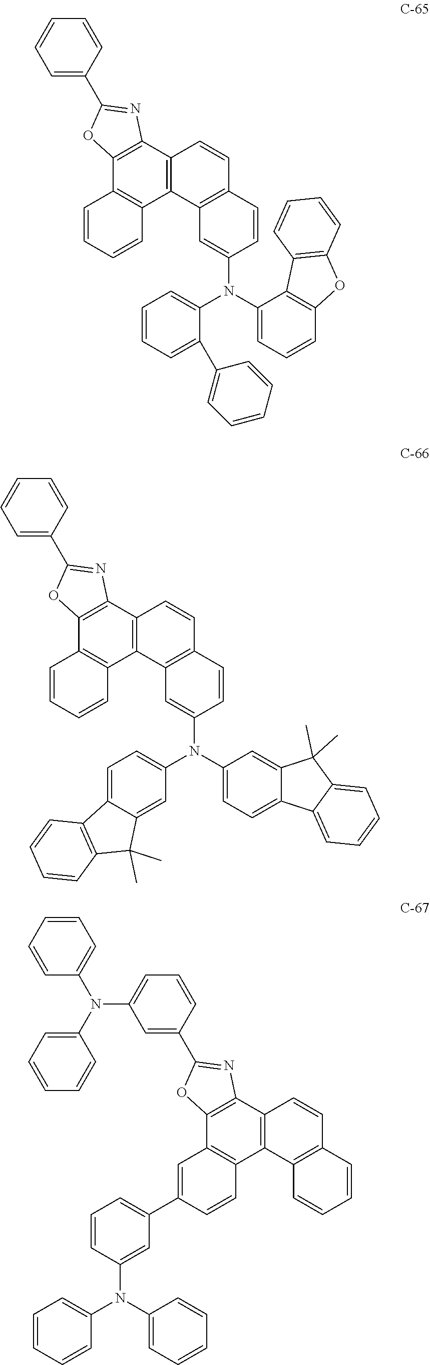

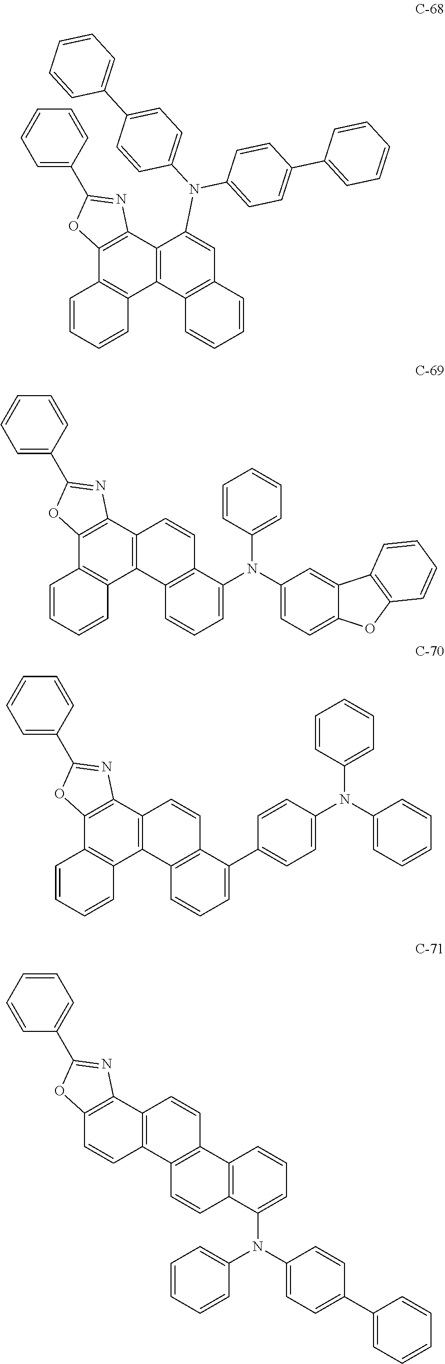 [SMILES: c1ccc(-c2ccc(N(c3ccc(-c4ccccc4)cc3)c3cc4ccccc4c4c5ccccc5c5oc(-c6ccccc6)nc5c34)cc2)cc1 ; c1ccc(-c2nc3c4ccc5c(N(c6ccccc6)c6ccc7oc8ccccc8c7c6)cccc5c4c4ccccc4c3o2)cc1 ; c1ccc(-c2nc3c4ccc5c(-c6ccc(N(c7ccccc7)c7ccccc7)cc6)cccc5c4c4ccccc4c3o2)cc1 ; c1ccc(-c2ccc(N(c3ccccc3)c3cccc4c3ccc3c4ccc4c3ccc3oc(-c5ccccc5)nc34)cc2)cc1]

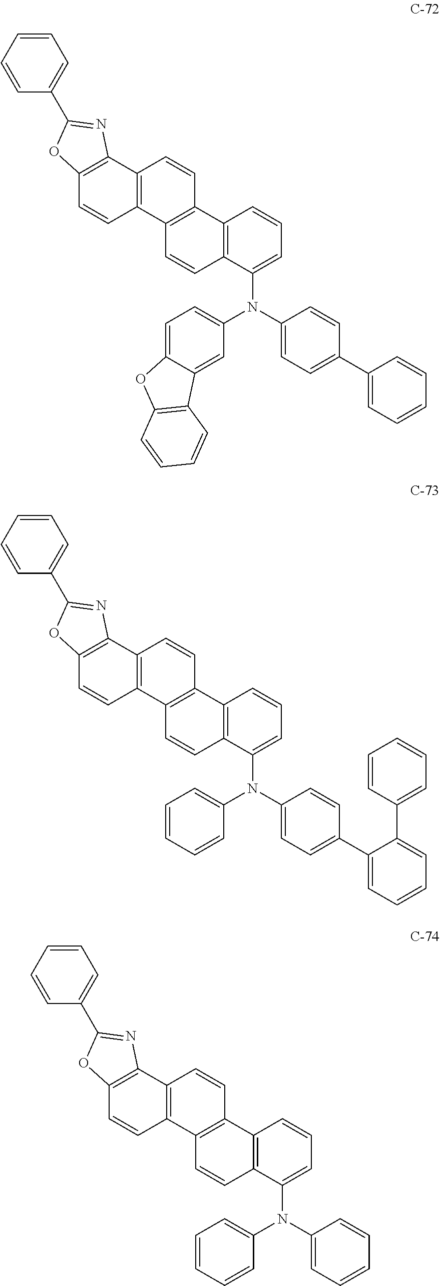 [SMILES: c1ccc(-c2ccc(N(c3ccc4oc5ccccc5c4c3)c3cccc4c3ccc3c4ccc4c3ccc3oc(-c5ccccc5)nc34)cc2)cc1 ; c1ccc(-c2nc3c(ccc4c5ccc6c(N(c7ccccc7)c7ccc(-c8ccccc8-c8ccccc8)cc7)cccc6c5ccc43)o2)cc1 ; c1ccc(-c2nc3c(ccc4c5ccc6c(N(c7ccccc7)c7ccccc7)cccc6c5ccc43)o2)cc1]

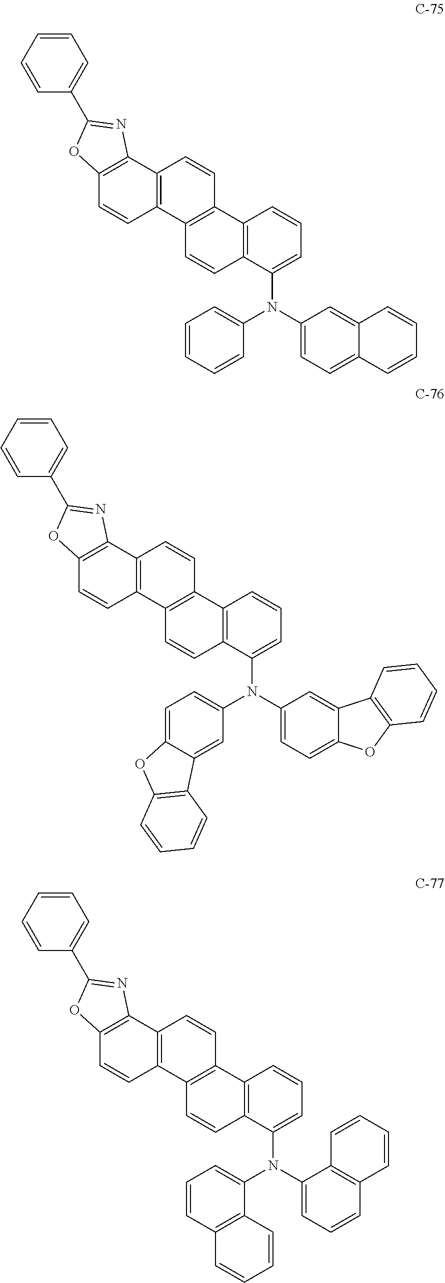 [SMILES: c1ccc(-c2nc3c(ccc4c5ccc6c(N(c7ccccc7)c7ccc8ccccc8c7)cccc6c5ccc43)o2)cc1 ; c1ccc(-c2nc3c(ccc4c5ccc6c(N(c7ccc8oc9ccccc9c8c7)c7ccc8oc9ccccc9c8c7)cccc6c5ccc43)o2)cc1 ; c1ccc(-c2nc3c(ccc4c5ccc6c(N(c7cccc8ccccc78)c7cccc8ccccc78)cccc6c5ccc43)o2)cc1]

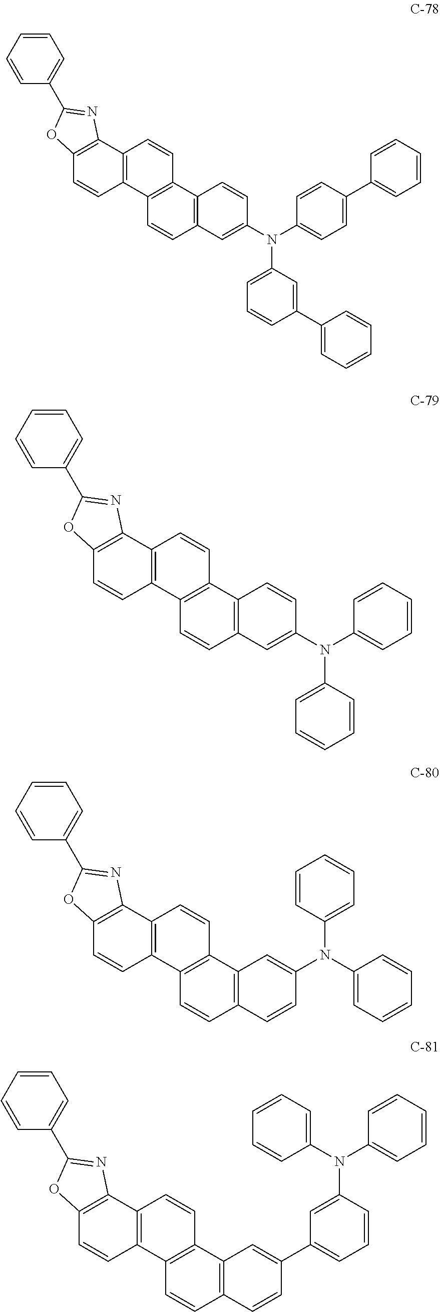 [SMILES: c1ccc(-c2ccc(N(c3cccc(-c4ccccc4)c3)c3ccc4c(ccc5c4ccc4c5ccc5oc(-c6ccccc6)nc54)c3)cc2)cc1 ; c1ccc(-c2nc3c(ccc4c5ccc6cc(N(c7ccccc7)c7ccccc7)ccc6c5ccc43)o2)cc1 ; c1ccc(-c2nc3c(ccc4c5ccc6ccc(N(c7ccccc7)c7ccccc7)cc6c5ccc43)o2)cc1 ; c1ccc(-c2nc3c(ccc4c5ccc6ccc(-c7cccc(N(c8ccccc8)c8ccccc8)c7)cc6c5ccc43)o2)cc1]

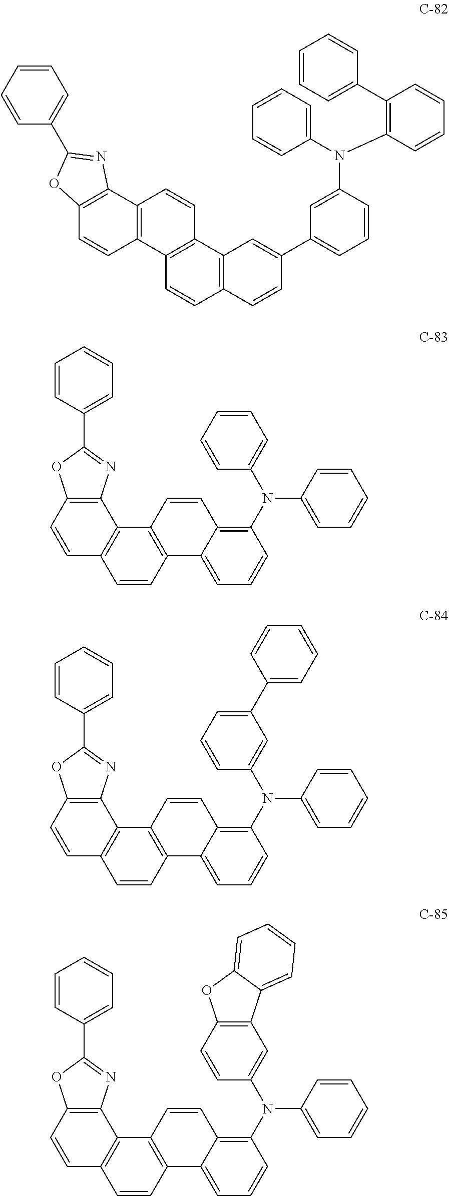

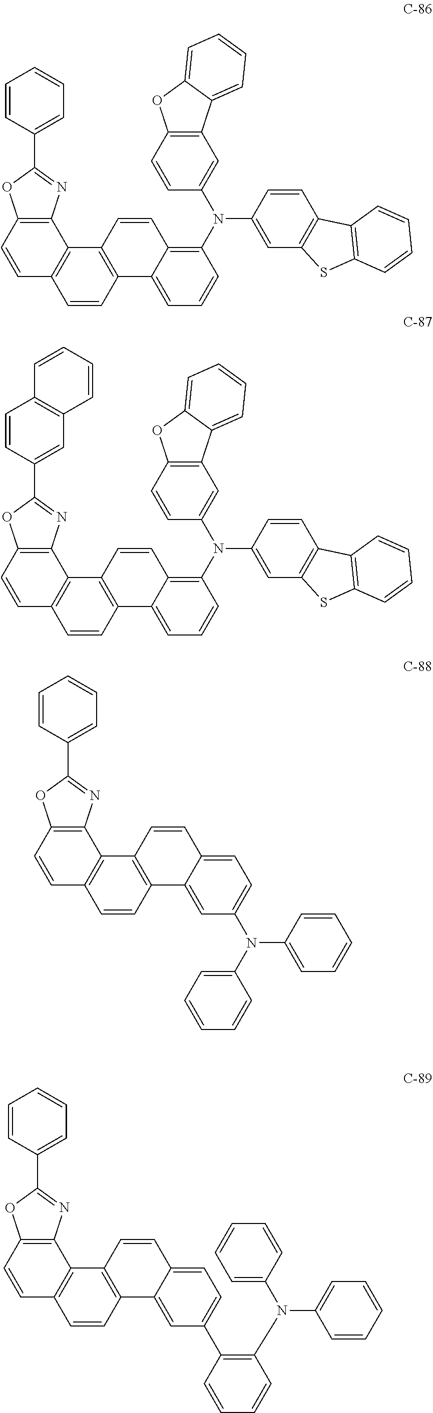

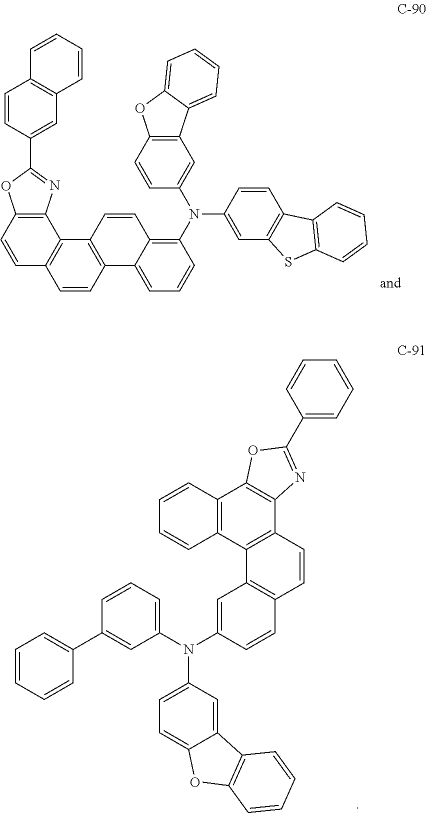 [SMILES: c1ccc2cc(-c3nc4c(ccc5ccc6c7cccc(N(c8ccc9c(c8)sc8ccccc89)c8ccc9oc%10ccccc%10c9c8)c7ccc6c54)o3)ccc2c1 ; c1ccc(-c2cccc(N(c3ccc4oc5ccccc5c4c3)c3ccc4ccc5c6nc(-c7ccccc7)oc6c6ccccc6c5c4c3)c2)cc1]

10. The plurality of host materials according to claim 1, wherein the compound represented by the formula 2 is selected from the following compounds:

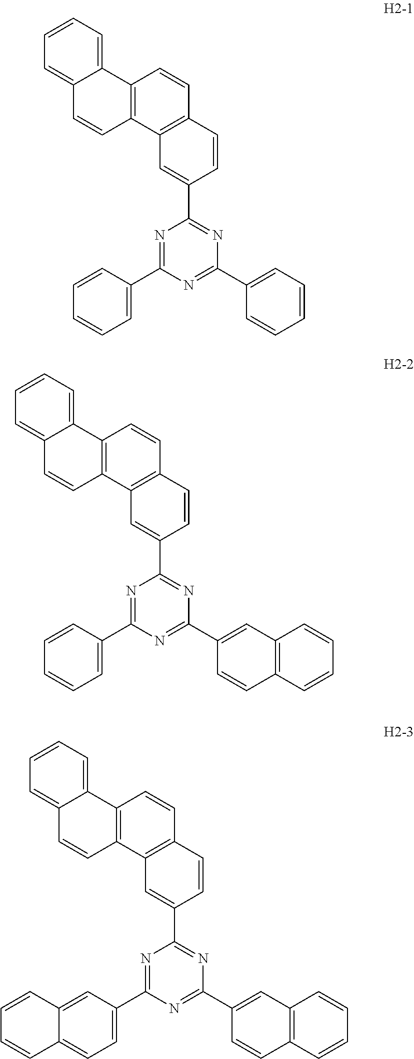 [SMILES: c1ccc(-c2nc(-c3ccccc3)nc(-c3ccc4ccc5c6ccccc6ccc5c4c3)n2)cc1 ; c1ccc(-c2nc(-c3ccc4ccccc4c3)nc(-c3ccc4ccc5c6ccccc6ccc5c4c3)n2)cc1 ; c1ccc2cc(-c3nc(-c4ccc5ccccc5c4)nc(-c4ccc5ccc6c7ccccc7ccc6c5c4)n3)ccc2c1]

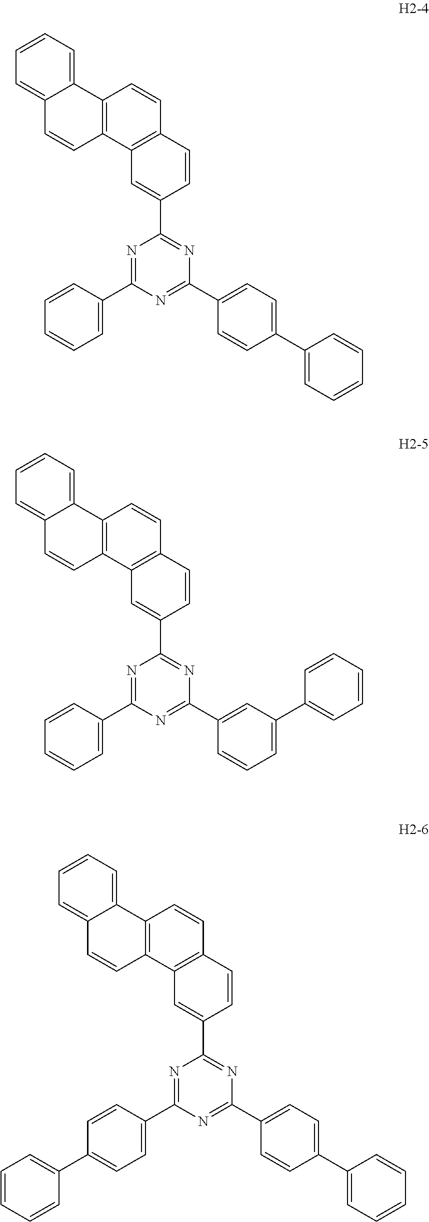 [SMILES: c1ccc(-c2ccc(-c3nc(-c4ccccc4)nc(-c4ccc5ccc6c7ccccc7ccc6c5c4)n3)cc2)cc1 ; c1ccc(-c2cccc(-c3nc(-c4ccccc4)nc(-c4ccc5ccc6c7ccccc7ccc6c5c4)n3)c2)cc1 ; c1ccc(-c2ccc(-c3nc(-c4ccc(-c5ccccc5)cc4)nc(-c4ccc5ccc6c7ccccc7ccc6c5c4)n3)cc2)cc1]

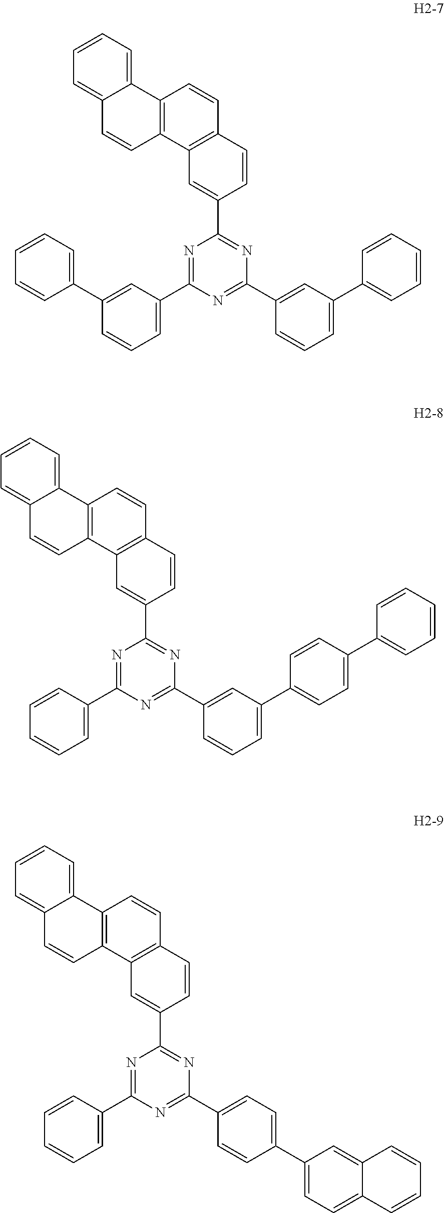 [SMILES: c1ccc(-c2cccc(-c3nc(-c4cccc(-c5ccccc5)c4)nc(-c4ccc5ccc6c7ccccc7ccc6c5c4)n3)c2)cc1 ; c1ccc(-c2ccc(-c3cccc(-c4nc(-c5ccccc5)nc(-c5ccc6ccc7c8ccccc8ccc7c6c5)n4)c3)cc2)cc1 ; c1ccc(-c2nc(-c3ccc(-c4ccc5ccccc5c4)cc3)nc(-c3ccc4ccc5c6ccccc6ccc5c4c3)n2)cc1]

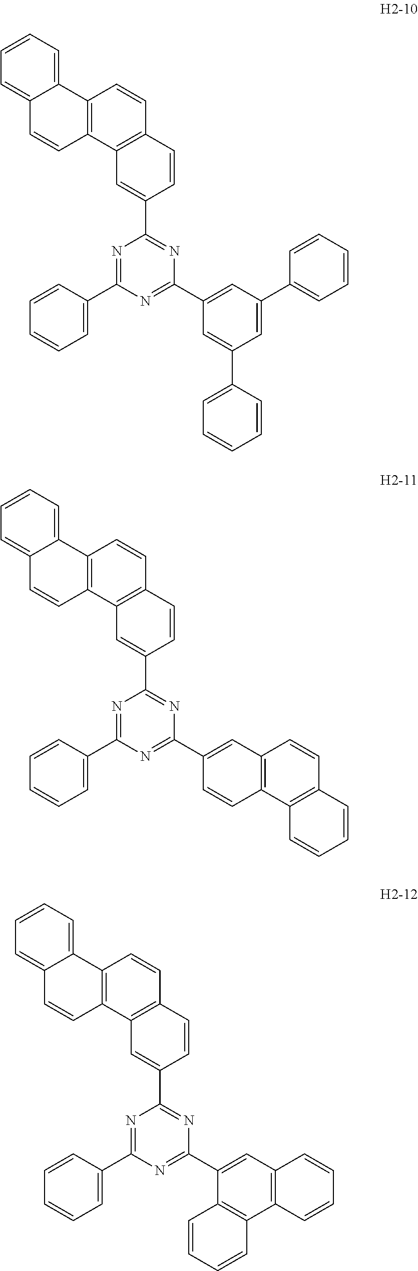 [SMILES: c1ccc(-c2cc(-c3ccccc3)cc(-c3nc(-c4ccccc4)nc(-c4ccc5ccc6c7ccccc7ccc6c5c4)n3)c2)cc1 ; c1ccc(-c2nc(-c3ccc4c(ccc5ccccc54)c3)nc(-c3ccc4ccc5c6ccccc6ccc5c4c3)n2)cc1 ; c1ccc(-c2nc(-c3ccc4ccc5c6ccccc6ccc5c4c3)nc(-c3cc4ccccc4c4ccccc34)n2)cc1]

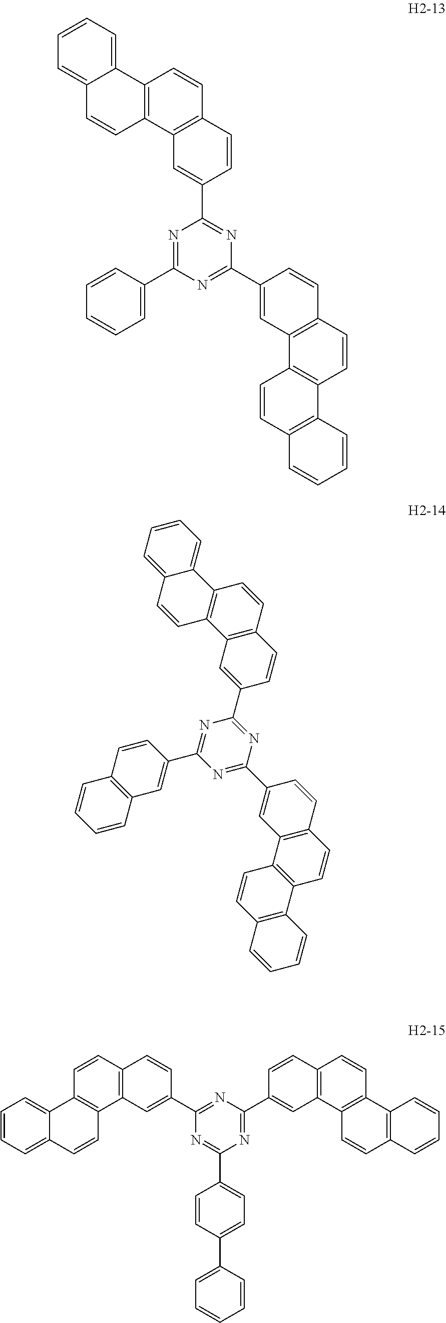 [SMILES: c1ccc(-c2nc(-c3ccc4ccc5c6ccccc6ccc5c4c3)nc(-c3ccc4ccc5c6ccccc6ccc5c4c3)n2)cc1 ; c1ccc2cc(-c3nc(-c4ccc5ccc6c7ccccc7ccc6c5c4)nc(-c4ccc5ccc6c7ccccc7ccc6c5c4)n3)ccc2c1 ; c1ccc(-c2ccc(-c3nc(-c4ccc5ccc6c7ccccc7ccc6c5c4)nc(-c4ccc5ccc6c7ccccc7ccc6c5c4)n3)cc2)cc1]

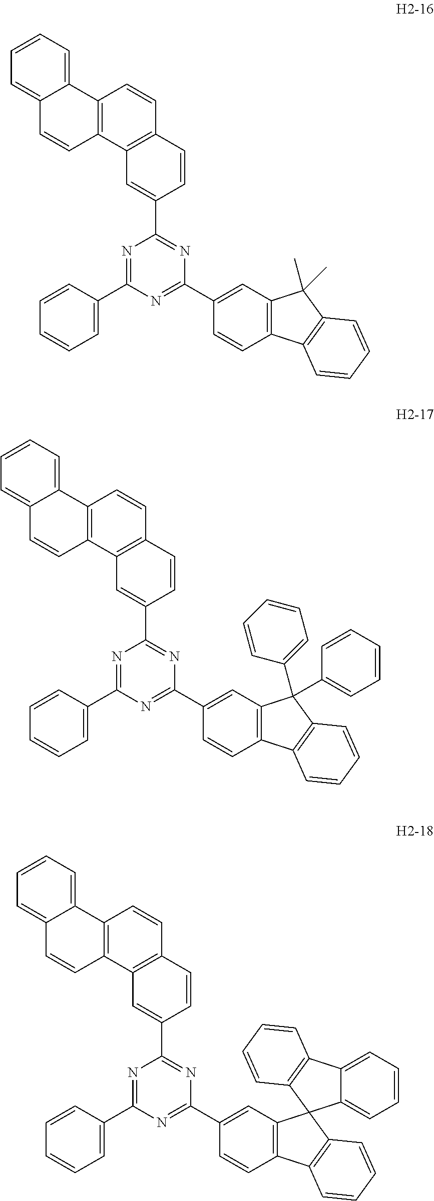 [SMILES: CC1(C)c2ccccc2-c2ccc(-c3nc(-c4ccccc4)nc(-c4ccc5ccc6c7ccccc7ccc6c5c4)n3)cc21 ; c1ccc(-c2nc(-c3ccc4c(c3)C(c3ccccc3)(c3ccccc3)c3ccccc3-4)nc(-c3ccc4ccc5c6ccccc6ccc5c4c3)n2)cc1 ; c1ccc(-c2nc(-c3ccc4c(c3)C3(c5ccccc5-c5ccccc53)c3ccccc3-4)nc(-c3ccc4ccc5c6ccccc6ccc5c4c3)n2)cc1]

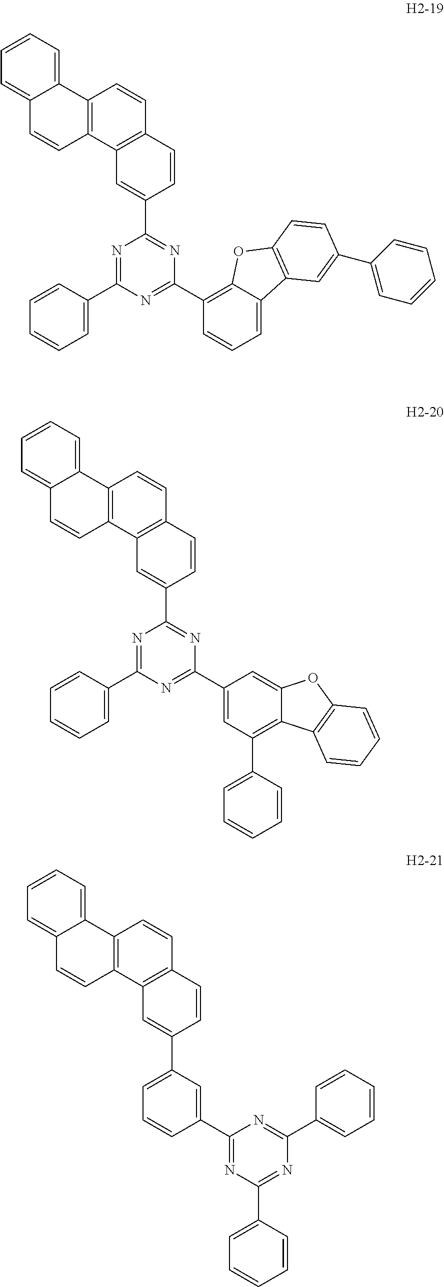 [SMILES: c1ccc(-c2ccc3oc4c(-c5nc(-c6ccccc6)nc(-c6ccc7ccc8c9ccccc9ccc8c7c6)n5)cccc4c3c2)cc1 ; c1ccc(-c2nc(-c3cc(-c4ccccc4)c4c(c3)oc3ccccc34)nc(-c3ccc4ccc5c6ccccc6ccc5c4c3)n2)cc1 ; c1ccc(-c2nc(-c3ccccc3)nc(-c3cccc(-c4ccc5ccc6c7ccccc7ccc6c5c4)c3)n2)cc1]

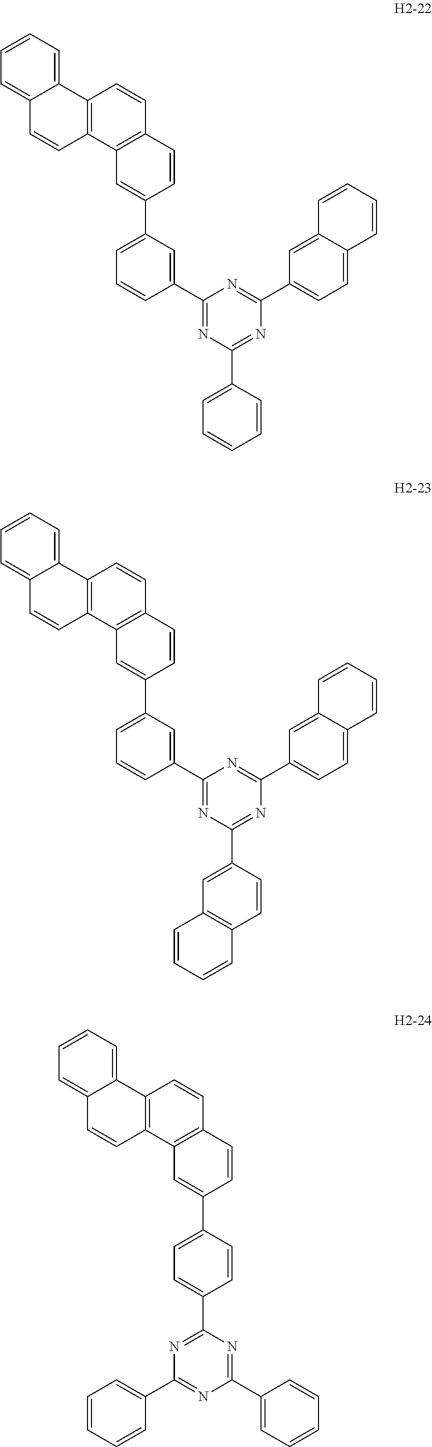 [SMILES: c1ccc(-c2nc(-c3cccc(-c4ccc5ccc6c7ccccc7ccc6c5c4)c3)nc(-c3ccc4ccccc4c3)n2)cc1 ; c1cc(-c2ccc3ccc4c5ccccc5ccc4c3c2)cc(-c2nc(-c3ccc4ccccc4c3)nc(-c3ccc4ccccc4c3)n2)c1 ; c1ccc(-c2nc(-c3ccccc3)nc(-c3ccc(-c4ccc5ccc6c7ccccc7ccc6c5c4)cc3)n2)cc1]

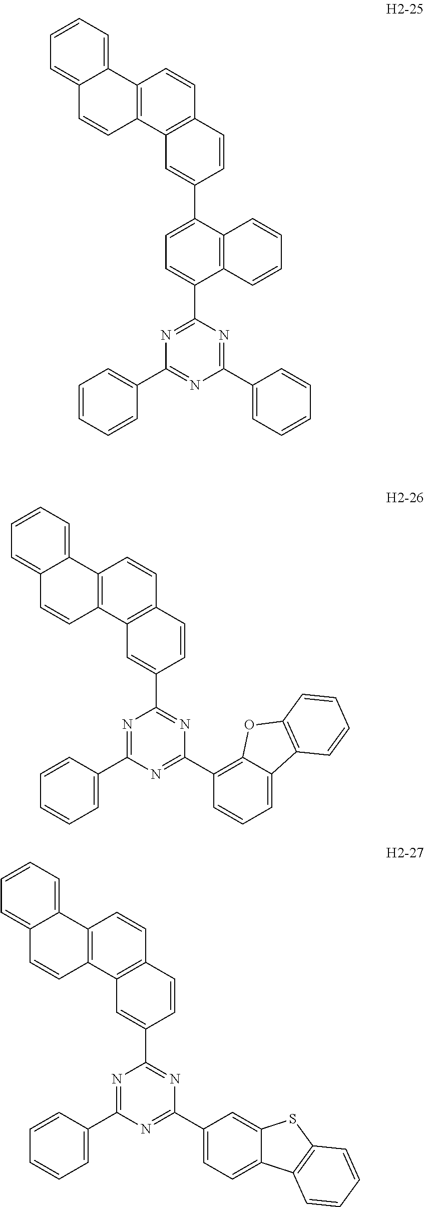 [SMILES: c1ccc(-c2nc(-c3ccccc3)nc(-c3ccc(-c4ccc5ccc6c7ccccc7ccc6c5c4)c4ccccc34)n2)cc1 ; c1ccc(-c2nc(-c3ccc4ccc5c6ccccc6ccc5c4c3)nc(-c3cccc4c3oc3ccccc34)n2)cc1 ; c1ccc(-c2nc(-c3ccc4c(c3)sc3ccccc34)nc(-c3ccc4ccc5c6ccccc6ccc5c4c3)n2)cc1]

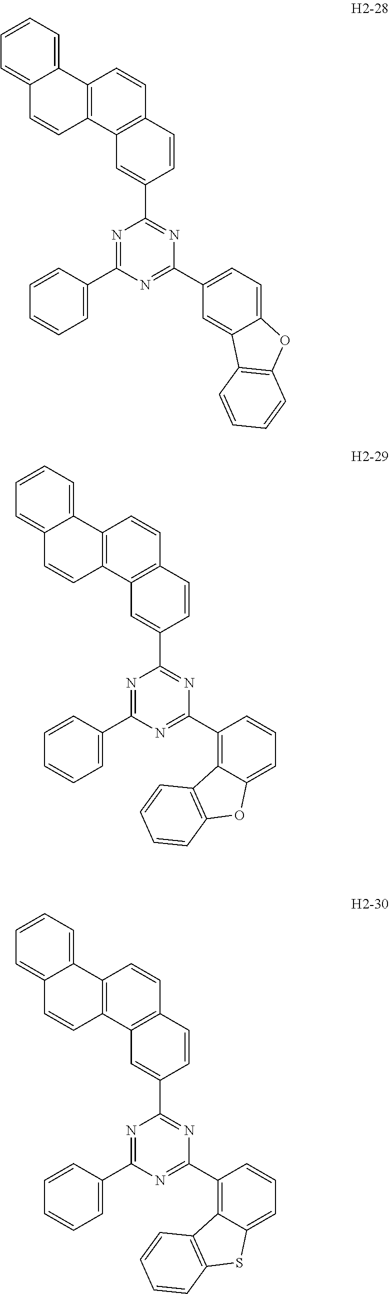 [SMILES: c1ccc(-c2nc(-c3ccc4ccc5c6ccccc6ccc5c4c3)nc(-c3ccc4oc5ccccc5c4c3)n2)cc1 ; c1ccc(-c2nc(-c3ccc4ccc5c6ccccc6ccc5c4c3)nc(-c3cccc4oc5ccccc5c34)n2)cc1 ; c1ccc(-c2nc(-c3ccc4ccc5c6ccccc6ccc5c4c3)nc(-c3cccc4sc5ccccc5c34)n2)cc1]

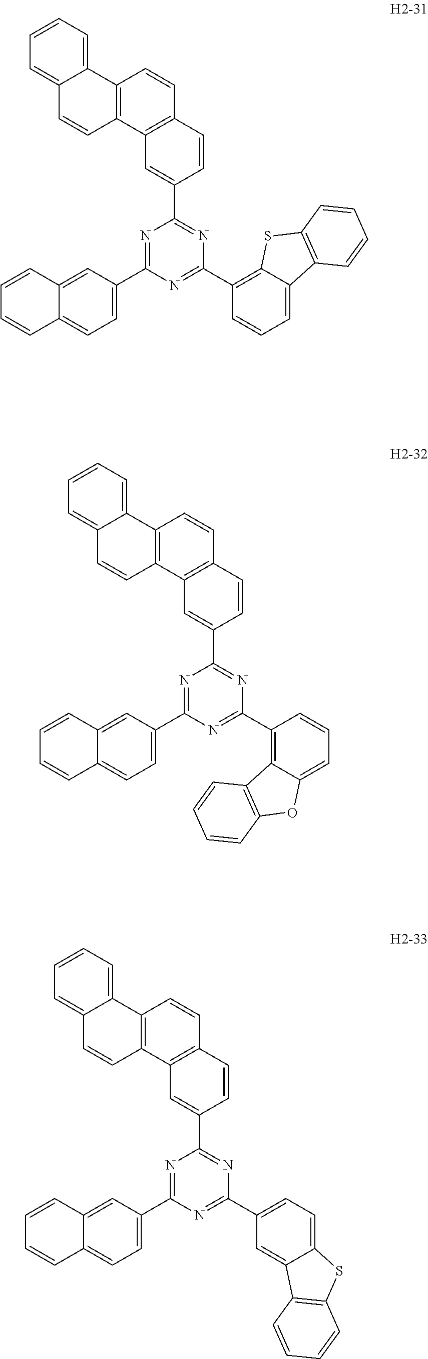 [SMILES: c1ccc2cc(-c3nc(-c4ccc5ccc6c7ccccc7ccc6c5c4)nc(-c4cccc5c4sc4ccccc45)n3)ccc2c1 ; c1ccc2cc(-c3nc(-c4ccc5ccc6c7ccccc7ccc6c5c4)nc(-c4cccc5oc6ccccc6c45)n3)ccc2c1 ; c1ccc2cc(-c3nc(-c4ccc5ccc6c7ccccc7ccc6c5c4)nc(-c4ccc5sc6ccccc6c5c4)n3)ccc2c1]

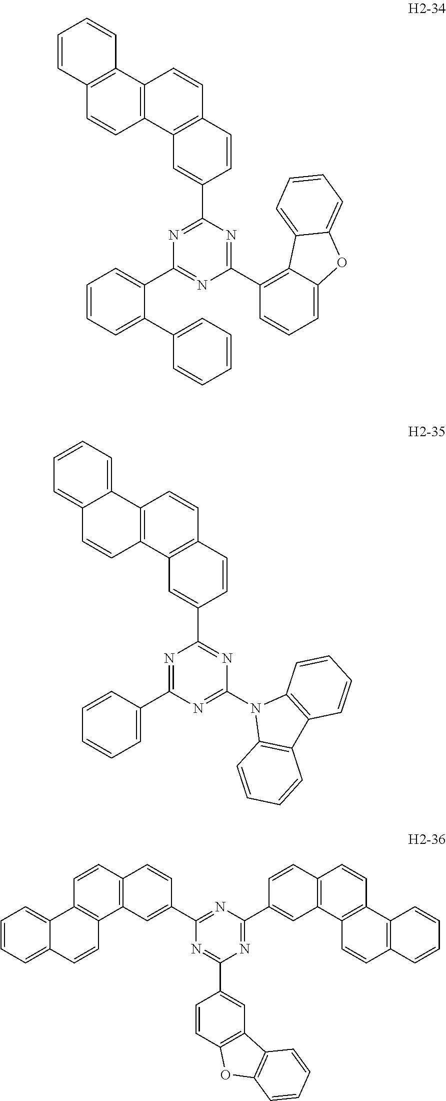 [SMILES: c1ccc(-c2ccccc2-c2nc(-c3ccc4ccc5c6ccccc6ccc5c4c3)nc(-c3cccc4oc5ccccc5c34)n2)cc1 ; c1ccc(-c2nc(-c3ccc4ccc5c6ccccc6ccc5c4c3)nc(-n3c4ccccc4c4ccccc43)n2)cc1 ; c1ccc2c(c1)ccc1c3cc(-c4nc(-c5ccc6ccc7c8ccccc8ccc7c6c5)nc(-c5ccc6oc7ccccc7c6c5)n4)ccc3ccc21]

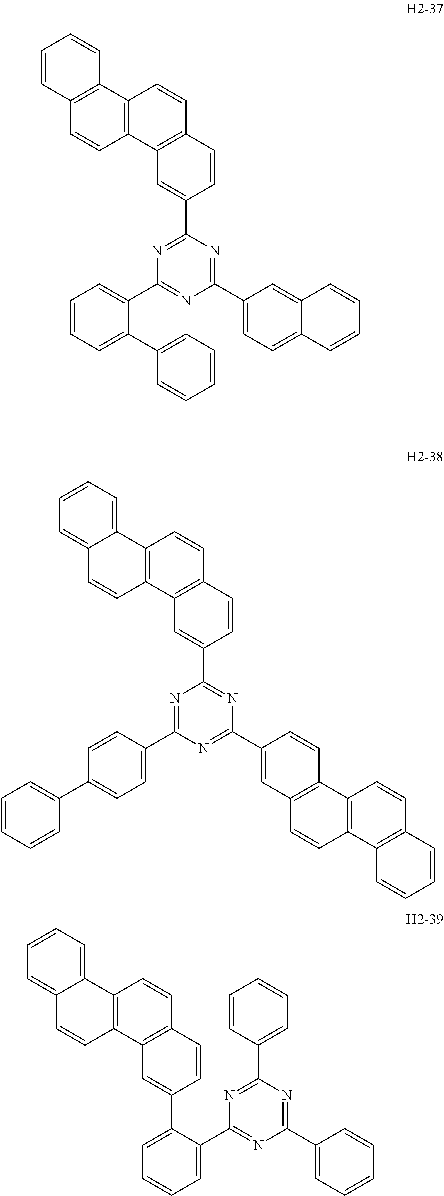 [SMILES: c1ccc(-c2ccccc2-c2nc(-c3ccc4ccccc4c3)nc(-c3ccc4ccc5c6ccccc6ccc5c4c3)n2)cc1 ; c1ccc(-c2ccc(-c3nc(-c4ccc5c(ccc6c7ccccc7ccc56)c4)nc(-c4ccc5ccc6c7ccccc7ccc6c5c4)n3)cc2)cc1 ; c1ccc(-c2nc(-c3ccccc3)nc(-c3ccccc3-c3ccc4ccc5c6ccccc6ccc5c4c3)n2)cc1]

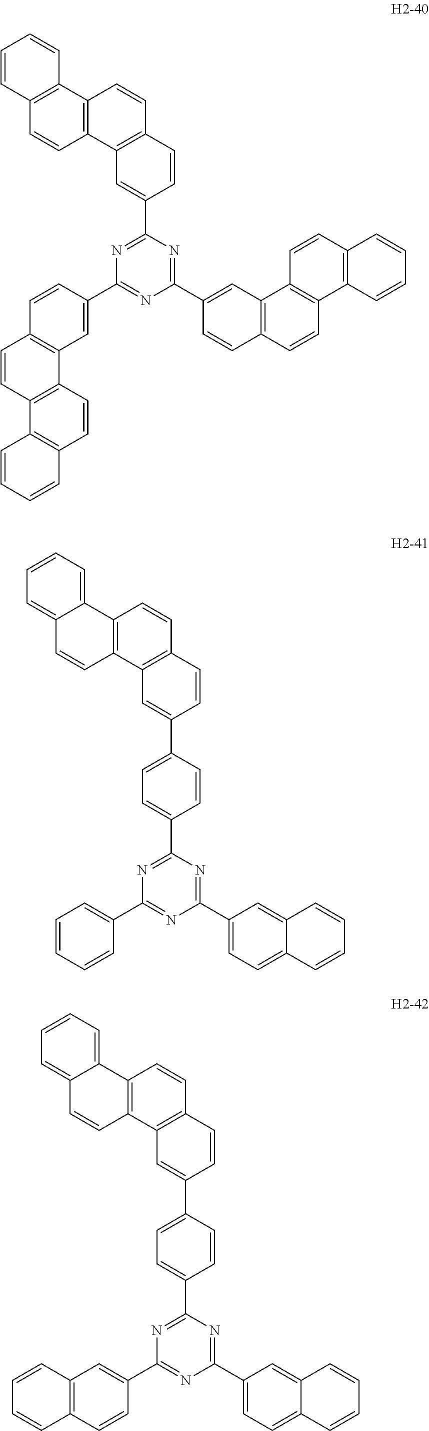

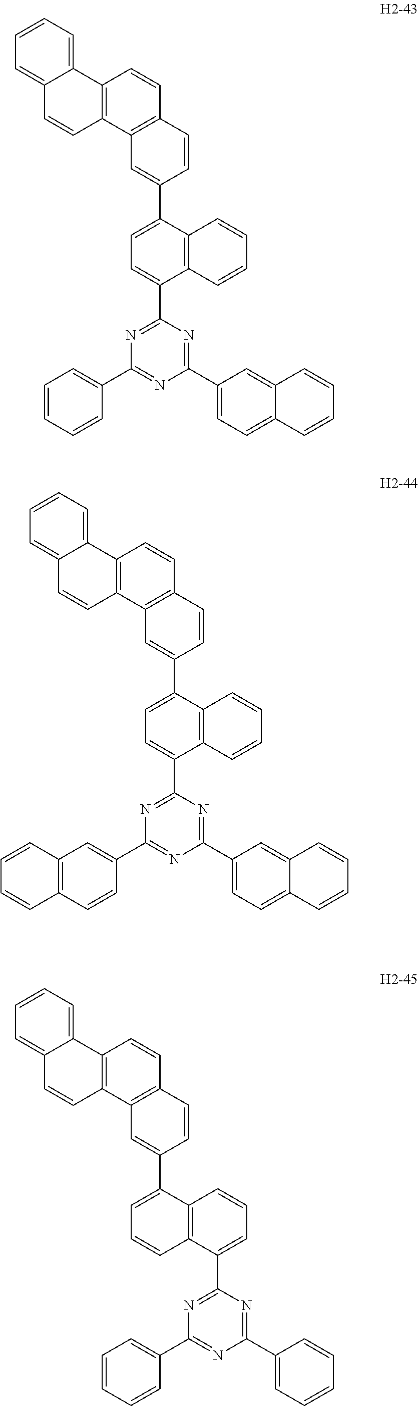 [SMILES: c1ccc(-c2nc(-c3ccc4ccccc4c3)nc(-c3ccc(-c4ccc5ccc6c7ccccc7ccc6c5c4)c4ccccc34)n2)cc1 ; c1ccc2cc(-c3nc(-c4ccc5ccccc5c4)nc(-c4ccc(-c5ccc6ccc7c8ccccc8ccc7c6c5)c5ccccc45)n3)ccc2c1 ; c1ccc(-c2nc(-c3ccccc3)nc(-c3cccc4c(-c5ccc6ccc7c8ccccc8ccc7c6c5)cccc34)n2)cc1]

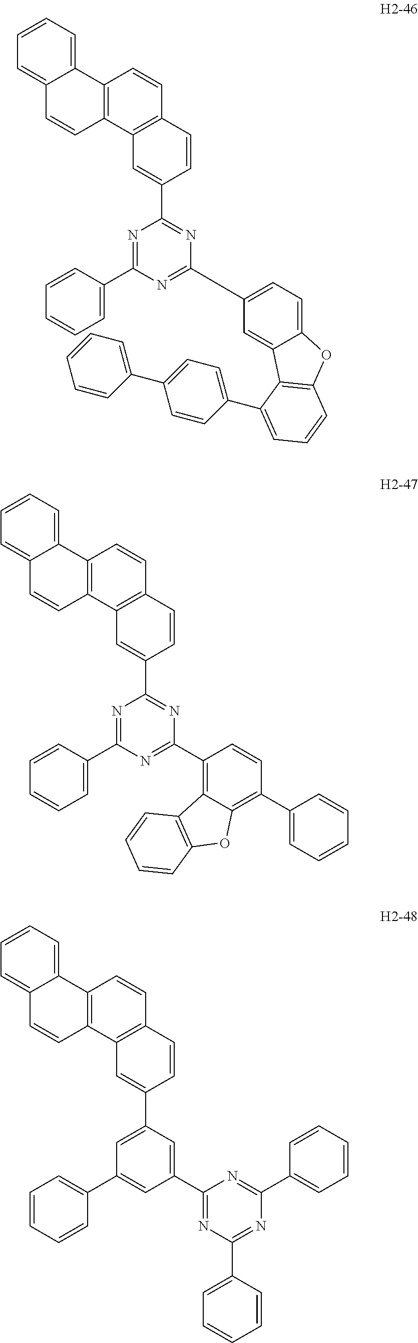 [SMILES: c1ccc(-c2ccc(-c3cccc4oc5ccc(-c6nc(-c7ccccc7)nc(-c7ccc8ccc9c%10ccccc%10ccc9c8c7)n6)cc5c34)cc2)cc1 ; c1ccc(-c2nc(-c3ccc4ccc5c6ccccc6ccc5c4c3)nc(-c3ccc(-c4ccccc4)c4oc5ccccc5c34)n2)cc1 ; c1ccc(-c2cc(-c3ccc4ccc5c6ccccc6ccc5c4c3)cc(-c3nc(-c4ccccc4)nc(-c4ccccc4)n3)c2)cc1]

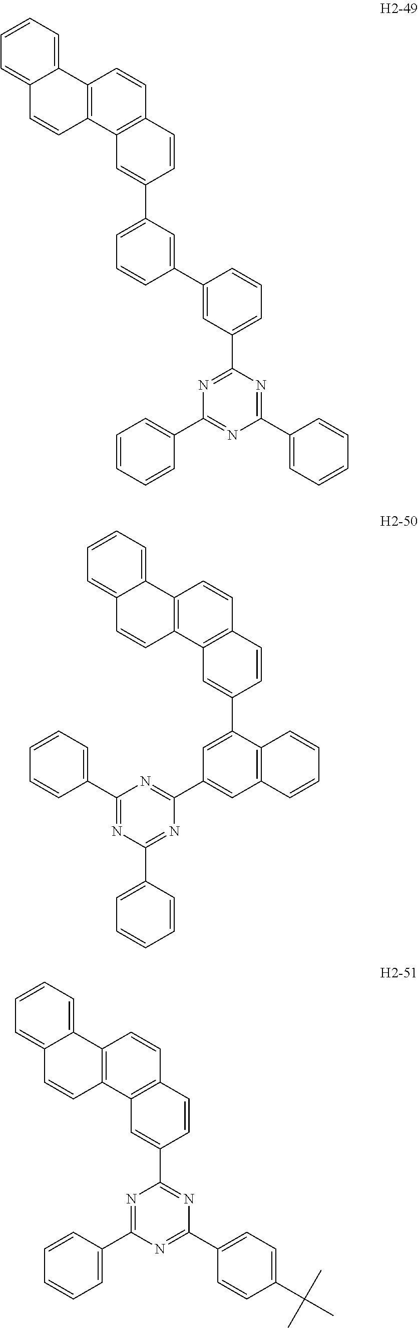 [SMILES: c1ccc(-c2nc(-c3ccccc3)nc(-c3cccc(-c4cccc(-c5ccc6ccc7c8ccccc8ccc7c6c5)c4)c3)n2)cc1 ; c1ccc(-c2nc(-c3ccccc3)nc(-c3cc(-c4ccc5ccc6c7ccccc7ccc6c5c4)c4ccccc4c3)n2)cc1 ; CC(C)(C)c1ccc(-c2nc(-c3ccccc3)nc(-c3ccc4ccc5c6ccccc6ccc5c4c3)n2)cc1]

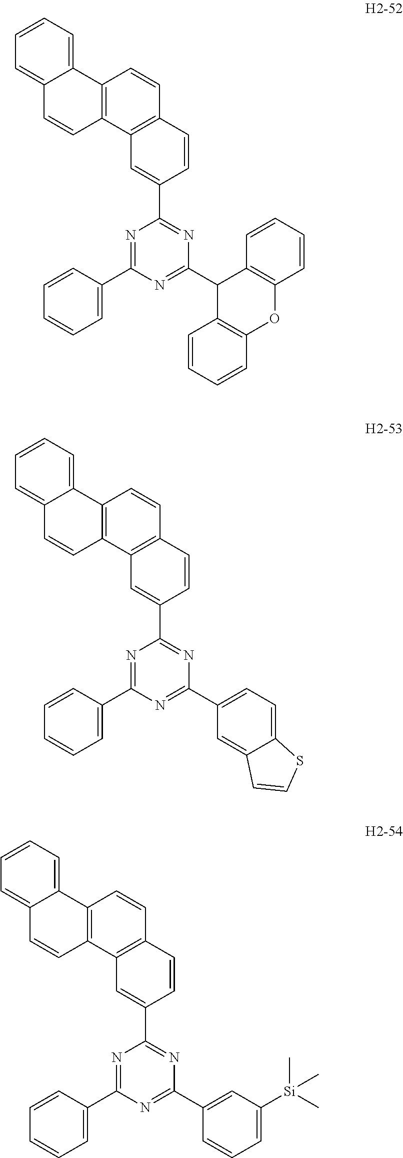 [SMILES: c1ccc(-c2nc(-c3ccc4ccc5c6ccccc6ccc5c4c3)nc(C3c4ccccc4Oc4ccccc43)n2)cc1 ; c1ccc(-c2nc(-c3ccc4sccc4c3)nc(-c3ccc4ccc5c6ccccc6ccc5c4c3)n2)cc1 ; C[Si](C)(C)c1cccc(-c2nc(-c3ccccc3)nc(-c3ccc4ccc5c6ccccc6ccc5c4c3)n2)c1]

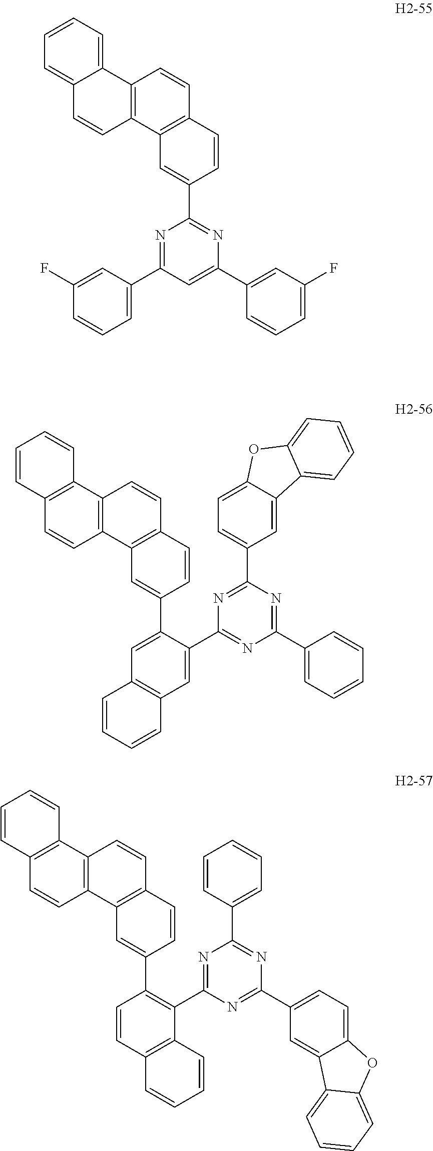 [SMILES: Fc1cccc(-c2cc(-c3cccc(F)c3)nc(-c3ccc4ccc5c6ccccc6ccc5c4c3)n2)c1 ; c1ccc(-c2nc(-c3ccc4oc5ccccc5c4c3)nc(-c3cc4ccccc4cc3-c3ccc4ccc5c6ccccc6ccc5c4c3)n2)cc1 ; c1ccc(-c2nc(-c3ccc4oc5ccccc5c4c3)nc(-c3c(-c4ccc5ccc6c7ccccc7ccc6c5c4)ccc4ccccc34)n2)cc1]

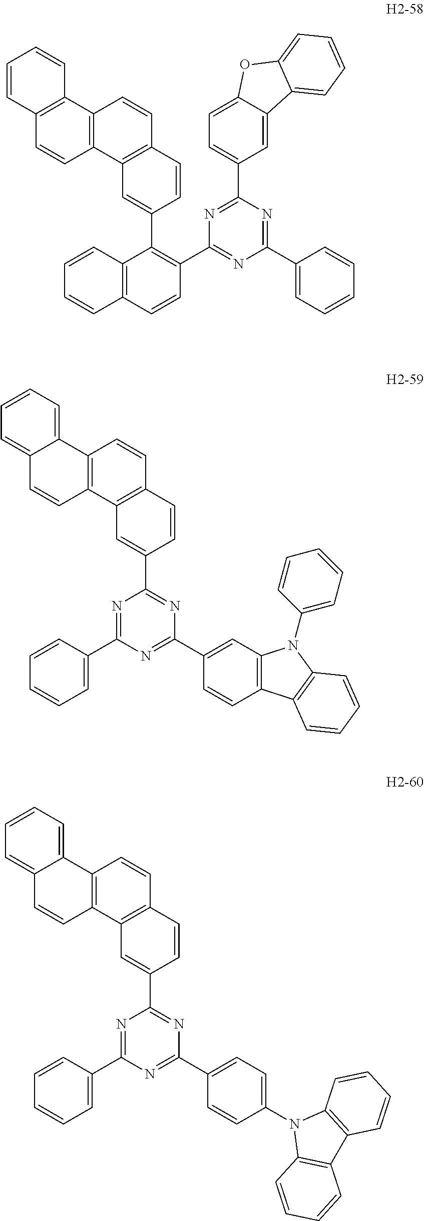 [SMILES: c1ccc(-c2nc(-c3ccc4oc5ccccc5c4c3)nc(-c3ccc4ccccc4c3-c3ccc4ccc5c6ccccc6ccc5c4c3)n2)cc1 ; c1ccc(-c2nc(-c3ccc4ccc5c6ccccc6ccc5c4c3)nc(-c3ccc4c5ccccc5n(-c5ccccc5)c4c3)n2)cc1 ; c1ccc(-c2nc(-c3ccc(-n4c5ccccc5c5ccccc54)cc3)nc(-c3ccc4ccc5c6ccccc6ccc5c4c3)n2)cc1]

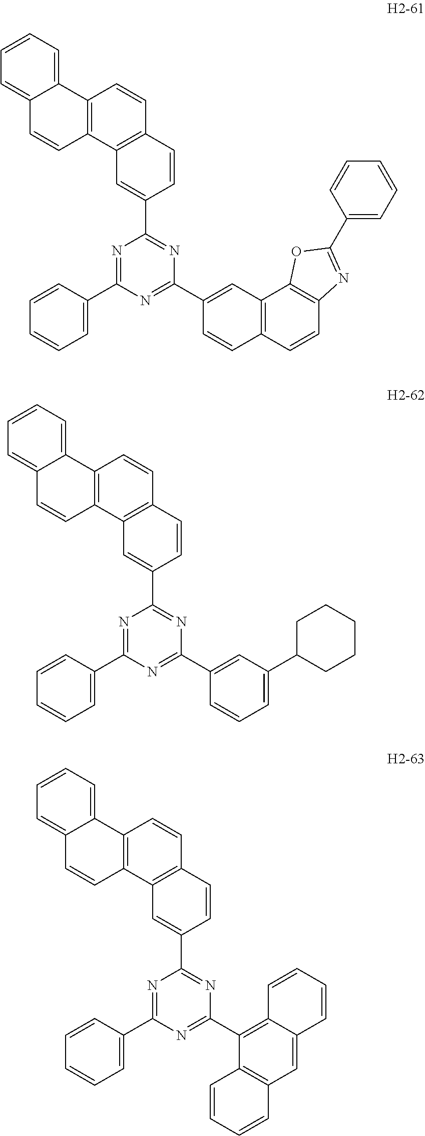 [SMILES: c1ccc(-c2nc(-c3ccc4ccc5c6ccccc6ccc5c4c3)nc(-c3ccc4ccc5nc(-c6ccccc6)oc5c4c3)n2)cc1 ; c1ccc(-c2nc(-c3cccc(C4CCCCC4)c3)nc(-c3ccc4ccc5c6ccccc6ccc5c4c3)n2)cc1 ; c1ccc(-c2nc(-c3ccc4ccc5c6ccccc6ccc5c4c3)nc(-c3c4ccccc4cc4ccccc34)n2)cc1]

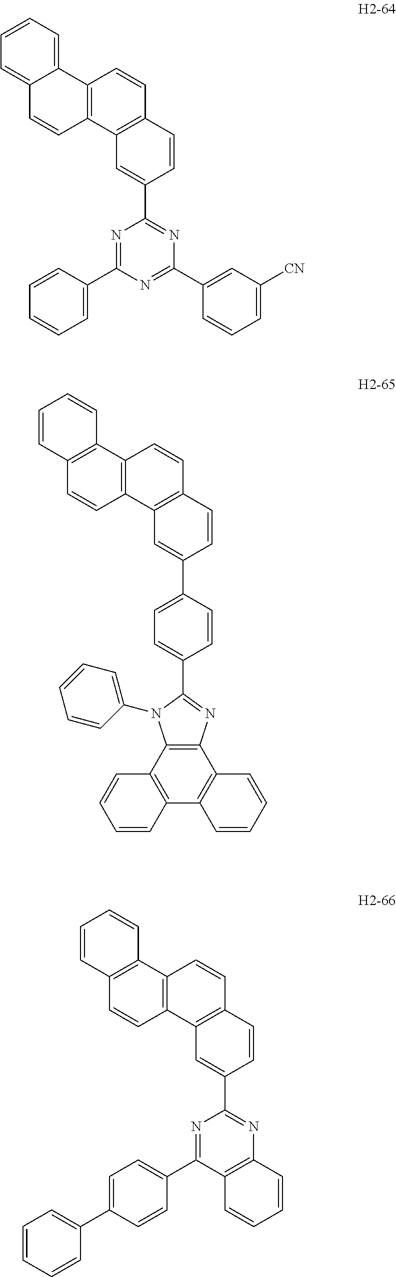 [SMILES: N#Cc1cccc(-c2nc(-c3ccccc3)nc(-c3ccc4ccc5c6ccccc6ccc5c4c3)n2)c1 ; c1ccc(-n2c(-c3ccc(-c4ccc5ccc6c7ccccc7ccc6c5c4)cc3)nc3c4ccccc4c4ccccc4c32)cc1 ; c1ccc(-c2ccc(-c3nc(-c4ccc5ccc6c7ccccc7ccc6c5c4)nc4ccccc34)cc2)cc1]

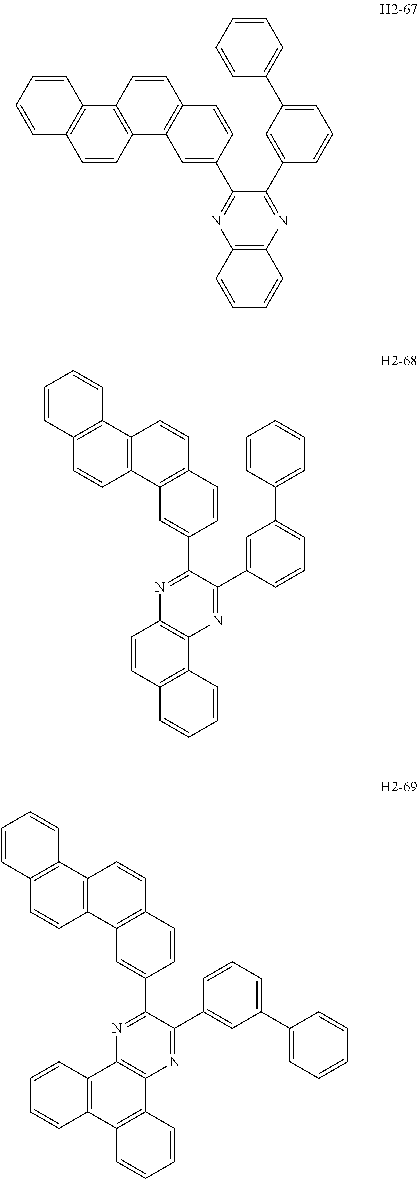 [SMILES: c1ccc(-c2cccc(-c3nc4ccccc4nc3-c3ccc4ccc5c6ccccc6ccc5c4c3)c2)cc1 ; c1ccc(-c2cccc(-c3nc4c(ccc5ccccc54)nc3-c3ccc4ccc5c6ccccc6ccc5c4c3)c2)cc1 ; c1ccc(-c2cccc(-c3nc4c5ccccc5c5ccccc5c4nc3-c3ccc4ccc5c6ccccc6ccc5c4c3)c2)cc1]

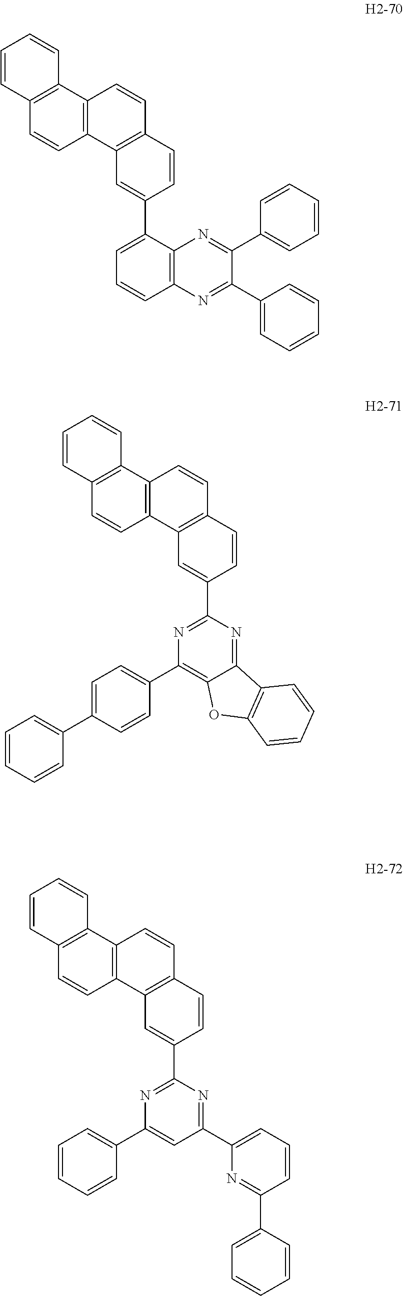 [SMILES: c1ccc(-c2nc3cccc(-c4ccc5ccc6c7ccccc7ccc6c5c4)c3nc2-c2ccccc2)cc1 ; c1ccc(-c2ccc(-c3nc(-c4ccc5ccc6c7ccccc7ccc6c5c4)nc4c3oc3ccccc34)cc2)cc1 ; c1ccc(-c2cccc(-c3cc(-c4ccccc4)nc(-c4ccc5ccc6c7ccccc7ccc6c5c4)n3)n2)cc1]

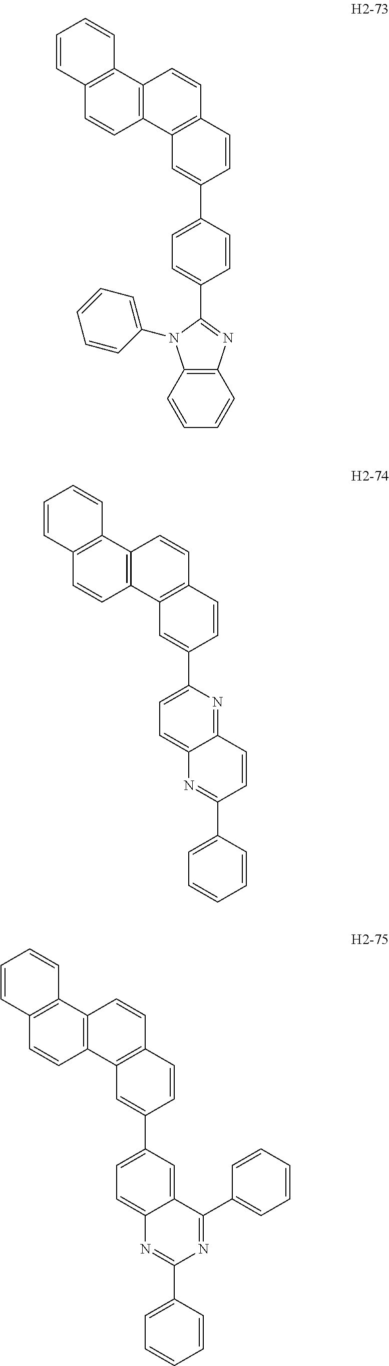 [SMILES: c1ccc(-n2c(-c3ccc(-c4ccc5ccc6c7ccccc7ccc6c5c4)cc3)nc3ccccc32)cc1 ; c1ccc(-c2ccc3nc(-c4ccc5ccc6c7ccccc7ccc6c5c4)ccc3n2)cc1 ; c1ccc(-c2nc(-c3ccccc3)c3cc(-c4ccc5ccc6c7ccccc7ccc6c5c4)ccc3n2)cc1]

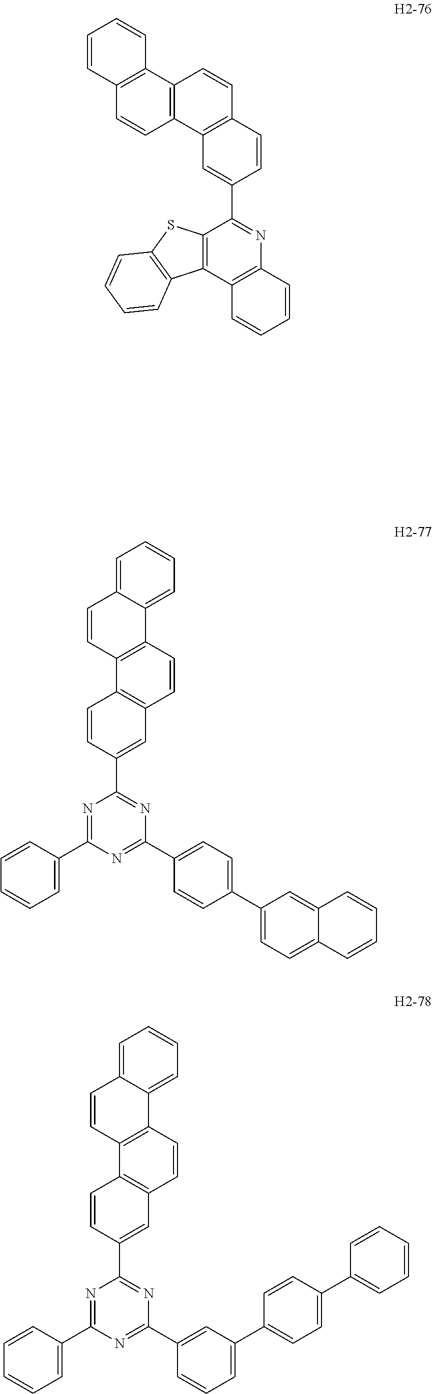 [SMILES: c1ccc2c(c1)ccc1c3cc(-c4nc5ccccc5c5c4sc4ccccc45)ccc3ccc21 ; c1ccc(-c2nc(-c3ccc(-c4ccc5ccccc5c4)cc3)nc(-c3ccc4c(ccc5c6ccccc6ccc45)c3)n2)cc1 ; c1ccc(-c2ccc(-c3cccc(-c4nc(-c5ccccc5)nc(-c5ccc6c(ccc7c8ccccc8ccc67)c5)n4)c3)cc2)cc1]

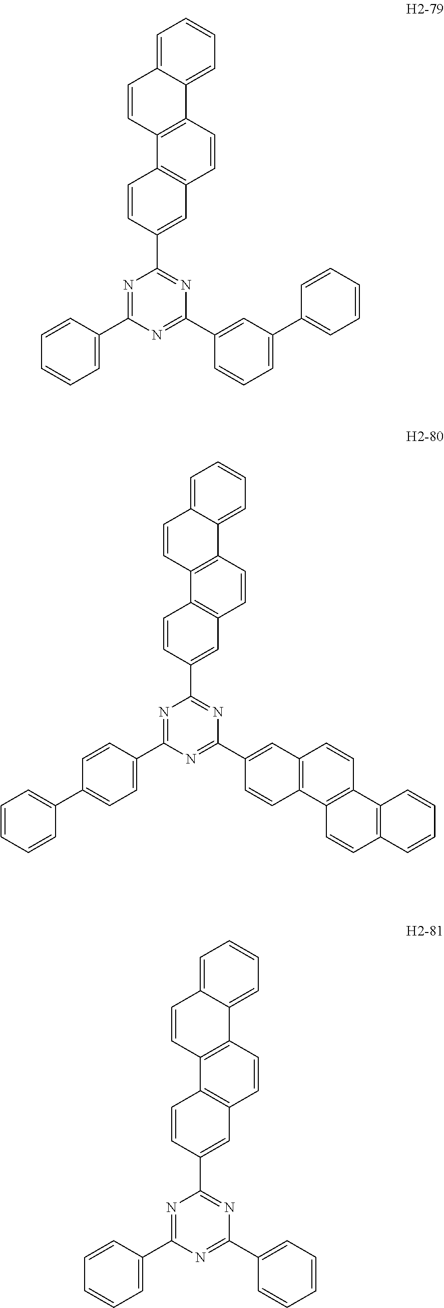 [SMILES: c1ccc(-c2cccc(-c3nc(-c4ccccc4)nc(-c4ccc5c(ccc6c7ccccc7ccc56)c4)n3)c2)cc1 ; c1ccc(-c2ccc(-c3nc(-c4ccc5c(ccc6c7ccccc7ccc56)c4)nc(-c4ccc5c(ccc6c7ccccc7ccc56)c4)n3)cc2)cc1 ; c1ccc(-c2nc(-c3ccccc3)nc(-c3ccc4c(ccc5c6ccccc6ccc45)c3)n2)cc1]

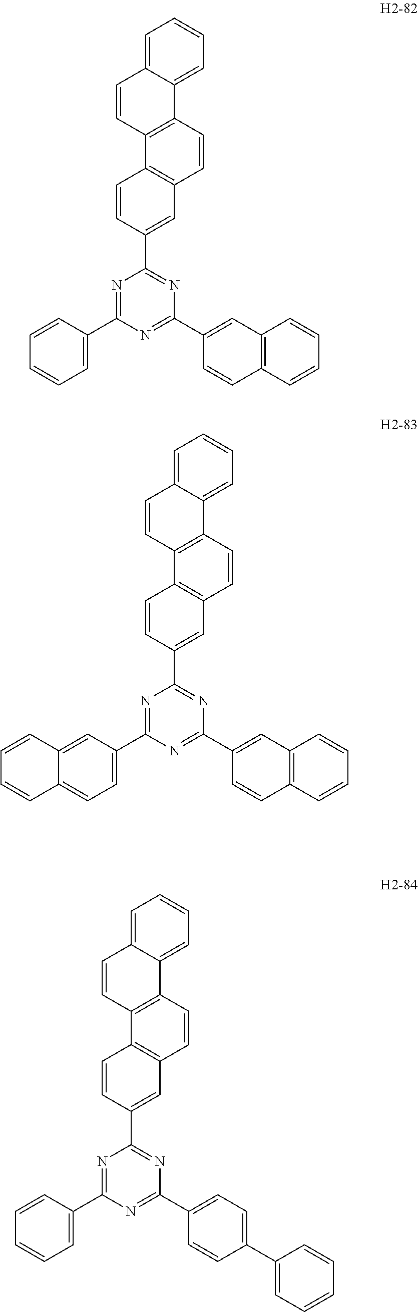 [SMILES: c1ccc(-c2nc(-c3ccc4ccccc4c3)nc(-c3ccc4c(ccc5c6ccccc6ccc45)c3)n2)cc1 ; c1ccc2cc(-c3nc(-c4ccc5ccccc5c4)nc(-c4ccc5c(ccc6c7ccccc7ccc56)c4)n3)ccc2c1 ; c1ccc(-c2ccc(-c3nc(-c4ccccc4)nc(-c4ccc5c(ccc6c7ccccc7ccc56)c4)n3)cc2)cc1]

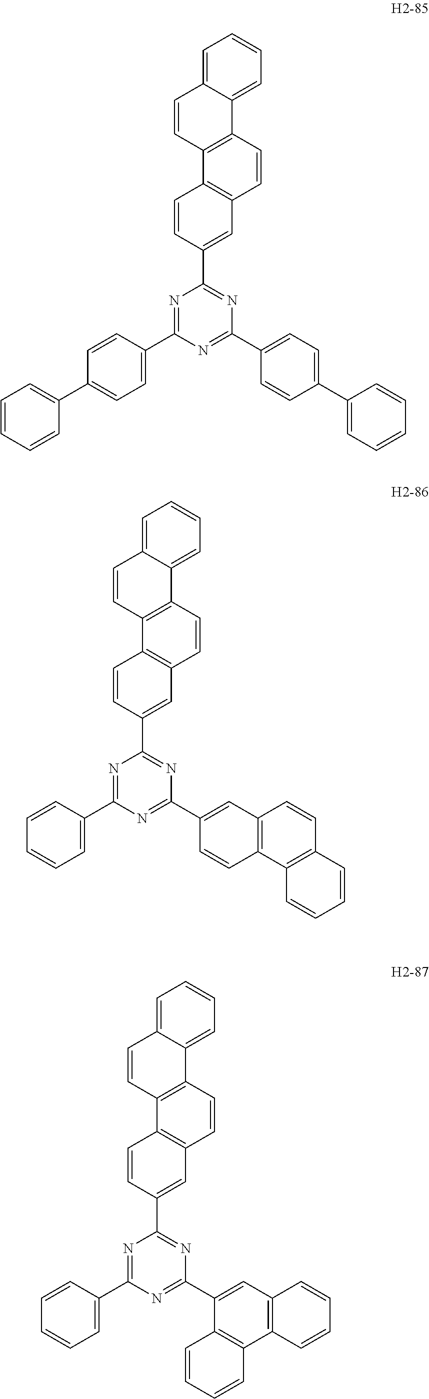 [SMILES: c1ccc(-c2ccc(-c3nc(-c4ccc(-c5ccccc5)cc4)nc(-c4ccc5c(ccc6c7ccccc7ccc56)c4)n3)cc2)cc1 ; c1ccc(-c2nc(-c3ccc4c(ccc5ccccc54)c3)nc(-c3ccc4c(ccc5c6ccccc6ccc45)c3)n2)cc1 ; c1ccc(-c2nc(-c3ccc4c(ccc5c6ccccc6ccc45)c3)nc(-c3cc4ccccc4c4ccccc34)n2)cc1]

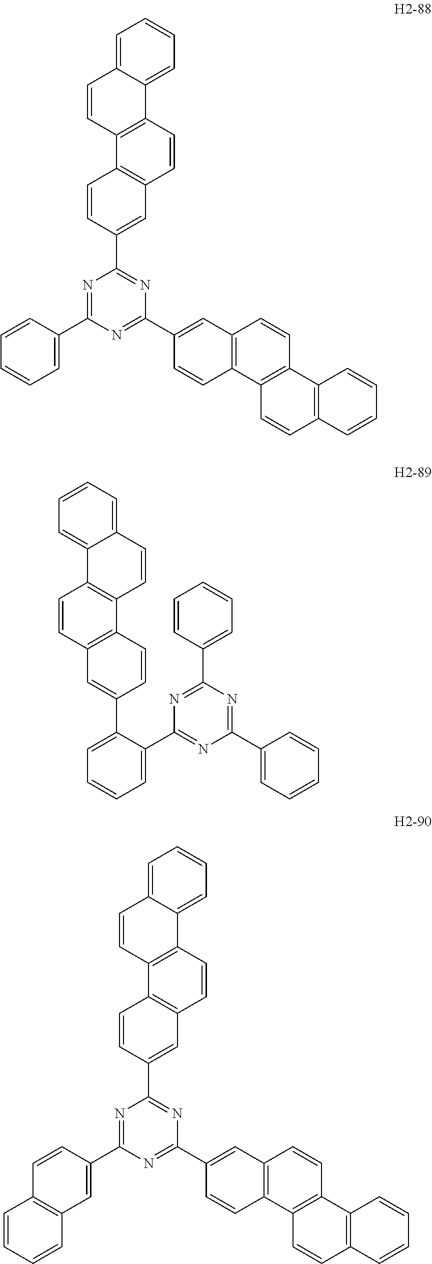 [SMILES: c1ccc(-c2nc(-c3ccc4c(ccc5c6ccccc6ccc45)c3)nc(-c3ccc4c(ccc5c6ccccc6ccc45)c3)n2)cc1 ; c1ccc(-c2nc(-c3ccccc3)nc(-c3ccccc3-c3ccc4c(ccc5c6ccccc6ccc45)c3)n2)cc1 ; c1ccc2cc(-c3nc(-c4ccc5c(ccc6c7ccccc7ccc56)c4)nc(-c4ccc5c(ccc6c7ccccc7ccc56)c4)n3)ccc2c1]

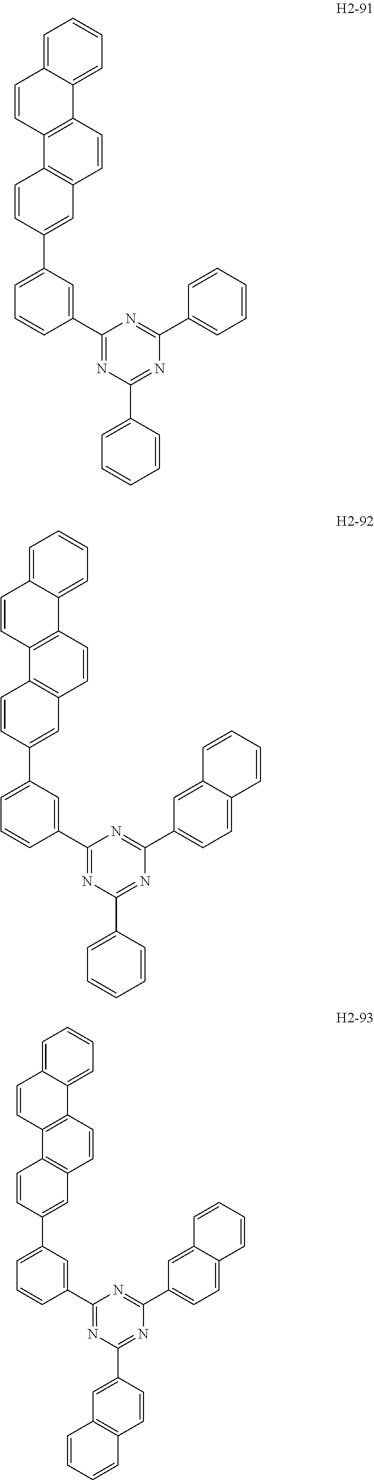 [SMILES: c1ccc(-c2nc(-c3ccccc3)nc(-c3cccc(-c4ccc5c(ccc6c7ccccc7ccc56)c4)c3)n2)cc1 ; c1ccc(-c2nc(-c3cccc(-c4ccc5c(ccc6c7ccccc7ccc56)c4)c3)nc(-c3ccc4ccccc4c3)n2)cc1 ; c1cc(-c2ccc3c(ccc4c5ccccc5ccc34)c2)cc(-c2nc(-c3ccc4ccccc4c3)nc(-c3ccc4ccccc4c3)n2)c1]

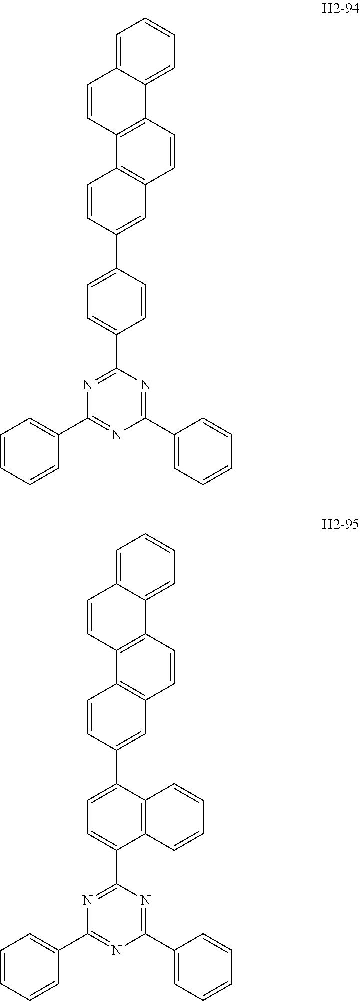 [SMILES: c1ccc(-c2nc(-c3ccccc3)nc(-c3ccc(-c4ccc5c(ccc6c7ccccc7ccc56)c4)cc3)n2)cc1 ; c1ccc(-c2nc(-c3ccccc3)nc(-c3ccc(-c4ccc5c(ccc6c7ccccc7ccc56)c4)c4ccccc34)n2)cc1]

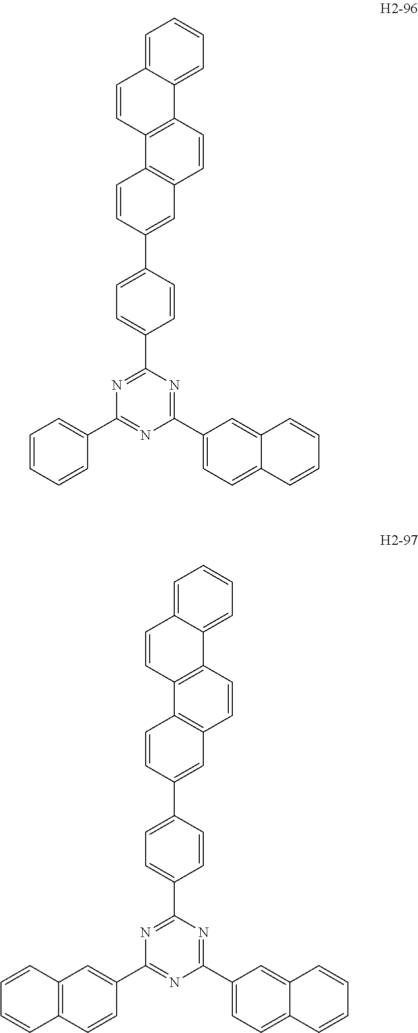 [SMILES: c1ccc(-c2nc(-c3ccc(-c4ccc5c(ccc6c7ccccc7ccc56)c4)cc3)nc(-c3ccc4ccccc4c3)n2)cc1 ; c1ccc2cc(-c3nc(-c4ccc(-c5ccc6c(ccc7c8ccccc8ccc67)c5)cc4)nc(-c4ccc5ccccc5c4)n3)ccc2c1]

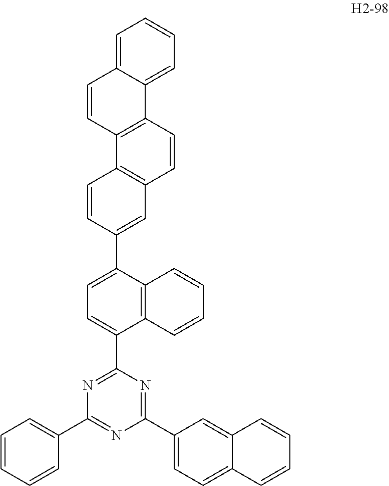 [SMILES: c1ccc(-c2nc(-c3ccc4ccccc4c3)nc(-c3ccc(-c4ccc5c(ccc6c7ccccc7ccc56)c4)c4ccccc34)n2)cc1]

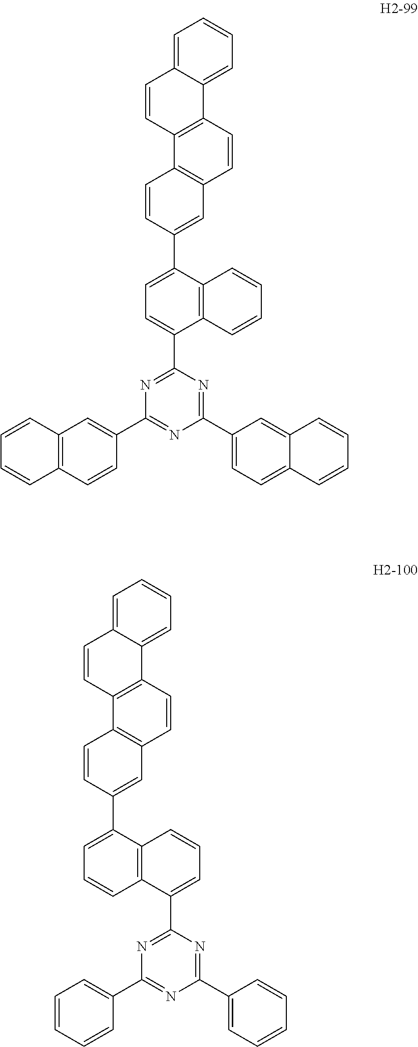 [SMILES: c1ccc2cc(-c3nc(-c4ccc5ccccc5c4)nc(-c4ccc(-c5ccc6c(ccc7c8ccccc8ccc67)c5)c5ccccc45)n3)ccc2c1 ; c1ccc(-c2nc(-c3ccccc3)nc(-c3cccc4c(-c5ccc6c(ccc7c8ccccc8ccc67)c5)cccc34)n2)cc1]

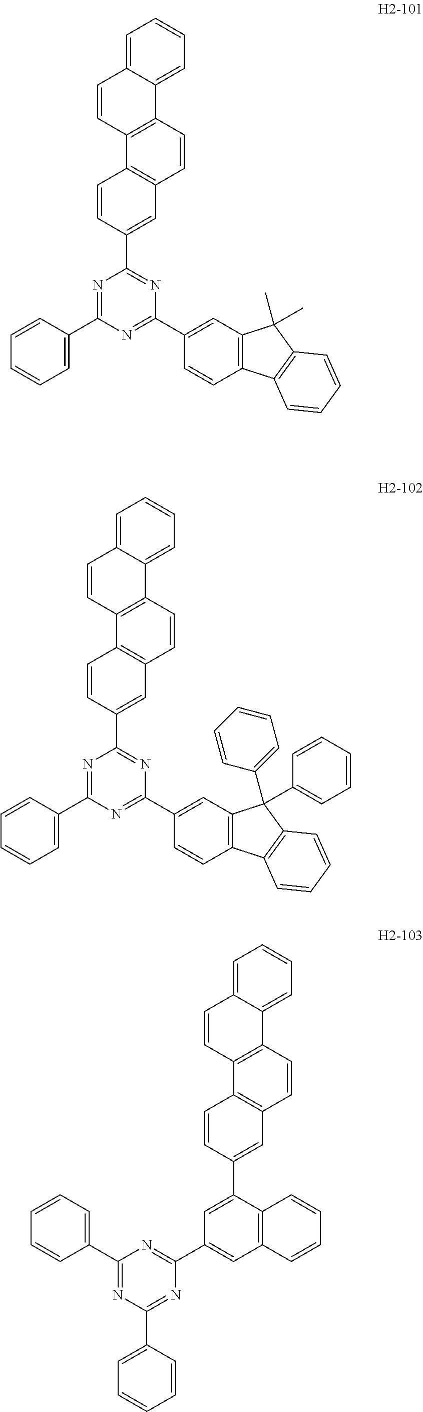 [SMILES: CC1(C)c2ccccc2-c2ccc(-c3nc(-c4ccccc4)nc(-c4ccc5c(ccc6c7ccccc7ccc56)c4)n3)cc21 ; c1ccc(-c2nc(-c3ccc4c(c3)C(c3ccccc3)(c3ccccc3)c3ccccc3-4)nc(-c3ccc4c(ccc5c6ccccc6ccc45)c3)n2)cc1 ; c1ccc(-c2nc(-c3ccccc3)nc(-c3cc(-c4ccc5c(ccc6c7ccccc7ccc56)c4)c4ccccc4c3)n2)cc1]

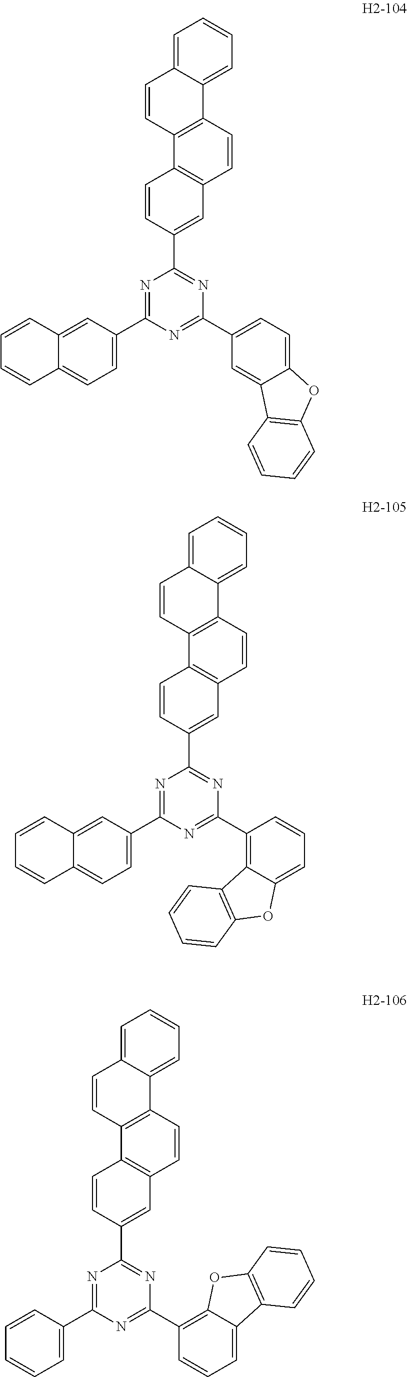 [SMILES: c1ccc2cc(-c3nc(-c4ccc5c(ccc6c7ccccc7ccc56)c4)nc(-c4ccc5oc6ccccc6c5c4)n3)ccc2c1 ; c1ccc2cc(-c3nc(-c4ccc5c(ccc6c7ccccc7ccc56)c4)nc(-c4cccc5oc6ccccc6c45)n3)ccc2c1 ; c1ccc(-c2nc(-c3ccc4c(ccc5c6ccccc6ccc45)c3)nc(-c3cccc4c3oc3ccccc34)n2)cc1]

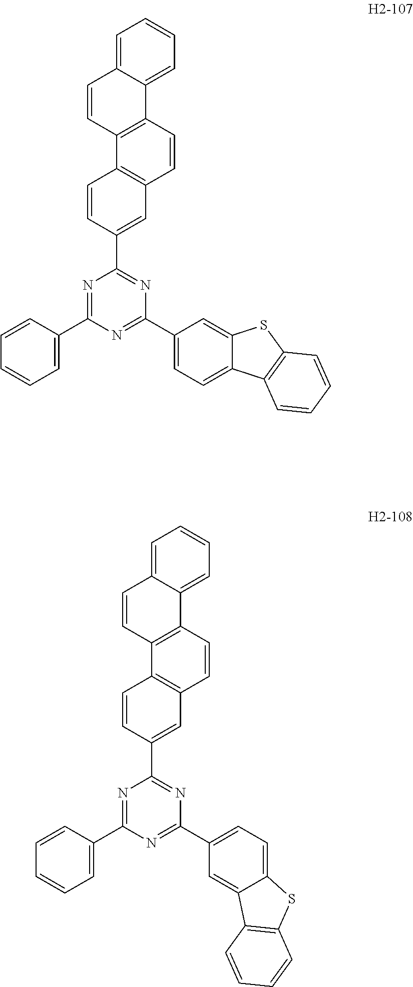 [SMILES: c1ccc(-c2nc(-c3ccc4c(ccc5c6ccccc6ccc45)c3)nc(-c3ccc4c(c3)sc3ccccc34)n2)cc1 ; c1ccc(-c2nc(-c3ccc4c(ccc5c6ccccc6ccc45)c3)nc(-c3ccc4sc5ccccc5c4c3)n2)cc1]

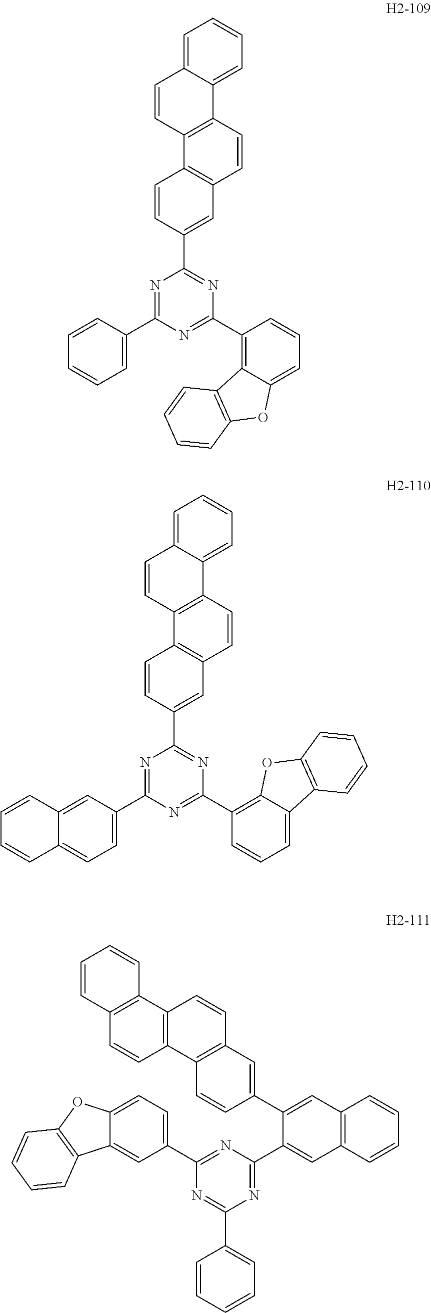 [SMILES: c1ccc(-c2nc(-c3ccc4c(ccc5c6ccccc6ccc45)c3)nc(-c3cccc4oc5ccccc5c34)n2)cc1 ; c1ccc2cc(-c3nc(-c4ccc5c(ccc6c7ccccc7ccc56)c4)nc(-c4cccc5c4oc4ccccc45)n3)ccc2c1 ; c1ccc(-c2nc(-c3ccc4oc5ccccc5c4c3)nc(-c3cc4ccccc4cc3-c3ccc4c(ccc5c6ccccc6ccc45)c3)n2)cc1]

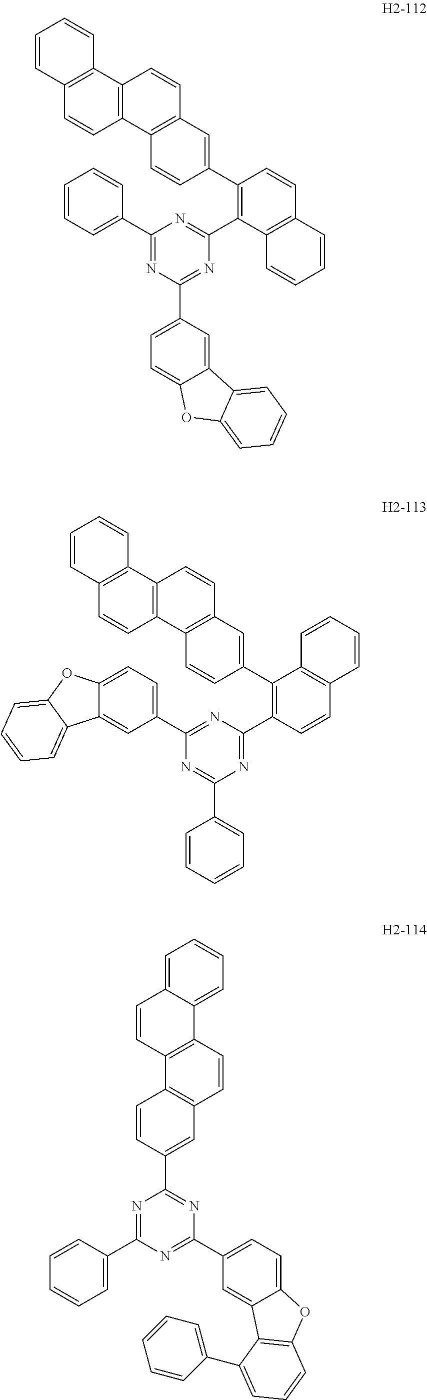 [SMILES: c1ccc(-c2nc(-c3ccc4oc5ccccc5c4c3)nc(-c3c(-c4ccc5c(ccc6c7ccccc7ccc56)c4)ccc4ccccc34)n2)cc1 ; c1ccc(-c2nc(-c3ccc4oc5ccccc5c4c3)nc(-c3ccc4ccccc4c3-c3ccc4c(ccc5c6ccccc6ccc45)c3)n2)cc1 ; c1ccc(-c2nc(-c3ccc4c(ccc5c6ccccc6ccc45)c3)nc(-c3ccc4oc5cccc(-c6ccccc6)c5c4c3)n2)cc1]

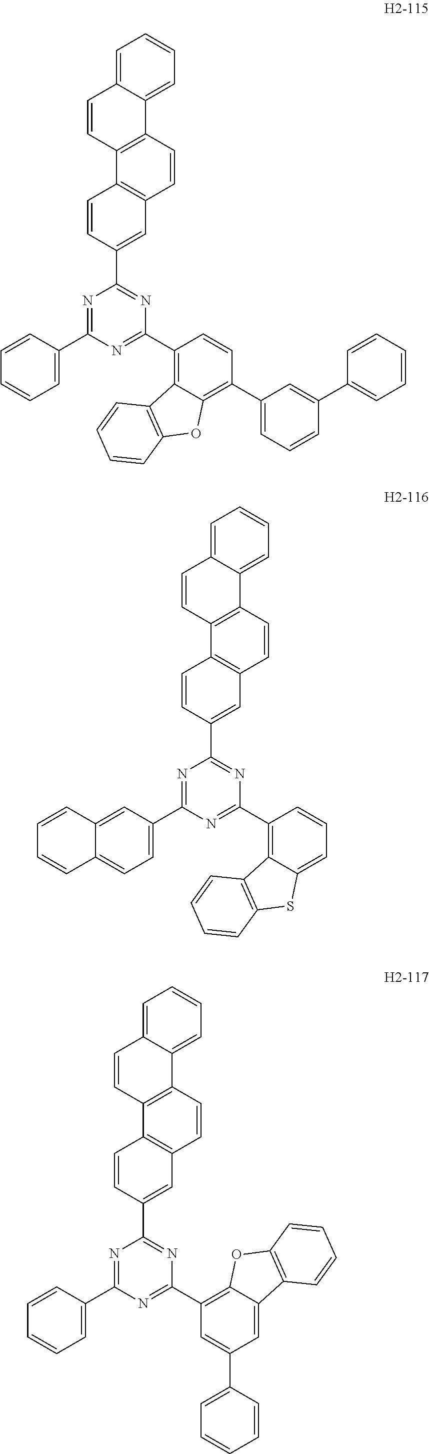 [SMILES: c1ccc(-c2cccc(-c3ccc(-c4nc(-c5ccccc5)nc(-c5ccc6c(ccc7c8ccccc8ccc67)c5)n4)c4c3oc3ccccc34)c2)cc1 ; c1ccc2cc(-c3nc(-c4ccc5c(ccc6c7ccccc7ccc56)c4)nc(-c4cccc5sc6ccccc6c45)n3)ccc2c1 ; c1ccc(-c2cc(-c3nc(-c4ccccc4)nc(-c4ccc5c(ccc6c7ccccc7ccc56)c4)n3)c3oc4ccccc4c3c2)cc1]

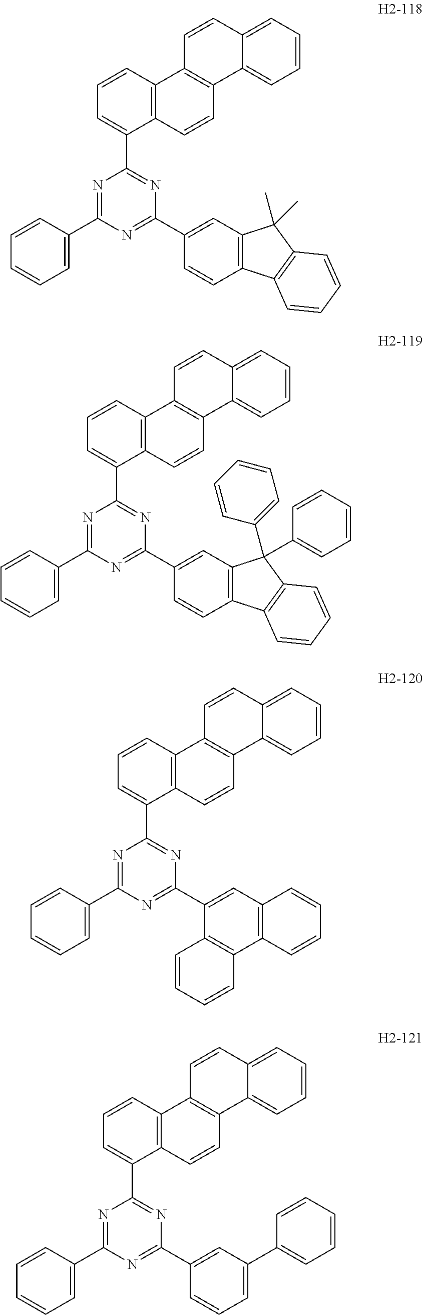

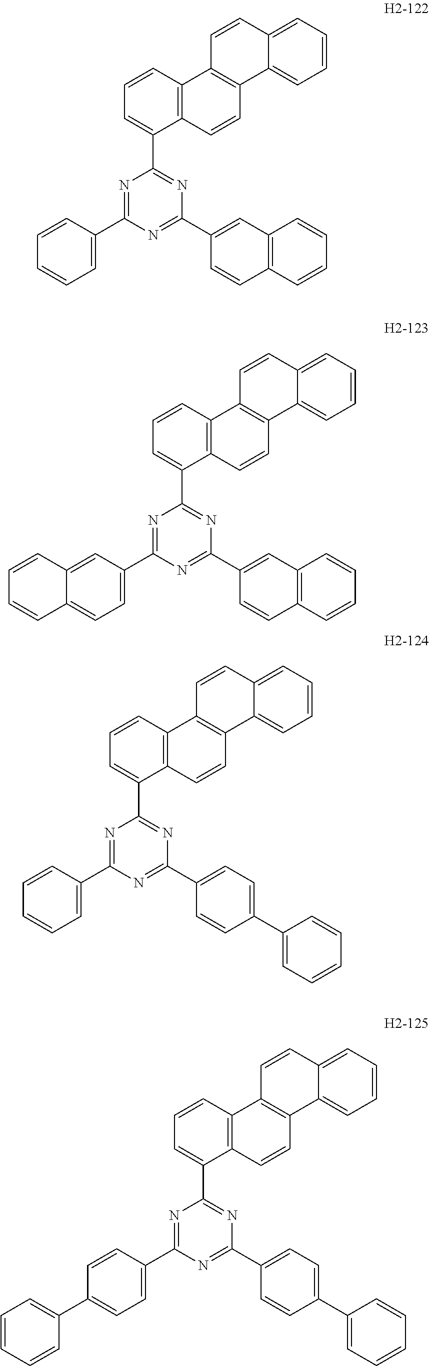 [SMILES: c1ccc(-c2nc(-c3ccc4ccccc4c3)nc(-c3cccc4c3ccc3c5ccccc5ccc43)n2)cc1 ; c1ccc2cc(-c3nc(-c4ccc5ccccc5c4)nc(-c4cccc5c4ccc4c6ccccc6ccc54)n3)ccc2c1 ; c1ccc(-c2ccc(-c3nc(-c4ccccc4)nc(-c4cccc5c4ccc4c6ccccc6ccc54)n3)cc2)cc1 ; c1ccc(-c2ccc(-c3nc(-c4ccc(-c5ccccc5)cc4)nc(-c4cccc5c4ccc4c6ccccc6ccc54)n3)cc2)cc1]

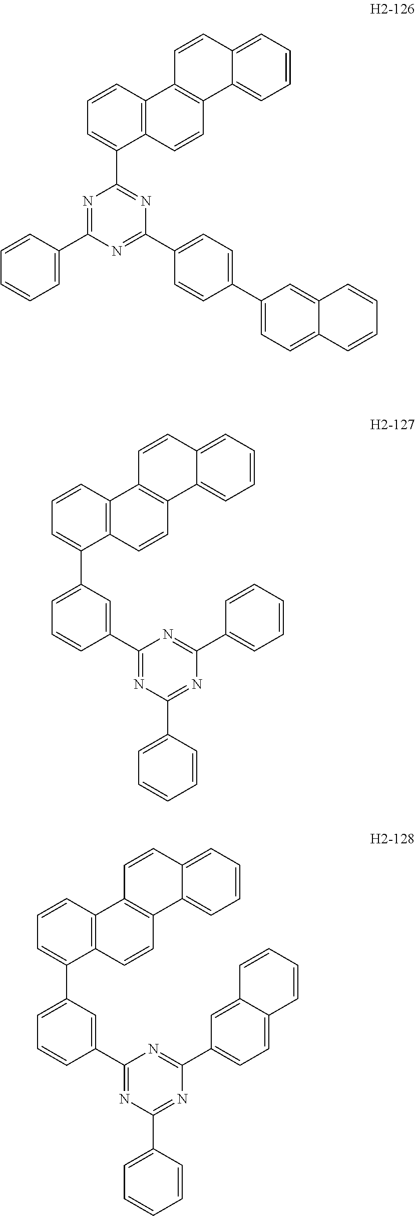 [SMILES: c1ccc(-c2nc(-c3ccc(-c4ccc5ccccc5c4)cc3)nc(-c3cccc4c3ccc3c5ccccc5ccc43)n2)cc1 ; c1ccc(-c2nc(-c3ccccc3)nc(-c3cccc(-c4cccc5c4ccc4c6ccccc6ccc54)c3)n2)cc1 ; c1ccc(-c2nc(-c3cccc(-c4cccc5c4ccc4c6ccccc6ccc54)c3)nc(-c3ccc4ccccc4c3)n2)cc1]

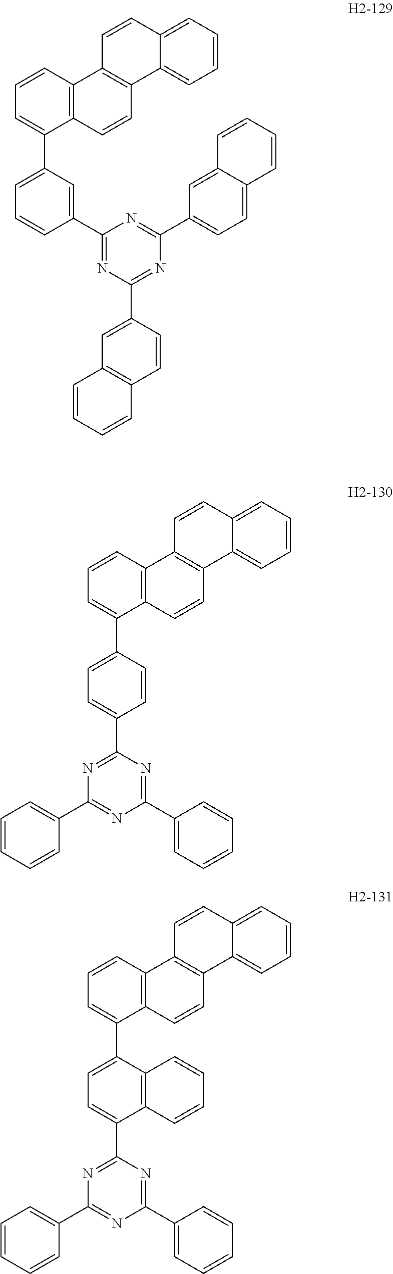

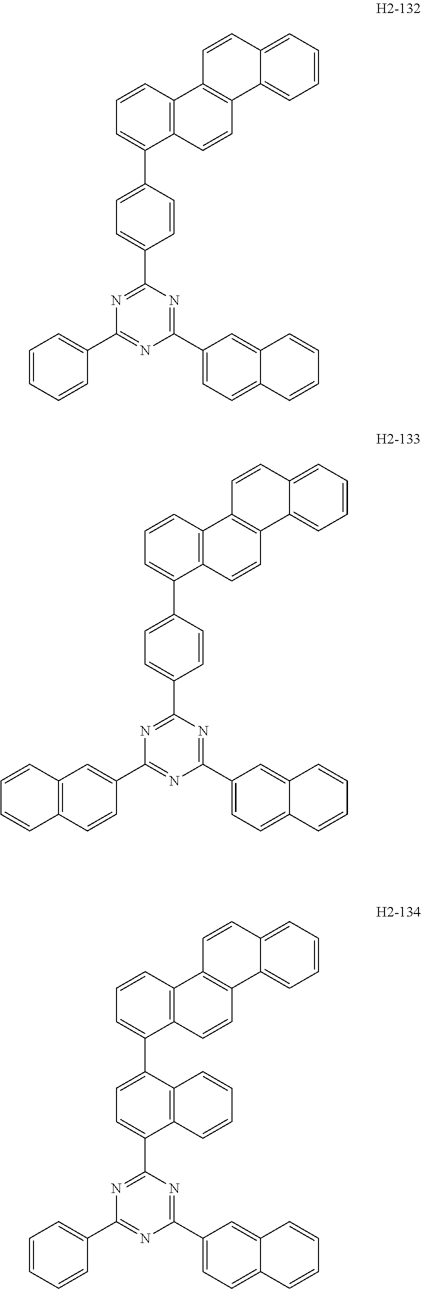 [SMILES: c1ccc(-c2nc(-c3ccc(-c4cccc5c4ccc4c6ccccc6ccc54)cc3)nc(-c3ccc4ccccc4c3)n2)cc1 ; c1ccc2cc(-c3nc(-c4ccc(-c5cccc6c5ccc5c7ccccc7ccc65)cc4)nc(-c4ccc5ccccc5c4)n3)ccc2c1 ; c1ccc(-c2nc(-c3ccc4ccccc4c3)nc(-c3ccc(-c4cccc5c4ccc4c6ccccc6ccc54)c4ccccc34)n2)cc1]

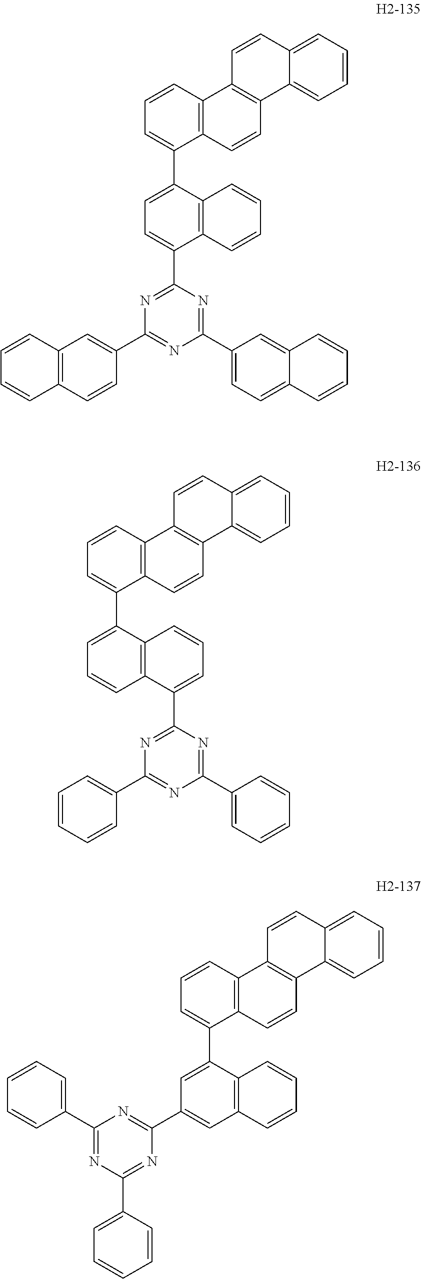 [SMILES: c1ccc2cc(-c3nc(-c4ccc5ccccc5c4)nc(-c4ccc(-c5cccc6c5ccc5c7ccccc7ccc65)c5ccccc45)n3)ccc2c1 ; c1ccc(-c2nc(-c3ccccc3)nc(-c3cccc4c(-c5cccc6c5ccc5c7ccccc7ccc65)cccc34)n2)cc1 ; c1ccc(-c2nc(-c3ccccc3)nc(-c3cc(-c4cccc5c4ccc4c6ccccc6ccc54)c4ccccc4c3)n2)cc1]

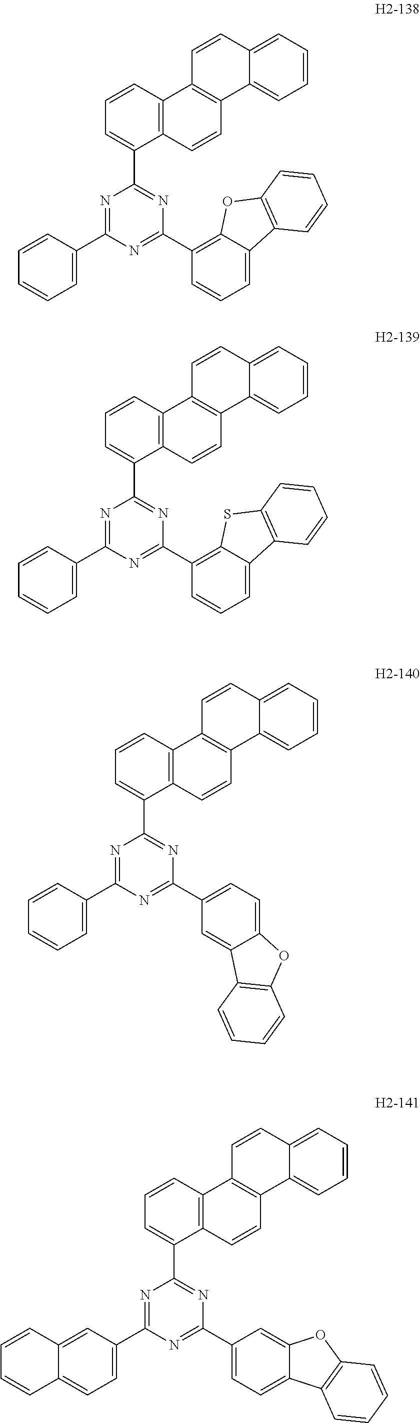

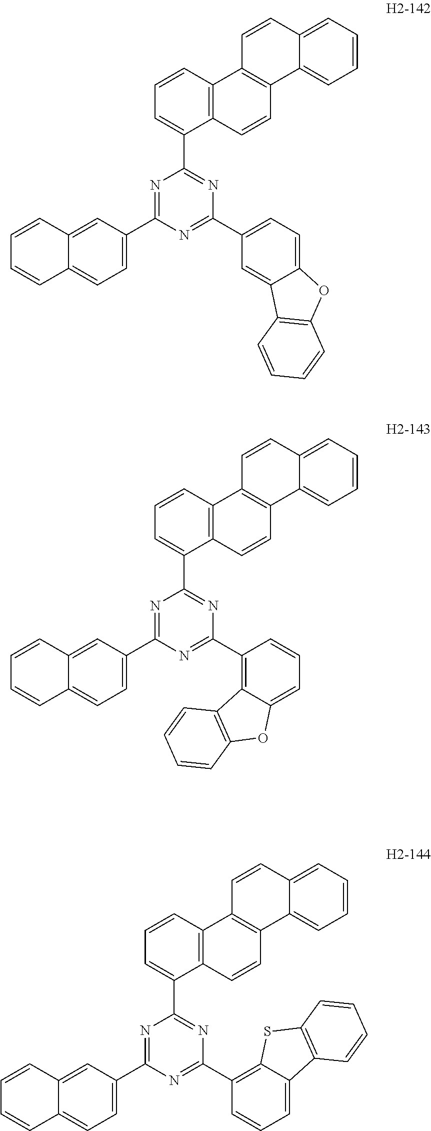 [SMILES: c1ccc2cc(-c3nc(-c4ccc5oc6ccccc6c5c4)nc(-c4cccc5c4ccc4c6ccccc6ccc54)n3)ccc2c1 ; c1ccc2cc(-c3nc(-c4cccc5c4ccc4c6ccccc6ccc54)nc(-c4cccc5oc6ccccc6c45)n3)ccc2c1 ; c1ccc2cc(-c3nc(-c4cccc5c4ccc4c6ccccc6ccc54)nc(-c4cccc5c4sc4ccccc45)n3)ccc2c1]

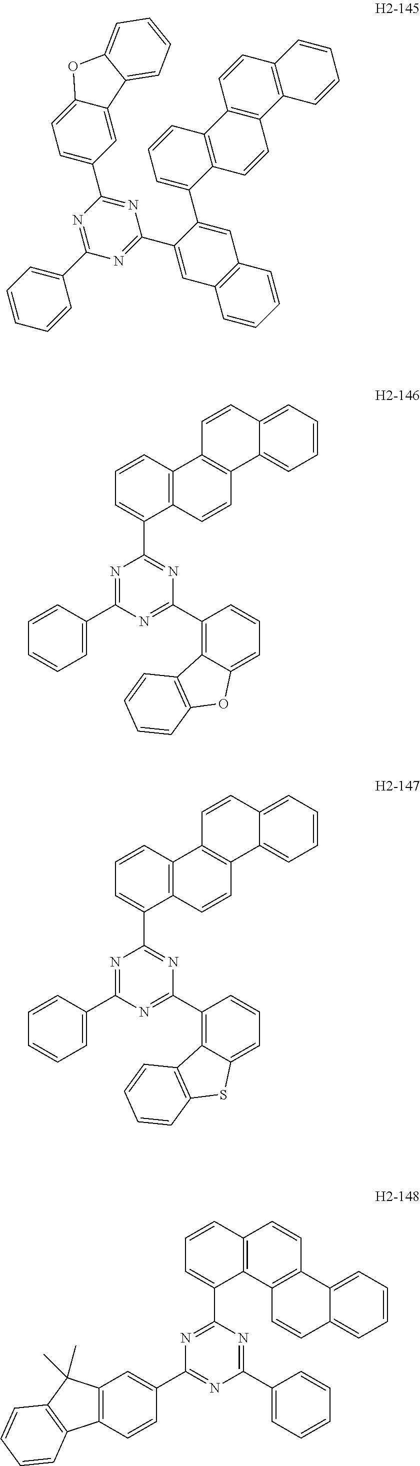 [SMILES: c1ccc(-c2nc(-c3ccc4oc5ccccc5c4c3)nc(-c3cc4ccccc4cc3-c3cccc4c3ccc3c5ccccc5ccc43)n2)cc1 ; c1ccc(-c2nc(-c3cccc4c3ccc3c5ccccc5ccc43)nc(-c3cccc4oc5ccccc5c34)n2)cc1 ; c1ccc(-c2nc(-c3cccc4c3ccc3c5ccccc5ccc43)nc(-c3cccc4sc5ccccc5c34)n2)cc1 ; CC1(C)c2ccccc2-c2ccc(-c3nc(-c4ccccc4)nc(-c4cccc5ccc6c7ccccc7ccc6c45)n3)cc21]

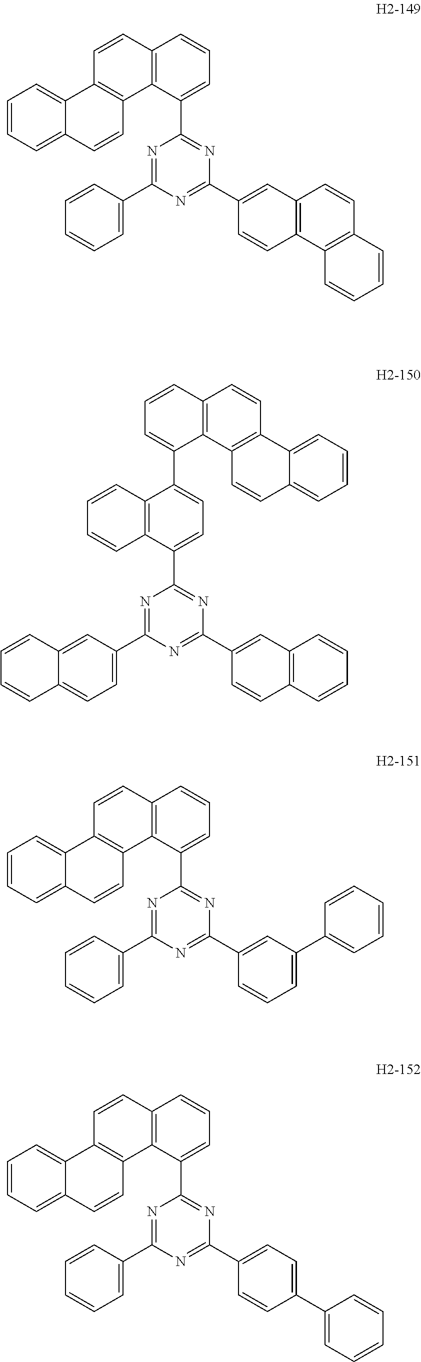 [SMILES: c1ccc(-c2nc(-c3ccc4c(ccc5ccccc54)c3)nc(-c3cccc4ccc5c6ccccc6ccc5c34)n2)cc1 ; c1ccc2cc(-c3nc(-c4ccc5ccccc5c4)nc(-c4ccc(-c5cccc6ccc7c8ccccc8ccc7c56)c5ccccc45)n3)ccc2c1 ; c1ccc(-c2cccc(-c3nc(-c4ccccc4)nc(-c4cccc5ccc6c7ccccc7ccc6c45)n3)c2)cc1 ; c1ccc(-c2ccc(-c3nc(-c4ccccc4)nc(-c4cccc5ccc6c7ccccc7ccc6c45)n3)cc2)cc1]

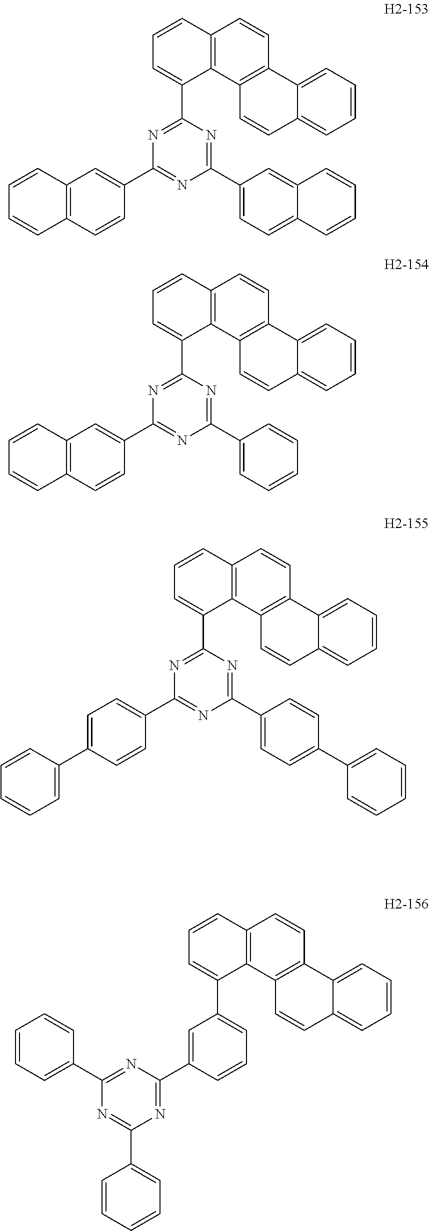 [SMILES: c1ccc2cc(-c3nc(-c4ccc5ccccc5c4)nc(-c4cccc5ccc6c7ccccc7ccc6c45)n3)ccc2c1 ; c1ccc(-c2nc(-c3ccc4ccccc4c3)nc(-c3cccc4ccc5c6ccccc6ccc5c34)n2)cc1 ; c1ccc(-c2ccc(-c3nc(-c4ccc(-c5ccccc5)cc4)nc(-c4cccc5ccc6c7ccccc7ccc6c45)n3)cc2)cc1 ; c1ccc(-c2nc(-c3ccccc3)nc(-c3cccc(-c4cccc5ccc6c7ccccc7ccc6c45)c3)n2)cc1]

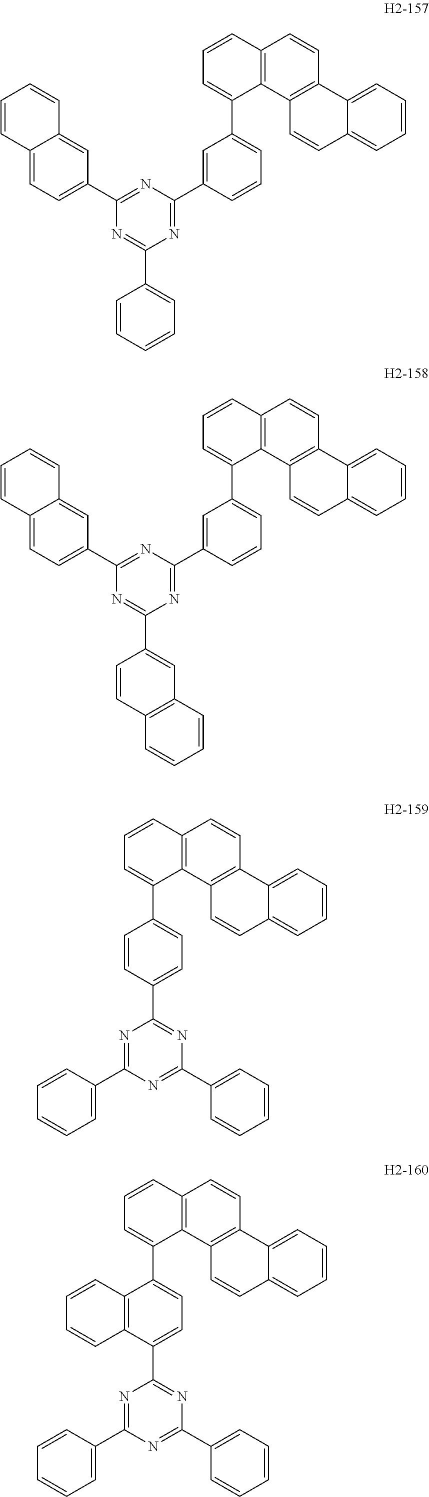 [SMILES: c1ccc(-c2nc(-c3cccc(-c4cccc5ccc6c7ccccc7ccc6c45)c3)nc(-c3ccc4ccccc4c3)n2)cc1 ; c1cc(-c2nc(-c3ccc4ccccc4c3)nc(-c3ccc4ccccc4c3)n2)cc(-c2cccc3ccc4c5ccccc5ccc4c23)c1 ; c1ccc(-c2nc(-c3ccccc3)nc(-c3ccc(-c4cccc5ccc6c7ccccc7ccc6c45)cc3)n2)cc1 ; c1ccc(-c2nc(-c3ccccc3)nc(-c3ccc(-c4cccc5ccc6c7ccccc7ccc6c45)c4ccccc34)n2)cc1]

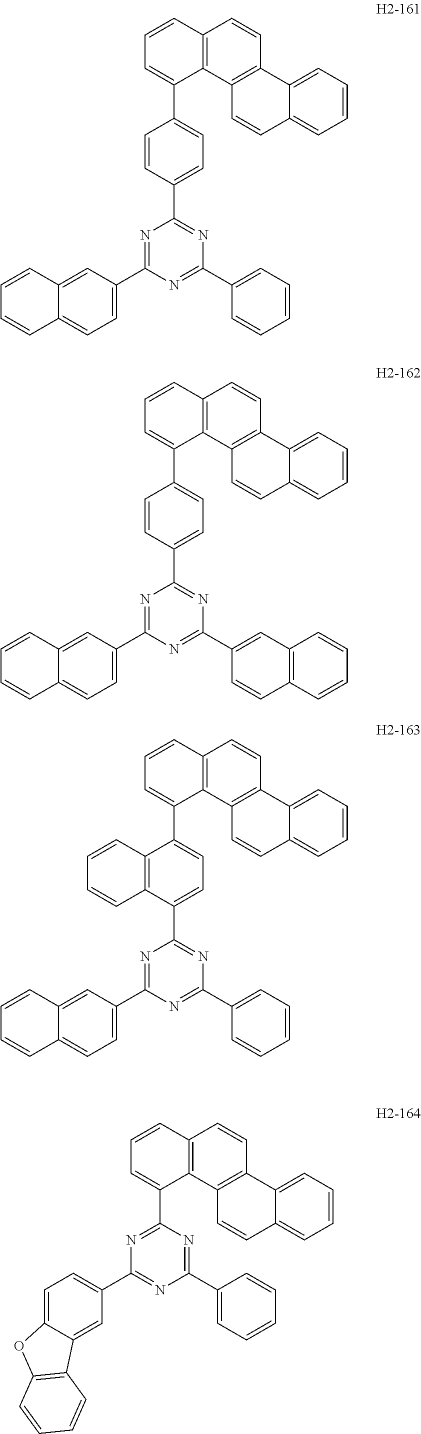 [SMILES: c1ccc(-c2nc(-c3ccc(-c4cccc5ccc6c7ccccc7ccc6c45)cc3)nc(-c3ccc4ccccc4c3)n2)cc1 ; c1ccc2cc(-c3nc(-c4ccc(-c5cccc6ccc7c8ccccc8ccc7c56)cc4)nc(-c4ccc5ccccc5c4)n3)ccc2c1 ; c1ccc(-c2nc(-c3ccc4ccccc4c3)nc(-c3ccc(-c4cccc5ccc6c7ccccc7ccc6c45)c4ccccc34)n2)cc1 ; c1ccc(-c2nc(-c3ccc4oc5ccccc5c4c3)nc(-c3cccc4ccc5c6ccccc6ccc5c34)n2)cc1]

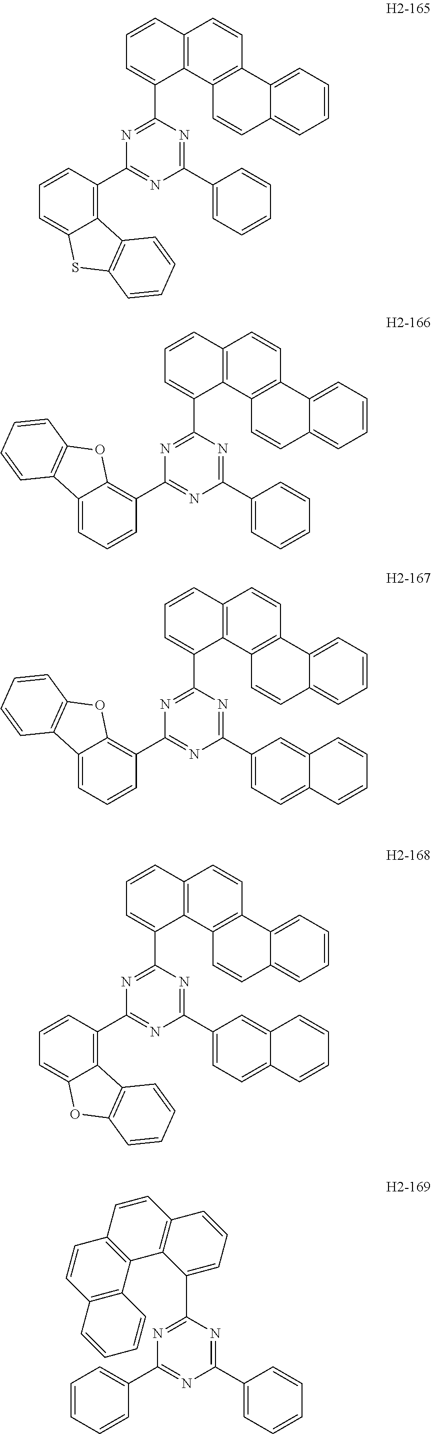 [SMILES: c1ccc(-c2nc(-c3cccc4ccc5c6ccccc6ccc5c34)nc(-c3cccc4sc5ccccc5c34)n2)cc1 ; c1ccc(-c2nc(-c3cccc4c3oc3ccccc34)nc(-c3cccc4ccc5c6ccccc6ccc5c34)n2)cc1 ; c1ccc2cc(-c3nc(-c4cccc5c4oc4ccccc45)nc(-c4cccc5ccc6c7ccccc7ccc6c45)n3)ccc2c1 ; c1ccc2cc(-c3nc(-c4cccc5ccc6c7ccccc7ccc6c45)nc(-c4cccc5oc6ccccc6c45)n3)ccc2c1 ; c1ccc(-c2nc(-c3ccccc3)nc(-c3cccc4ccc5ccc6ccccc6c5c34)n2)cc1]

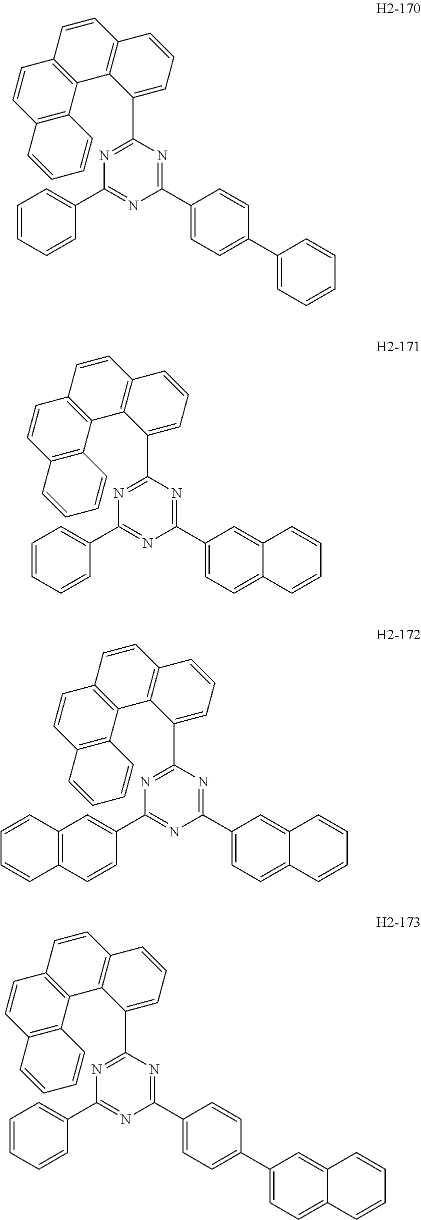 [SMILES: c1ccc(-c2ccc(-c3nc(-c4ccccc4)nc(-c4cccc5ccc6ccc7ccccc7c6c45)n3)cc2)cc1 ; c1ccc(-c2nc(-c3ccc4ccccc4c3)nc(-c3cccc4ccc5ccc6ccccc6c5c34)n2)cc1 ; c1ccc2cc(-c3nc(-c4ccc5ccccc5c4)nc(-c4cccc5ccc6ccc7ccccc7c6c45)n3)ccc2c1 ; c1ccc(-c2nc(-c3ccc(-c4ccc5ccccc5c4)cc3)nc(-c3cccc4ccc5ccc6ccccc6c5c34)n2)cc1]

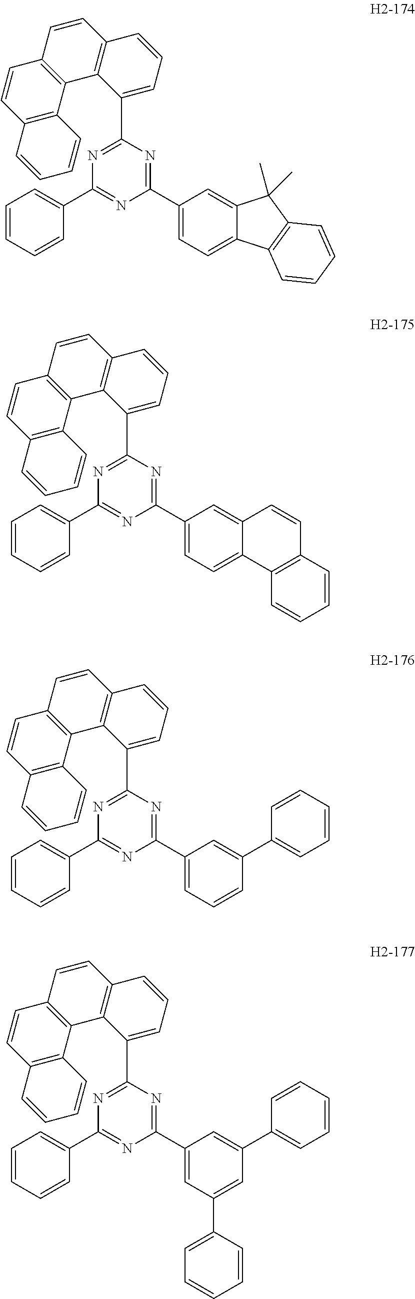 [SMILES: CC1(C)c2ccccc2-c2ccc(-c3nc(-c4ccccc4)nc(-c4cccc5ccc6ccc7ccccc7c6c45)n3)cc21 ; c1ccc(-c2nc(-c3ccc4c(ccc5ccccc54)c3)nc(-c3cccc4ccc5ccc6ccccc6c5c34)n2)cc1 ; c1ccc(-c2cccc(-c3nc(-c4ccccc4)nc(-c4cccc5ccc6ccc7ccccc7c6c45)n3)c2)cc1 ; c1ccc(-c2cc(-c3ccccc3)cc(-c3nc(-c4ccccc4)nc(-c4cccc5ccc6ccc7ccccc7c6c45)n3)c2)cc1]

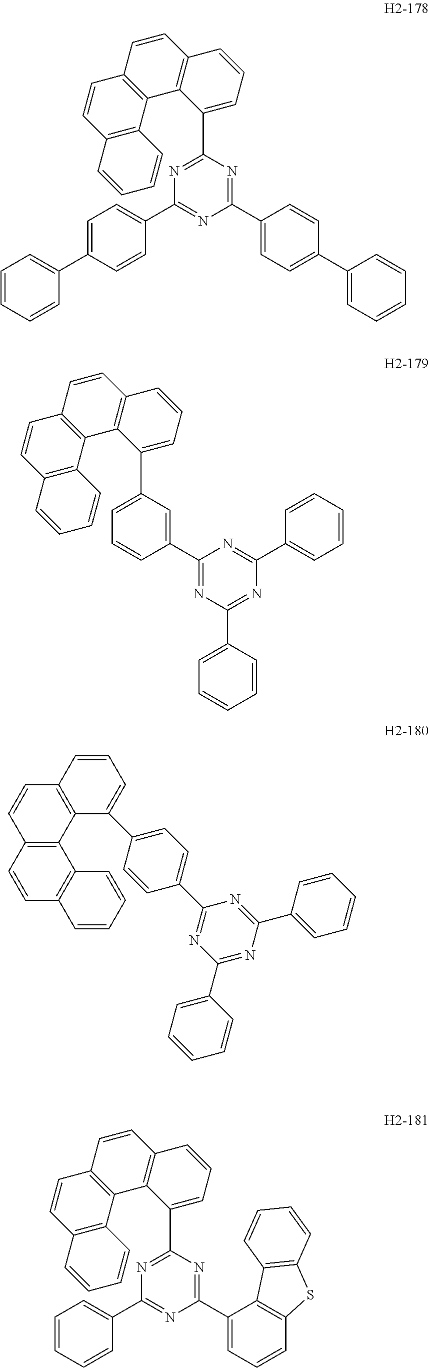 [SMILES: c1ccc(-c2ccc(-c3nc(-c4ccc(-c5ccccc5)cc4)nc(-c4cccc5ccc6ccc7ccccc7c6c45)n3)cc2)cc1 ; c1ccc(-c2nc(-c3ccccc3)nc(-c3cccc(-c4cccc5ccc6ccc7ccccc7c6c45)c3)n2)cc1 ; c1ccc(-c2nc(-c3ccccc3)nc(-c3ccc(-c4cccc5ccc6ccc7ccccc7c6c45)cc3)n2)cc1 ; c1ccc(-c2nc(-c3cccc4sc5ccccc5c34)nc(-c3cccc4ccc5ccc6ccccc6c5c34)n2)cc1]

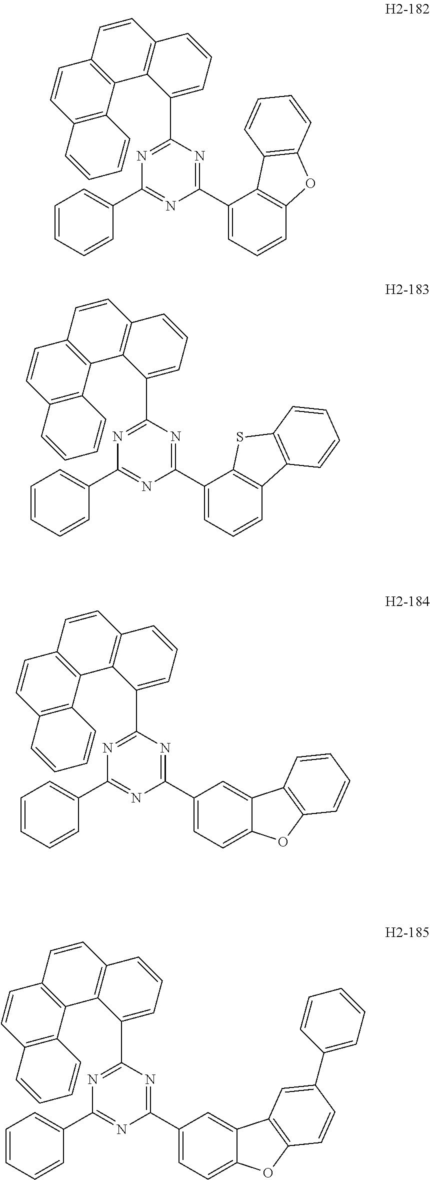 [SMILES: c1ccc(-c2nc(-c3cccc4oc5ccccc5c34)nc(-c3cccc4ccc5ccc6ccccc6c5c34)n2)cc1 ; c1ccc(-c2nc(-c3cccc4c3sc3ccccc34)nc(-c3cccc4ccc5ccc6ccccc6c5c34)n2)cc1 ; c1ccc(-c2nc(-c3ccc4oc5ccccc5c4c3)nc(-c3cccc4ccc5ccc6ccccc6c5c34)n2)cc1 ; c1ccc(-c2ccc3oc4ccc(-c5nc(-c6ccccc6)nc(-c6cccc7ccc8ccc9ccccc9c8c67)n5)cc4c3c2)cc1]

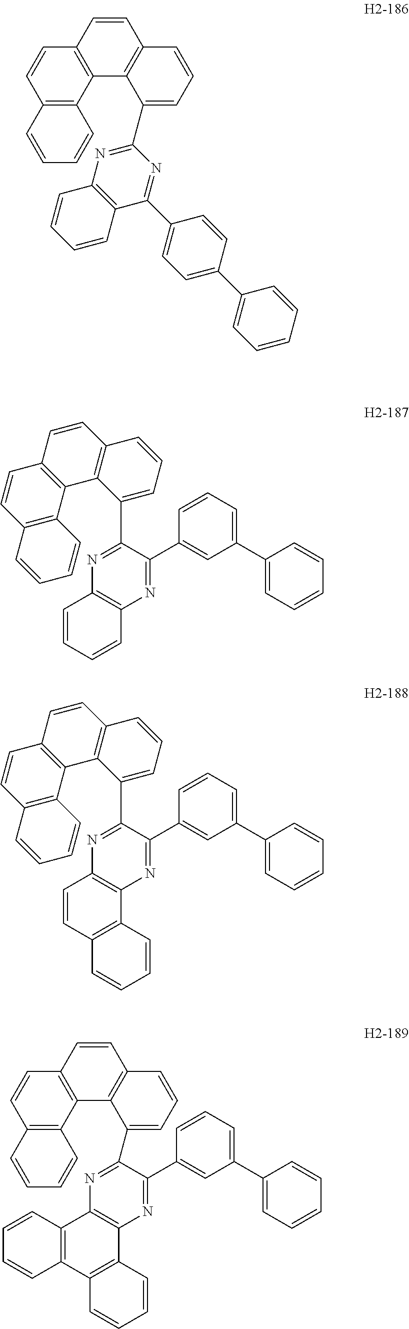

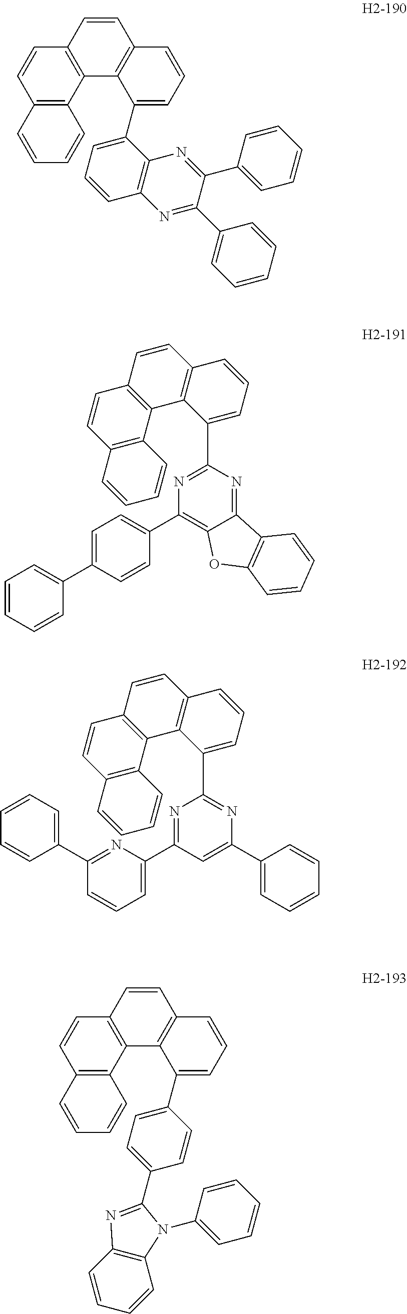 [SMILES: c1ccc(-c2nc3cccc(-c4cccc5ccc6ccc7ccccc7c6c45)c3nc2-c2ccccc2)cc1 ; c1ccc(-c2ccc(-c3nc(-c4cccc5ccc6ccc7ccccc7c6c45)nc4c3oc3ccccc34)cc2)cc1 ; c1ccc(-c2cccc(-c3cc(-c4ccccc4)nc(-c4cccc5ccc6ccc7ccccc7c6c45)n3)n2)cc1 ; c1ccc(-n2c(-c3ccc(-c4cccc5ccc6ccc7ccccc7c6c45)cc3)nc3ccccc32)cc1]

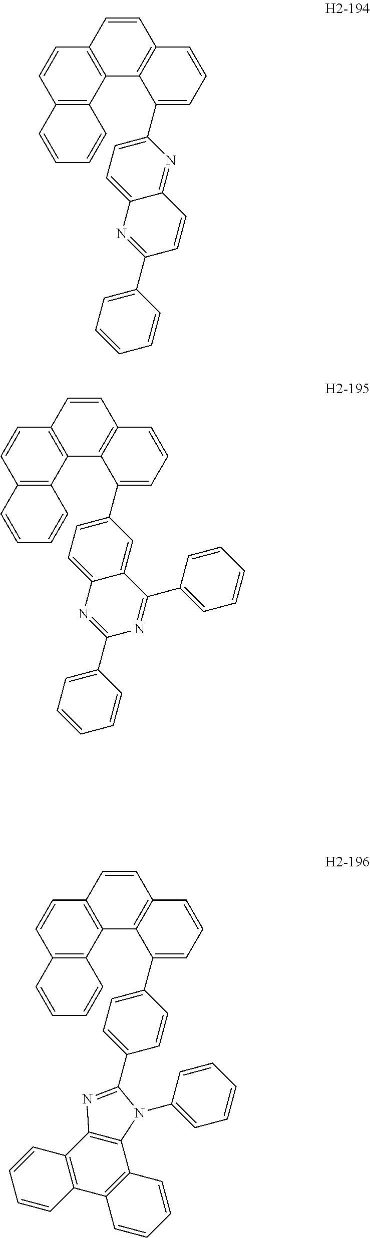 [SMILES: c1ccc(-c2ccc3nc(-c4cccc5ccc6ccc7ccccc7c6c45)ccc3n2)cc1 ; c1ccc(-c2nc(-c3ccccc3)c3cc(-c4cccc5ccc6ccc7ccccc7c6c45)ccc3n2)cc1 ; c1ccc(-n2c(-c3ccc(-c4cccc5ccc6ccc7ccccc7c6c45)cc3)nc3c4ccccc4c4ccccc4c32)cc1]

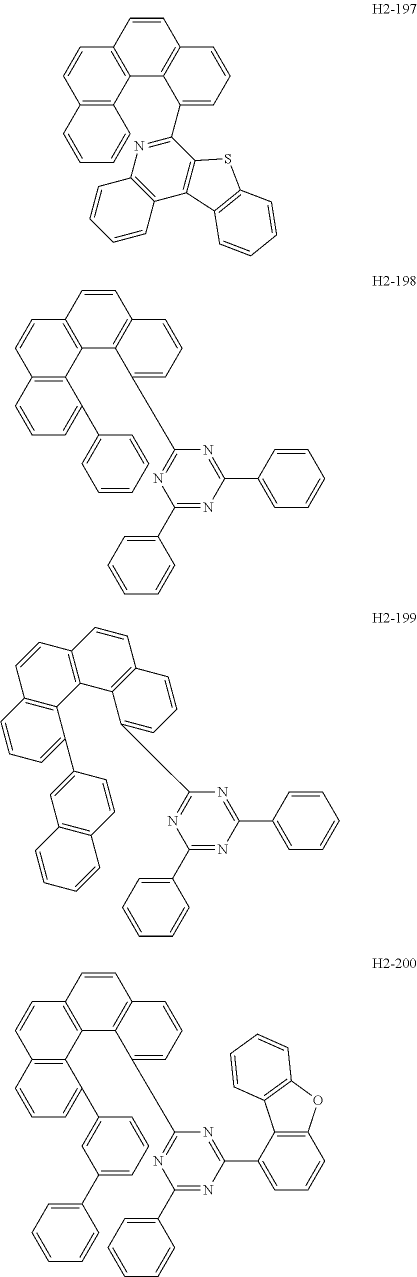

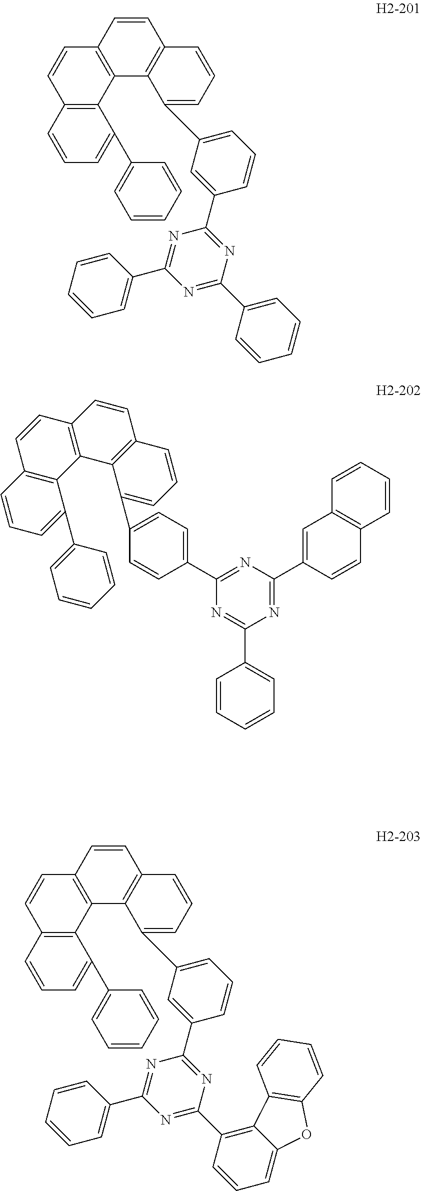 [SMILES: c1ccc(-c2nc(-c3ccccc3)nc(-c3cccc(-c4cccc5ccc6ccc7cccc(-c8ccccc8)c7c6c45)c3)n2)cc1 ; c1ccc(-c2nc(-c3ccc(-c4cccc5ccc6ccc7cccc(-c8ccccc8)c7c6c45)cc3)nc(-c3ccc4ccccc4c3)n2)cc1 ; c1ccc(-c2nc(-c3cccc(-c4cccc5ccc6ccc7cccc(-c8ccccc8)c7c6c45)c3)nc(-c3cccc4oc5ccccc5c34)n2)cc1]

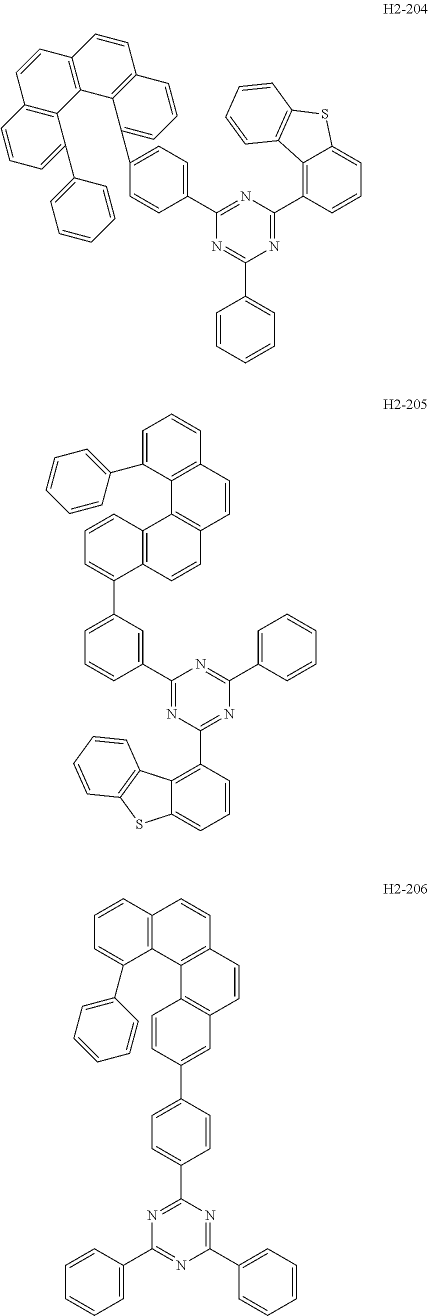 [SMILES: c1ccc(-c2nc(-c3ccc(-c4cccc5ccc6ccc7cccc(-c8ccccc8)c7c6c45)cc3)nc(-c3cccc4sc5ccccc5c34)n2)cc1 ; c1ccc(-c2nc(-c3cccc(-c4cccc5c4ccc4ccc6cccc(-c7ccccc7)c6c45)c3)nc(-c3cccc4sc5ccccc5c34)n2)cc1 ; c1ccc(-c2nc(-c3ccccc3)nc(-c3ccc(-c4ccc5c(ccc6ccc7cccc(-c8ccccc8)c7c65)c4)cc3)n2)cc1]

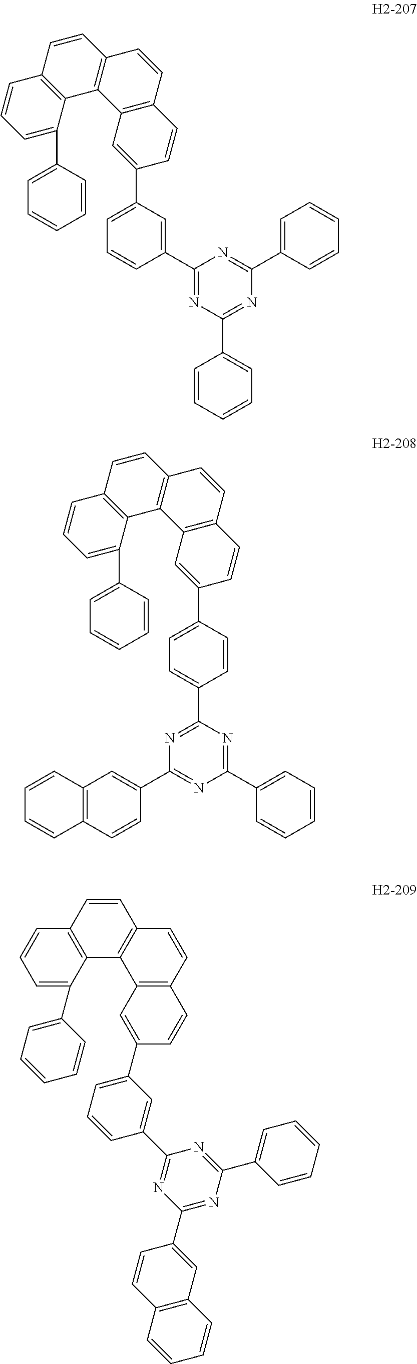 [SMILES: c1ccc(-c2nc(-c3ccccc3)nc(-c3cccc(-c4ccc5ccc6ccc7cccc(-c8ccccc8)c7c6c5c4)c3)n2)cc1 ; c1ccc(-c2nc(-c3ccc(-c4ccc5ccc6ccc7cccc(-c8ccccc8)c7c6c5c4)cc3)nc(-c3ccc4ccccc4c3)n2)cc1 ; c1ccc(-c2nc(-c3cccc(-c4ccc5ccc6ccc7cccc(-c8ccccc8)c7c6c5c4)c3)nc(-c3ccc4ccccc4c3)n2)cc1]

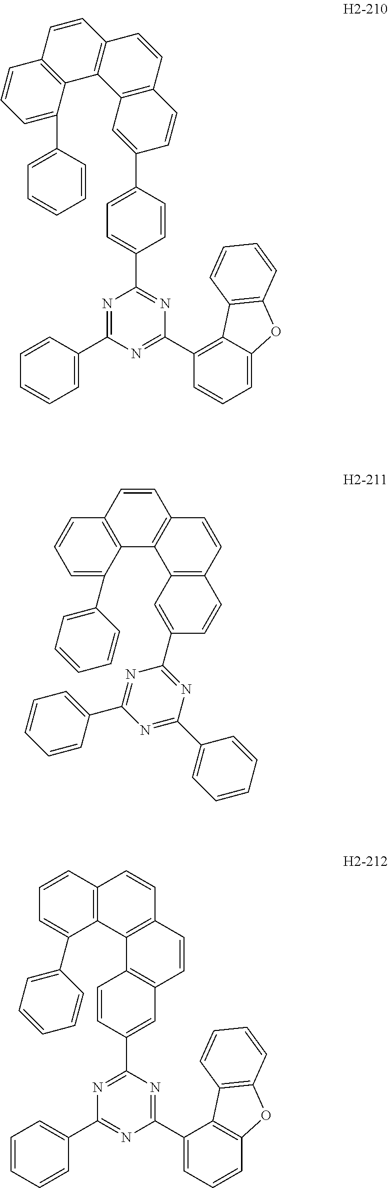 [SMILES: c1ccc(-c2nc(-c3ccc(-c4ccc5ccc6ccc7cccc(-c8ccccc8)c7c6c5c4)cc3)nc(-c3cccc4oc5ccccc5c34)n2)cc1 ; c1ccc(-c2nc(-c3ccccc3)nc(-c3ccc4ccc5ccc6cccc(-c7ccccc7)c6c5c4c3)n2)cc1 ; c1ccc(-c2nc(-c3ccc4c(ccc5ccc6cccc(-c7ccccc7)c6c54)c3)nc(-c3cccc4oc5ccccc5c34)n2)cc1]

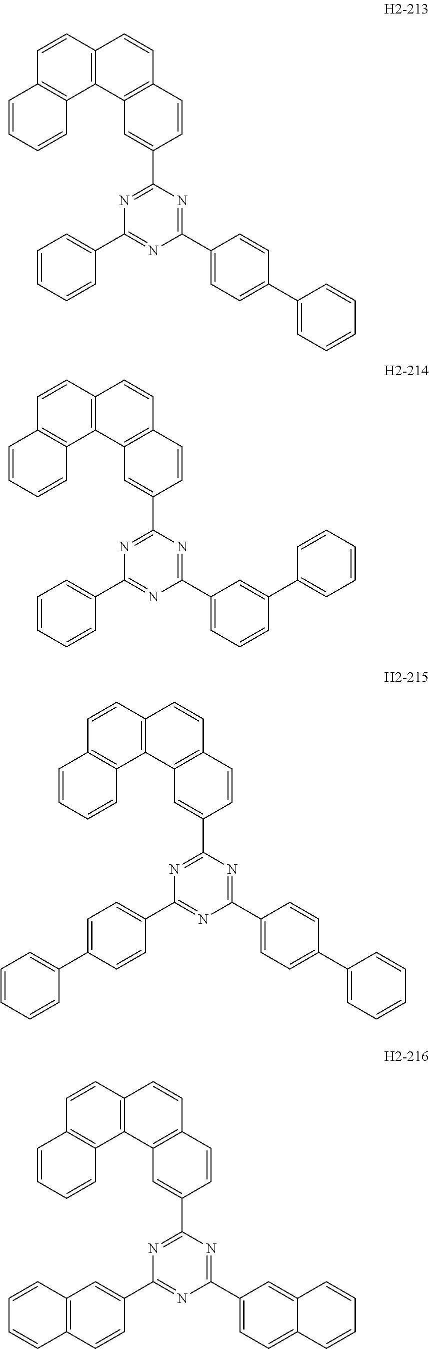 [SMILES: c1ccc(-c2ccc(-c3nc(-c4ccccc4)nc(-c4ccc5ccc6ccc7ccccc7c6c5c4)n3)cc2)cc1 ; c1ccc(-c2cccc(-c3nc(-c4ccccc4)nc(-c4ccc5ccc6ccc7ccccc7c6c5c4)n3)c2)cc1 ; c1ccc(-c2ccc(-c3nc(-c4ccc(-c5ccccc5)cc4)nc(-c4ccc5ccc6ccc7ccccc7c6c5c4)n3)cc2)cc1 ; c1ccc2cc(-c3nc(-c4ccc5ccccc5c4)nc(-c4ccc5ccc6ccc7ccccc7c6c5c4)n3)ccc2c1]

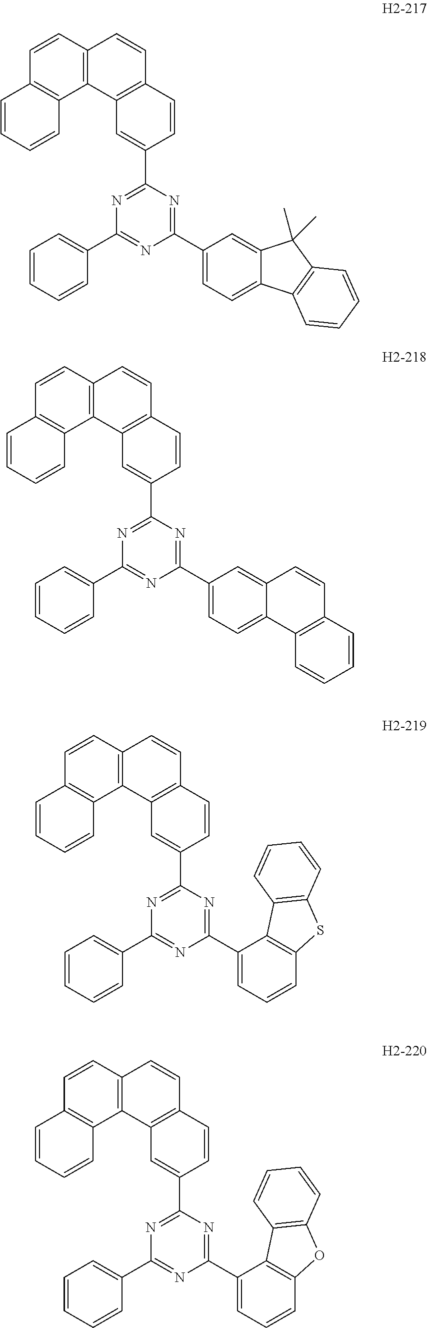 [SMILES: CC1(C)c2ccccc2-c2ccc(-c3nc(-c4ccccc4)nc(-c4ccc5ccc6ccc7ccccc7c6c5c4)n3)cc21 ; c1ccc(-c2nc(-c3ccc4c(ccc5ccccc54)c3)nc(-c3ccc4ccc5ccc6ccccc6c5c4c3)n2)cc1 ; c1ccc(-c2nc(-c3ccc4ccc5ccc6ccccc6c5c4c3)nc(-c3cccc4sc5ccccc5c34)n2)cc1 ; c1ccc(-c2nc(-c3ccc4ccc5ccc6ccccc6c5c4c3)nc(-c3cccc4oc5ccccc5c34)n2)cc1]

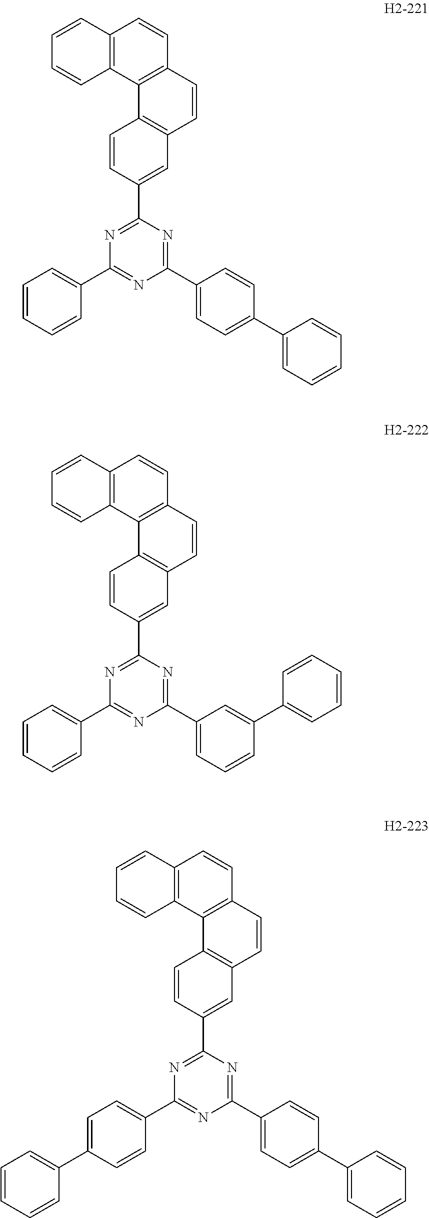 [SMILES: c1ccc(-c2ccc(-c3nc(-c4ccccc4)nc(-c4ccc5c(ccc6ccc7ccccc7c65)c4)n3)cc2)cc1 ; c1ccc(-c2cccc(-c3nc(-c4ccccc4)nc(-c4ccc5c(ccc6ccc7ccccc7c65)c4)n3)c2)cc1 ; c1ccc(-c2ccc(-c3nc(-c4ccc(-c5ccccc5)cc4)nc(-c4ccc5c(ccc6ccc7ccccc7c65)c4)n3)cc2)cc1]

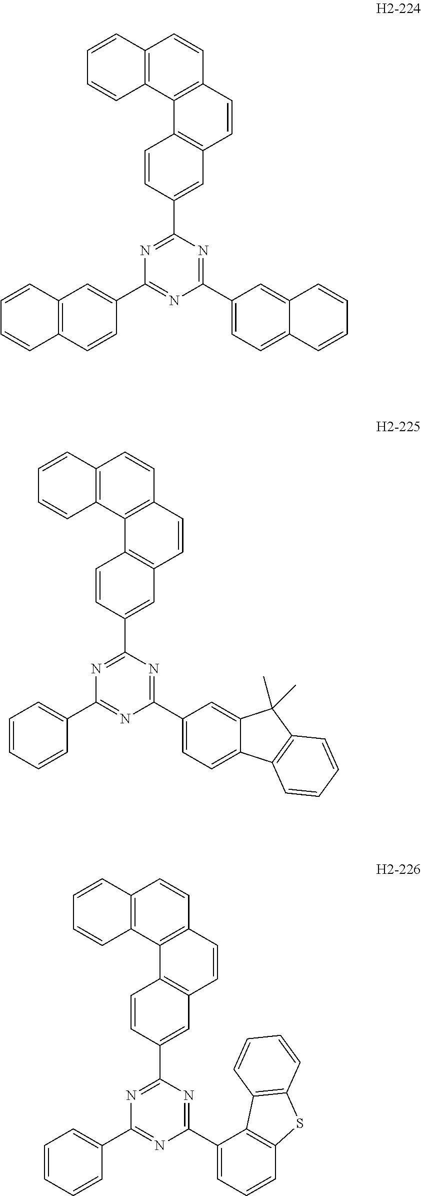 [SMILES: c1ccc2cc(-c3nc(-c4ccc5ccccc5c4)nc(-c4ccc5c(ccc6ccc7ccccc7c65)c4)n3)ccc2c1 ; CC1(C)c2ccccc2-c2ccc(-c3nc(-c4ccccc4)nc(-c4ccc5c(ccc6ccc7ccccc7c65)c4)n3)cc21 ; c1ccc(-c2nc(-c3ccc4c(ccc5ccc6ccccc6c54)c3)nc(-c3cccc4sc5ccccc5c34)n2)cc1]

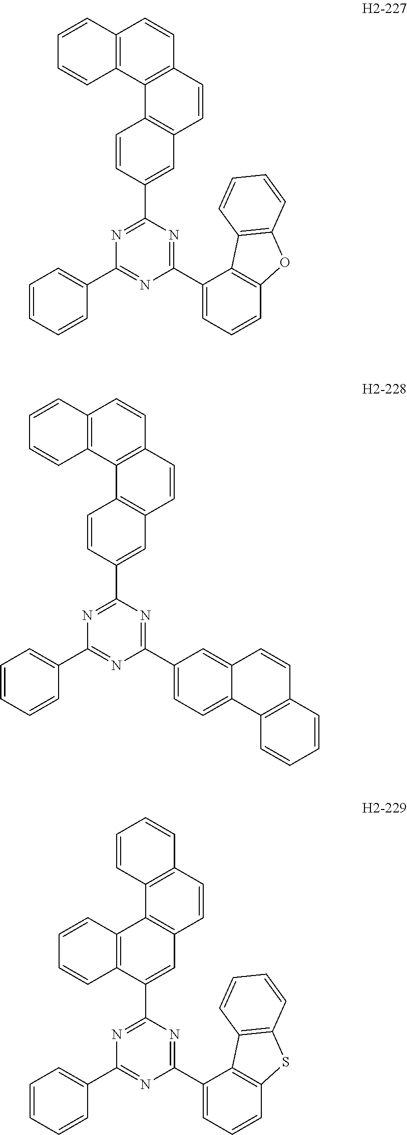 [SMILES: c1ccc(-c2nc(-c3ccc4c(ccc5ccc6ccccc6c54)c3)nc(-c3cccc4oc5ccccc5c34)n2)cc1 ; c1ccc(-c2nc(-c3ccc4c(ccc5ccccc54)c3)nc(-c3ccc4c(ccc5ccc6ccccc6c54)c3)n2)cc1 ; c1ccc(-c2nc(-c3cc4ccc5ccccc5c4c4ccccc34)nc(-c3cccc4sc5ccccc5c34)n2)cc1]

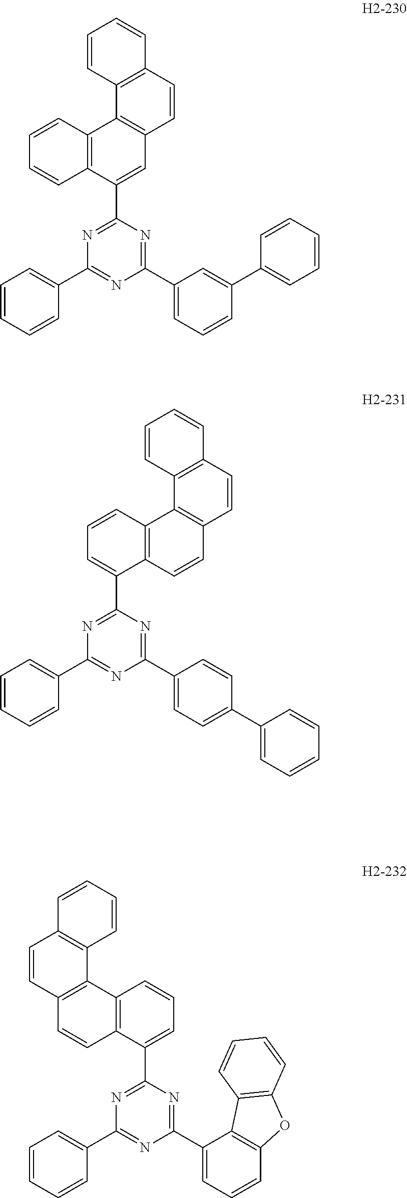 [SMILES: c1ccc(-c2cccc(-c3nc(-c4ccccc4)nc(-c4cc5ccc6ccccc6c5c5ccccc45)n3)c2)cc1 ; c1ccc(-c2ccc(-c3nc(-c4ccccc4)nc(-c4cccc5c4ccc4ccc6ccccc6c45)n3)cc2)cc1 ; c1ccc(-c2nc(-c3cccc4c3ccc3ccc5ccccc5c34)nc(-c3cccc4oc5ccccc5c34)n2)cc1]

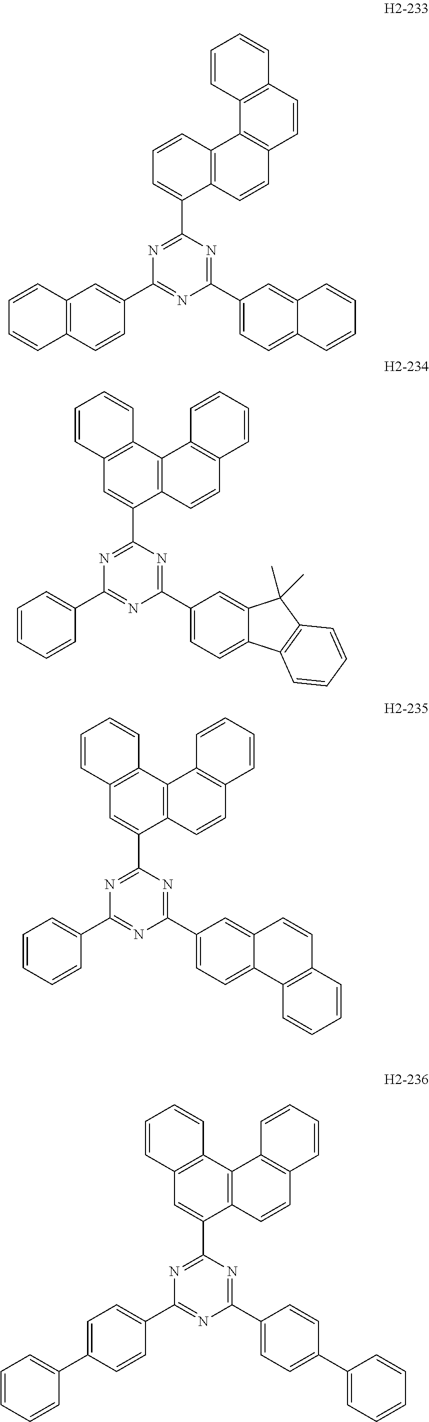

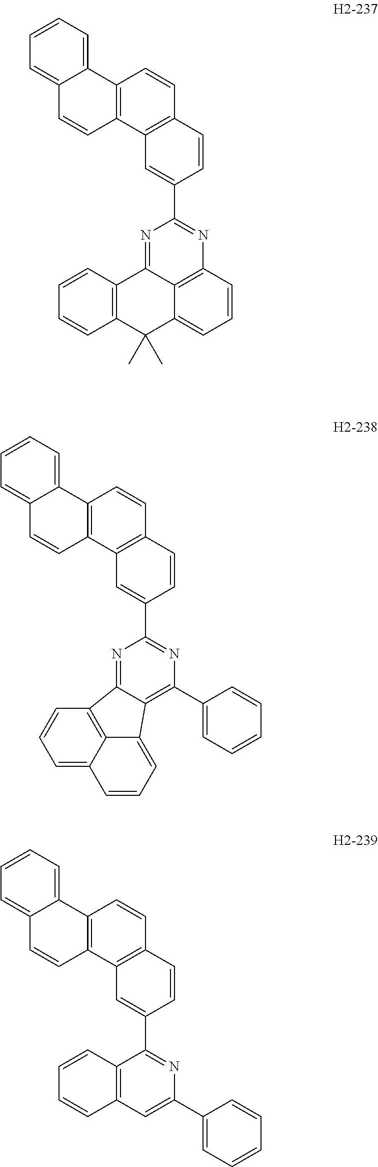 [SMILES: CC1(C)c2ccccc2-c2nc(-c3ccc4ccc5c6ccccc6ccc5c4c3)nc3cccc1c23 ; c1ccc(-c2nc(-c3ccc4ccc5c6ccccc6ccc5c4c3)nc3c2-c2cccc4cccc-3c24)cc1 ; c1ccc(-c2cc3ccccc3c(-c3ccc4ccc5c6ccccc6ccc5c4c3)n2)cc1]

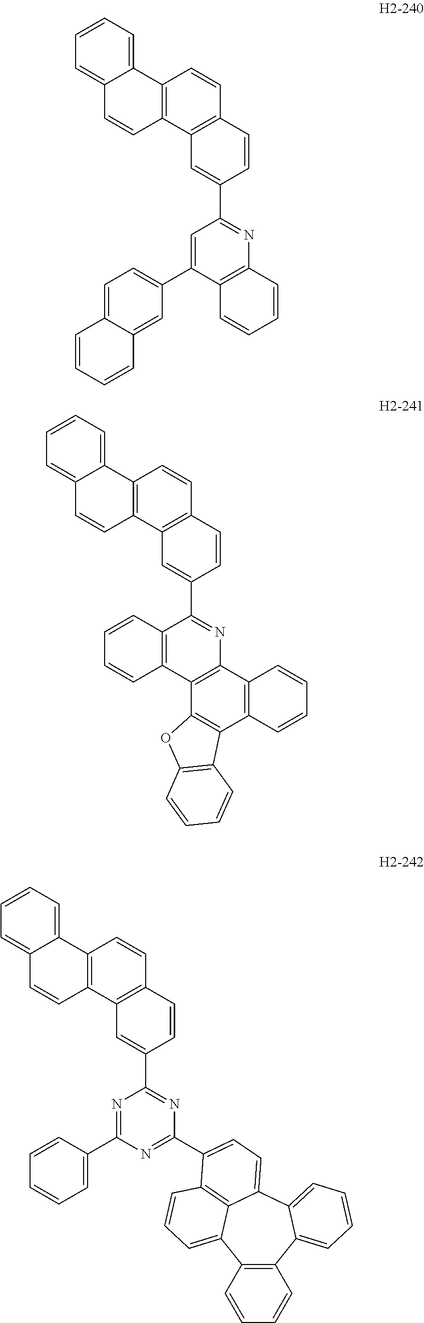

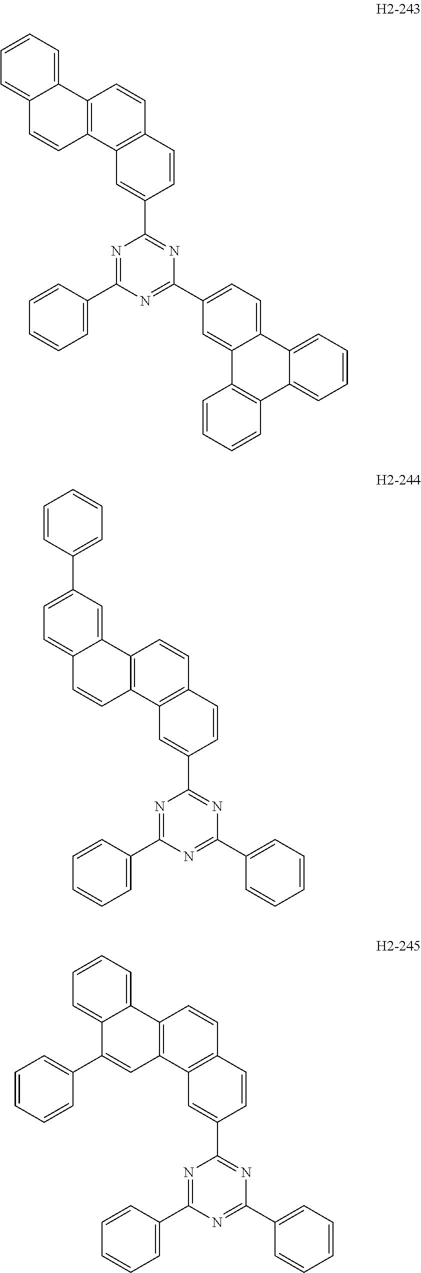 [SMILES: c1ccc(-c2nc(-c3ccc4ccc5c6ccccc6ccc5c4c3)nc(-c3ccc4c5ccccc5c5ccccc5c4c3)n2)cc1 ; c1ccc(-c2ccc3ccc4c5cc(-c6nc(-c7ccccc7)nc(-c7ccccc7)n6)ccc5ccc4c3c2)cc1 ; c1ccc(-c2nc(-c3ccccc3)nc(-c3ccc4ccc5c6ccccc6c(-c6ccccc6)cc5c4c3)n2)cc1]

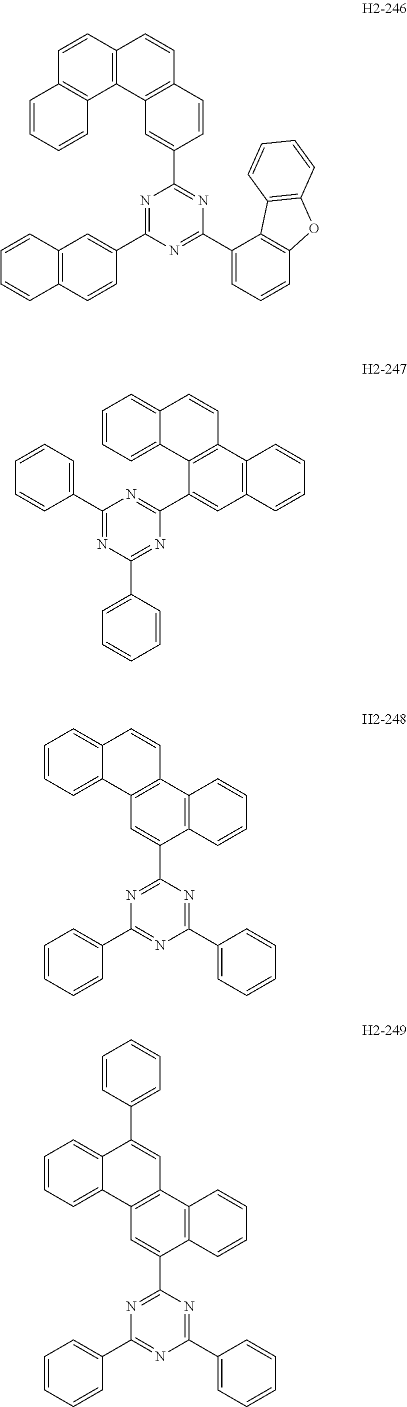 [SMILES: c1ccc2cc(-c3nc(-c4ccc5ccc6ccc7ccccc7c6c5c4)nc(-c4cccc5oc6ccccc6c45)n3)ccc2c1 ; c1ccc(-c2nc(-c3ccccc3)nc(-c3cc4ccccc4c4ccc5ccccc5c34)n2)cc1 ; c1ccc(-c2nc(-c3ccccc3)nc(-c3cc4c5ccccc5ccc4c4ccccc34)n2)cc1 ; c1ccc(-c2nc(-c3ccccc3)nc(-c3cc4c5ccccc5c(-c5ccccc5)cc4c4ccccc34)n2)cc1]

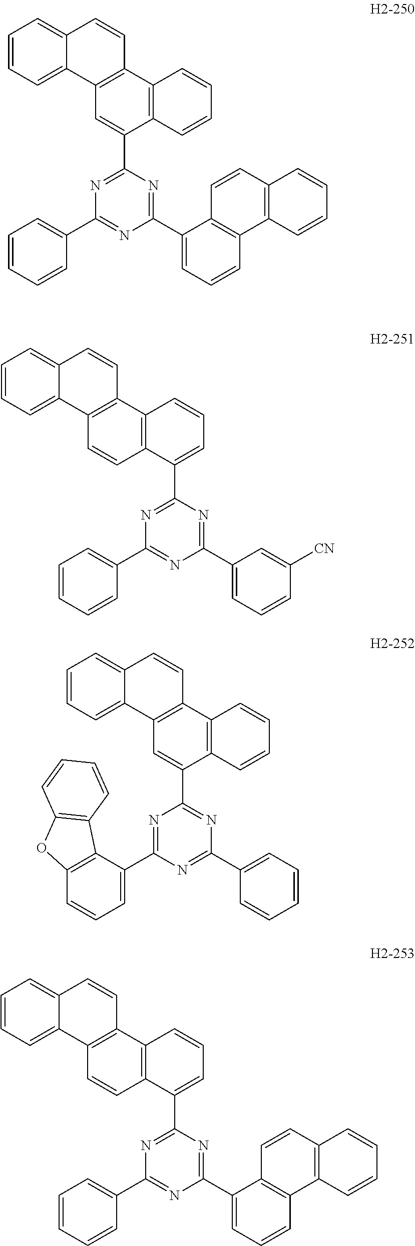

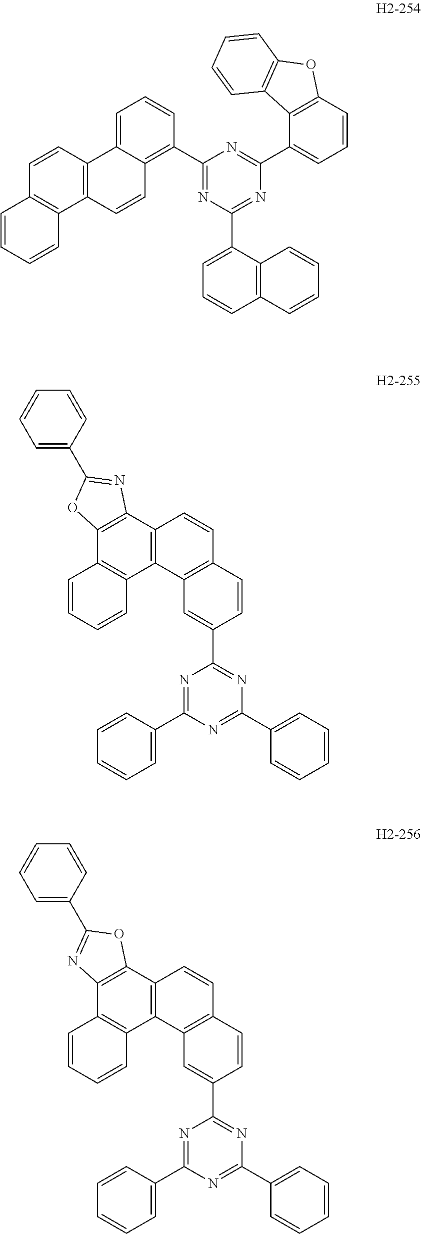 [SMILES: c1ccc2c(-c3nc(-c4cccc5c4ccc4c6ccccc6ccc54)nc(-c4cccc5oc6ccccc6c45)n3)cccc2c1 ; c1ccc(-c2nc(-c3ccccc3)nc(-c3ccc4ccc5c6nc(-c7ccccc7)oc6c6ccccc6c5c4c3)n2)cc1 ; c1ccc(-c2nc(-c3ccccc3)nc(-c3ccc4ccc5c6oc(-c7ccccc7)nc6c6ccccc6c5c4c3)n2)cc1]

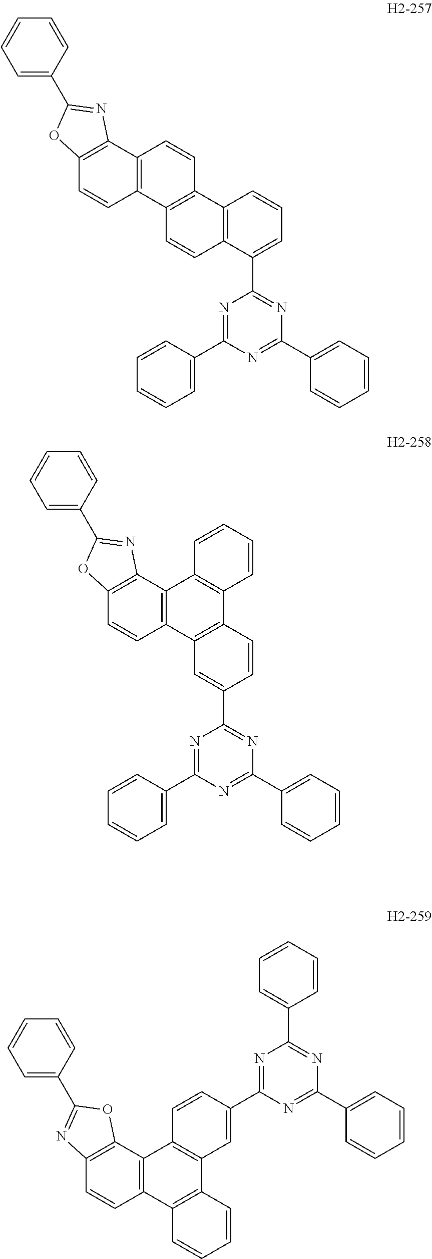 [SMILES: c1ccc(-c2nc(-c3ccccc3)nc(-c3cccc4c3ccc3c4ccc4c3ccc3oc(-c5ccccc5)nc34)n2)cc1 ; c1ccc(-c2nc(-c3ccccc3)nc(-c3ccc4c5ccccc5c5c(ccc6oc(-c7ccccc7)nc65)c4c3)n2)cc1 ; c1ccc(-c2nc(-c3ccccc3)nc(-c3ccc4c(c3)c3ccccc3c3ccc5nc(-c6ccccc6)oc5c34)n2)cc1]

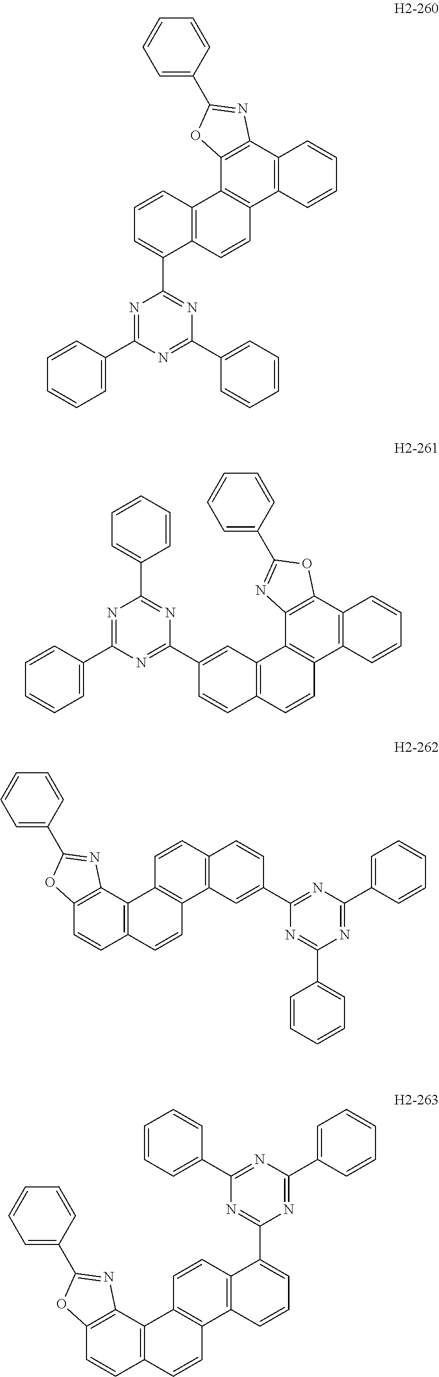 [SMILES: c1ccc(-c2nc(-c3ccccc3)nc(-c3cccc4c3ccc3c5ccccc5c5nc(-c6ccccc6)oc5c43)n2)cc1 ; c1ccc(-c2nc(-c3ccccc3)nc(-c3ccc4ccc5c6ccccc6c6oc(-c7ccccc7)nc6c5c4c3)n2)cc1 ; c1ccc(-c2nc(-c3ccccc3)nc(-c3ccc4ccc5c(ccc6ccc7oc(-c8ccccc8)nc7c65)c4c3)n2)cc1 ; c1ccc(-c2nc(-c3ccccc3)nc(-c3cccc4c3ccc3c4ccc4ccc5oc(-c6ccccc6)nc5c43)n2)cc1]

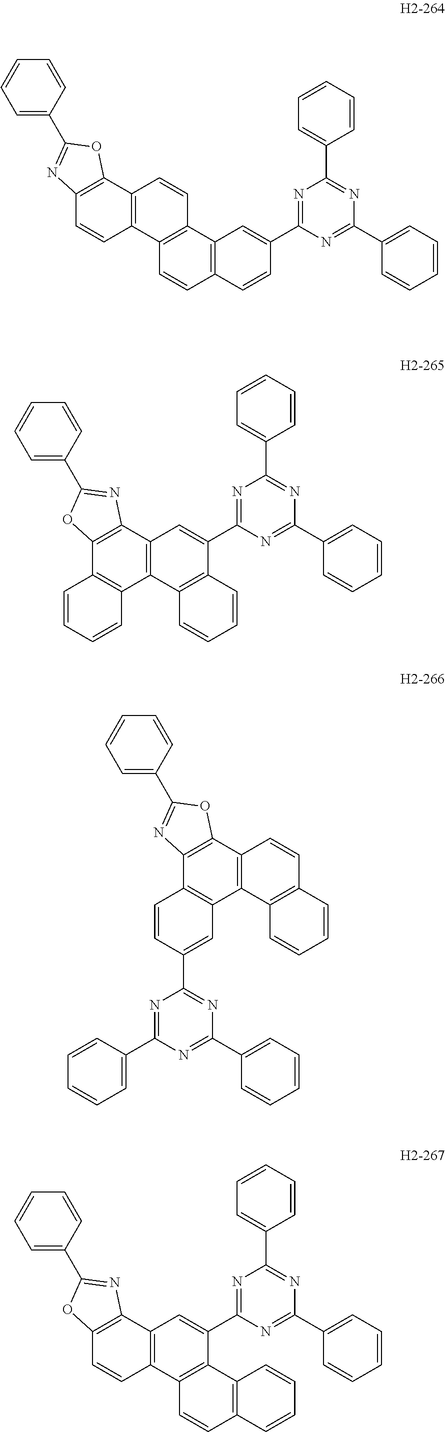

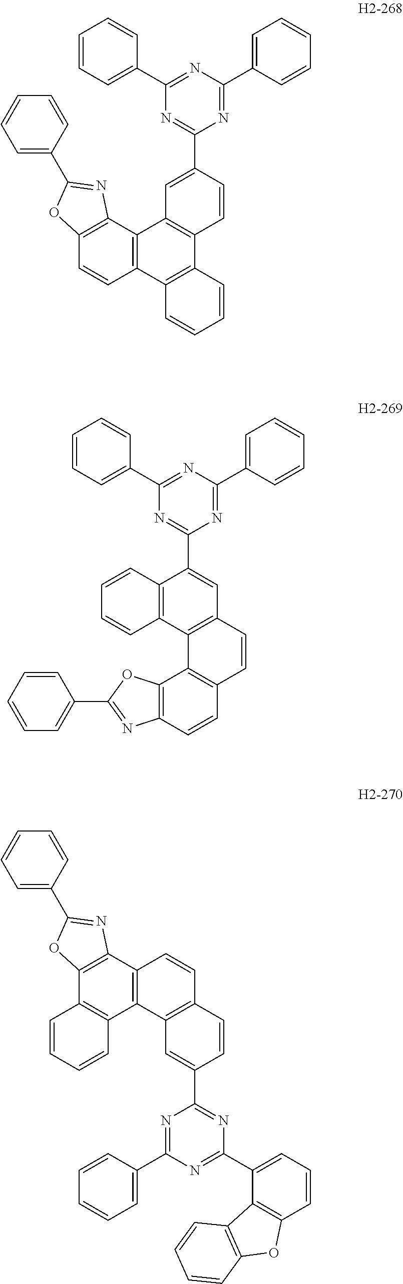

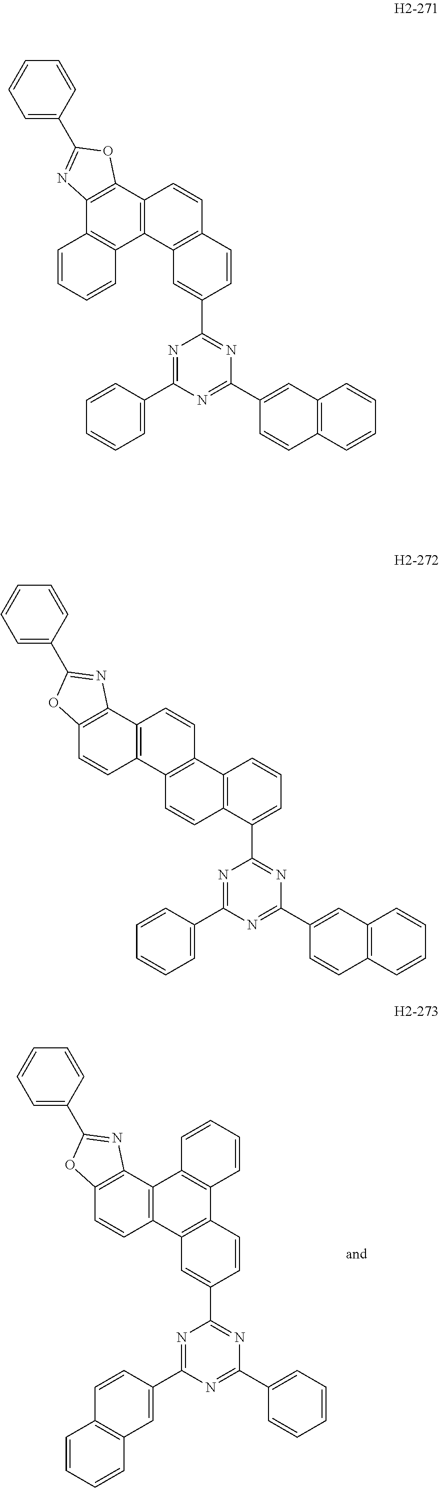

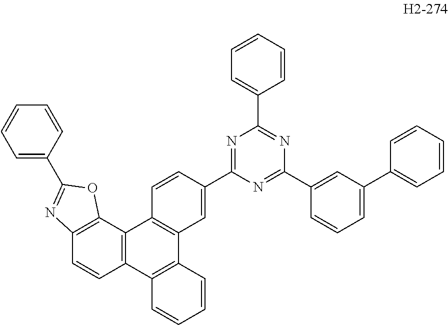

11. An organic electroluminescent device comprising: a first electrode; a second electrode; and at least one light-emitting layer between the first electrode and the second electrode, wherein the at least one light-emitting layer(s) comprises the plurality of host materials according to claim 1.

12. An organic electroluminescent compound represented by the following formula 1′: 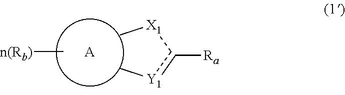
wherein
ring A represents a substituted or unsubstituted aromatic ring in which 4 benzene rings are sequentially fused;
X₁ and Y₁ each independently represent, —N═, —NR_{c}—, —O— or —S—; provided that any one of X₁ and Y₁ is —N═, and the other of X₁ and Y₁ is —NR_{c}—, —O— or —S—;
Rₐ and R_{c} each independently represent, a substituted or unsubstituted (C6-C30)aryl a substituted or unsubstituted (3- to 30-membered)heteroaryl, -L′₁—NR′₁R′₂, or -L′₁-HAr;
R_{b} represents hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted fused ring of (C3-C30) aliphatic ring and (C6-C30) aromatic ring, —SiR′₁R′₂R′₃, -L′₁—NR′₁R′₂, or -L′₁-HAr;
provided that at least one of Rₐ and R_{b} is (are) -L′₁—NR′₁R′₂ or -L′₁-HAr;
L′₁ represents a single bond, a substituted or unsubstituted (C6-C30)arylene, or a substituted or unsubstituted (3- to 30-membered)heteroarylene;
HAr represents a substituted or unsubstituted (3- to 30-membered)heteroaryl;
R′₁ to R′₃ each independently represent, a substituted or unsubstituted (C1-C30)alkyl, a substituted or unsubstituted (C2-C30)alkenyl, a substituted or unsubstituted (C6-C30)aryl, a substituted or unsubstituted (3- to 30-membered)heteroaryl, or a substituted or unsubstituted fused ring of (C3-C30) aliphatic ring and (C6-C30) aromatic ring; and
n represents an integer of 1 to 10, when n is an integer of 2 or more, each of R_{b} may be the same or different.

13. The organic electroluminescent compound according to claim 12, wherein the formula 1′ is represented by the following formula 1′-1: 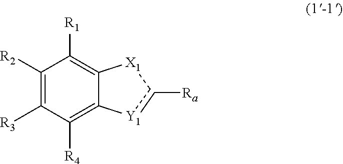
wherein,
X₁, Y₁, and Rₐ are as defined in claim 12; and
one of R₁ and R₂, and R₃ and R₄ is linked to each other to form the following formula 1A, or the other is linked to each other to form the following formula 1B; or any one of R₁ and R₂, R₂ and R₃, and R₃ and R₄ is linked to each other to form the following formula 1C or 1D; 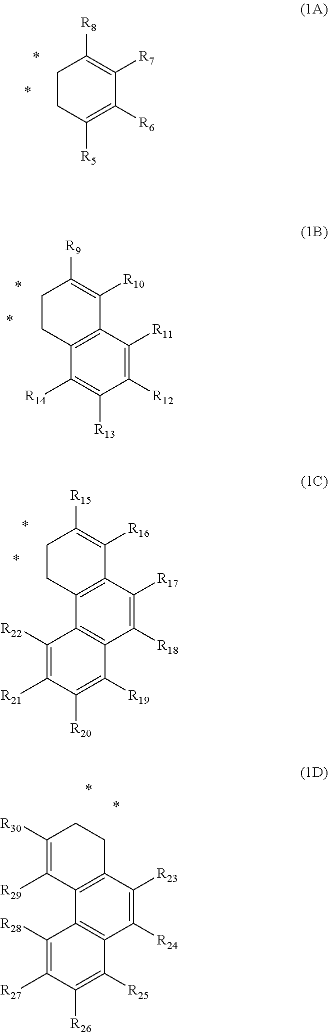
wherein,
R₁ to R₄, which do not form the formula 1C or 1D, and R₅ to R₃₀ are as defined as R_{b} in claim 12.

14. The organic electroluminescent compound according to claim 13, wherein the formula 1′-1 is represented by any one of the following formula 11′-1 to 11′-7: 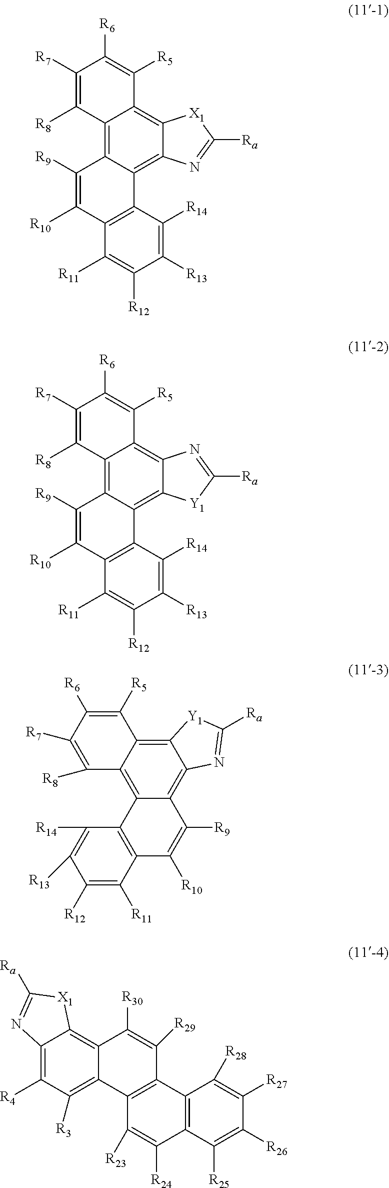 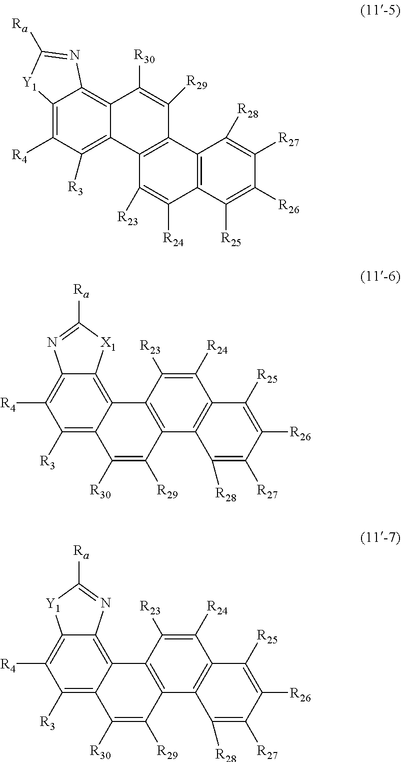
wherein,
X₁, Y₁, and Rₐ, R₃ to R₁₄ and R₂₃ to R₃₀ are as defined in claim 13.

15. The organic electroluminescent compound according to claim 13, wherein at least one of Rₐ, R₃ to R₁₄, and R₂₃ to R₃₀ is (are) represents by the following formula R_{b}-1: 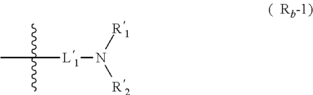
wherein,
L′₁ represents a single bond, a substituted or unsubstituted (C6-C30)arylene, or a substituted or unsubstituted (3- to 30-membered)heteroarylene; and
R′₁ and R′₂ each independently represent, a substituted or unsubstituted (C6-C30)aryl, a substituted or unsubstituted (3- to 30-membered)heteroaryl, or a substituted or unsubstituted fused ring of (C3-C30) aliphatic ring and (C6-C30) aromatic ring.

16. The organic electroluminescent compound according to claim 12, wherein the compound represented by the formula 1′ is selected from the following compounds:

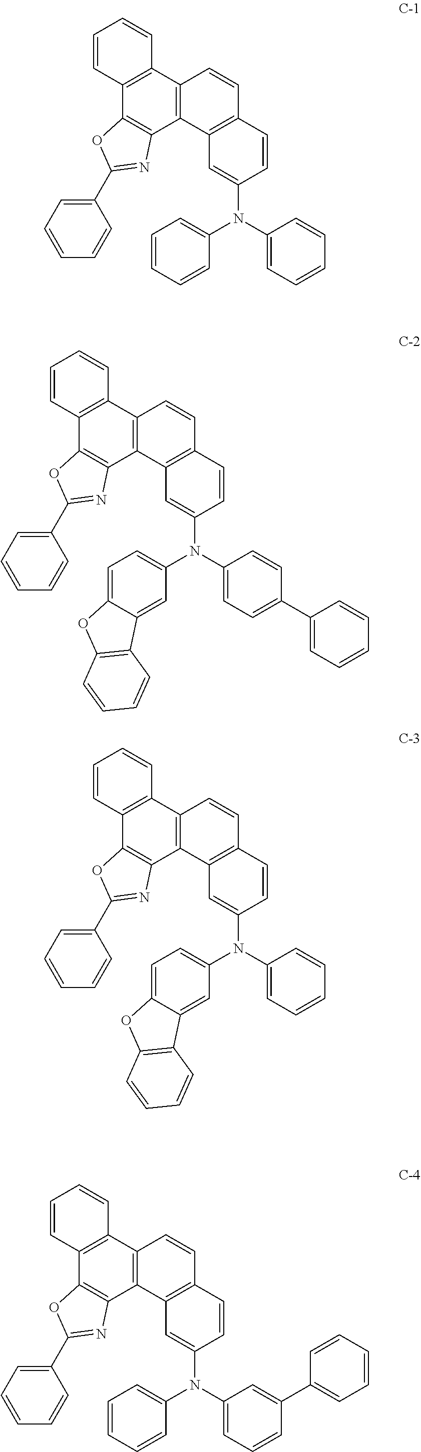

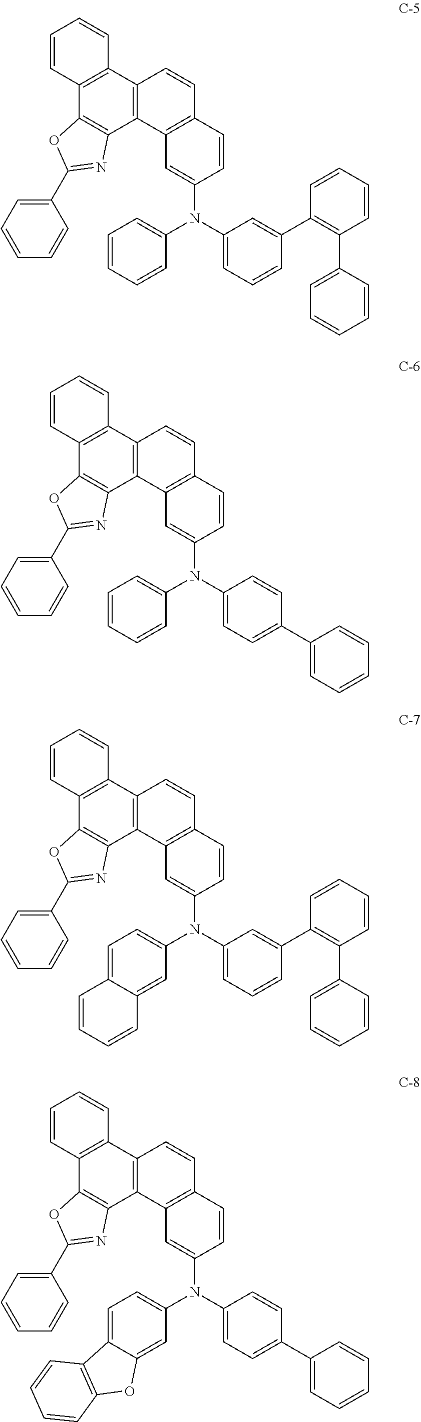 [SMILES: c1ccc(-c2nc3c(o2)c2ccccc2c2ccc4ccc(N(c5ccccc5)c5cccc(-c6ccccc6-c6ccccc6)c5)cc4c23)cc1 ; c1ccc(-c2ccc(N(c3ccccc3)c3ccc4ccc5c6ccccc6c6oc(-c7ccccc7)nc6c5c4c3)cc2)cc1 ; c1ccc(-c2nc3c(o2)c2ccccc2c2ccc4ccc(N(c5cccc(-c6ccccc6-c6ccccc6)c5)c5ccc6ccccc6c5)cc4c23)cc1 ; c1ccc(-c2ccc(N(c3ccc4c(c3)oc3ccccc34)c3ccc4ccc5c6ccccc6c6oc(-c7ccccc7)nc6c5c4c3)cc2)cc1]

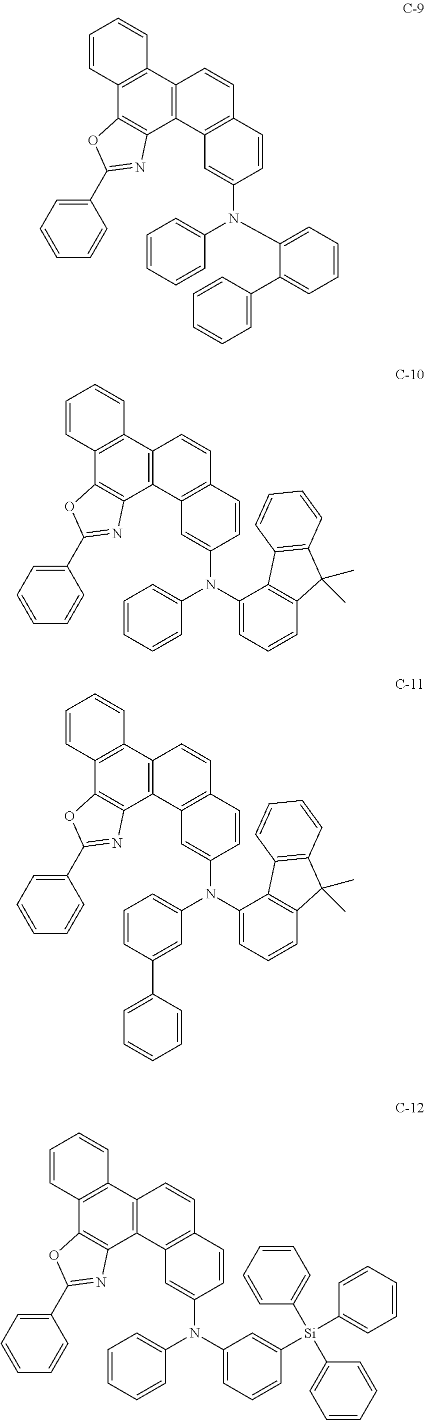 [SMILES: c1ccc(-c2nc3c(o2)c2ccccc2c2ccc4ccc(N(c5ccccc5)c5ccccc5-c5ccccc5)cc4c23)cc1 ; CC1(C)c2ccccc2-c2c(N(c3ccccc3)c3ccc4ccc5c6ccccc6c6oc(-c7ccccc7)nc6c5c4c3)cccc21 ; CC1(C)c2ccccc2-c2c(N(c3cccc(-c4ccccc4)c3)c3ccc4ccc5c6ccccc6c6oc(-c7ccccc7)nc6c5c4c3)cccc21 ; c1ccc(-c2nc3c(o2)c2ccccc2c2ccc4ccc(N(c5ccccc5)c5cccc([Si](c6ccccc6)(c6ccccc6)c6ccccc6)c5)cc4c23)cc1]

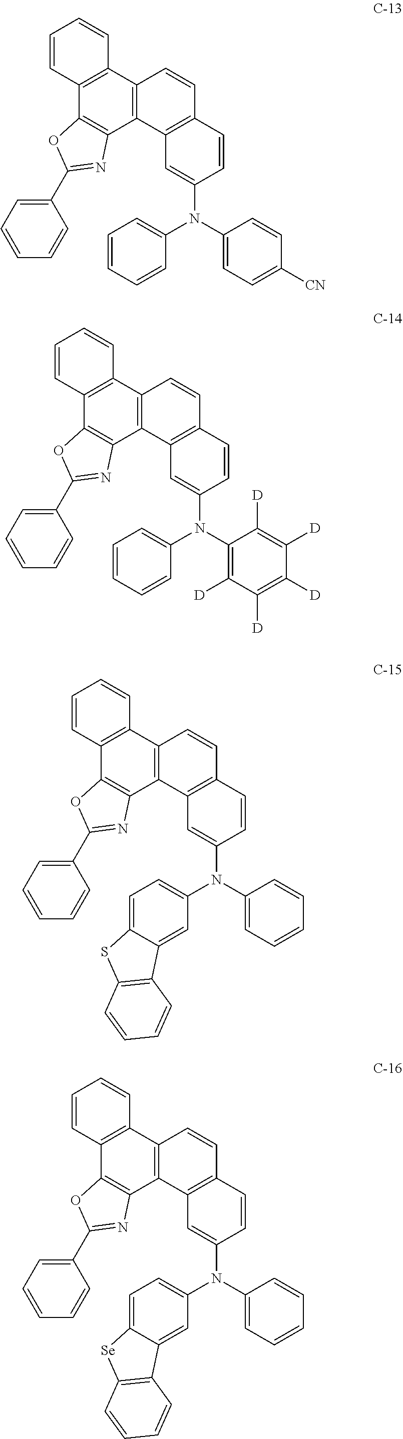

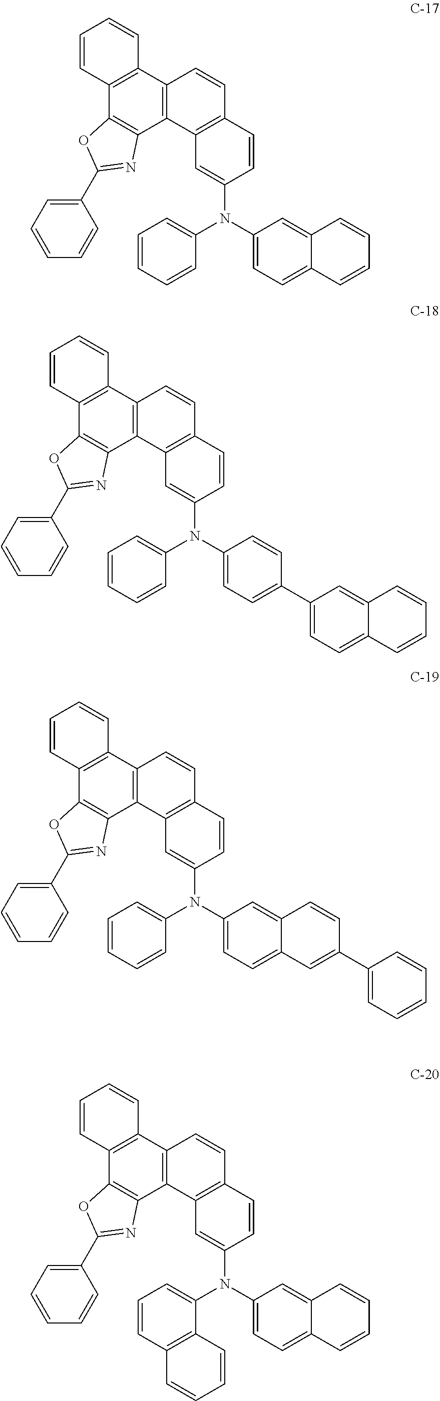 [SMILES: c1ccc(-c2nc3c(o2)c2ccccc2c2ccc4ccc(N(c5ccccc5)c5ccc6ccccc6c5)cc4c23)cc1 ; c1ccc(-c2nc3c(o2)c2ccccc2c2ccc4ccc(N(c5ccccc5)c5ccc(-c6ccc7ccccc7c6)cc5)cc4c23)cc1 ; c1ccc(-c2ccc3cc(N(c4ccccc4)c4ccc5ccc6c7ccccc7c7oc(-c8ccccc8)nc7c6c5c4)ccc3c2)cc1 ; c1ccc(-c2nc3c(o2)c2ccccc2c2ccc4ccc(N(c5ccc6ccccc6c5)c5cccc6ccccc56)cc4c23)cc1]

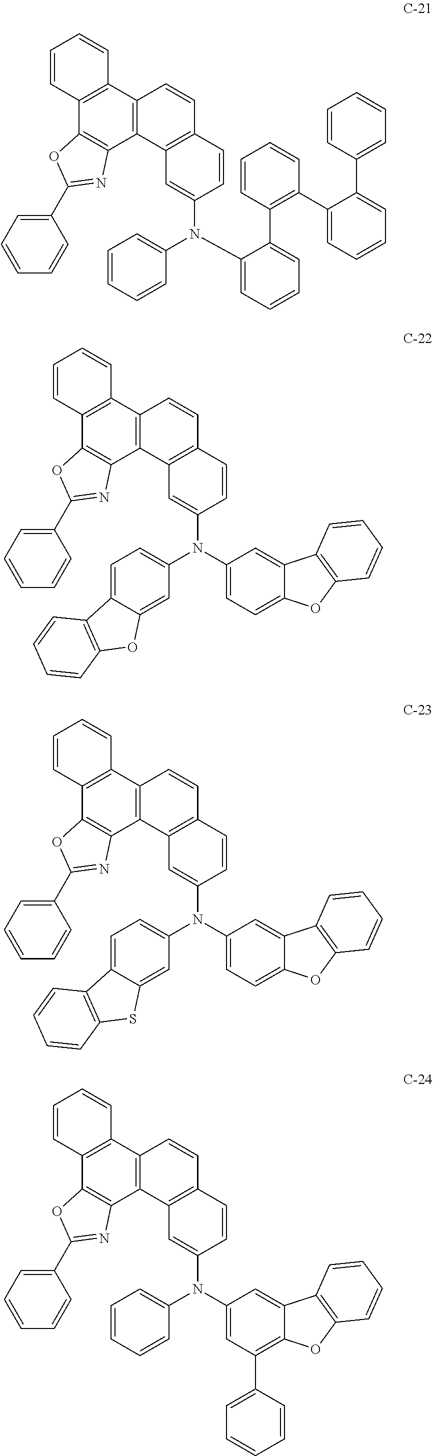

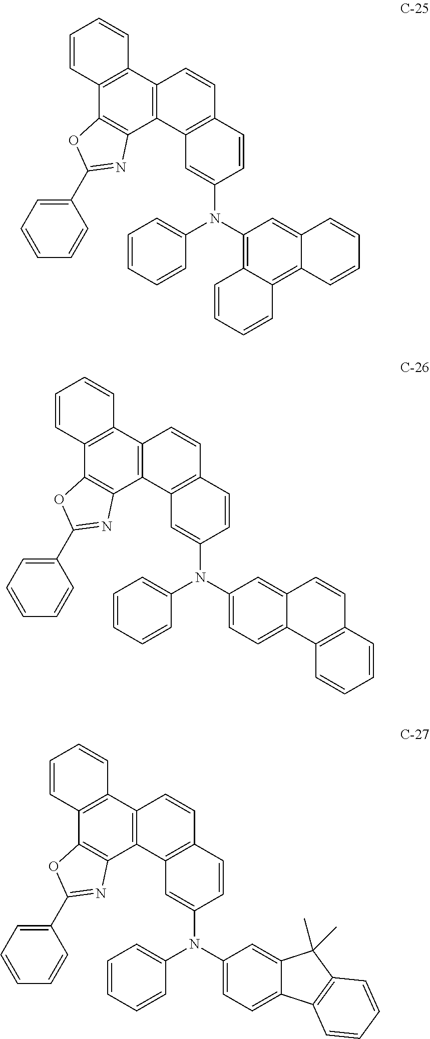 [SMILES: c1ccc(-c2nc3c(o2)c2ccccc2c2ccc4ccc(N(c5ccccc5)c5cc6ccccc6c6ccccc56)cc4c23)cc1 ; c1ccc(-c2nc3c(o2)c2ccccc2c2ccc4ccc(N(c5ccccc5)c5ccc6c(ccc7ccccc76)c5)cc4c23)cc1 ; CC1(C)c2ccccc2-c2ccc(N(c3ccccc3)c3ccc4ccc5c6ccccc6c6oc(-c7ccccc7)nc6c5c4c3)cc21]

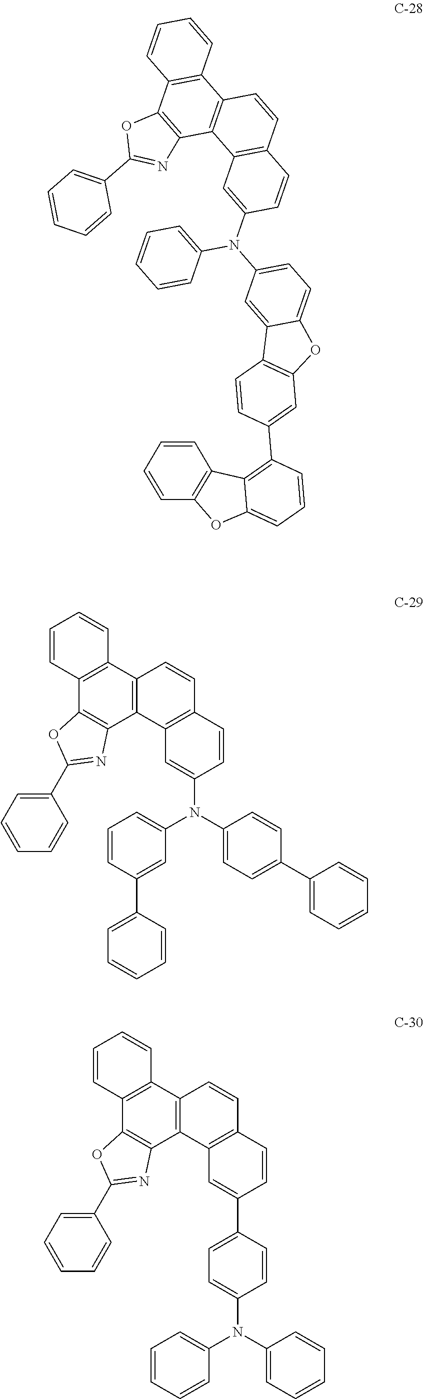 [SMILES: c1ccc(-c2nc3c(o2)c2ccccc2c2ccc4ccc(N(c5ccccc5)c5ccc6oc7cc(-c8cccc9oc%10ccccc%10c89)ccc7c6c5)cc4c23)cc1 ; c1ccc(-c2ccc(N(c3cccc(-c4ccccc4)c3)c3ccc4ccc5c6ccccc6c6oc(-c7ccccc7)nc6c5c4c3)cc2)cc1 ; c1ccc(-c2nc3c(o2)c2ccccc2c2ccc4ccc(-c5ccc(N(c6ccccc6)c6ccccc6)cc5)cc4c23)cc1]

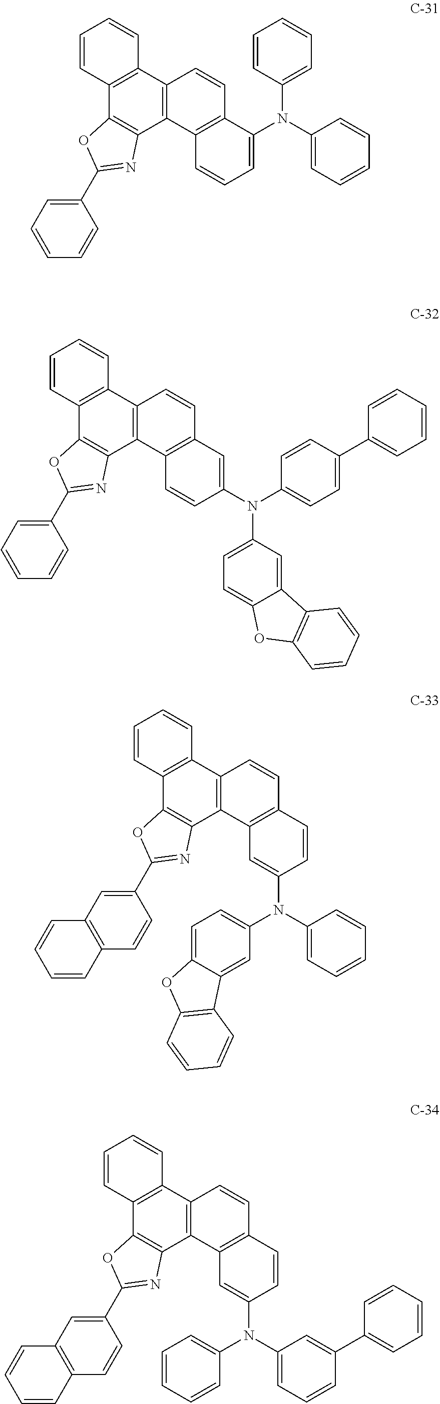 [SMILES: c1ccc(-c2nc3c(o2)c2ccccc2c2ccc4c(N(c5ccccc5)c5ccccc5)cccc4c23)cc1 ; c1ccc(-c2ccc(N(c3ccc4c(ccc5c6ccccc6c6oc(-c7ccccc7)nc6c45)c3)c3ccc4oc5ccccc5c4c3)cc2)cc1 ; c1ccc(N(c2ccc3oc4ccccc4c3c2)c2ccc3ccc4c5ccccc5c5oc(-c6ccc7ccccc7c6)nc5c4c3c2)cc1 ; c1ccc(-c2cccc(N(c3ccccc3)c3ccc4ccc5c6ccccc6c6oc(-c7ccc8ccccc8c7)nc6c5c4c3)c2)cc1]

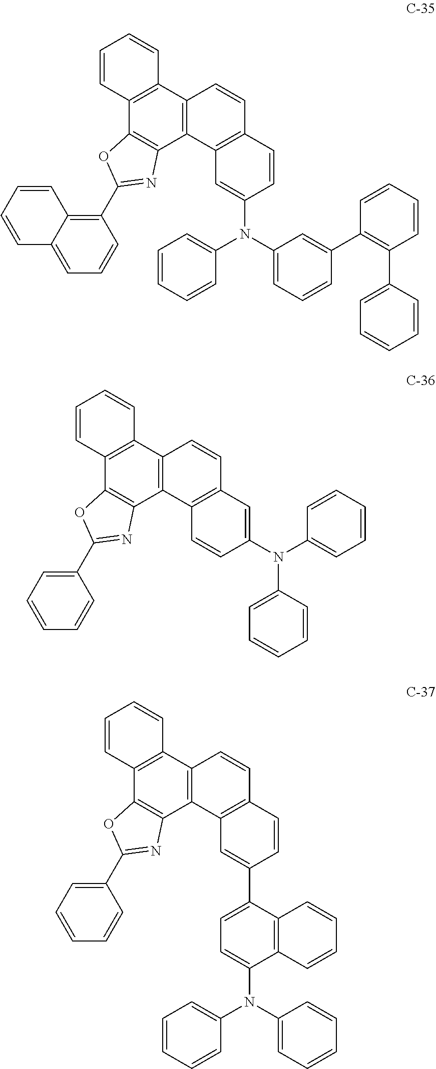 [SMILES: c1ccc(-c2ccccc2-c2cccc(N(c3ccccc3)c3ccc4ccc5c6ccccc6c6oc(-c7cccc8ccccc78)nc6c5c4c3)c2)cc1 ; c1ccc(-c2nc3c(o2)c2ccccc2c2ccc4cc(N(c5ccccc5)c5ccccc5)ccc4c23)cc1 ; c1ccc(-c2nc3c(o2)c2ccccc2c2ccc4ccc(-c5ccc(N(c6ccccc6)c6ccccc6)c6ccccc56)cc4c23)cc1]

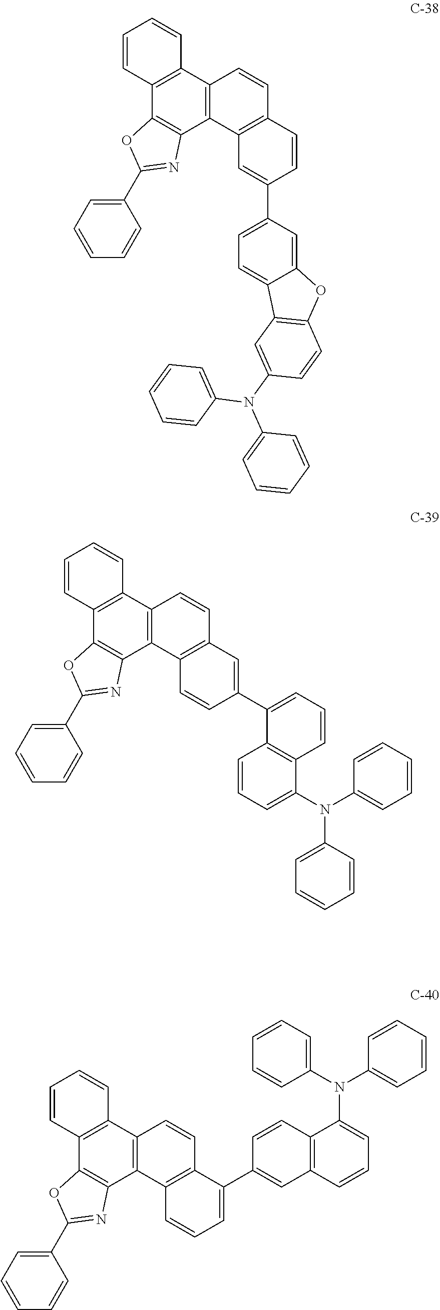 [SMILES: c1ccc(-c2nc3c(o2)c2ccccc2c2ccc4ccc(-c5ccc6c(c5)oc5ccc(N(c7ccccc7)c7ccccc7)cc56)cc4c23)cc1 ; c1ccc(-c2nc3c(o2)c2ccccc2c2ccc4cc(-c5cccc6c(N(c7ccccc7)c7ccccc7)cccc56)ccc4c23)cc1 ; c1ccc(-c2nc3c(o2)c2ccccc2c2ccc4c(-c5ccc6c(N(c7ccccc7)c7ccccc7)cccc6c5)cccc4c23)cc1]

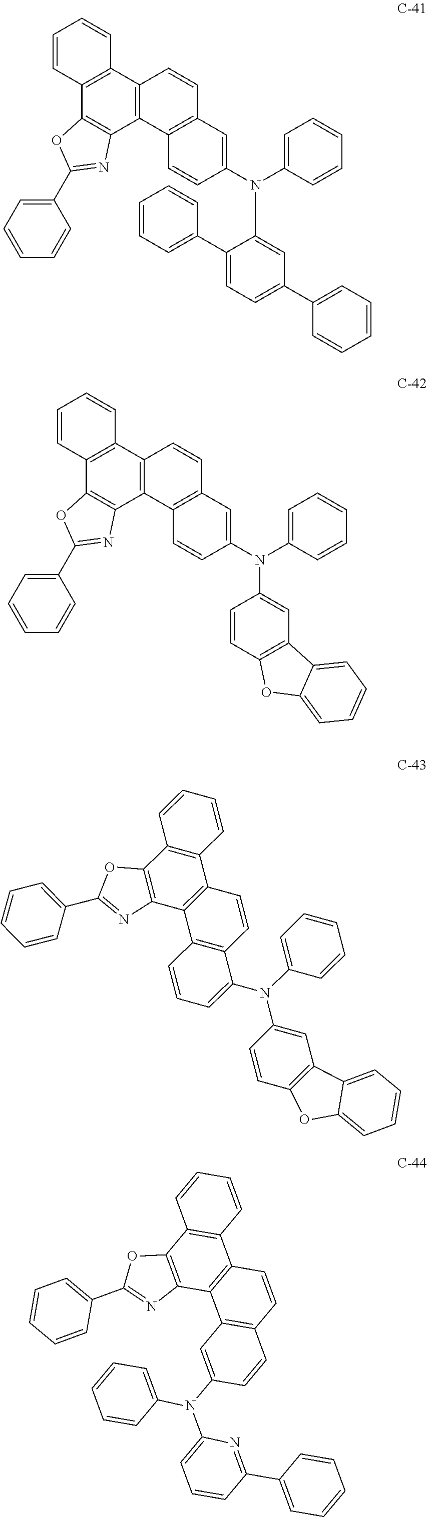 [SMILES: c1ccc(-c2ccc(-c3ccccc3)c(N(c3ccccc3)c3ccc4c(ccc5c6ccccc6c6oc(-c7ccccc7)nc6c45)c3)c2)cc1 ; c1ccc(-c2nc3c(o2)c2ccccc2c2ccc4cc(N(c5ccccc5)c5ccc6oc7ccccc7c6c5)ccc4c23)cc1 ; c1ccc(-c2nc3c(o2)c2ccccc2c2ccc4c(N(c5ccccc5)c5ccc6oc7ccccc7c6c5)cccc4c23)cc1 ; c1ccc(-c2cccc(N(c3ccccc3)c3ccc4ccc5c6ccccc6c6oc(-c7ccccc7)nc6c5c4c3)n2)cc1]

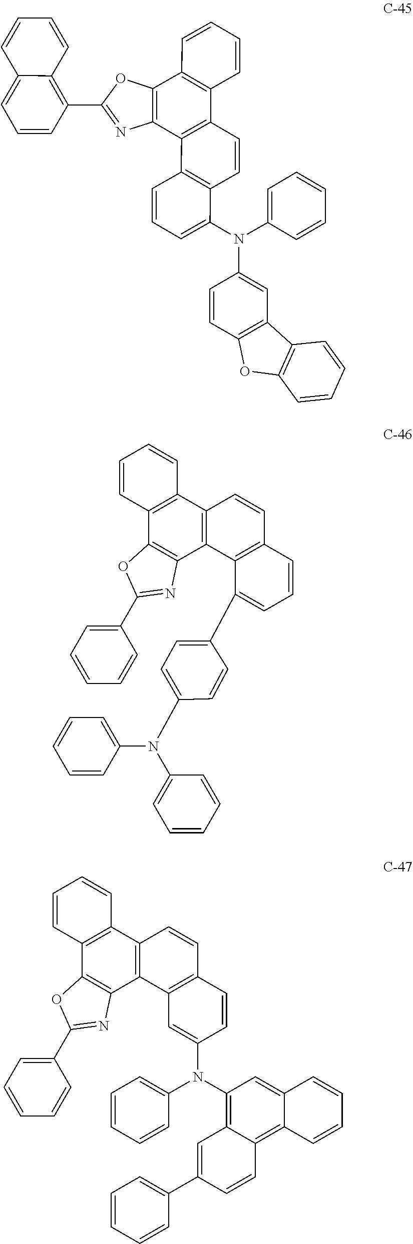 [SMILES: c1ccc(N(c2ccc3oc4ccccc4c3c2)c2cccc3c2ccc2c4ccccc4c4oc(-c5cccc6ccccc56)nc4c32)cc1 ; c1ccc(-c2nc3c(o2)c2ccccc2c2ccc4cccc(-c5ccc(N(c6ccccc6)c6ccccc6)cc5)c4c23)cc1 ; c1ccc(-c2ccc3c(c2)c(N(c2ccccc2)c2ccc4ccc5c6ccccc6c6oc(-c7ccccc7)nc6c5c4c2)cc2ccccc23)cc1]

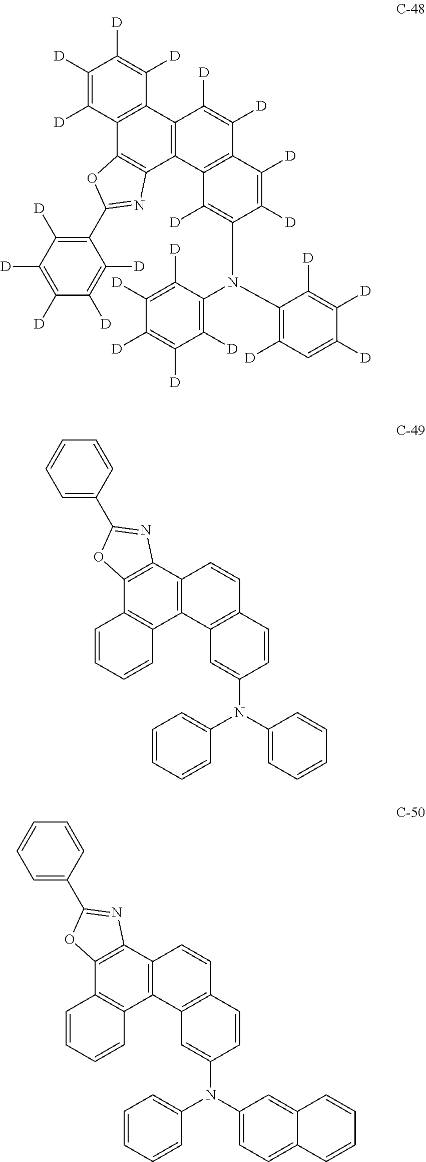 [SMILES: [2H]c1cc([2H])c(N(c2c([2H])c([2H])c([2H])c([2H])c2[2H])c2c([2H])c([2H])c3c([2H])c([2H])c4c5c([2H])c([2H])c([2H])c([2H])c5c5oc(-c6c([2H])c([2H])c([2H])c([2H])c6[2H])nc5c4c3c2[2H])c([2H])c1[2H] ; c1ccc(-c2nc3c4ccc5ccc(N(c6ccccc6)c6ccccc6)cc5c4c4ccccc4c3o2)cc1 ; c1ccc(-c2nc3c4ccc5ccc(N(c6ccccc6)c6ccc7ccccc7c6)cc5c4c4ccccc4c3o2)cc1]

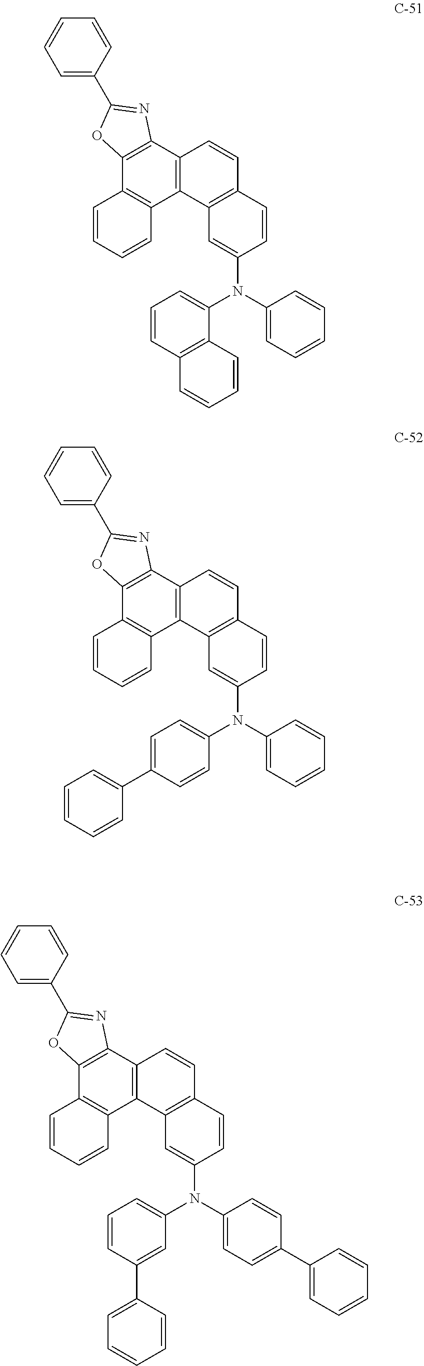 [SMILES: c1ccc(-c2nc3c4ccc5ccc(N(c6ccccc6)c6cccc7ccccc67)cc5c4c4ccccc4c3o2)cc1 ; c1ccc(-c2ccc(N(c3ccccc3)c3ccc4ccc5c6nc(-c7ccccc7)oc6c6ccccc6c5c4c3)cc2)cc1 ; c1ccc(-c2ccc(N(c3cccc(-c4ccccc4)c3)c3ccc4ccc5c6nc(-c7ccccc7)oc6c6ccccc6c5c4c3)cc2)cc1]

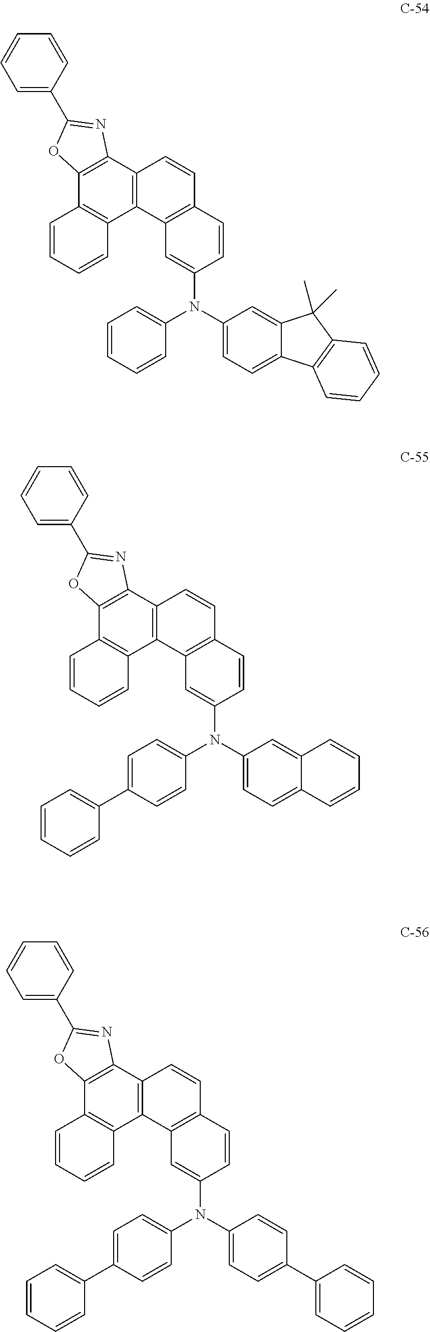 [SMILES: CC1(C)c2ccccc2-c2ccc(N(c3ccccc3)c3ccc4ccc5c6nc(-c7ccccc7)oc6c6ccccc6c5c4c3)cc21 ; c1ccc(-c2ccc(N(c3ccc4ccccc4c3)c3ccc4ccc5c6nc(-c7ccccc7)oc6c6ccccc6c5c4c3)cc2)cc1 ; c1ccc(-c2ccc(N(c3ccc(-c4ccccc4)cc3)c3ccc4ccc5c6nc(-c7ccccc7)oc6c6ccccc6c5c4c3)cc2)cc1]

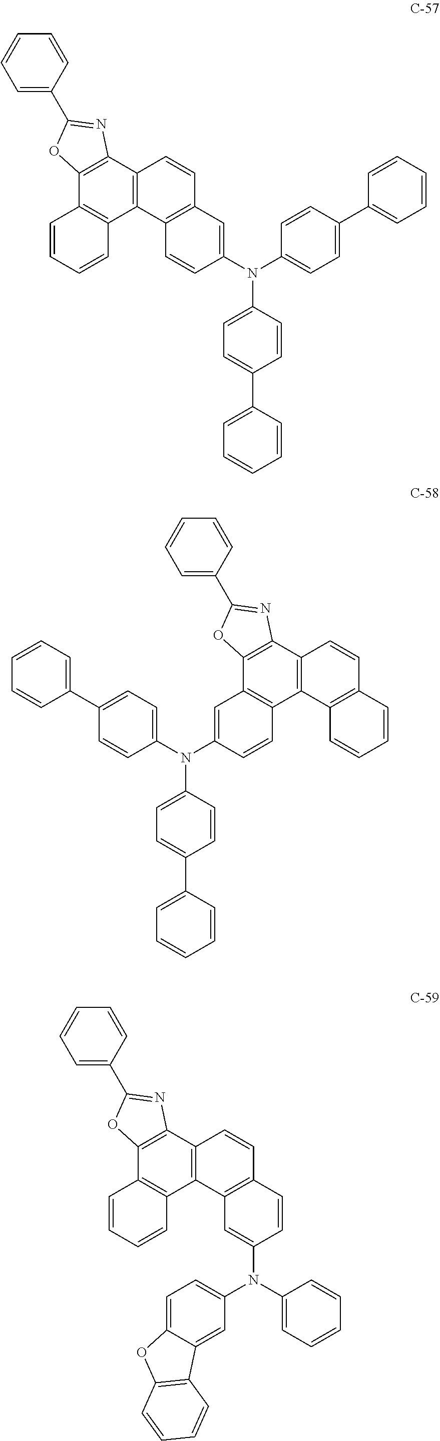 [SMILES: c1ccc(-c2ccc(N(c3ccc(-c4ccccc4)cc3)c3ccc4c(ccc5c6nc(-c7ccccc7)oc6c6ccccc6c45)c3)cc2)cc1 ; c1ccc(-c2ccc(N(c3ccc(-c4ccccc4)cc3)c3ccc4c(c3)c3oc(-c5ccccc5)nc3c3ccc5ccccc5c43)cc2)cc1 ; c1ccc(-c2nc3c4ccc5ccc(N(c6ccccc6)c6ccc7oc8ccccc8c7c6)cc5c4c4ccccc4c3o2)cc1]

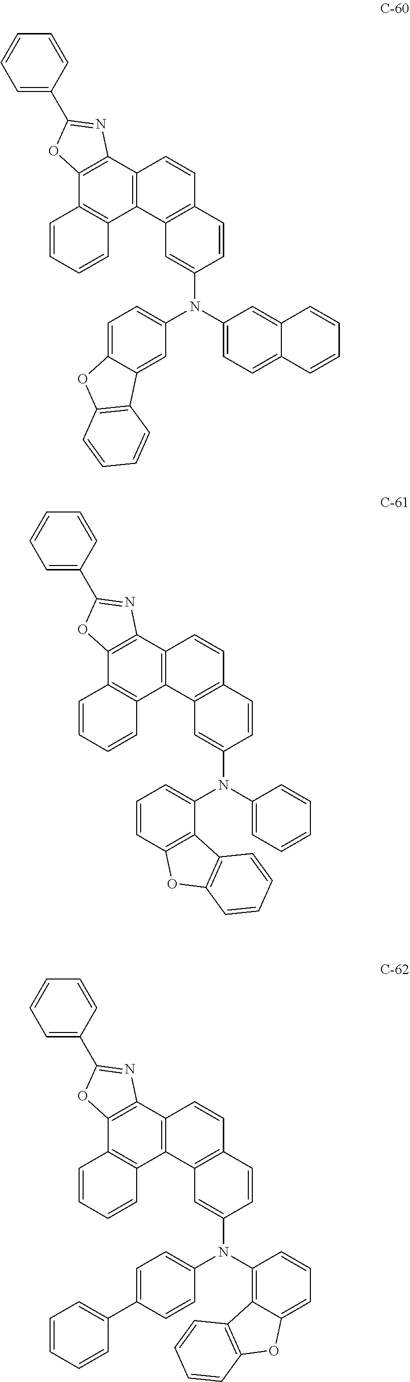 [SMILES: c1ccc(-c2nc3c4ccc5ccc(N(c6ccc7ccccc7c6)c6ccc7oc8ccccc8c7c6)cc5c4c4ccccc4c3o2)cc1 ; c1ccc(-c2nc3c4ccc5ccc(N(c6ccccc6)c6cccc7oc8ccccc8c67)cc5c4c4ccccc4c3o2)cc1 ; c1ccc(-c2ccc(N(c3ccc4ccc5c6nc(-c7ccccc7)oc6c6ccccc6c5c4c3)c3cccc4oc5ccccc5c34)cc2)cc1]

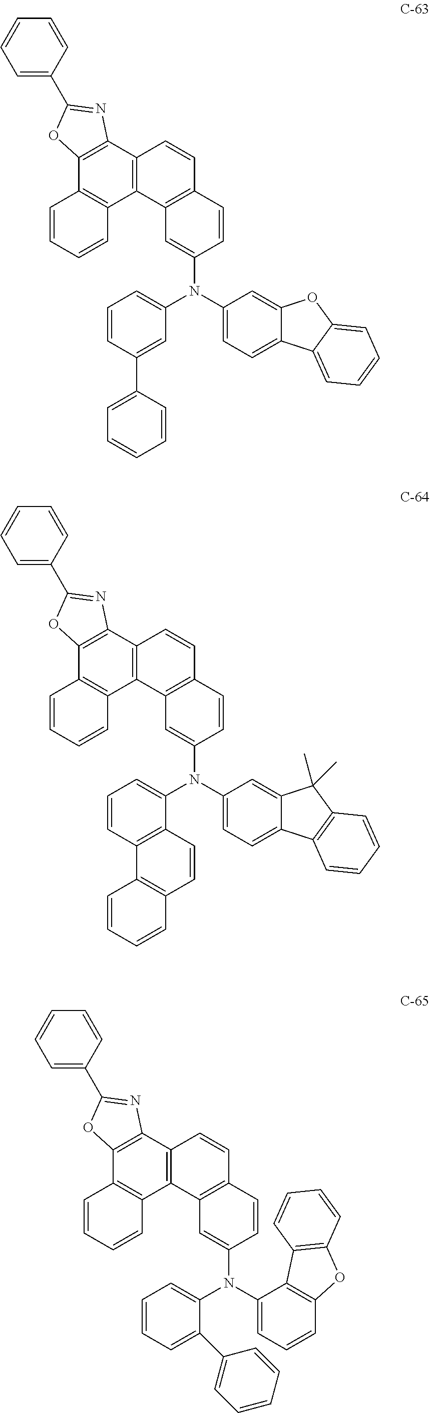 [SMILES: c1ccc(-c2cccc(N(c3ccc4c(c3)oc3ccccc34)c3ccc4ccc5c6nc(-c7ccccc7)oc6c6ccccc6c5c4c3)c2)cc1 ; CC1(C)c2ccccc2-c2ccc(N(c3ccc4ccc5c6nc(-c7ccccc7)oc6c6ccccc6c5c4c3)c3cccc4c3ccc3ccccc34)cc21 ; c1ccc(-c2nc3c4ccc5ccc(N(c6ccccc6-c6ccccc6)c6cccc7oc8ccccc8c67)cc5c4c4ccccc4c3o2)cc1]

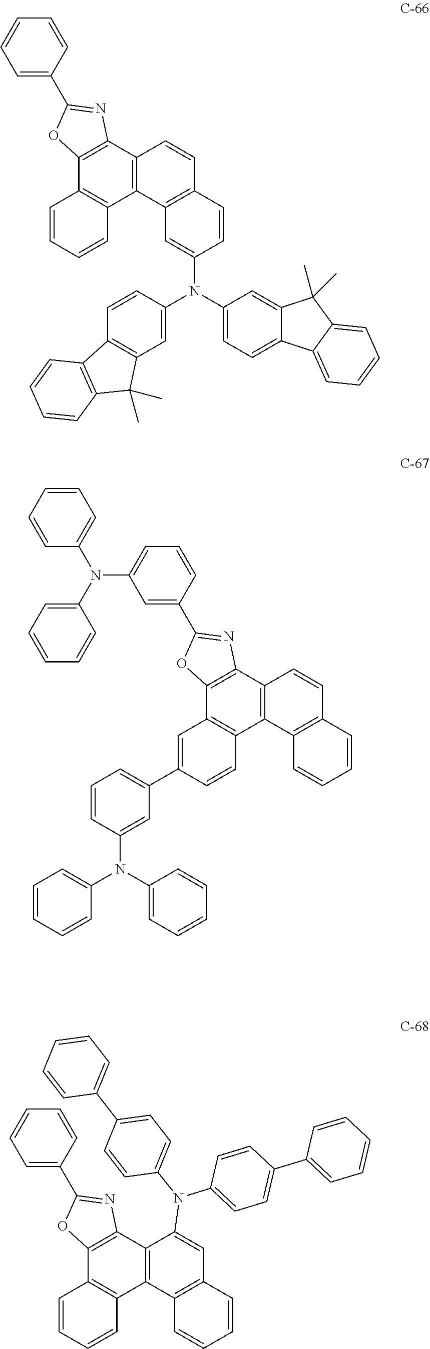 [SMILES: CC1(C)c2ccccc2-c2ccc(N(c3ccc4c(c3)C(C)(C)c3ccccc3-4)c3ccc4ccc5c6nc(-c7ccccc7)oc6c6ccccc6c5c4c3)cc21 ; c1ccc(N(c2ccccc2)c2cccc(-c3ccc4c(c3)c3oc(-c5cccc(N(c6ccccc6)c6ccccc6)c5)nc3c3ccc5ccccc5c43)c2)cc1 ; c1ccc(-c2ccc(N(c3ccc(-c4ccccc4)cc3)c3cc4ccccc4c4c5ccccc5c5oc(-c6ccccc6)nc5c34)cc2)cc1]

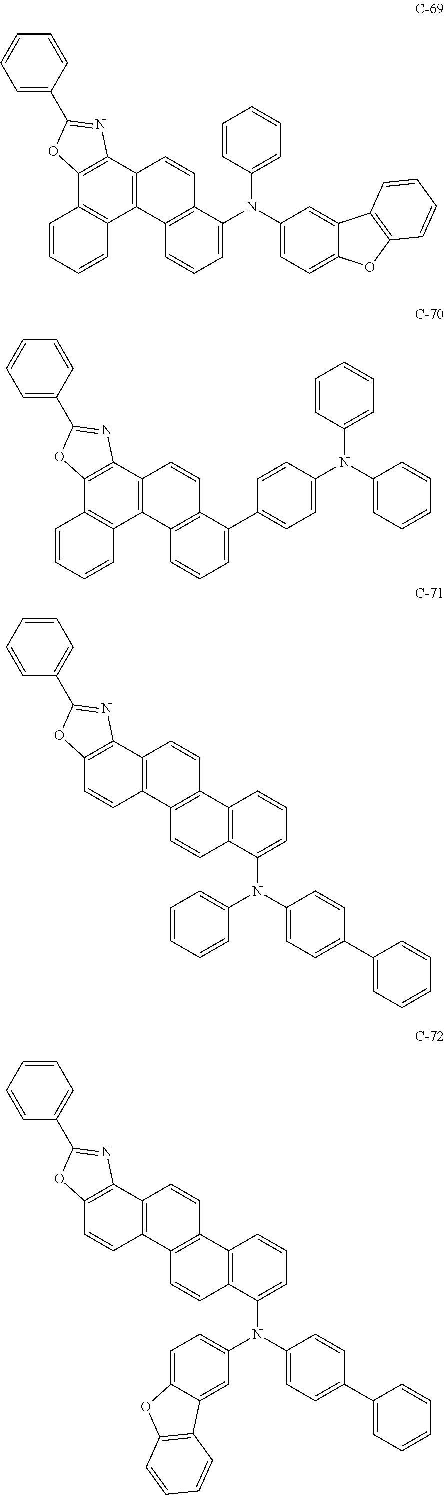 [SMILES: c1ccc(-c2nc3c4ccc5c(N(c6ccccc6)c6ccc7oc8ccccc8c7c6)cccc5c4c4ccccc4c3o2)cc1 ; c1ccc(-c2nc3c4ccc5c(-c6ccc(N(c7ccccc7)c7ccccc7)cc6)cccc5c4c4ccccc4c3o2)cc1 ; c1ccc(-c2ccc(N(c3ccccc3)c3cccc4c3ccc3c4ccc4c3ccc3oc(-c5ccccc5)nc34)cc2)cc1 ; c1ccc(-c2ccc(N(c3ccc4oc5ccccc5c4c3)c3cccc4c3ccc3c4ccc4c3ccc3oc(-c5ccccc5)nc34)cc2)cc1]

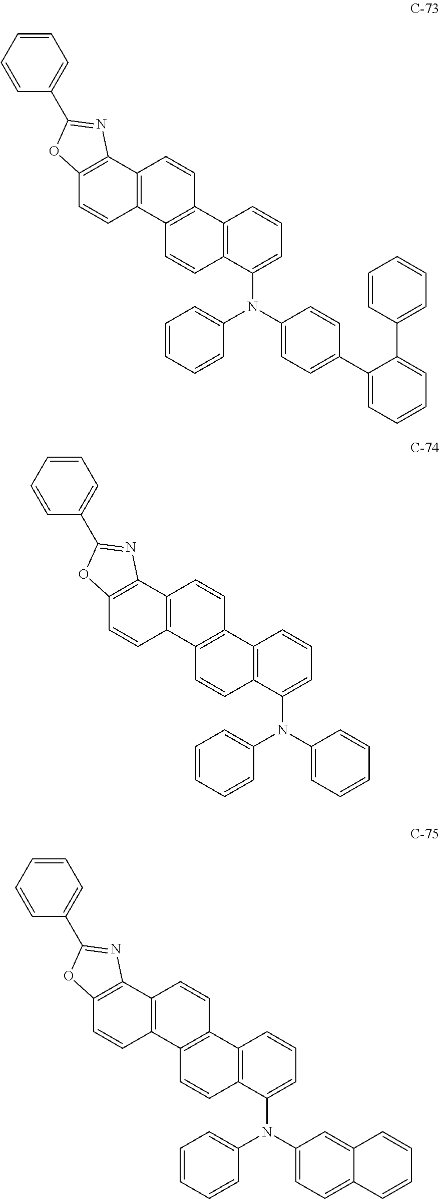 [SMILES: c1ccc(-c2nc3c(ccc4c5ccc6c(N(c7ccccc7)c7ccc(-c8ccccc8-c8ccccc8)cc7)cccc6c5ccc43)o2)cc1 ; c1ccc(-c2nc3c(ccc4c5ccc6c(N(c7ccccc7)c7ccccc7)cccc6c5ccc43)o2)cc1 ; c1ccc(-c2nc3c(ccc4c5ccc6c(N(c7ccccc7)c7ccc8ccccc8c7)cccc6c5ccc43)o2)cc1]

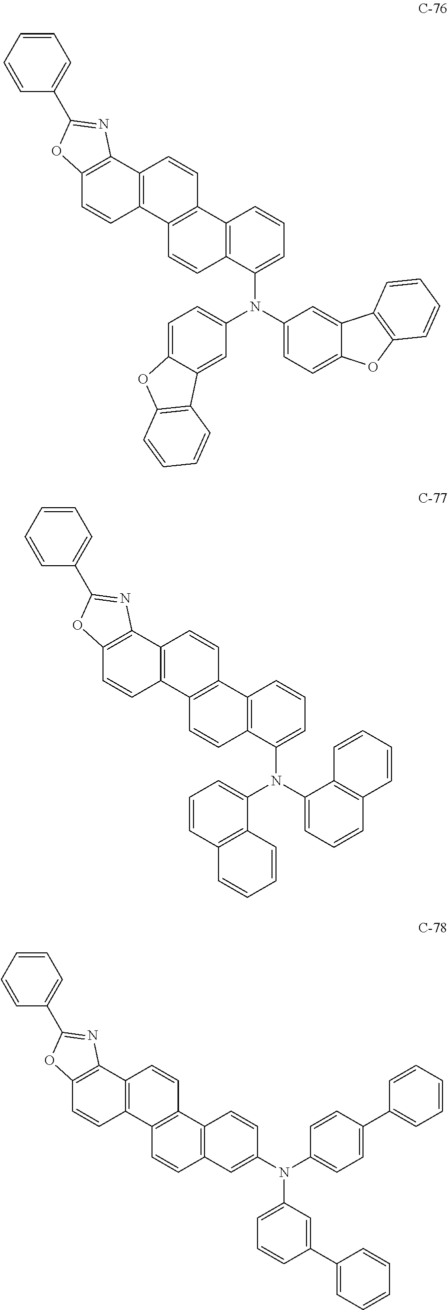 [SMILES: c1ccc(-c2nc3c(ccc4c5ccc6c(N(c7ccc8oc9ccccc9c8c7)c7ccc8oc9ccccc9c8c7)cccc6c5ccc43)o2)cc1 ; c1ccc(-c2nc3c(ccc4c5ccc6c(N(c7cccc8ccccc78)c7cccc8ccccc78)cccc6c5ccc43)o2)cc1 ; c1ccc(-c2ccc(N(c3cccc(-c4ccccc4)c3)c3ccc4c(ccc5c4ccc4c5ccc5oc(-c6ccccc6)nc54)c3)cc2)cc1]

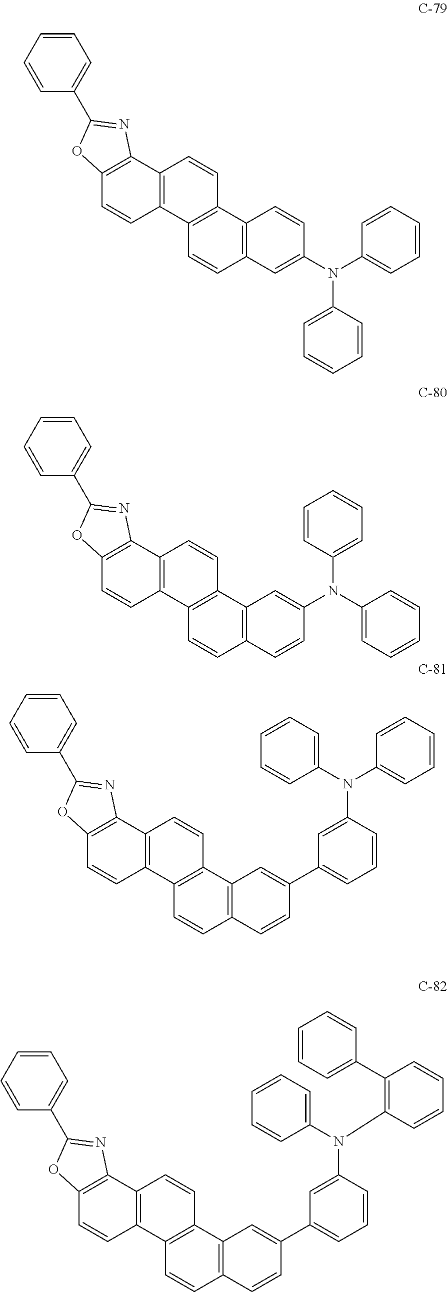 [SMILES: c1ccc(-c2nc3c(ccc4c5ccc6cc(N(c7ccccc7)c7ccccc7)ccc6c5ccc43)o2)cc1 ; c1ccc(-c2nc3c(ccc4c5ccc6ccc(N(c7ccccc7)c7ccccc7)cc6c5ccc43)o2)cc1 ; c1ccc(-c2nc3c(ccc4c5ccc6ccc(-c7cccc(N(c8ccccc8)c8ccccc8)c7)cc6c5ccc43)o2)cc1 ; c1ccc(-c2nc3c(ccc4c5ccc6ccc(-c7cccc(N(c8ccccc8)c8ccccc8-c8ccccc8)c7)cc6c5ccc43)o2)cc1]

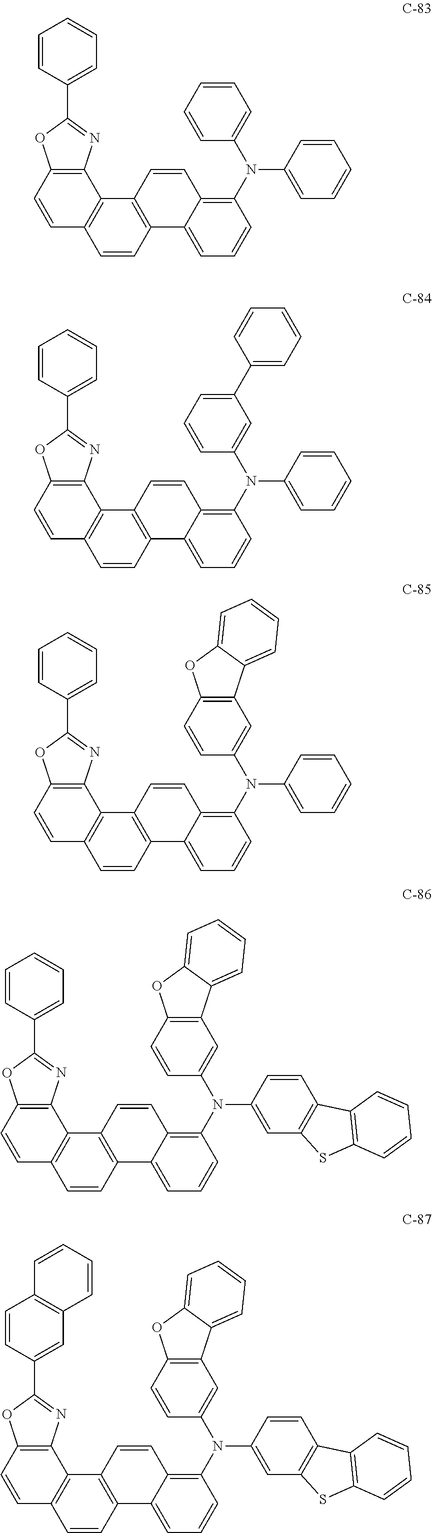

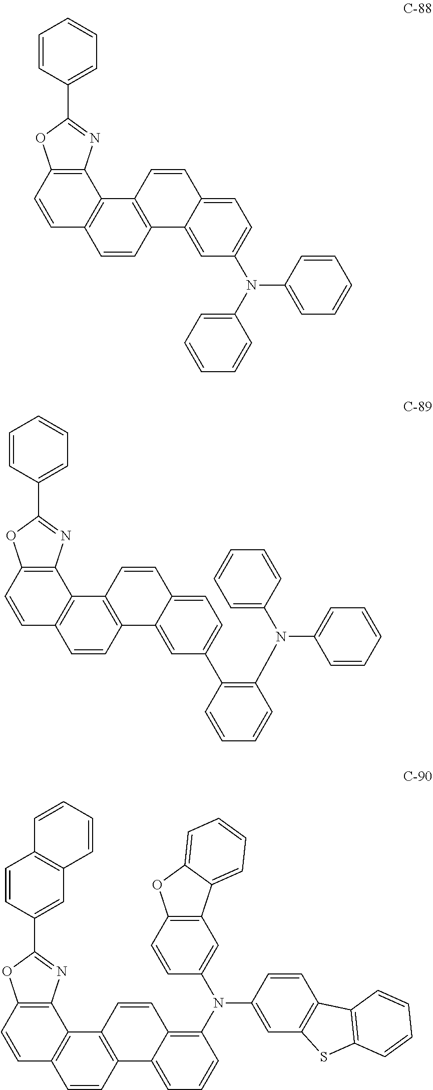 [SMILES: c1ccc(-c2nc3c(ccc4ccc5c6cc(N(c7ccccc7)c7ccccc7)ccc6ccc5c43)o2)cc1 ; c1ccc(-c2nc3c(ccc4ccc5c6cc(-c7ccccc7N(c7ccccc7)c7ccccc7)ccc6ccc5c43)o2)cc1 ; c1ccc2cc(-c3nc4c(ccc5ccc6c7cccc(N(c8ccc9c(c8)sc8ccccc89)c8ccc9oc%10ccccc%10c9c8)c7ccc6c54)o3)ccc2c1]

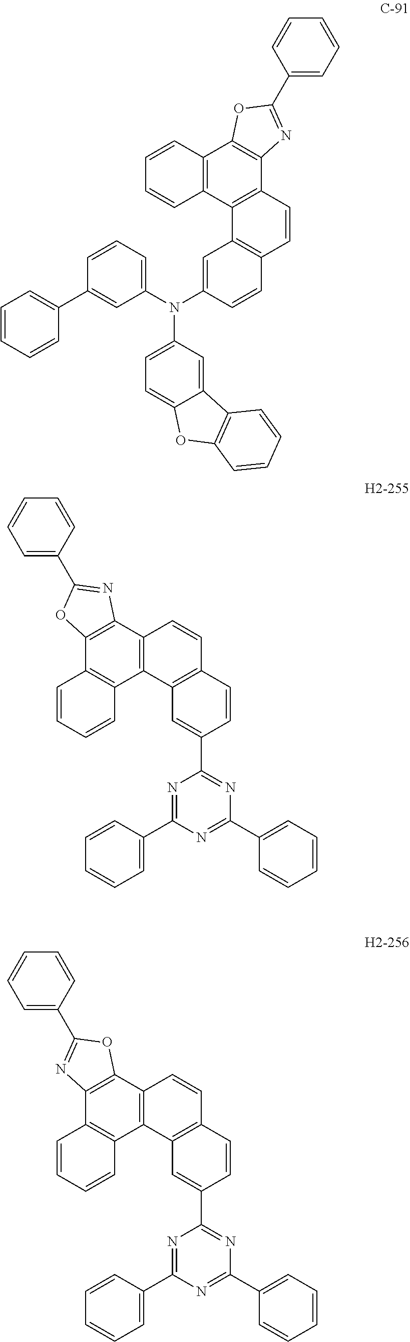 [SMILES: c1ccc(-c2cccc(N(c3ccc4oc5ccccc5c4c3)c3ccc4ccc5c6nc(-c7ccccc7)oc6c6ccccc6c5c4c3)c2)cc1 ; c1ccc(-c2nc(-c3ccccc3)nc(-c3ccc4ccc5c6nc(-c7ccccc7)oc6c6ccccc6c5c4c3)n2)cc1 ; c1ccc(-c2nc(-c3ccccc3)nc(-c3ccc4ccc5c6oc(-c7ccccc7)nc6c6ccccc6c5c4c3)n2)cc1]

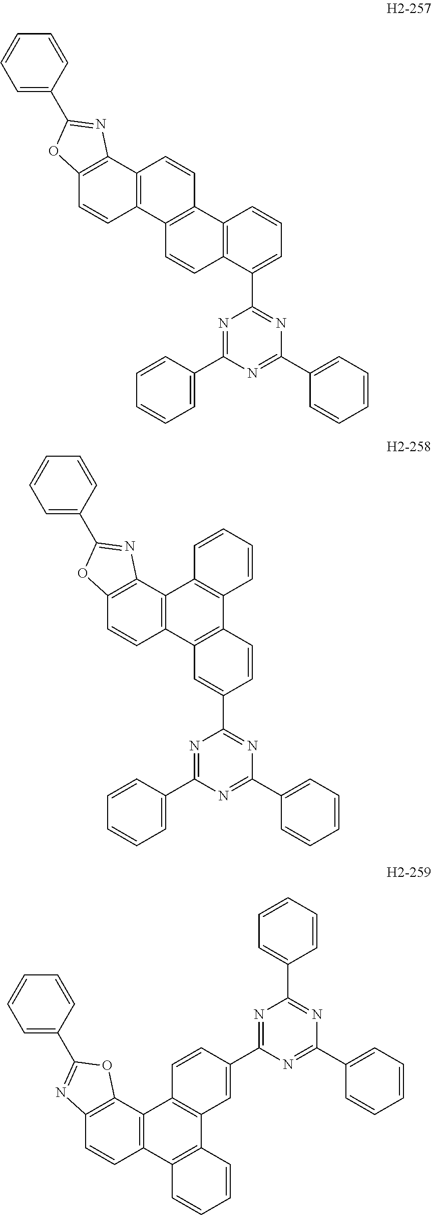 [SMILES: c1ccc(-c2nc(-c3ccccc3)nc(-c3cccc4c3ccc3c4ccc4c3ccc3oc(-c5ccccc5)nc34)n2)cc1 ; c1ccc(-c2nc(-c3ccccc3)nc(-c3ccc4c5ccccc5c5c(ccc6oc(-c7ccccc7)nc65)c4c3)n2)cc1 ; c1ccc(-c2nc(-c3ccccc3)nc(-c3ccc4c(c3)c3ccccc3c3ccc5nc(-c6ccccc6)oc5c34)n2)cc1]

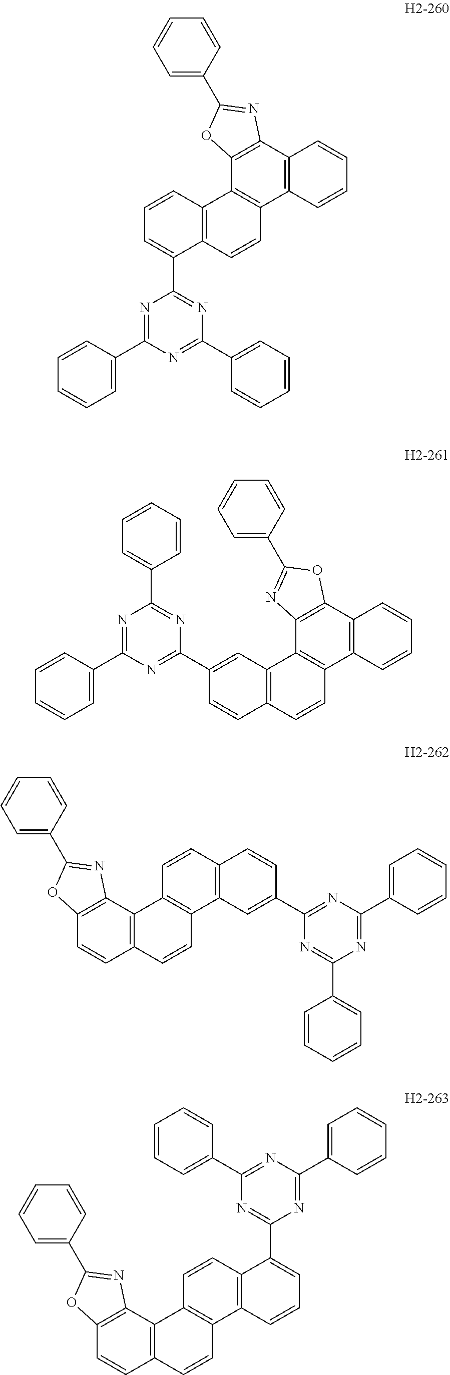 [SMILES: c1ccc(-c2nc(-c3ccccc3)nc(-c3cccc4c3ccc3c5ccccc5c5nc(-c6ccccc6)oc5c43)n2)cc1 ; c1ccc(-c2nc(-c3ccccc3)nc(-c3ccc4ccc5c6ccccc6c6oc(-c7ccccc7)nc6c5c4c3)n2)cc1 ; c1ccc(-c2nc(-c3ccccc3)nc(-c3ccc4ccc5c(ccc6ccc7oc(-c8ccccc8)nc7c65)c4c3)n2)cc1 ; c1ccc(-c2nc(-c3ccccc3)nc(-c3cccc4c3ccc3c4ccc4ccc5oc(-c6ccccc6)nc5c43)n2)cc1]

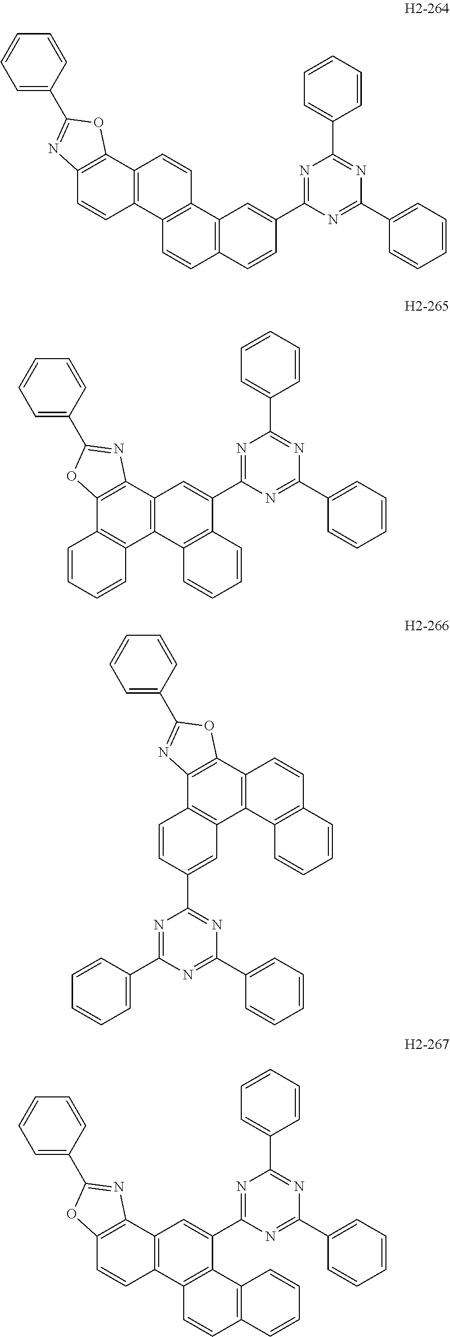

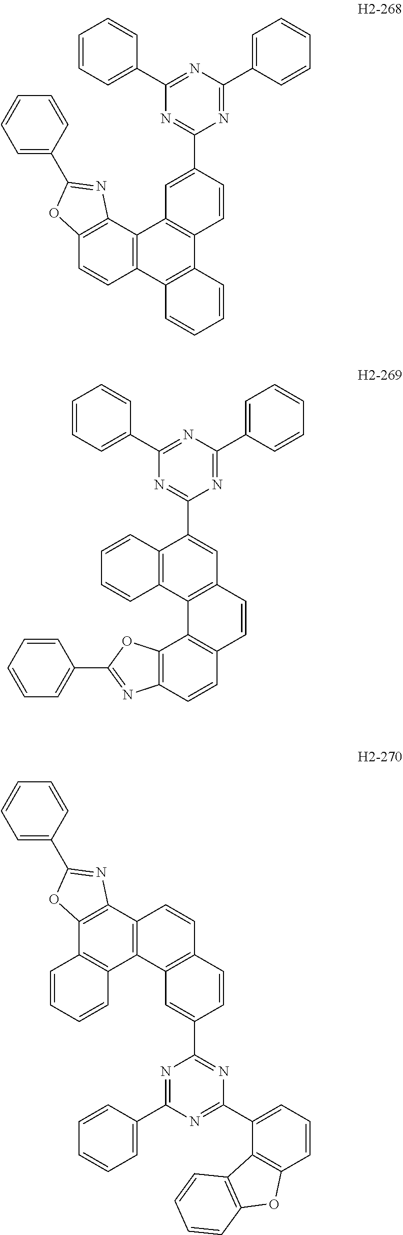 [SMILES: c1ccc(-c2nc(-c3ccccc3)nc(-c3ccc4c5ccccc5c5ccc6oc(-c7ccccc7)nc6c5c4c3)n2)cc1 ; c1ccc(-c2nc(-c3ccccc3)nc(-c3cc4ccc5ccc6nc(-c7ccccc7)oc6c5c4c4ccccc34)n2)cc1 ; c1ccc(-c2nc(-c3ccc4ccc5c6nc(-c7ccccc7)oc6c6ccccc6c5c4c3)nc(-c3cccc4oc5ccccc5c34)n2)cc1]

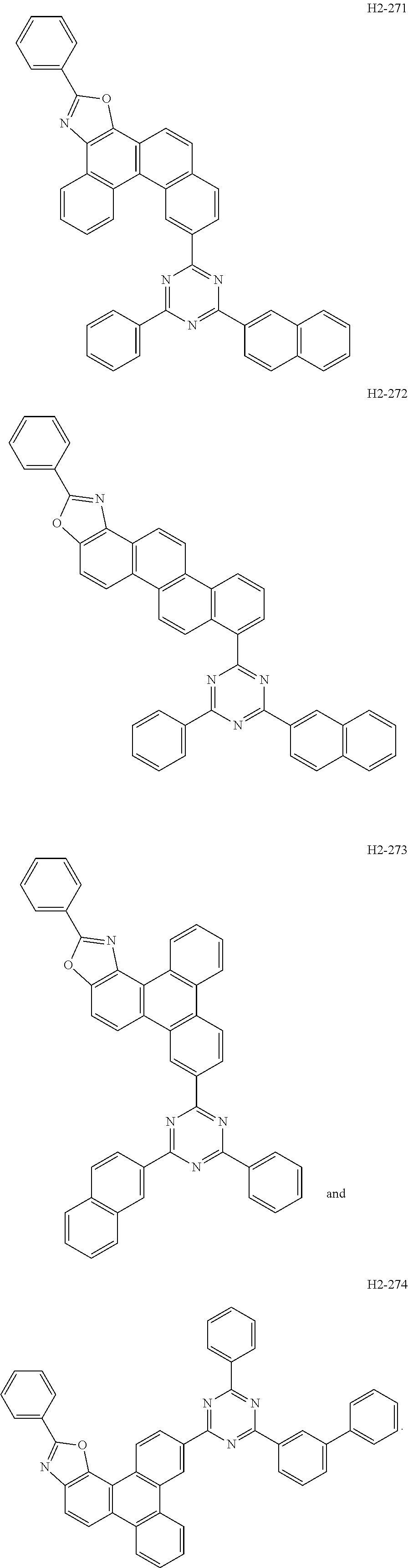 [SMILES: c1ccc(-c2nc(-c3ccc4ccccc4c3)nc(-c3ccc4ccc5c6oc(-c7ccccc7)nc6c6ccccc6c5c4c3)n2)cc1 ; c1ccc(-c2nc(-c3ccc4ccccc4c3)nc(-c3cccc4c3ccc3c4ccc4c3ccc3oc(-c5ccccc5)nc34)n2)cc1 ; c1ccc(-c2nc(-c3ccc4ccccc4c3)nc(-c3ccc4c5ccccc5c5c(ccc6oc(-c7ccccc7)nc65)c4c3)n2)cc1 ; c1ccc(-c2cccc(-c3nc(-c4ccccc4)nc(-c4ccc5c(c4)c4ccccc4c4ccc6nc(-c7ccccc7)oc6c45)n3)c2)cc1]

17. An organic electroluminescent device comprising an organic electroluminescent compound according to claim 12.
